(19) United States
(12) Patent Application Publication
(10) Pub. No.: US 2025/0063935 A1
(43) Pub. Date: Feb. 20, 2025

(54) COMPOSITION, AND METHOD FOR MANUFACTURING ORGANIC ELECTROLUMINESCENT ELEMENT

(71) Applicant: Mitsubishi Chemical Corporation, Tokyo (JP)

(72) Inventors: Yuki OHSHIMA, Tokyo (JP); Yoshimasa BANDO, Tokyo (JP); Manabu SAKURAI, Tokyo (JP); Koji ADACHI, Tokyo (JP); Keiko SAITO, Tokyo (JP)

(73) Assignee: Mitsubishi Chemical Corporation, Tokyo (JP)

(21) Appl. No.: 18/653,055

(22) Filed: May 2, 2024

Related U.S. Application Data
(63) Continuation of application No. PCT/JP2022/040870, filed on Nov. 1, 2022.

(30) Foreign Application Priority Data
Nov. 12, 2021 (JP) 2021-184744

(51) Int. Cl. H10K 85/10; H10K 71/13; H10K 85/20; H10K 85/60

(52) U.S. Cl. CPC H10K 85/111; H10K 71/135; H10K 85/151; H10K 85/20; H10K 85/615; H10K 85/631; H10K 85/6572; H10K 85/658

(57) ABSTRACT

A composition including at least one high-molecular weight charge transport compound having a weight average molecular weight of 10,000 or more and having a crosslinking group; at least one low-molecular weight charge transport compound having a molecular weight of 5,000 or less and having a crosslinking group; and at least one aromatic organic solvent, wherein the low-molecular weight charge transport compound is a compound represented by formula (71) below, and the like. A method for manufacturing an organic electroluminescent element including the step of applying this composition to regions separated by a partition wall layer by printing using an inkjet method, the step of vacuum-drying the printed composition in a vacuum chamber to volatilize the organic solvent, and the step of baking the vacuum-dried composition at high temperature.

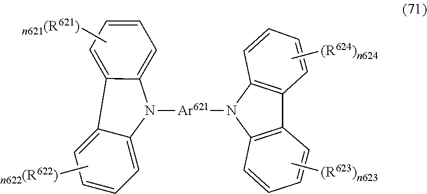

### TECHNICAL FIELD

The present invention relates to a composition preferably used to form a functional organic film formed from functional materials in the manufacture of an organic electroluminescent element and a method for manufacturing an organic electroluminescent element using the composition.

### BACKGROUND ART

One common method for manufacturing an organic electroluminescent element includes depositing organic materials by a vacuum vapor deposition method to stack films. In recent years, a manufacturing method using wet deposition in which organic materials in solution form are deposited by, for example, an inkjet method to stack films has been actively investigated as a manufacturing method with higher material utilization efficiency.

In the manufacture of an organic electroluminescent element, particularly an organic EL display, by wet deposition, it is contemplated to use a method including: forming pixels separated by partition walls called banks; and ejecting inks, which are organic electroluminescent element-forming compositions for forming organic films included in the organic electroluminescent element, into the small regions surrounded by the banks using an inkjet method. In techniques proposed to obtain flatter films in the regions surrounded by the banks with the above method (PTL 1 and PTL 2), various surface modifiers are mixed with the inks.

However, with the conventional techniques, the flatness of the films in the regions surrounded by the banks is insufficient.

PTL 3 discloses a technique that uses two or more solvents with different boiling points for the purpose of forming a functional layer having a substantially flat cross-sectional shape after drying and curing.

In particular, when an inkjet device etc. is used to apply an ink to the regions separated by the banks (partition walls) to form a film, a sufficient amount of the ink is generally applied so as to be spread over the entire separated regions, and then a solvent component is volatilized by drying means such as vacuum drying to obtain a functional film.

As the ink dries in the separated regions, the edges of the ink on the side surfaces of the banks gradually recede, and the concentration of the ink gradually increases, so that a functional film is finally formed.

However, if a self-pinning phenomenon occurs in which the movement of the edge of the ink on the side surface of a bank stops at an intermediate point due to the difference in wettability of the side surface of the bank and a change in the shape of the side surface of the bank, the edge of the ink cannot recede sufficiently along the side surface of the bank. When the self-pinning occurs at the intermediate point on the side surface of the bank as described above, the functional film formed has a shape rising along the side surface of the bank. Therefore, the film is unlikely to be a flat film having a uniform thickness.

The occurrence of the self-pinning phenomenon can be checked by measuring the receding contact angle of the ink on the side wall of the bank.

However, it is difficult to measure the receding contact angle on a side wall of a bank having a complicated structure and complicated surface properties, and one problem in this case is that the receding contact angle is difficult to control. Moreover, as the ink dries, its viscosity increases as the temperature increases during the drying process. A problem in this case is that the ink loses its flowability and this results in self-pinning.

### CITATION LIST

### Patent Literature

PTL 1: WO2010/104183
PTL 2: JP2002-056980A
PTL 3: JP2015-185640A

### SUMMARY OF INVENTION

### Technical Problem

It is an object of the invention to improve the uniformity of the film thickness in regions surrounded by banks when an organic film included in an organic electroluminescent element is formed by wet deposition.

### Solution to Problem

The present inventors have found that, when an organic film included in an organic electroluminescent element is formed in regions separated by banks by wet deposition, the occurrence of self-pinning can be prevented and the film formed can have a flat shape while the characteristics of the organic electroluminescent element are maintained by forming the film using a functional layer-forming composition including a specific low-molecular weight charge transport compound having a crosslinking group, a high-molecular weight charge transport compound having a crosslinking group, and an aromatic organic solvent.

The present invention has the following gist.
[1]A composition comprising: at least one high-molecular weight charge transport compound having a weight average molecular weight of 10,000 or more and having a crosslinking group; at least one low-molecular weight charge transport compound having a molecular weight of 5,000 or less and having a crosslinking group; and at least one aromatic organic solvent,
   wherein the low-molecular weight charge transport compound is selected from the group consisting of a compound represented by formula (71) below, a compound represented by formula (72) below, a compound represented by formula (73) below, a compound represented by formula (74) below, a compound represented by formula (75) below, a compound represented by formula (1) below, and a compound represented by formula (2) below,

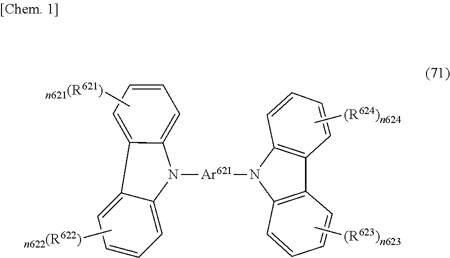

(wherein, in formula (71),
   Ar⁶²¹ represents a divalent aromatic hydrocarbon group having 6 to 50 carbon atoms and optionally having a substituent;
   R⁶²¹, R⁶²², R⁶²³, and R⁶²⁴ each independently represent a deuterium atom, a halogen atom, a monovalent aromatic hydrocarbon group having 6 to 50 carbon atoms and optionally having and/or a crosslinking group, or a crosslinking group;
   formula (71) includes at least two crosslinking groups; and
   n621, n622, n623, and n624 are each independently an integer of 0 to 4.
   However, the sum of n621, n622, n633, and n624 is 1 or more),

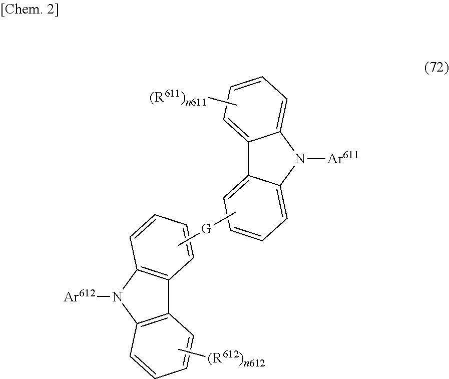

(wherein, in formula (72),
   Ar⁶¹¹ and Ar⁶¹² each independently represent a divalent aromatic hydrocarbon group having 6 to 50 carbon atoms and optionally having a substituent and/or a crosslinking group;
   R⁶¹¹ and R⁶¹² are each independently a deuterium atom, a halogen atom, a monovalent aromatic hydrocarbon group having 6 to 50 carbon atoms and optionally having a substituent and/or a crosslinking group, or a crosslinking group;
   G represents a single bond or a divalent aromatic hydrocarbon group having 6 to 50 carbon atoms and optionally having a substituent and/or a crosslinking group;
   the compound represented by formula (72) has at least two crosslinking groups; and
   n⁶¹¹ and n⁶¹² are each independently an integer of 0 to 4),

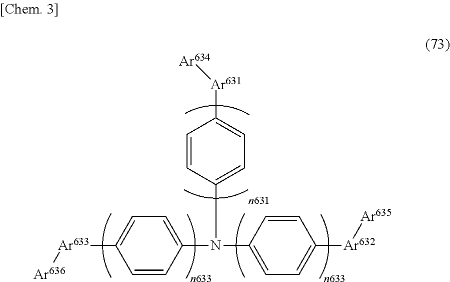

(wherein, in formula (73),
   Ar⁶³¹, Ar⁶³², and Ar⁶³³ each independently represent a direct bond or an aromatic hydrocarbon group having 6 to 30 carbon atoms optionally having a monovalent substituent;
   Ar⁶³⁴, Ar⁶³⁵, and Ar⁶³⁶ are each independently a monovalent aromatic hydrocarbon group having 6 to 30 carbon atoms or a monovalent aromatic heterocyclic group having 3 to 24 carbon atoms, and the monovalent aromatic hydrocarbon group and the monovalent aromatic heterocyclic group may each optionally have a substituent or a crosslinking group;
   at least two selected from Ar⁶³⁴, Ar⁶³⁵, and Ar⁶³⁶ each have a crosslinking group;
   n⁶³¹, n⁶³², and n⁶³³ each independently represent an integer of 0 to 3; and
   the crosslinking groups included in Ar⁶³⁴, Ar⁶³⁵, and Ar⁶³⁶ are each independently formula (a) or (b) below),

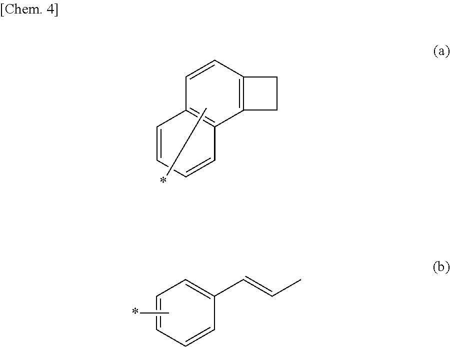

(wherein, in formulas (a) and (b), * represents a position of bonding to Ar⁶³⁴, Ar⁶³⁵, or Ar⁶³⁶),

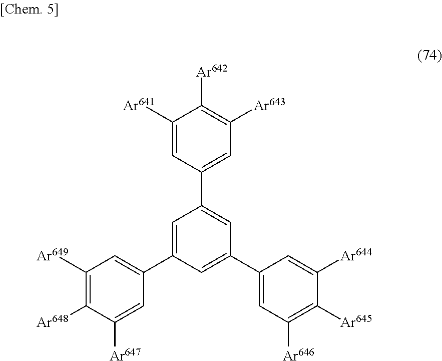

(wherein, in formula (74),
   Ar⁶⁴¹ to Ar⁶⁴⁹ each independently represent a hydrogen atom, a benzene ring structure optionally having a substituent and/or a crosslinking group, or a structure in which 2 to 10 benzene ring structures each optionally having a substituent and/or a crosslinking group are linked together in a non-branched or branched manner; and
   the compound represented by formula (74) has at least two crosslinking groups),

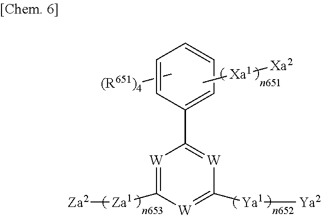

(wherein, in formula (75),
   W's each independently represent CH or N, and at least one W is N;
   Xa¹, Ya¹, and Za¹ each independently represent a divalent aromatic hydrocarbon group having 6 to 30 carbon atoms and optionally having a substituent or a divalent aromatic heterocyclic group having 3 to 30 carbon atoms and optionally having a substituent;
   Xa², Ya², and Za² each independently represent a hydrogen atom, an aromatic hydrocarbon group having 6 to 30 carbon atoms and optionally having a substituent and/or a crosslinking group, an aromatic heterocyclic group having 3 to 30 carbon atoms and optionally having a substituent and/or a crosslinking group, or a crosslinking group;
   n651, n652, and n653 each independently represent an integer of 0 to 6;
   at least one of n651, n652, and n653 is an integer of 1 or more;
   when n651 is 2 or more, a plurality of Xa¹'s present may be the same or different;
   when n652 is 2 or more, a plurality of Ya¹'s present may be the same or different;
   when n653 is 2 or more, a plurality of Za¹'s present may be the same or different;
   at least two of Xa², Ya², and Za² each have a crosslinking group;
   each of four R⁶⁵¹'s represents a hydrogen atom or a substituent, and the four R⁶⁵¹'s may be the same or different; and
   when n651, n652, or n653 is 0, a corresponding one of Xa², Ya², and Za² is not a hydrogen atom),

[Chem. 7]

CHₓA₍₄₋ₓ₎ (1)
(wherein, in formula (1),
   C represents a carbon atom, and H represents a hydrogen atom;
   A's each independently represent a substituent represented by formula (2′) below; and
   x represents an integer of 0 to 2),

[Chem. 8]

*-(L²¹)_{y}-(CL²¹)_{z} (2′)
(wherein, in formula (2′),
   L²¹'s each independently represent a bonding group optionally having a substituent;
   CL²¹'s each independently represent a crosslinking group represented by formula (3) below;
   * represents a direct bond to the carbon atom in formula (1);
   y represents an integer of 1 to 6, and z represents an integer of 0 to 4;
   when z is 0, a hydrogen atom instead of CL²¹ is bonded to a bonding group L²¹; and
   three or more CL²¹'s are present in the compound represented by formula (1)),

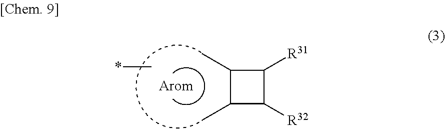

(wherein, in formula (3),
   Arom represents an aromatic ring having 3 to 30 carbon atoms and optionally having a substituent;
   R³¹ and R³² each independently represent a hydrogen atom or an alkyl group;
   * represents a direct bond to L²¹ in formula (2′), and the direct bond to formula (2′) is bonded to Arom),

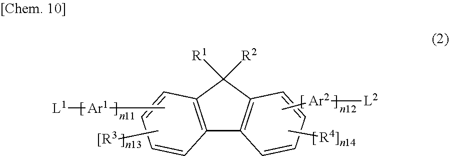

(wherein, in formula (2),
   Ar¹ and Ar² each independently represent a divalent aromatic group having 6 to 60 carbon atoms and optionally having a substituent;
   R¹, R², R³, and R⁴ each independently represent an alkyl group optionally having a substituent or an aromatic group optionally having a substituent;
   R¹ and R², R³'s, or R⁴'s may be bonded together to form a ring;
   L¹ and L² each independently represent a crosslinking group;
   n11 and n12 each independently represent an integer of 0 to 5; and
   n13 and n14 each independently represent an integer of 0 to 3).
[2] The composition according to [1], further comprising at least one electron accepting compound having a fluorine atom and a crosslinking group in a molecular structure thereof.
[3] The composition according to [1] or [2], wherein each crosslinking group included in the high-molecular weight charge transport compound, each crosslinking group included in the low-molecular weight charge transport compound (except for the crosslinking groups included in Ar⁶³⁴, Ar⁶³⁵, and Ar⁶³⁶ in formula (73) above), and each crosslinking group included in the electron accepting compound are each selected from the following group T of crosslinking groups:
<group T of crosslinking groups>

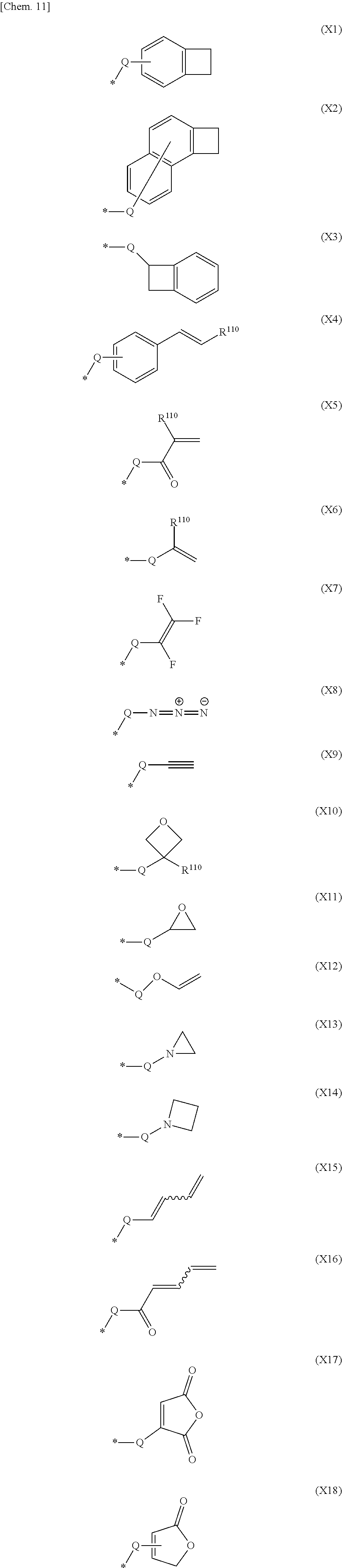

(wherein, in formulas (X1) to (X18), Q represents a direct bond or a linking group;
   * represents a bonding position;
   R¹¹⁰ in each of formulas (X4), (X5), (X6), and (X10) represents a hydrogen atom or an alkyl group optionally having a substituent;
   each of the benzene rings and the naphthalene ring in formula (X1) to (X4) may optionally have a substituent, and any of the substituents may be bonded together to form a ring; and
   each cyclobutene ring in formula (X1) to (X3) may optionally have a substituent).
[4] The composition according to [3], wherein at least one of the high-molecular weight charge transport compound, the low-molecular weight charge transport compound, and the electron accepting compound includes a crosslinking group represented by formula (X2) or (X4) included in the group T of crosslinking groups.
[5] The composition according to [3] or [4], wherein Q is a divalent aromatic hydrocarbon group optionally having a substituent.
[6] The composition according to any one of [1] to [5], wherein the high-molecular weight charge transport compound having a crosslinking group includes a repeating unit represented by formula (50) below:

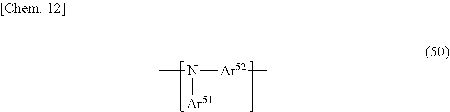

(wherein, in formula (50),
   Ar⁵¹ represents an aromatic hydrocarbon group, an aromatic heterocyclic group, or a group in which a plurality of groups selected from aromatic hydrocarbon groups and aromatic heterocyclic groups are linked together;
   Ar⁵² represents a divalent aromatic hydrocarbon group, a divalent aromatic heterocyclic group, or a divalent group in which a plurality of groups selected from the group consisting of divalent aromatic hydrocarbon groups and divalent aromatic heterocyclic groups are linked together directly or via a linking group;
   Ar⁵¹ and Ar⁵² do not form a ring via a single bond or a linking group; and
Ar⁵¹ and Ar⁵² may each optionally have a substituent and/or a crosslinking group).
[7] The composition according to [6], wherein the repeating unit represented by formula (50) is a repeating unit represented by the following formula (60):

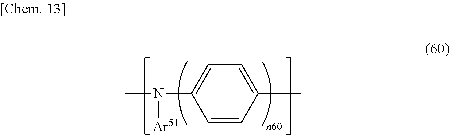

(wherein, in formula (60),
   Ar⁵¹ is the same as Ar⁵¹ in formula (50) above; and
   n60 represents an integer of 1 to 5).
[8] The composition according to [6], wherein the repeating unit represented by formula (50) is a repeating unit represented by formula (54), (55), (56), or (57) below:

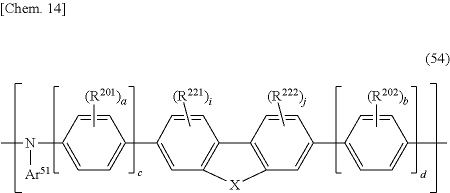

(wherein, in formula (54),
   Ar⁵¹ is the same as Ar⁵¹ in formula (50) above;
   X is —C(R²⁰⁷)(R²⁰⁸)—, —N(R²⁰⁹)—, or —C(R²¹¹)(R²¹²)—C(R²¹³)(R²¹⁴)—;
   R²⁰¹, R²⁰², R²²¹, and R²²² are each independently an alkyl group optionally having a substituent and/or a crosslinking group;
   R²⁰⁷ to R²⁰⁹ and R²¹¹ to R²¹⁴ are each independently a hydrogen atom, an alkyl group optionally having a substituent and/or a crosslinking group, an aralkyl group optionally having a substituent and/or a crosslinking group, or an aromatic hydrocarbon group optionally having a substituent and/or a crosslinking group;
   a and b are each independently an integer of 0 to 4;
   c is an integer of 0 to 3;
   d is an integer of 0 to 4; and
   i and j are each independently an integer of 0 to 3),

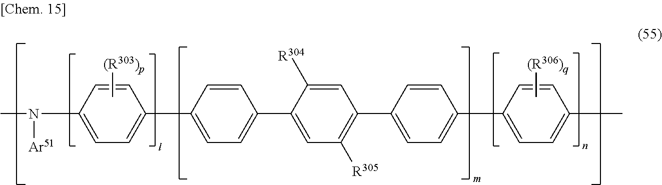

(wherein, in formula (55),
   Ar⁵¹ is the same as Ar⁵¹ in formula (54) above;
   R³⁰³ and R³⁰⁶ each independently represent an alkyl group optionally having a substituent and/or a crosslinking group;
   R³⁰⁴ and R³⁰⁵ each independently represent an alkyl group optionally having a substituent and/or a crosslinking group, an alkoxy group optionally having a substituent and/or a crosslinking group, or an aralkyl group optionally having a substituent and/or a crosslinking group;
   l is 0 or 1;
   m is 1 or 2;
   n is 0 or 1;
   p is 0 or 1; and
   q is 0 or 1),

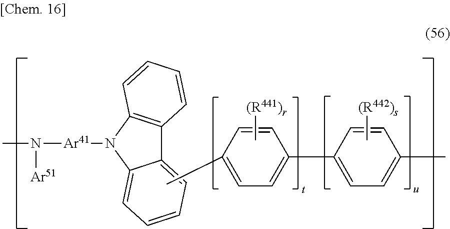

(wherein, in formula (56),
   Ar⁵¹ is the same as Ar⁵¹ in formula (54) above;
   Ar⁴¹ represents a divalent aromatic hydrocarbon group optionally having a substituent, a divalent aromatic heterocyclic group optionally having a substituent, or a divalent group in which a plurality of groups selected from the group consisting of divalent aromatic hydrocarbon groups and divalent aromatic heterocyclic groups are linked together directly or via a linking group;
   R⁴⁴¹ and R⁴⁴² each independently represent an alkyl group optionally having a substituent;
   t is 1 or 2;
   u is 0 or 1; and
   r and s are each independently an integer of 0 to 4),

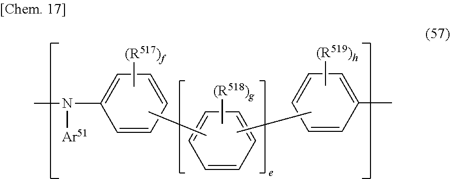

(wherein, in formula (57),
   Ar⁵¹ is the same as Ar⁵¹ in formula (50) above;
   R⁵¹⁷ to R⁵¹⁹ each independently represent an alkyl group optionally having a substituent and/or a crosslinking group, an alkoxy group optionally having a substituent and/or a crosslinking group, an aralkyl group optionally having a substituent and/or a crosslinking group, an aromatic hydrocarbon group optionally having a substituent and/or a crosslinking group, or an aromatic heterocyclic group optionally having a substituent and/or a crosslinking group;
   f, g, and h each independently represent an integer of 0 to 4; and
   e represents an integer of 0 to 3,
   provided that, when g is 1 or more, e is 1 or more).
[9] The composition according to [8], wherein X in formula (54) above is —C(R²⁰⁷)(R²⁰⁸)—, —N(R²⁰⁹)—, or —C(R²¹¹)(R²¹²)—C(R²¹³)(R²¹⁴)—; and at least one of R²⁰⁷ and R²⁰⁸, R²⁰⁹, or at least one of R²¹¹ to R²¹⁴ is an alkyl group having a crosslinking group, an aralkyl group having a crosslinking group, or an aromatic hydrocarbon group having a crosslinking group.
[10] The composition according to [8] or [9], wherein the high-molecular weight charge transport compound having a crosslinking group further includes, as the repeating unit represented by formula (50) above, a repeating unit represented by formula (60) below in addition to at least one selected from the repeating unit represented by formula (54) above, the repeating unit represented by formula (55) above, the repeating unit represented by formula (56) above, and the repeating unit represented by formula (57) above:

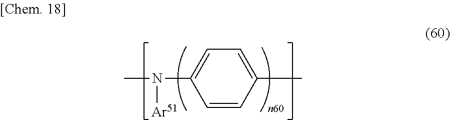

(wherein, in formula (60),
   Ar⁵¹ is the same as Ar⁵¹ in formula (50) above; and
   n60 represents an integer of 1 to 5).
[11] The composition according to any one of [6] to [10], wherein Ar⁵¹ has a crosslinking group.
[12] The composition according to any one of [1] to [11], wherein Ar⁶²¹ in formula (71) above is a divalent group formed by bonding a plurality of structures selected from 1 to 4 benzene rings each optionally having a substituent and 1 or 2 fluorene rings each optionally having a substituent in any order in a linear or branched manner.
[13] The composition according to any one of [1] to [12], wherein Ar⁶²¹ in formula (71) above has at least one partial structure selected from the following formulas (71-1) to (71-11) and (71-21) to (71-24):

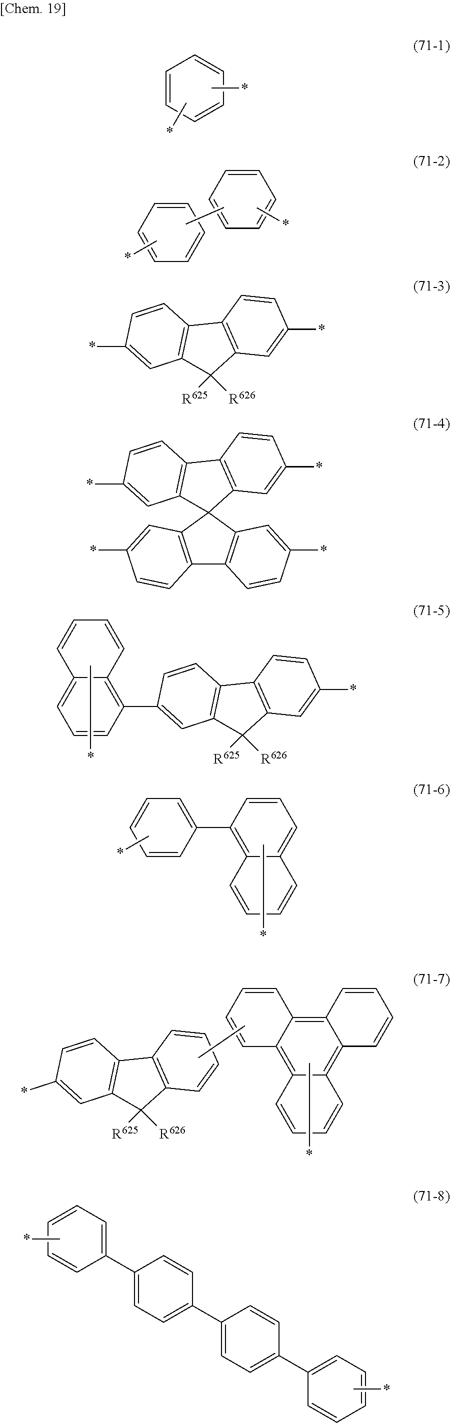

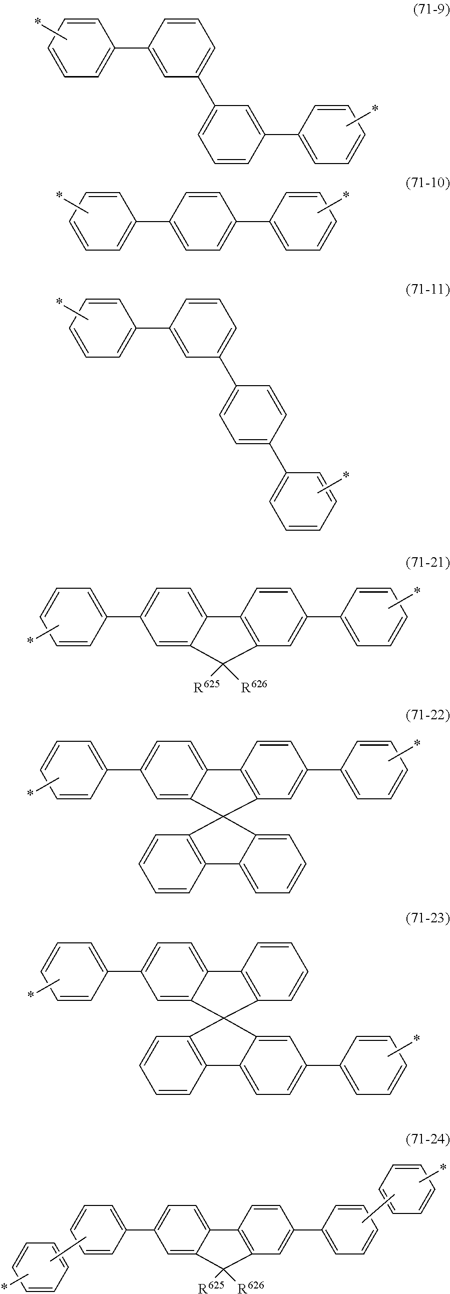

(in each of formulas (71-1) to (71-11) and (71-21) to (71-24) above,
   each * represents a bond to an adjacent structure or a hydrogen atom; when two *'s are present, at least one of the two *'s represents a position of bonding to an adjacent structure; when four *'s are present, at least one of any two of the four *'s represents a position of bonding to an adjacent structure;
   R⁶²⁵ and R⁶²⁶ each independently represent an alkyl group having 6 to 12 carbon atoms, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, a cyano group, an aralkyl group, or a monovalent aromatic hydrocarbon group having 6 to 30 carbon atoms; and R⁶²⁵ and R⁶²⁶ may be bonded together to form a ring).
[14] The composition according to any one of [1] to [13], wherein R⁶²¹, R⁶²², R⁶²³, and R⁶²⁴ in formula (71) above are each independently an aromatic hydrocarbon group having 6 to 50 carbon atoms and optionally having a crosslinking group or a crosslinking group.
[15] The composition according to any one of [1] to [14], wherein, in formula (71) above, n621 and n623 are each 1; n622 and n624 are each 0; and R⁶²¹ and R⁶²³ are each independently an aromatic hydrocarbon group having 6 to 50 carbon atoms and substituted with a crosslinking group or a crosslinking group.
[16] The composition according to any one of [1] to [15], wherein Ar⁶¹¹ and Ar⁶¹² in formula (72) above are each independently a phenyl group having a crosslinking group or a monovalent group that includes a plurality of benzene rings bonded together in a linear or branched manner and that has a crosslinking group.
[17] The composition according to any one of [1] to [16], wherein at least one of Ar⁶¹¹ and Ar⁶¹² in formula (72) above has at least one partial structure selected from the following formulas (72-1) to (72-6):

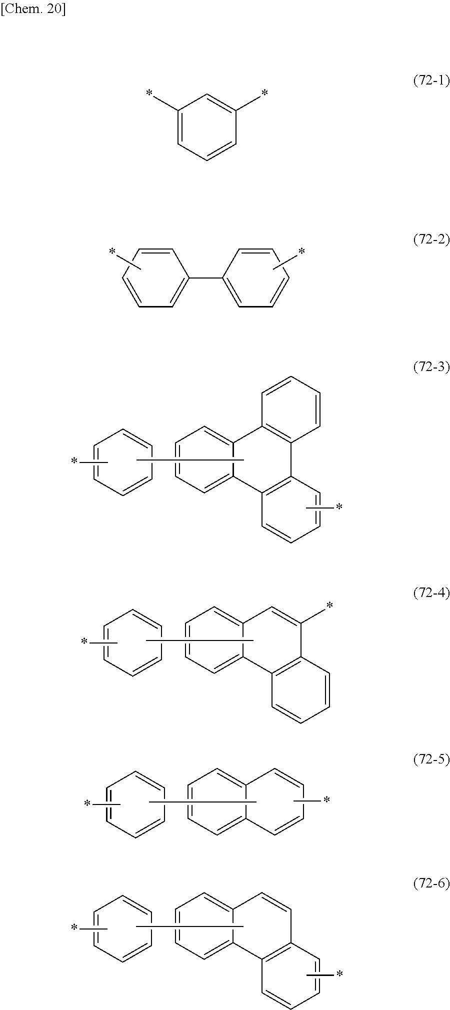

(in each of formulas (72-1) to (72-6) above, each * represents a bond to an adjacent structure or a hydrogen atom; and at least one of two *'s represents a position of bonding to an adjacent structure).
[18] The composition according to any one of [1] to [17], wherein, in formula (72) above, n⁶¹¹ and n⁶¹² are each 0.
[19] The composition according to any one of [1] to [18], wherein, in formula (72) above, G is a single bond.
[20] The composition according to any one of [2] to [19], wherein the electron accepting compound is represented by the following formula (81):

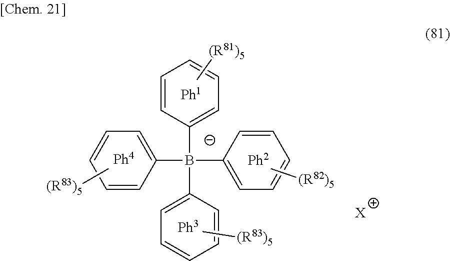

(wherein, in formula (81), five R⁸¹'s, five R⁸²'s, five R⁸³'s, five R⁸⁴'s are each independent; R⁸¹'s to R⁸⁴'s each independently represent a hydrogen atom, a deuterium atom, a halogen atom, an aromatic hydrocarbon group having 6 to 50 carbon atoms and optionally having a substituent and/or a crosslinking group, an aromatic heterocyclic group having 3 to 50 carbon atoms and optionally having a substituent and/or a crosslinking group, a fluorine-substituted alkyl group having 1 to 12 carbon atoms, or a crosslinking group;
   Ph¹, Ph², Ph³, Ph⁴ are symbols representing four benzene rings; and
   X⁺ represents a counter cation).
[21] The composition according to [20], wherein, in formula (81) above, at least one of -Ph¹-(R⁸¹)₅, -Ph²-(R⁸²)₅, -Ph³-(R⁸³)₅, and -Ph⁴-(R⁸⁴)₅ is a group represented by the following formula (84) and having four fluorine atoms:

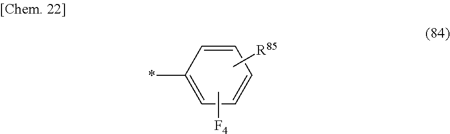

(wherein, in formula (84), * represents a bond to boron B in formula (81);
   F₄ represents substitution with four fluorine atoms; and
   R⁸⁵ represents an aromatic hydrocarbon group optionally having a substituent and/or a crosslinking group or a crosslinking group).
[22] The composition according to any one of [1] to [21], wherein the substituents included in the high-molecular weight charge transport compound and the low-molecular weight charge transport compound are each independently selected from the following substituent group X:
<substituent group X>
   alkyl groups having 1 to 24 carbon atoms,
   alkenyl group having 2 to 24 carbon atoms,
   alkynyl groups having 2 to 24 carbon atoms,
   alkoxy groups having 1 to 24 carbon atoms,
   aryloxy groups and heteroaryloxy groups having 4 to 36 carbon atoms,
   alkoxycarbonyl groups having 2 to 24 carbon atoms,
   dialkylamino groups having 2 to 24 carbon atoms,
   diarylamino groups having 10 to 36 carbon atoms,
   arylalkylamino groups having 7 to 36 carbon atoms,
   acyl groups having 2 to 24 carbon atoms,
   halogen atoms,
   haloalkyl groups having 1 to 12 carbon atoms,
   alkylthio groups having 1 to 24 carbon atoms,
   arylthio groups having 4 to 36 carbon atoms,
   silyl groups having 2 to 36 carbon atoms,
   siloxy groups having 2 to 36 carbon atoms,
   a cyano group,
   aromatic hydrocarbon groups having 6 to 36 carbon atoms, and
   aromatic heterocyclic groups having 4 to 36 carbon atoms,
   wherein each of the above substituents may have a linear, branched, or cyclic structure, and wherein, when any of the substituents are adjacent to each other, the substituents adjacent to each other may be bonded together to form a ring.
[23] The composition according to any one of [1] to [22], wherein the at least one aromatic organic solvent comprises two or more aromatic organic solvents having different boiling points, and wherein the two or more aromatic organic solvents include an aromatic organic solvent having a boiling point of 270° C. or higher.
[24] The composition according to any one of [1] to [23], wherein the content of the low-molecular weight charge transport compound with respect to the total amount of functional materials contained in the composition is 10% by weight to 75% by weight.
[25]A method for manufacturing an organic electroluminescent element using the composition according to any one of [1] to [24], the method comprising: the step of applying the composition to regions separated by a partition wall layer by printing using an inkjet method; the step of vacuum-drying the printed composition in a vacuum chamber to volatilize the organic solvent; and the step of baking the vacuum-dried composition at high temperature.
[26] The method for manufacturing an organic electroluminescent element according to [25], wherein, in the step of vacuum-drying in the vacuum chamber, the time required for the pressure in the vacuum chamber to reach a pressure lower than the vapor pressure of an organic solvent having the lowest vapor pressure among the at least one organic solvent contained in the composition is 60 seconds or longer and 1800 seconds or shorter.
[27] The method for manufacturing an organic electroluminescent element according to [25] or [26], wherein the composition is applied by printing such that films having two different thicknesses equal to or more than 10 nm are deposited, and the composition is vacuum-dried in one vacuum chamber simultaneously.

### Advantageous Effects of Invention

According to the composition of the invention, the uniformity of the thickness of the functional film in regions surrounded by banks can be improved.

Moreover, according to the invention, the composition can be used to improve the driving voltage, luminous efficiency, and driving lifetime of an organic electroluminescent element.

### BRIEF DESCRIPTION OF DRAWING

FIG. 1 A schematic cross-sectional view showing an example of the structure of an organic electroluminescent element in the invention.

### DESCRIPTION OF EMBODIMENTS

Embodiments of the invention will be described with reference to the drawing etc. The embodiments described below are embodiments for describing the invention and should not be construed as limiting the invention. Not all the components described in the embodiments are essential components for solving the problems of the invention.

In the present description, when the composition of the invention is used as an ink to be ejected from a nozzle such as an inkjet nozzle, the composition may be referred to simply as an ink. When the composition of the invention is used as an ink to be ejected from a nozzle such as an inkjet nozzle and the ink is ejected from the nozzle and applied to a region surrounded by a partition wall layer, the ink in the region surrounded by the partition wall layer may be referred to as a liquid or a liquid film, and the ink ejected from the nozzle may be referred to as a droplet.

A product obtained by drying a liquid film in a region surrounded by a partition wall layer (bank) and having a solvent compositional ratio changed due to volatilization of the solvent may also be referred to as a liquid or a liquid film. A film containing functional materials that is obtained by applying the composition of the invention to form the film and volatilizing an organic solvent to dry the film may be referred to as a functional film or layer containing the functional materials.

A film containing an organic compound and containing no solvent or substantially dried by volatilizing the solvent is referred to as an organic film.

The functional film is one type of organic film.

### [Composition]

The composition of the invention contains: at least one high-molecular weight charge transport compound having a crosslinking group and having a weight average molecular weight of 10,000 or more; at least one low-molecular weight charge transport compound having a crosslinking group and having a molecular weight of 5,000 or less; and at least one aromatic organic solvent,

wherein the low-molecular weight charge transport compound is selected from the group consisting of a compound represented by formula (71) below, a compound represented by formula (72) below, a compound represented by formula (73) below, a compound represented by formula (74) below, a compound represented by formula (75) below, a compound represented by formula (1) below, and a compound represented by formula (2) below.

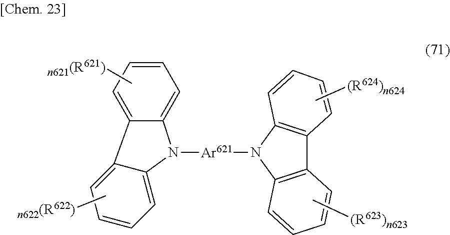

(In formula (71),

Ar⁶²¹ represents a divalent aromatic hydrocarbon group having 6 to 50 carbon atoms and optionally having a substituent.

R⁶²¹, R⁶²², R⁶²³, and R⁶²⁴ are each independently a deuterium atom, a halogen atom, a monovalent aromatic hydrocarbon group having 6 to 50 carbon atoms and optionally having and/or a crosslinking group, or a crosslinking group.

Formula (71) includes at least two crosslinking groups.

n621, n622, n623, and n624 are each independently an integer of 0 to 4. However, the sum of n621, n622, n633, and n624 is 1 or more.)

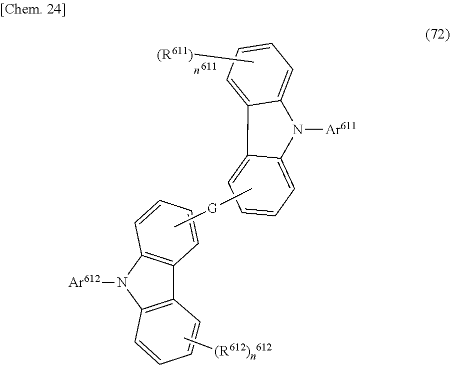

(In formula (72),

Ar⁶¹¹ and Ar⁶¹² each independently represent a divalent aromatic hydrocarbon group having 6 to 50 carbon atoms and optionally having a substituent and/or a crosslinking group.

R⁶¹¹ and R⁶¹² are each independently a deuterium atom, a halogen atom, a monovalent aromatic hydrocarbon group having 6 to 50 carbon atoms and optionally having a substituent and/or a crosslinking group, or a crosslinking group.

G represents a single bond or a divalent aromatic hydrocarbon group having 6 to 50 carbon atoms and optionally having a substituent and/or a crosslinking group.

The compound represented by formula (72) has at least two crosslinking group.

n⁶¹¹ and n⁶¹² are each independently an integer of 0 to 4.)

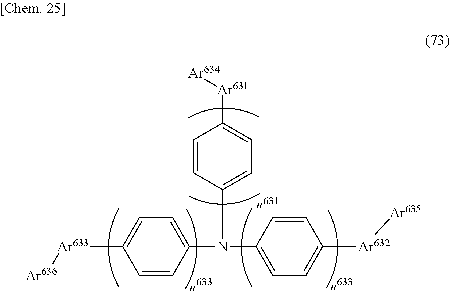

(In formula (73),

Ar⁶³¹, Ar⁶³², and Ar⁶³³ are each independently a direct bond or an aromatic hydrocarbon group having 6 to 30 carbon atoms optionally having a monovalent substituent.

Ar⁶³⁴, Ar⁶³⁵, and Ar⁶³⁶ are each independently a monovalent aromatic hydrocarbon group having 6 to 30 carbon atoms or a monovalent aromatic heterocyclic group having 3 to 24 carbon atoms, and the monovalent aromatic hydrocarbon group and monovalent aromatic heterocyclic group may each optionally have a substituent or a crosslinking group.

At least two of Ar⁶³⁴, Ar⁶³⁵, and Ar⁶³⁶ each have a crosslinking group.

n⁶³¹, n⁶³², and n⁶³³ each independently represent an integer of 0 to 3.

The crosslinking groups included in Ar⁶³⁴, Ar⁶³⁵, and Ar⁶³⁶ are each independently the following formula (a) or (b).)

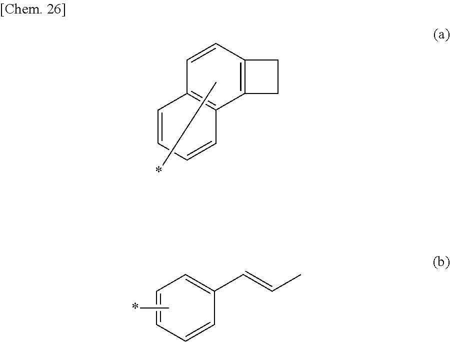

(In formulas (a) and (b), * represents a position of bonding to Ar⁶³⁴, Ar⁶³⁵, or Ar⁶³⁶.)

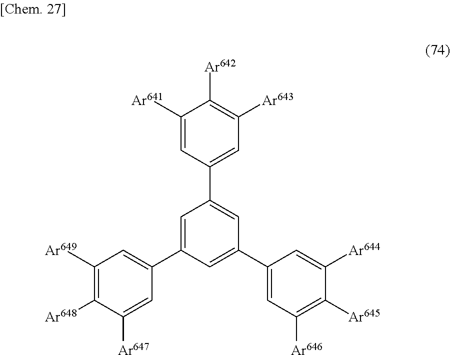

(In formula (74),

Ar⁶⁴¹ to Ar⁶⁴⁹ each independently represent a hydrogen atom, a benzene ring structure optionally having a substituent and/or a crosslinking group, or a structure in which 2 to 10 benzene ring structures each optionally having a substituent and/or a crosslinking group are linked together in a non-branched or branched manner.

The compound represented by formula (74) has at least two crosslinking groups.)

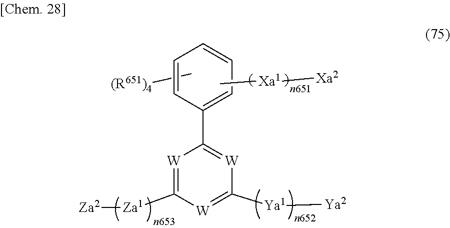

(In formula (75),

W's each independently represent CH or N, and at least one W is N.

Xa¹, Ya¹, and Za¹ each independently represent a divalent aromatic hydrocarbon group having 6 to 30 carbon atoms and optionally having a substituent or a divalent aromatic heterocyclic group having 3 to 30 carbon atoms and optionally having a substituent.

Xa², Ya², and Za² each independently represent a hydrogen atom, an aromatic hydrocarbon group having 6 to 30 carbon atoms and optionally having a substituent and/or a crosslinking group, an aromatic heterocyclic group having 3 to 30 carbon atoms and optionally having a substituent and/or a crosslinking group, or a crosslinking group.

n651, n652, and n653 each independently represent an integer of 0 to 6.

At least one of n651, n652, and n653 is an integer of 1 or more.

When n651 is 2 or more, a plurality of Xa¹'s present may be the same or different.

When n652 is 2 or more, a plurality of Ya¹'s present may be the same or different.

When n653 is 2 or more, a plurality of Za¹'s present may be the same or different.

At least two of Xa², Ya², and Za² each have a crosslinking group.

Four R⁶⁵¹'s each represent a hydrogen atom or a substituent and may be the same or different.

When n651, n652, or n653 is 0, the corresponding one of Xa², Ya², and Za² is not a hydrogen atom.)

[Chem. 29]

CHₓA₍₄₋ₓ₎ (1)

(In formula (1),

C represents a carbon atom, and H represents a hydrogen atom.

A's each independently represent a substituent represented by formula (2′) below.

x represents an integer of 0 to 2.)

[Chem. 30]

*-(L²¹)_{y}-(CL²¹)_{z} (2′)

(In formula (2′),

L²¹'s each independently represent a bonding group optionally having a substituent.

CL²¹'s each independently represent a crosslinking group represented by formula (3) below.

* represents a direct bond bonded to the carbon atom in formula (1).

y represents an integer of 1 to 6, and z represents an integer of 0 to 4.

When z is 0, a hydrogen atom instead of CL²¹ is bonded to bonding group L²¹.

Three or more CL²¹'s are present in the compound represented by formula (1).)

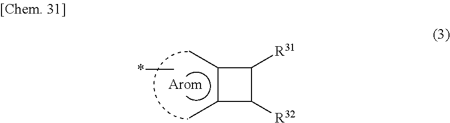

(In formula (3),

Arom represents an aromatic ring having 3 to 30 carbon atoms and optionally having a substituent.

R³¹ and R³² each independently represent a hydrogen atom or an alkyl group.

* represents a direct bond bonded to L²¹ in formula (2′), and the direct bond to formula (2′) is bonded to Arom.)

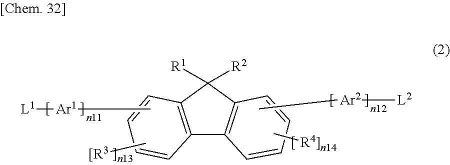

(In formula (2),

Ar¹ and Ar² each independently represent a divalent aromatic group having 6 to 60 carbon atoms and optionally having a substituent.

R¹, R², R³, and R⁴ each independently represent an alkyl group optionally having a substituent or an aromatic group optionally having a substituent.

L¹ and L² each independently represent a crosslinking group.

n11 and n12 each independently represent an integer of 0 to 5.

n13 and n14 each independently represent an integer of 0 to 3.)

### [Mechanism]

The object of the invention is to appropriately reduce the occurrence of self-pinning that occurs when the composition is applied to regions separated by a partition wall layer and dried to thereby obtain a more uniform film thickness in each separated region. During drying of the composition, the solvent volatilizes. This causes the concentrations of the functional materials to increase, and the viscosity of the composition thereby increases. Since the increase in the viscosity causes a reduction in the flowability of the composition, the movement of the composition on the side surfaces of the partition wall layer is impeded, and this causes self-pinning on the side surfaces of the partition wall layer. Therefore, the resulting functional film has a shape rising along the side surfaces of the partition walls, and it is not easy to form a uniform flat film. In particular, when the functional materials are formed of polymer materials, the effect of the increase in the viscosity on the non-uniformity of the film thickness is significant.

Since the composition of the invention contains the low-molecular weight charge transport compound having a certain molecular weight or less, the degree of increase in viscosity influenced by the concentrations of the functional materials in the composition is small. Therefore, the flowability is unlikely to decrease, so that the occurrence of self-pinning can be reduced.

However, when a composition into which the low-molecular weight charge transport compound is simply mixed is used to form a functional film by a wet deposition method, a problem arises in that, for example, the composition re-dissolves when an additional functional film is stacked on the formed functional film. In an organic electroluminescent element manufactured by stacking a plurality of functional layers, it is feared that the above problem may significantly deteriorate its functions.

In the present invention, crosslinking groups are introduced into both the low-molecular weight charge transport compound and the high-molecular weight charge transport compound. In this manner, a uniform film thickness can be achieved, and at the same time the functions of an organic electroluminescent element to be manufactured can be maintained.

Therefore, the present invention includes the composition containing at least one high-molecular weight charge transport compound having a weight average molecular weight of 10,000 or more and having a crosslinking group, at least one low-molecular weight charge transport compound having a molecular weight of 5,000 or less and having a crosslinking group, and at least one aromatic organic solvent and further includes a method for forming a film using the above composition.

### [Organic Solvent]

Solvents usable in the invention will be described with reference to examples.

### <Type of Solvent>

No particular limitation is imposed on the type of solvent used in the present invention. Preferred examples of the solvent include water-insoluble aromatic-based solvents such as aromatic hydrocarbon-based solvents, aromatic ester-based solvents, aromatic ether-based solvents, and aromatic ketone-based solvents.

The aromatic hydrocarbon-based solvent is preferably a benzene derivative, a naphthalene derivative, a hydrogenated naphthalene derivative, a biphenyl derivative, or a diphenylmethane derivative.

The benzene derivative is preferably a benzene derivative including a linear, branched, or alicyclic alkyl group as a substituent with the total number of carbon atoms in the substituent being 5 to 12, and examples thereof include n-octylbenzene, n-nonylbenzene, n-decylbenzene, and dodecylbenzene.

No particular limitation is imposed on the naphthalene derivative. The naphthalene derivative is preferably a naphthalene derivative substituted with an alkyl group, and examples thereof include 1-methylnaphthalene, 2-ethylnaphthalene, 2-isopropylnaphthalene, 2,6-dimethylnaphthalene, 1-methoxynaphthalene, 2,7-diisopropylnaphthalene, and 1-butylnaphthalene.

Examples of the hydrogenated naphthalene derivative include tetralin, 1,2-dihydronaphthalene, and 1,4-dihydronaphthalene. These may be substituted with an alkyl group having 1 to 6 carbon atoms.

No particular limitation is imposed on the biphenyl derivative. The biphenyl derivative is preferably a biphenyl derivative substituted with an alkyl group having 1 to 6 carbon atoms, and examples thereof include 3-ethylbiphenyl, 4-isopropylbiphenyl, and 4-butylbiphenyl.

No particular limitation is imposed on the diphenylmethane derivative. The diphenylmethane derivative is preferably a diphenylmethane derivative substituted with an alkyl group having 1 to 6 carbon atoms, and examples thereof include 1,1-diphenylethane, 1,1-diphenylpentane, 1,1-diphenylhexane, 1,1-bis(3,4-dimethylphenyl)ethane, and benzyltoluene.

Examples of the aromatic ester-based solvents include benzoate-based solvents, phenylacetate-based solvents, and phthalate-based solvents.

The benzoate-based solvent is a compound including benzoic acid and an ester bond, and a compound in which a benzoic acid optionally having a substituent and an alcohol having 2 to 12 carbon atoms are ester-bonded together can be used. The optional substituent is preferably a linear or branched alkyl group having 1 to 6 carbon atoms or a linear or branched alkoxy group having 1 to 6 carbon atoms. The benzoate-based solvent may have a plurality of substituents. When a plurality of substituents are included, the total number of carbon atoms in the substituents is preferably 6 or less.

Examples of the benzoate-based solvent include butyl benzoate, n-pentyl benzoate, isoamyl benzoate, n-hexyl benzoate, 2-ethylhexyl benzoate, benzyl benzoate, and ethyl 4-methoxybenzoate.

Examples of the phenylacetate-based solvent include ethyl phenylacetate.

Examples of the phthalate-based solvent include dimethyl phthalate, diethyl phthalate, and dibutyl phthalate.

Other preferred examples of the aromatic ester-based solvent include 2-phenoxyethyl acetate and 2-phenoxyethyl isobutyrate.

The aromatic ether-based solvent is a compound including an aromatic ring and an ether bond, and example thereof include the following compounds:
diphenyl ether derivatives optionally substituted with a linear or branched alkyl group having 1 to 6 carbon atoms such as diphenyl ether, 2-phenoxytoluene, 3-phenoxytoluene, and 4-phenoxytoluene;
benzene derivatives having two ether bonds to linear or branched alkyl groups having 1 to 6 carbon atoms such as 1,4-diethoxybenzene and 1-ethoxy-4-hexyloxybenzene;
benzene derivatives having one ether bond to a linear or branched alkyl group having 4 to 12 carbon atoms such as phenylhexyl ether;
benzyl ether-based solvents such as dibenzyl ether; and
other aromatic ether-based solvents such as 2-phenoxyethanol:

The aromatic ketone-based solvent is a compound including an aromatic ring and a ketone structure, and examples thereof include 1-acetylnaphthalene, propiophenone, and 4′-ethylpropiophenone.

### <Surface Modifier>

The solvent may contain a surface modifier in order to control its surface tension. By adding a small amount of a surface modifier to a liquid, functionality can be imparted to the surface of the liquid after the application of the liquid or to the surface of a solid obtained by applying the liquid. Examples of the functionality imparted include liquid repellency, non-adhesiveness, wettability, smoothness, dispersibility, and defoamability.

Preferred materials that can be used as the surface modifier are those that can easily segregate at the surface of liquid, and specific examples thereof include materials containing silicon or fluorine (such as polymers, oligomers, and low-molecular weight materials), paraffin, and surfactants.

The surfactant as used herein is a material having an amphiphilic chemical structure including a hydrophilic moiety (group) and a hydrophobic moiety (group) and is used for a wide variety of applications such as dispersants, foaming agents, antifoaming agents, emulsifiers, food additives, moisturizing agents, antistatic agents, wettability improvers, lubricants, and anticorrosives. Such surfactants are broadly classified into surfactants in which their hydrophilic moiety is a cationic, anionic, or amphoteric moiety and surfactants in which their hydrophilic moiety is a nonionic moiety. In the present invention, nonionic surfactants are preferred so as not to impede the flow of current in an organic electroluminescent element.

### <Boiling Point>

No particular limitation is imposed on the aromatic organic solvent used in the present invention, but the aromatic organic solvent is preferably a solvent with a boiling point or 200° C. or higher, more preferably a solvent with a boiling point or 230° C. or higher, still more preferably a solvent with a boiling point of 250° C. or higher, and most preferably a solvent with a boiling point of 270° C. or higher. The boiling point of the solvent is preferably 350° C. or lower, more preferably 340° C. or lower, and still more preferably 330° C. or lower.

For example, when an ink is charged into an inkjet head, its solid concentration at the forward end of the nozzle tends to increase because drying of the ink starts from the forward end of the nozzle. If this state is maintained, solids precipitate at the forward end of the nozzle, and this may eventually cause fatal damage to the inkjet device such as clogging of the nozzle. To avoid the trouble due to the clogging of the nozzle, the solvent is preferably a solvent with a boiling point of 200° C. or higher, more preferably a solvent with a boiling point of 230° C. or higher, still more preferably a solvent with a boiling point of 250° C. or higher, and most preferably a solvent with a boiling point of 270° C. or higher.

However, from the viewpoint of manufacturing an organic electroluminescent element, the boiling point of the solvent must be such that the solvent can be dried in a vacuum drying facility because the element cannot be produced unless the solvent is volatilized to obtain a functional film. From this point of view, the boiling point of the solvent is preferably 350° C. or lower, more preferably 340° C. or lower, and still more preferably 330° C. or lower.

### <Vapor Pressure>

The vapor pressure of a solvent is the pressure of its vapor phase when the liquid and vapor phases of the solvent are in a phase equilibrium state, and the boiling point of the solvent is the temperature at which the partial vapor pressure of the solvent is equal to the vapor pressure. The vapor pressure can be determined by experimental methods such as a static method, a boiling point method, an isoteniscope, and a gas flow method. The vapor pressure in the present invention is the vapor pressure computed using Advanced Chemistry Development (ACD/Labs) Software V11.02 (Copyright 1994-2021 ACD/Labs) at 25° C.

### <Type of Solvent Contained and Number of Solvents>

The aromatic organic solvent used in the invention may be a single solvent or may be a mixture of two or more solvents.

When a mixture of two or more solvents is used, two solvents with different boiling points may be used in order to both prevent drying at the forward end of the nozzle of the inkjet head as described above and to facilitate drying during the formation of a film. To prevent drying at the forward end of the nozzle of the inkjet head to thereby prevent clogging of the nozzle, it is preferable to contain a solvent with a boiling point of 270° C. or higher. One solvent with a boiling point of 270° C. or higher may be used, or two or more such solvents may be used. To prevent the ink from drying at the forward end of the nozzle to thereby prevent clogging of the nozzle, the content of the solvent with a boiling point of 270° C. or higher with respect to the total amount of the composition is preferably 10% by weight or more, more preferably 15% by weight or more, and still more preferably 25% by weight or more.

The solvent with a high boiling point can prevent drying of the ink at the forward end of the nozzle. Therefore, to ensure that the ink has a good drying property, a solvent with a lower boiling point may be included in the rest of the solvent. The low-boiling point solvent has a boiling point of preferably 265° C. or lower and more preferably 250° C. or lower. One low-boiling point solvent or two or more low-boiling point solvents may be used. For the purpose of assisting the drying of the composition, the content of the low-boiling point solvent with respect to the total amount of the composition is preferably 30% by weight or more, more preferably 40% by weight or more, and still more preferably 50% by weight or more.

In the present invention, the boiling point of each solvent is a value measured at atmospheric pressure.

### <Combination of Solvents>

No particular limitation is imposed on the combination of the high-boiling point solvent and the low-boiling point solvent. These solvents are each preferably benzene optionally having a substituent, naphthalene optionally having a substituent, diphenylmethane optionally having a substituent, biphenyl optionally having a substituent, a benzoate, an aromatic ether, or an aromatic ketone.

The high-boiling point solvent includes preferably one or two or more selected from octylbenzene, nonylbenzene, decylbenzene, dodecylbenzene, hexyl benzoate, 2-ethylhexyl benzoate, benzyl benzoate, acetylnaphthalene, methyl naphthaleneacetate, ethyl naphthaleneacetate, isopropylnaphthalene, diisopropylnaphthalene, butylnaphthalene, pentylnaphthalene, methoxynaphthalene, dimethyl phthalate, diethyl phthalate, ethylbiphenyl, isopropylbiphenyl, diisopropylbiphenyl, triisopropylbiphenyl, butylbiphenyl, 1,1-diphenylethane, 1,1-diphenylpropane, 1,1-diphenylbutane, 1,1-diphenylpentane, 1,1-diphenylhexane, and 2-phenoxyethyl isobutyrate.

The low-boiling point solvent includes preferably one or two or more selected from methylnaphthalene, ethylnaphthalene, isopropylnaphthalene, ethyl benzoate, propyl benzoate, butyl benzoate, isobutyl benzoate, pentyl benzoate, isopentyl benzoate, methyl toluate, and ethyl toluate.

### [Viscosity of Composition]

For example, when consideration is given to the use of an application method in which the composition of the invention charged into an inkjet head is ejected, the viscosity of the composition at 23° C. is preferably 1 mPas or more and 20 mPas or less.

Generally, in an inkjet head using a piezoelectric element, a composition charged into an ink chamber in the head is pushed out by utilizing the deformation pressure of the piezoelectric element. Therefore, if the viscosity of the composition exceeds 20 mPas, the pressure of the piezoelectric element is insufficient, and the composition cannot be ejected. From the viewpoint of allowing the ink composition to be easily held within the head so as to prevent the ink from dripping from the nozzle, the viscosity of the composition is preferably 1 mPas or more.

In the present invention, the viscosity of the solvent and the viscosity of the composition can be measured using an E-type viscometer RE85L (manufactured by Toki Sangyo Co., Ltd.) in a 23° C. environment at a cone-plate rotation speed of 20 rpm to 100 rpm.

### [Surface Tension of Composition]

The surface tension of the composition of the invention is preferably 25 mN/m or more and is preferably 45 mN/m or less. When the surface tension of the composition is within the above range, the composition may be stably ejected from an inkjet device, and films may be formed stably.

When a composition with a low surface tension is used, the composition spreads very well over a nozzle plate of an inkjet head, and this causes unstable ejection of the composition and flight deflection. If the surface tension is low, the ejected composition is not properly cut and tends to be elongated, and this may easily cause satellites etc. If the surface tension is excessively high, convection due to the Laplace pressure is likely to occur in the composition applied to pixel portions of a substrate during drying, and the shape of the film tends to be unstable.

The surface tension of the solvent and the surface tension of the composition in the invention can be measured in an environment at 23.0° C. by a plate method using a platinum plate or a pendant drop method using a contact angle meter DMo-501 (manufactured by Kyowa Interface Science Co., Ltd.).

### [Additional Components]

The composition of the invention may contain components other than the functional materials and the solvent. For example, the composition may contain an antioxidant and an additive that changes the physical properties of the composition. These components are important elements that determine the storage stability of the composition and its ejection stability from an inkjet head. However, it is unpreferable that these components significantly influence the intrinsic performance of the composition. Therefore, the content of the additional components with respect to the total amount of the composition is preferably 0.1% by weight or less and more preferably 0.05% by weight or less.

### [Functional Materials]

The functional materials are materials that have a charge transport function, a charge injection function, etc. or improve these functions.

The charge transportability is preferably hole transportability, and the charge injectability is preferably hole injectability.

A material having the function of improving charge transportability is a material having the function of improving the charge transportability of a charge transport material different from that material.

A material having the function of improving charge injectability is a material having the function of improving the charge injectability of a charge injection material different from that material.

For example, by doping a hole transport material with an electron acceptor material, the electron acceptor material oxidizes the hole transport material to generate a cation radical, and the hole transportability and/or the hole injectability of the hole transport material is thereby improved. In this case, the electron acceptor material is a material that improves the hole transportability and/or the hole injectability of the hole transport material.

The functional materials used in the invention include preferably a material for a hole injection layer described later or a material for a hole transport layer and particularly preferably a material for a hole transport layer.

The details of the functional materials usable in the invention will be described by way of specific examples, but the scope of the invention is not limited to the functional materials described below.

### <Molecular Weights of Charge Transport Compounds>

The functional materials in the invention include a high-molecular weight charge transport compound having a weight average molecular weight of 10,000 or more and a low-molecular weight charge transport compound having a molecular weight of 5,000 or less. Hereinafter, the high-molecular weight charge transport compound used as a functional material in the invention may be referred to simply as a high-molecular weight compound, and the low-molecular weight charge transport compound used as a functional material in the invention may be referred to simply as a low-molecular weight compound.

Generally, the high-molecular weight charge transport compound has high charge transportability in the direction of the main chain of the high-molecular weight compound. Therefore, the larger the average molecular weight, the more stable the charge transportability obtained. To ensure the charge transport function, the weight average molecular weight is 10,000 or more, preferably 12,000 or more, and more preferably 15,000 or more. One feature of the high-molecular weight compound having a high weight average molecular weight is that it increases the viscosity of an ink to be prepared. To allow the viscosity to fall within the above-described preferred range, it is preferable that the weight average molecular weight is low to some extent. Specifically, the weight average molecular weight of the high-molecular weight compound is generally 1,000,000 or less, preferably 500,000 or less, more preferably 100,000 or less, still more preferably 70,000 or less, and particularly preferably 50,000 or less.

The low-molecular weight charge transport compound is an essential element in order for the functional film in the invention to have a uniform thickness and is added for the purpose of preventing self-pinning. By preventing an increase in the viscosity due to an increase in the concentration during the drying process, the effect of preventing self-pinning on the side surfaces of the partition wall layer is obtained. Therefore, the molecular weight of the low-molecular weight charge transport compound is 5,000 or less, preferably 4,000 or less, more preferably 3,000 or less, still more preferably 2,500 or less, and particularly preferably 2,000 or less. When a commonly used functional film is formed, baking is performed at a certain temperature to volatilize the remaining solvent to thereby form a functional film with no impurities, and this functional film can function well in an organic electroluminescent element. In this case, if the material used has low heat resistance, phenomena such as shrinkage of the film and blank spots occur, so that a flat film cannot be obtained. From the viewpoint of ensuring the heat resistance of the film, the molecular weight of the low-molecular weight charge transport compound is preferably 500 or more, more preferably 650 or more, and still more preferably 800 or more.

The composition of the invention may contain one high-molecular weight charge transport compound having a weight average molecular weight of 10,000 or more or two or more high-molecular weight charge transport compounds. The composition may contain one low-molecular weight charge transport compound having a molecular weight of 5,000 or less or two or more low-molecular weight charge transport compounds. When two or more high-molecular weight charge transport compounds each having a molecular weight within the above range are present, the weight average molecular weight of the high-molecular weight charge transport compounds is the weight average molecular weight of all the materials, and the sums of weights are used for their chemical composition. When two or more low-molecular weight charge transport compounds each having a molecular weight within the above range are present, the molecular weight of the low-molecular weight charge transport compounds is the weight average molecular weight of all the materials, and the sums of weights are used for their chemical composition.

The composition of the invention may contain a third compound having a molecular weight outside the above ranges. When the third compound is contained, its content with respect to the total amount of the functional materials is preferably 30% by weight or less and more preferably 20% by weight or less in order to avoid an unexpected viscosity increase behavior in the drying process.

Preferably, the composition of the invention contains an electron accepting compound in order to improve the charge transport performance.

The weight average molecular weight and the number average molecular weight of the high-molecular weight charge transport compound in the invention are determined by SEC (size exclusion chromatography) measurement. In the SEC measurement, the elution time is shorter for a higher molecular weight component and longer for a lower molecular weight component. A calibration curve computed from the elution times of polystyrenes (standard specimens) with known molecular weights is used to convert the elution time of a sample to its molecular weights. The weight average molecular weight and the number average molecular weight of the sample are thereby computed.

### <Crosslinking Group>

In the present invention, to form a flat functional film without deterioration in the performance of the organic electroluminescent element, it is essential that the high-molecular weight charge transport compound and the low-molecular weight charge transport compound each have a crosslinking group to improve the solvent resistance of the functional film.

Specifically, in the present invention, the crosslinking groups are essential in order to prevent the low-molecular weight charge transport compound from dissolving in a solvent of a composition applied to the upper portion of the functional film. In this case, the number of crosslinking groups contained in one low-molecular weight charge transport compound molecule is preferably 2 or more in order that at least the low-molecular weight charge transport compound can be crosslinked by a chain reaction to thereby prevent it from dissolving in the solvent.

As for the high-molecular weight charge transport compound, the number of crosslinking groups contained in one polymer chain is one or more and preferably two or more. To prevent the elution of the high-molecular weight charge transport compound more reliably, the number of crosslinking groups per 10,000 molecular weight is generally 1 or more, preferably 2 or more, and more preferably 5 or more and is generally 30 or less, preferably 20 or less, and more preferably 10 or less.

Each crosslinking group is preferably a substituent that undergoes a chemical reaction under external force such as light or heat, and preferred examples of the crosslinking group include, but not limited to, the following thermal crosslinking groups that undergo a crosslinking reaction under heat. Specifically, examples of the crosslinking group include groups derived from a benzocyclobutene ring, a naphthocyclobutene ring, and an oxetane ring, a vinyl group, an acrylic group, and a styryl group. Any of these crosslinking groups may optionally have a substituent, and the substituent is preferably a methyl group, a methoxy group, etc.

As described above, the composition of the invention contains the functional materials each having a crosslinking group. Preferably, all the functional materials contained in the composition of the invention have respective crosslinking groups.

### Definitions

In the detailed descriptions of the high-molecular weight charge transport compound, the low-molecular weight charge transport compound, and the electron accepting compound in the invention, partial structures common to these compounds are the following structures, unless otherwise specified.

### <Aromatic Group>

Examples of the aromatic group include aromatic hydrocarbon groups described below, aromatic heterocyclic groups described below, and structures in which a plurality of rings selected from these groups are linked together. A structure in which a plurality of groups selected from aromatic hydrocarbon groups and aromatic heterocyclic groups are linked together is generally a structure including 2 to 10 groups linked together and preferably a structure including 2 to 5 groups linked together. When a plurality of groups selected from aromatic hydrocarbon groups and aromatic heterocyclic groups are linked together, groups having the same structure may be linked together, or groups having different structures may be linked together.

The structure in which a plurality of groups selected from aromatic hydrocarbon groups and aromatic heterocyclic groups are linked together is preferably a group derived from a phenylpyridine ring, a group derived from a diphenylpyridine ring, a group derived from a phenylcarbazole ring, or a group derived from a diphenylcarbazole ring.

### <Aromatic Hydrocarbon Group>

The aromatic hydrocarbon group is any of monovalent, divalent, trivalent, and higher valent aromatic hydrocarbon ring structures and is selected according to the bonding state in the structure of a compound to be described later.

Generally, no particular limitation is imposed on the number of carbon atoms in the structure of the aromatic hydrocarbon ring. However, the number of carbon atoms is preferably 6 or more and 60 or less. The upper limit of the number of carbon atoms is more preferably 48 or less and still more preferably 30 or less. Specific examples of the aromatic hydrocarbon group include: 6-membered monocyclic groups and condensed ring groups including 2 to 5 rings such as a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, and a fluorene ring; and structures in which a plurality of groups selected from the above groups are linked together.

A structure including a plurality of aromatic hydrocarbon rings linked together is generally a structure including 2 to 10 aromatic hydrocarbon rings linked together and preferably a structure including 2 to 5 aromatic hydrocarbon rings linked together. In the structure including a plurality of aromatic hydrocarbon rings linked together, groups having the same structure may be linked together, or groups having different structures may be linked together.

The aromatic hydrocarbon ring structure is preferably a benzene ring, a biphenyl ring, i.e., a structure including two benzene rings linked together, a terphenyl ring, i.e., a structure including three benzene rings linked together, a quaterphenyl ring, i.e., a structure including four benzene rings linked together, a naphthalene ring, or a fluorene ring.

### <Aromatic Heterocyclic Group>

The aromatic heterocyclic group is any of monovalent, divalent, trivalent, and higher valent aromatic heterocyclic structures and is selected according to the bonding state in the structure of a compound to be described later.

Generally, no particular limitation is imposed on the number of carbon atoms in the structure of the aromatic heterocycle. However, the number of carbon atoms is preferably 3 or more and 60 or less. The upper limit of the number of carbon atoms is more preferably 48 or less and still more preferably 30 or less. Specific examples of the aromatic heterocyclic group include: divalent 5- and 6-membered monocyclic groups and divalent condensed ring groups including 2 to 4 rings such as a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a benzimidazole ring, a perimidine ring, a quinazoline ring, a quinazolinone ring, and an azulene ring; and groups in which a plurality of groups selected from the above groups are linked together.

When a plurality of aromatic heterocycles are linked together, heterocycles having the same structure may be linked together, or heterocycles having different structures may be linked together. The structure including a plurality of aromatic heterocycles linked together is generally a structure including 2 to 10 aromatic heterocycles linked together and preferably a structure including 2 to 5 aromatic heterocycles linked together.

The aromatic heterocyclic structure is preferably a thiophene ring, a benzothiophene ring, a pyrimidine ring, a triazine ring, a carbazole ring, a dibenzofuran ring, or a dibenzothiophene ring.

### <Crosslinking Group>

The crosslinking group is a group that reacts with another crosslinking group located near the crosslinking group when heated and/or irradiated with active energy rays to thereby form a new chemical bond. In this case, the crosslinking groups reacted with each other may be the same or may be different.

No particular limitation is imposed on the crosslinking group. Examples of the crosslinking group include groups including an alkenyl group, groups including a conjugated diene structure, groups including an alkynyl group, groups including an oxirane structure, groups including an oxetane structure, groups including an aziridine structure, an azido group, groups including a maleic anhydride structure, groups including an alkenyl group bonded to an aromatic ring, and a cyclobutene ring fused to an aromatic ring. Preferred specific examples of the crosslinking group include groups represented by formulas (X1) to (X18) in the following group T of crosslinking groups.

### <Group T of Crosslinking Groups>

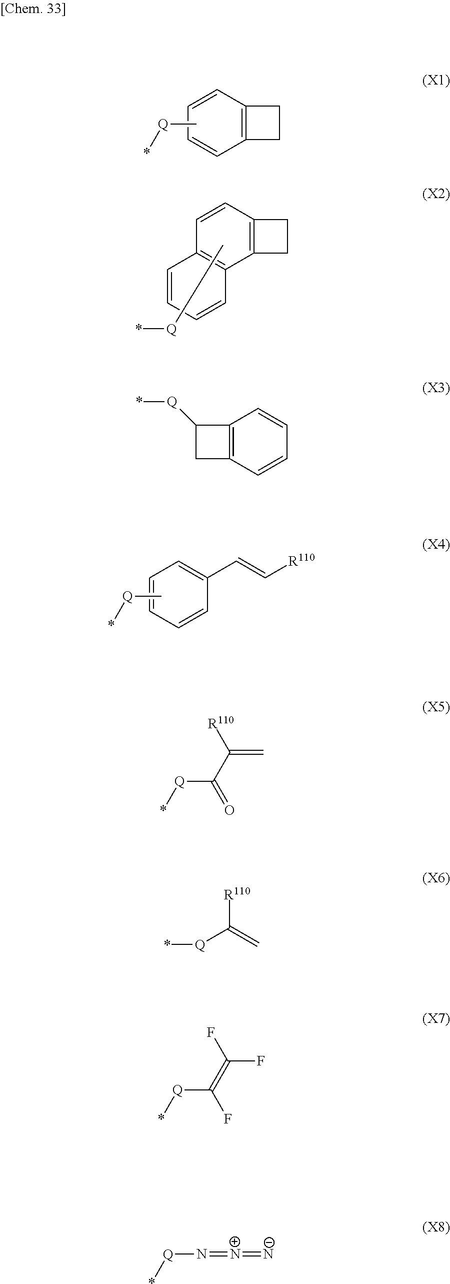

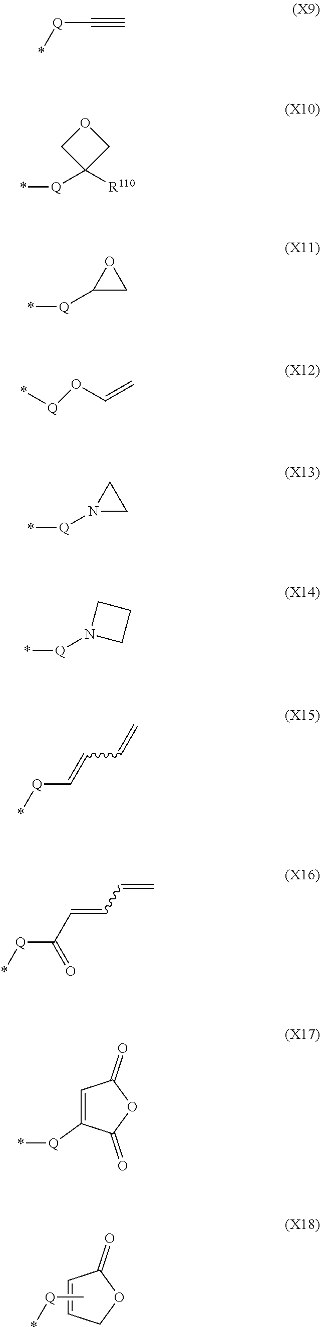

(In formulas (X1) to (X18), Q represents a direct bond or a linking group, and

* represents a bonding position.

In formulas (X4), (X5), (X6), and (X10), R¹¹⁰ represents a hydrogen atom or an alkyl group optionally having a substituent.

In formulas (X1) to (X4), the benzene rings and the naphthalene ring may each optionally have a substituent. Any of the substituents may be bonded together to form a ring.

In formulas (X1) to (X3), each cyclobutene ring may optionally have a substituent.)

When Q is a linking group, no particular limitation is imposed on the linking group. However, the linking group is preferably an alkylene group, a divalent oxygen atom, or a divalent aromatic hydrocarbon group optionally having a substituent.

The alkylene group is generally an alkylene group having 1 to 12 carbon atoms, preferably an alkylene group having 1 to 8 carbon atoms, and more preferably an alkylene group having 1 to 6 carbon atoms.

The number of carbon atoms in the divalent aromatic hydrocarbon group is generally 6 or more and is generally 36 or less, preferably 30 or less, and more preferably 24 or less. The structure of the aromatic hydrocarbon ring is preferably a benzene ring, and the optional substituent can be selected from a substituent group Z described later.

Q is preferably a divalent aromatic hydrocarbon group optionally having a substituent because the reactivity of the crosslinking group can be increased while the performance of the element is maintained.

The alkyl group represented by R¹¹⁰ has a linear, branched, or cyclic structure, and the number of carbon atoms in the alkyl group is 1 or more and is preferably 24 or less, more preferably 12 or less, and still more preferably 8 or less.

The optional substituents on the benzene and naphthalene rings in formulas (X1) to (X4) and R¹¹⁰ in formulas (X4), (X6), and (X10) are each preferably an alkyl group, an aromatic hydrocarbon group, an alkyloxy group, or an aralkyl group.

The alkyl group serving as a substituent has a linear, branched, or cyclic structure, and the number of carbon atoms in the alkyl group is preferably 24 or less, more preferably 12 or less, and still more preferably 8 or less and is preferably 1 or more.

The number of carbon atoms in the aromatic hydrocarbon group serving as a substituent is preferably 24 or less, more preferably 18 or less, and still more preferably 12 or less and is preferably 6 or more. The aromatic hydrocarbon group may further optionally have the above-described alkyl group as a substituent.

The number of carbon atoms in the alkyloxy group serving as a substituent is preferably 24 or less, more preferably 12 or less, and still more preferably 8 or less and is preferably 1 or more.

The number of carbon atoms in the aralkyl group serving as a substituent is preferably 30 or less, more preferably 24 or less, and still more preferably 14 or less and is preferably 7 or more. Preferably, the alkylene group included in the aralkyl group has a linear or branched structure. The aryl group included in the aralkyl group may further optionally have the above-described alkyl group as a substituent.

The optional substituents on the cyclobutene rings in formulas (X1), (X2), and (X3) are each preferably an alkyl group. The alkyl group serving as a substituent has a linear, branched, or cyclic structure, and the number of carbon atoms in the alkyl group is preferably 24 or less, more preferably 12 or less, and still more preferably 8 or less and is preferably 1 or more.

The crosslinking group is preferably any of the crosslinking groups represented by formulas (X1) to (X3) because their polarity is small, their influence on charge transportability is small, and the crosslinking reaction can be initiated only by heat.

In the crosslinking group represented by formula (X1), the cyclobutene ring undergoes ring-opening by heat, and the ring-opened groups are bonded together to form a crosslinked structure as shown by a formula below. In the following description, the linking groups Q in formulas (X1) to (X4) etc. are omitted.

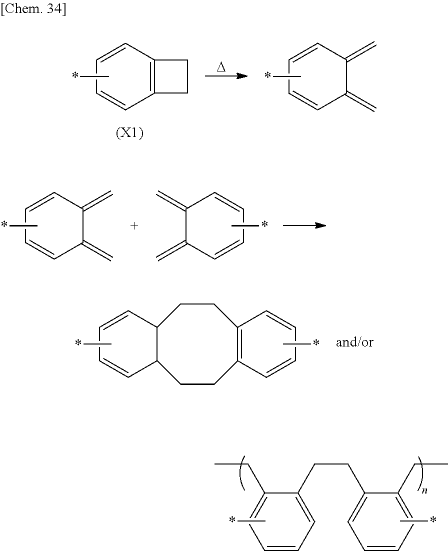

In the crosslinking group represented by formula (X2), the cyclobutene ring undergoes ring-opening by heat, and the ring-opened groups are bonded together to form a crosslinked structure as shown by the following formula.

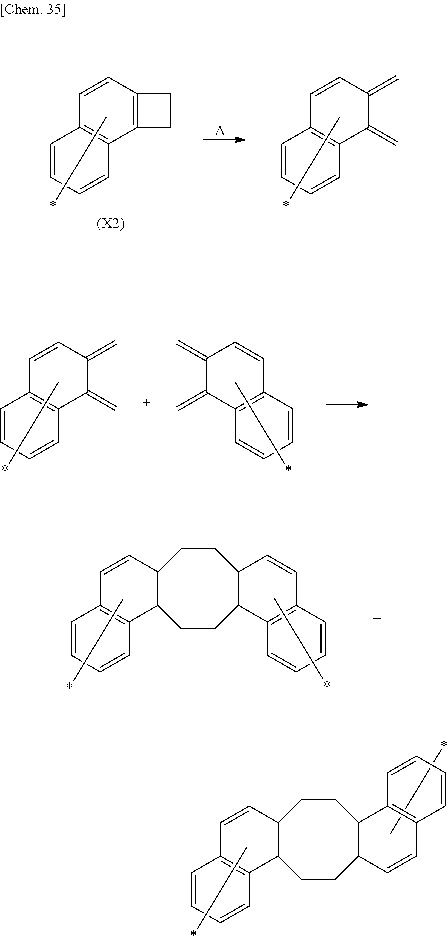

In the crosslinking group represented by formula (X3), the cyclobutene ring undergoes ring-opening by heat, and the ring-opened groups are bonded together to form a crosslinked structure as shown by the following formula.

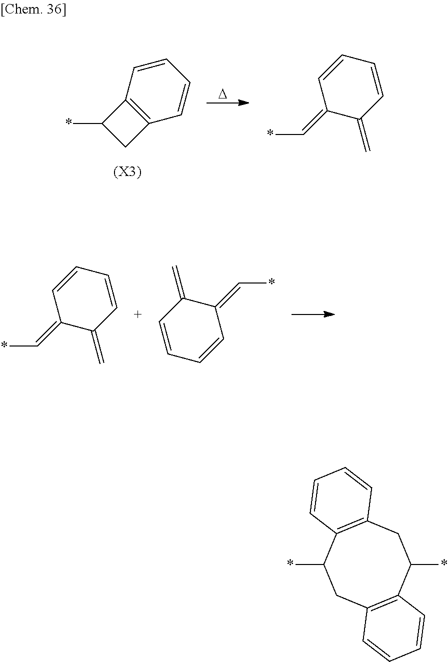

In the crosslinking group represented by any of formulas (X1) to (X3), the cyclobutene ring undergoes ring-opening by heat. When a double bond is present near the ring-opened group, the ring-opened group reacts with the double bond to form a crosslinked structure.

An example in which the ring-opened group obtained as a result of ring-opening of the crosslinking group represented by formula (X1) and the crosslinking group represented by formula (X4) and having a double bond form a crosslinked structure is shown below.

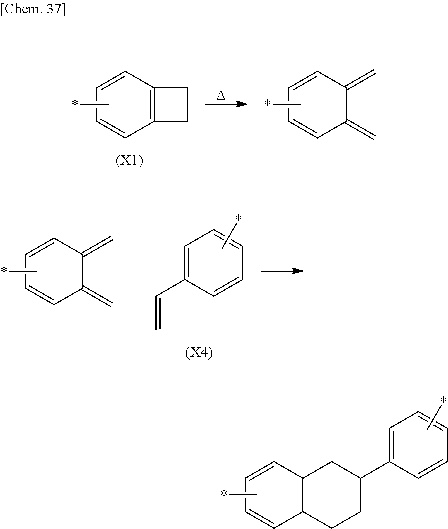

Examples of the group having a double bond reactable with the crosslinking group represented by any of formulas (X1) to (X3) include, in addition to the crosslinking group represented by formula (X4), crosslinking groups represented by formulas (X5), (X6), (X12), (X15), (X16), (X17), and (X18). When any of these groups each having a double bond is used as the crosslinking group in the electron accepting compound, it is preferable that the crosslinking group represented by any of formulas (X1) to (X3) is included in a component such as a hole transport compound that is included in a hole injection layer and/or a hole transport layer, because the possibility that a crosslinked structure is formed increases.

The crosslinking group is preferably a radical polymerizable crosslinking group represented by any of formulas (X4), (X5), and (X6) because their polarity is small and they are unlikely to impede charge transport.

In view of increasing the electron acceptability, the crosslinking group is preferably a crosslinking group represented by formula (X7). With the crosslinking group represented by formula (X7), the following crosslinking reaction proceeds.

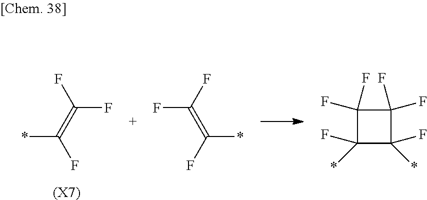

The crosslinking group represented by any of formulas (X8) and (X9) is preferred because of their high reactivity. When the crosslinking group represented by formula (X8) and the crosslinking group represented by formula (X9) are used, the following crosslinking reaction proceeds.

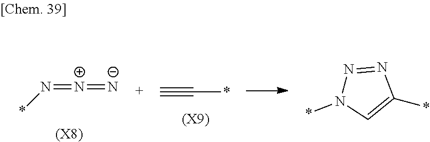

The crosslinking group is preferably a cationic polymerizable crosslinking group represented by any of formulas (X10), (X11), and (X12) because of their high reactivity.

From the viewpoint of improving the stability after crosslinking and the performance of the element, it is preferable that at least one of the high-molecular weight charge transport compound, the low-molecular weight charge transport compound, and the electron accepting compound contained in the composition of the invention and described later has the crosslinking group represented by any of formulas (X1) to (X4), and it is more preferable that at least one of them has the crosslinking group represented by formula (X2) or (X4). In the crosslinking group represented by formula (X4), R¹¹⁰ is preferably a substituent, and preferred examples of the substituent are as described above.

### <Substituents>

In the following description of the structures of the high-molecular weight compound, the low-molecular weight compound, and the electron accepting compound in the invention, each of the substituents can be any group, unless otherwise specified. However, the substituent is preferably a group selected from a substituent group Z described below and more preferably a group selected from a substituent group X described below. In the description of the structures of the high-molecular weight compound and the low-molecular weight compound in the invention, when it is stated that the optional substituent is selected from the substituent group Z, particularly from the substituent group X, or that it is preferable to select the optional substituent from the substituent group Z, particularly from the substituent group X, preferred examples of the substituent are those described in the substituent group Z and the substituent group X below.

### <Substituent Group Z>

The substituent group Z is the group consisting of alkyl groups, alkenyl groups, alkynyl groups, alkoxy groups, aryloxy groups, heteroaryloxy groups, alkoxycarbonyl groups, dialkylamino groups, diarylamino groups, arylalkylamino groups, acyl groups, halogen atoms, haloalkyl groups, alkylthio groups, arylthio groups, silyl groups, siloxy groups, a cyano group, aromatic hydrocarbon groups, and aromatic heterocyclic groups. These substituents may each include a linear, branched, or cyclic structure.

Among the substituent group Z, structures described in the following substituent group X are preferred.

### <Substituent Group X>

Alkyl groups having 1 to 24 carbon atoms,
alkenyl groups having 2 to 24 carbon atoms,
alkynyl groups having 2 to 24 carbon atoms,
alkoxy groups having 1 to 24 carbon atoms,
aryloxy groups and heteroaryloxy groups having 4 to 36 carbon atoms,
alkoxycarbonyl groups having 2 to 24 carbon atoms,
dialkylamino groups having 2 to 24 carbon atoms,
diarylamino groups having 10 to 36 carbon atoms,
arylalkylamino groups having 7 to 36 carbon atoms,
acyl groups having 2 to 24 carbon atoms,
halogen atoms,
haloalkyl groups having 1 to 12 carbon atoms,
alkylthio groups having 1 to 24 carbon atoms,
arylthio groups having 4 to 36 carbon atoms,
silyl groups having 2 to 36 carbon atoms,
siloxy groups having 2 to 36 carbon atoms,
a cyano group,
aromatic hydrocarbon groups having 6 to 36 carbon atoms, and
aromatic heterocyclic groups having 4 to 36 carbon atoms.

These substituent may each include a linear, branched, or cyclic structure. When any of the substituents are adjacent to each other, the substituents adjacent to each other may be bonded together to form a ring.

More specific examples of the substituent group X include the following structures.

Linear, branched, and cyclic alkyl groups having 1 or more carbon atoms and preferably 4 or more carbon atoms and having 24 or less carbon atoms, preferably 12 or less carbon atoms, still more preferably 8 or less carbon atoms, and yet more preferably 6 or less carbon atoms. Specific examples include a methyl group, an ethyl group, a n-propyl group, an i-propyl group, a n-butyl group, an i-butyl group, a sec-butyl group, a tert-butyl group, a n-hexyl group, a cyclohexyl group, and a dodecyl group.

Linear, branched, and cyclic alkyl groups having generally 2 or more carbon atoms and having generally 24 or less carbon atoms and preferably 12 or less carbon atoms. Specific examples include a vinyl group.

Linear and branched alkynyl groups having generally 2 or more carbon atoms and generally 24 or less carbon atoms and preferably 12 or less carbon atoms. Specific examples include an ethynyl group.

Alkoxy groups having 1 or more carbon atoms and having 24 or less carbon atoms and preferably 12 or less carbon atoms. Specific examples include a methoxy group and an ethoxy group.

Aryloxy groups and heteroaryloxy groups having 4 or more carbon atoms and preferably 5 carbon atoms and having 36 or less carbon atoms and preferably 24 or less carbon atoms. Specific examples include a phenoxy group, a naphthoxy group, and a pyridyloxy group.

Alkoxycarbonyl groups having 2 or more carbon atoms and having 24 or less carbon atoms and preferably 12 or less carbon atoms. Specific examples include a methoxycarbonyl group and an ethoxycarbonyl group.

Dialkylamino groups having 2 or more carbon atoms and having 24 or less carbon atoms and preferably 12 or less carbon atoms. Specific examples include a dimethylamino group and a diethylamino group.

Diarylamino groups having 10 or more carbon atoms and preferably 12 or more carbon atoms and having 36 or less carbon atoms and preferably 24 or less carbon atoms. Specific examples include a diphenylamino group, a ditolylamino group, and an N-carbazolyl group.

Arylalkylamino groups having 7 or more carbon atoms and having 36 or less carbon atoms and preferably 24 or less carbon atoms. Specific examples include a phenylmethylamino group.

Acyl groups having 2 or more carbon atoms and having 24 or less carbon atoms and preferably 12 or less carbon atoms. Specific examples include an acetyl group and a benzoyl group.

Halogen atoms such as a fluorine atom and a chlorine atom. A fluorine atom is preferred.

Haloalkyl groups having 1 or more carbon atoms and having 12 or less carbon atoms and preferably 6 or less carbon atoms. Specific examples include a trifluoromethyl group.

Alkylthio groups having 1 or more carbon atoms and having generally 24 carbon atoms and preferably 12 or less carbon atoms. Specific examples include a methylthio group and an ethylthio group.

Arylthio groups having 4 or more carbon atoms and preferably 5 or more carbon atoms and having 36 or less carbon atoms and preferably 24 or less carbon atoms. Specific examples include a phenylthio group, a naphthylthio group, and a pyridylthio group.

Silyl groups having generally 2 or more carbon atoms and preferably 3 or more carbon atoms and having generally 36 or less carbon atoms and preferably 24 or less carbon atoms. Specific examples include a trimethylsilyl group and a triphenylsilyl group.

Siloxy groups having 2 or more carbon atoms and preferably 3 or more carbon atoms and having generally 36 or less carbon atoms and preferably 24 or less carbon atoms. Specific examples include a trimethylsiloxy group and a triphenylsiloxy group.

A cyano group.

Aromatic hydrocarbon groups having 6 or more carbon atoms and having 36 or less carbon atoms and preferably 24 or less carbon atoms. Specific examples include a phenyl group, a naphthyl group, groups including a plurality of phenyl groups linked together.

Aromatic heterocyclic groups having 3 or more carbon atoms and preferably 4 or more carbon atoms and having 36 or less carbon atoms and preferably 24 or less carbon atoms. Specific examples include a thienyl group and a pyridyl group.

Each of the above substituents may include a linear, branched, or cyclic structure.

When any of these substituents are adjacent to each other, the substituents adjacent to each other may be bonded together to form a ring. A preferred size of the ring is a 4-membered ring, a 5-membered ring, or a 6-membered ring, and specific examples include a cyclobutane ring, a cyclopentane ring, and a cyclohexane ring.

Among the substituent group Z and the substituent group X, alkyl groups, alkoxy groups, aromatic hydrocarbon groups, and aromatic heterocyclic groups are preferred.

The substituents in the substituent group Z and the substituent group X may each further optionally have an additional substituent. Examples of the optional additional substituent include those in the substituent group Z and the substituent group X and crosslinking groups. Preferably, these substituents do not have an additional substituent. When these substituents each have an additional substituent, the additional substituent is preferably an alkyl group having 8 or less carbon atoms, an alkoxy group having 8 or less carbon atoms, or a phenyl group and more preferably an alkyl group having 6 or less carbon atoms, an alkoxy group having 6 or less carbon atoms, or a phenyl group. From the viewpoint of charge transportability, it is more preferable that these substituents have no additional substituent.

When the additional substituent optionally included in each of the substituents in the substituent group Z and the substituent group X is a crosslinking group, the crosslinking group is preferably a crosslinking group selected from the group T of crosslinking groups. Each substituent preferably having an additional crosslinking group is an alkyl group or an aromatic hydrocarbon group.

### [High-Molecular Weight Charge Transport Compound]

Preferably, the composition of the invention contains a high-molecular weight hole transport compound as the high-molecular weight charge transport compound. The high-molecular weight hole transport compound is generally used to form a hole injection layer or a hole transport layer and is contained in a hole injection layer-forming composition described later, a hole transport layer-forming composition described later, or a light-emitting layer-forming composition described later. The composition of the invention is a hole injection layer-forming composition or a hole transport layer-forming composition.

The high-molecular weight hole transport compound is preferably a polymer having an arylamine structure described below as a repeating unit and having a crosslinking group.

### [Polymer Having Arylamine Structure as Repeating Unit]

The high-molecular weight hole transport compound contained in the composition of the invention as the high-molecular weight charge transport compound is preferably a polymer having an arylamine structure as a repeating unit. The arylamine structure serving as a repeating unit is represented by the following formula (50).

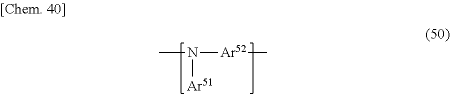

(In formula (50),

Ar⁵¹ represents an aromatic hydrocarbon group, an aromatic heterocyclic group, or a group in which a plurality of groups selected from aromatic hydrocarbon groups and aromatic heterocyclic groups are linked together.

Ar⁵² represents a divalent aromatic hydrocarbon group, a divalent aromatic heterocyclic group, or a divalent group in which a plurality of groups selected from the group consisting of divalent aromatic hydrocarbon groups and divalent aromatic heterocyclic groups are linked together directly or via a linking group.

Ar⁵¹ and Ar⁵² do not form a ring via a single bond or a linking group.

Ar⁵¹ and Ar⁵² may each optionally have a substituent and/or a crosslinking group.)

The optional substituents on Ar⁵¹ and Ar⁵² are preferably substituents selected from the substituent group Z, particularly from the substituent group X.

The optional crosslinking groups on Ar⁵¹ and Ar⁵² are preferably crosslinking groups selected from the group T of crosslinking groups.

The polymer having the arylamine structure represented by formula (50) as a repeating unit has a crosslinking group. The phrase “the polymer having the arylamine structure represented by formula (50) as a repeating unit has a crosslinking group” means that at least one repeating unit that has the arylamine structure represented by formula (50) and is contained in the polymer has a crosslinking group and/or that a repeating unit that is different from the repeating unit represented by formula (50) and is contained in the polymer has a crosslinking group.

Preferably, in the polymer, at least one repeating unit having the arylamine structure represented by formula (50) has a crosslinking group.

When the repeating unit having the arylamine structure represented by formula (50) has a crosslinking group, Ar⁵¹ and/or Ar⁵² has a crosslinking group. Preferably, Ar⁵¹ has a crosslinking group.

### (Terminal Group)

In the present description, the terminal group of a polymer is the structure of a terminal portion of the polymer that is formed by an end-capping agent used at the end of the polymerization of the polymer. In the composition of the invention, the terminal group of the polymer including the repeating unit represented by formula (50) is preferably a hydrocarbon group. From the viewpoint of charge transportability, the hydrocarbon group is preferably a hydrocarbon group having 1 to 60 carbon atoms, more preferably a hydrocarbon group having 1 to 40 carbon atoms, and still more preferably a hydrocarbon group having 1 to 30 carbon atoms.

Examples of the hydrocarbon group include:
linear, branched, and cyclic alkyl groups having generally 1 or more carbon atoms and preferably 4 or more carbon atoms and having generally 24 or less carbon atoms and preferably 12 or less carbon atoms such as a methyl group, an ethyl group, a n-propyl group, an i-propyl group, a n-butyl group, an i-butyl group, a sec-butyl group, a tert-butyl group, a n-hexyl group, a cyclohexyl group, and a dodecyl group;
linear, branched, and cyclic alkenyl groups having generally 2 or more carbon atoms and having generally 24 or less carbon atoms and preferably 12 or less carbon atoms such as a vinyl group;
linear and branched alkynyl groups having generally 2 or more carbon atoms and having generally 24 or less carbon atoms and preferably 12 or less carbon atoms such as an ethynyl group;
aromatic hydrocarbon groups having generally 6 or more carbon atoms and having generally 36 carbon atoms and preferably 24 or less carbon atoms such as a phenyl group and a naphthyl group; and
crosslinking groups that are hydrocarbon groups in the group T of crosslinking groups and are preferably crosslinking groups represented by formulas (X1) to (X4).

These hydrocarbon groups may each optionally have an additional substituent, and the optional additional substituent is preferably an alkyl group or an aromatic hydrocarbon group. When a plurality of optional additional substituents are present, they may be bonded together to form a ring. When these hydrocarbon groups are groups different from crosslinking groups, the substituent may further have a crosslinking group selected from the group T of crosslinking groups as an additional substituent.

From the viewpoint of charge transportability and durability, the terminal group is preferably an alkyl group, an aromatic hydrocarbon group, or a crosslinking group selected from the hydrocarbon groups in the group T of crosslinking groups and more preferably an aromatic hydrocarbon group. When the terminal group is not a crosslinking group, it is also preferable that the terminal group has a crosslinking group selected from the group T of crosslinking groups as a substituent.

### (Ar⁵²)

Ar⁵² represents a divalent aromatic hydrocarbon group, a divalent aromatic heterocyclic group, or a divalent group in which a plurality of groups selected from the group consisting of divalent aromatic hydrocarbon groups and divalent aromatic heterocyclic groups are linked together directly or via a linking group. The aromatic hydrocarbon group and the aromatic heterocyclic group may each optionally have a substituent and/or a crosslinking group.

The optional substituent is preferably a substituent selected from the substituent group Z. The optional crosslinking group is preferably a crosslinking group selected from the group T of crosslinking groups.

### (Ar⁵¹)

Ar⁵¹ is an aromatic hydrocarbon group, an aromatic heterocyclic group, or a group in which a plurality of groups selected from aromatic hydrocarbon groups and aromatic heterocyclic groups are linked together. The aromatic hydrocarbon group and the aromatic heterocyclic group may each optionally have a substituent and/or a crosslinking group.

The optional substituent is preferably a substituent selected from the substituent group Z, particularly from the substituent group X. The optional crosslinking group is preferably a crosslinking group selected from the group T of crosslinking groups.

From the viewpoint of improving the stability of the film, it is preferable that Ar⁵¹ has a crosslinking group.

### (Preferred Structure of Ar⁵¹ Having Crosslinking Group)

When Ar⁵¹ has a crosslinking group, it is preferable that Ar⁵¹ has a structure in which a monovalent group including 2 to 5 optionally substituted benzene rings linked together has at its terminal end a crosslinking group selected from the group T of crosslinking groups. It is more preferable that Ar⁵¹ has a structure in which a monovalent group including 2 to 5 non-substituted benzene rings linked together has at its terminal end a crosslinking group selected from the group T of crosslinking groups.

### <Preferred Ar⁵¹>

From the viewpoint of obtaining good charge transportability and good durability, Ar⁵¹ is preferably an aromatic hydrocarbon group, more preferably a benzene ring (phenyl group), a group including 2 to 5 benzene rings linked together, or a monovalent group including a fluorene ring (a fluorenyl group), still more preferably a fluorenyl group, and particularly preferably a 2-fluorenyl group. These groups may each optionally have a substituent and/or a crosslinking group. The substituent is preferably a group selected from the substituent group Z, particularly from the substituent group X, and the crosslinking group is preferably a crosslinking group selected from the group T of crosslinking groups.

No particular limitation is imposed on the optional substituent on each of the aromatic hydrocarbon group and the aromatic heterocyclic group represented by Ar⁵¹ so long as the characteristics of the polymer are not significantly impaired. The substituent is preferably a group selected from the substituent group Z, particularly from the substituent group X, more preferably an alkyl group, an alkoxy group, an aromatic hydrocarbon group, or an aromatic heterocyclic group, and still more preferably an alkyl group.

From the viewpoint of solubility in a solvent, Ar⁵¹ is preferably a fluorenyl group substituted with an alkyl group having 1 to 24 carbon atoms and particularly preferably a 2-fluorenyl group substituted with an alkyl group having 4 to 12 carbon atoms. Ar⁵¹ is still more preferably a 9-alkyl-2-fluorenyl group obtained by substituting a 2-fluorenyl group with an alkyl group at the 9-position and particularly preferably a 9,9′-dialkyl-2-fluorenyl group substituted with 2 alkyl groups.

When Ar⁵¹ is a fluorenyl group substituted with an alkyl group at at least one of the 9- and 9′-positions, the solubility in a solvent and the durability of the fluorene ring tend to be improved. When Ar⁵¹ is a fluorenyl group substituted with alkyl groups at both the 9- and 9′-positions, the solubility in a solvent and the durability of the fluorene ring tend to be further improved.

From the viewpoint of the solubility in a solvent, Ar⁵¹ is also preferably a spirobifluorenyl group.

In the polymer including the repeating unit represented by formula (50), it is preferable that the repeating unit represented by formula (50) is a repeating unit in which Ar⁵¹ is a group represented by formula (51) below, a group represented by formula (52) below, or a group represented by formula (53) below.

### <Group Represented by Formula (51)>

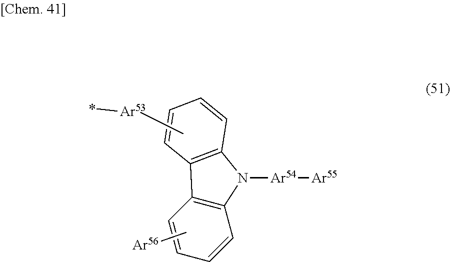

(In formula (51),

* represents a bond to the nitrogen atom in the main chain in formula (50).

Ar⁵³ and Ar⁵⁴ each independently represents a divalent aromatic hydrocarbon group optionally having a substituent and/or a crosslinking group, an aromatic heterocyclic group optionally having a substituent and/or a crosslinking group, or a divalent group in which a plurality of aromatic hydrocarbon groups each optionally having a substituent and/or a crosslinking group or a plurality of aromatic heterocyclic groups each optionally having a substituent and/or a crosslinking group are linked together directly or via a linking group.

Ar⁵⁵ represents an aromatic hydrocarbon group optionally having a substituent and/or a crosslinking group, an aromatic heterocyclic group optionally having a substituent and/or a crosslinking group, or a monovalent group in which aromatic hydrocarbon or aromatic heterocyclic groups each optionally having a substituent and/or a crosslinking group are linked together directly or via a linking group.

Ar⁵⁶ represents a hydrogen atom, a substituent, or a crosslinking group.)

The aromatic hydrocarbon groups and the aromatic heterocyclic groups may each optionally have a substituent and/or a crosslinking group.

The optional substituent is preferably a group selected from the substituent group Z, particularly from the substituent group X. The optional crosslinking group is preferably a group selected from the group T of crosslinking groups.

### (Ar⁵³)

Ar⁵³ is preferably a group including 1 to 6 divalent aromatic hydrocarbon groups linked together, more preferably a group including 2 to 4 divalent aromatic hydrocarbon groups linked together, still more preferably a group including 1 to 4 phenylene rings linked together, and particularly preferably a biphenylene group including two phenylene rings linked together.

These groups may each optionally have a substituent and/or a crosslinking group. The optional substituent is preferably a group selected from the substituent group Z, particularly from the substituent group X. The optional crosslinking group is preferably a group selected from the group T of crosslinking groups. Preferably, Ar⁵³ has no substituent and no crosslinking group.

When these divalent aromatic hydrocarbon groups or divalent aromatic heterocyclic groups are linked together, it is preferable that the resulting group is a group in which the plurality of bonded divalent aromatic hydrocarbon groups are bonded so as not to be conjugated to each other. Specifically, the resulting group includes preferably a 1,3-phenylene group or a group having a substituent and having a twisted structure due to a steric effect of the substituent and is more preferably a 1,3-phenylene group having no substituent and no crosslinking group or a group in which a plurality of 1,3-phenylene groups having no substituent and no crosslinking group are linked together.

### (Ar⁵⁴)

From the viewpoint of obtaining good charge transportability and good durability, Ar⁵⁴ is preferably one divalent aromatic hydrocarbon group or a group in which a plurality of divalent aromatic hydrocarbon groups that may be the same or different are linked together. Each divalent aromatic hydrocarbon group may optionally have a substituent. When a plurality of divalent aromatic hydrocarbon groups are linked together, the number of linked groups is preferably 2 to 10, more preferably 6 or less, and particularly preferably 3 or less from the viewpoint of the stability of the film. The aromatic hydrocarbon ring structure is preferably a benzene ring, a naphthalene ring, an anthracene ring, or a fluorene ring and more preferably a benzene ring or a fluorene ring. The group including a plurality of divalent aromatic hydrocarbon groups linked together is preferably a group including 1 to 4 phenylene rings linked together or a group including a phenylene ring and a fluorene ring linked together. It is particularly preferable to use a biphenylene group including two phenylene rings linked together because the LUMO spreads widely.

These groups may each optionally have a substituent and/or a crosslinking group. The optional substituent is preferably a group selected from the substituent group Z, particularly from the substituent group X. The optional crosslinking group is preferably a group selected from the group T of crosslinking groups. The substituent is more preferably a phenyl group, a naphthyl group, or a fluorenyl group. It is also preferable that no substituent is included.

### (Ar⁵⁵)

Ar⁵⁵ is an aromatic hydrocarbon group optionally having a substituent and/or a crosslinking group, an aromatic heterocyclic group optionally having a substituent and/or a crosslinking group, or a monovalent group in which a plurality of aromatic hydrocarbon or aromatic heterocyclic groups each optionally having a substituent and/or a crosslinking group are linked together directly or via a linking group. Preferably, Ar⁵⁵ is a monovalent aromatic hydrocarbon group or a group including a plurality of monovalent aromatic hydrocarbon groups linked together.

These groups may each optionally have a substituent and/or a crosslinking group. The optional substituent is preferably a group selected from the substituent group Z, particularly from the substituent group X. The optional crosslinking group is preferably a group selected from the group T of crosslinking groups.

When these groups are linked together, the resulting group is a monovalent group including 2 to 10 groups linked together and preferably a monovalent group including 2 to 5 groups linked together. The aromatic hydrocarbon group and the aromatic heterocyclic group used may be the same as the aromatic hydrocarbon group and the aromatic heterocyclic group, respectively, described above for Ar⁵¹.

Preferably, Ar⁵⁵ has a structure represented by any of the following schemes 2A, 2B, and 2C.

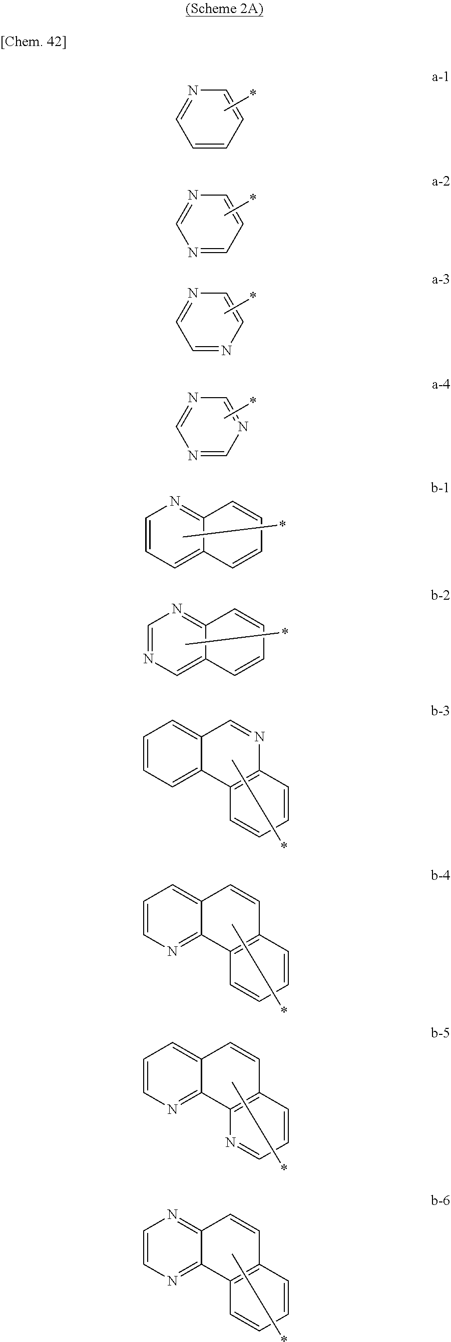

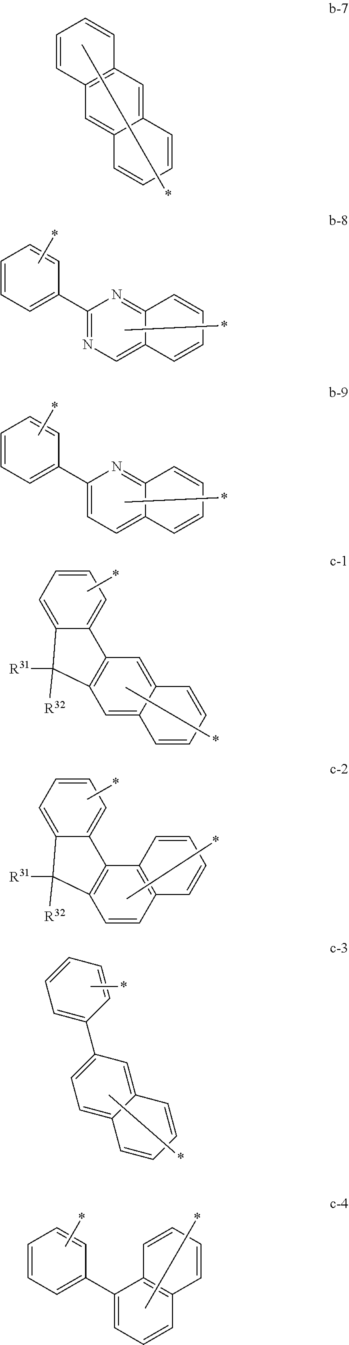

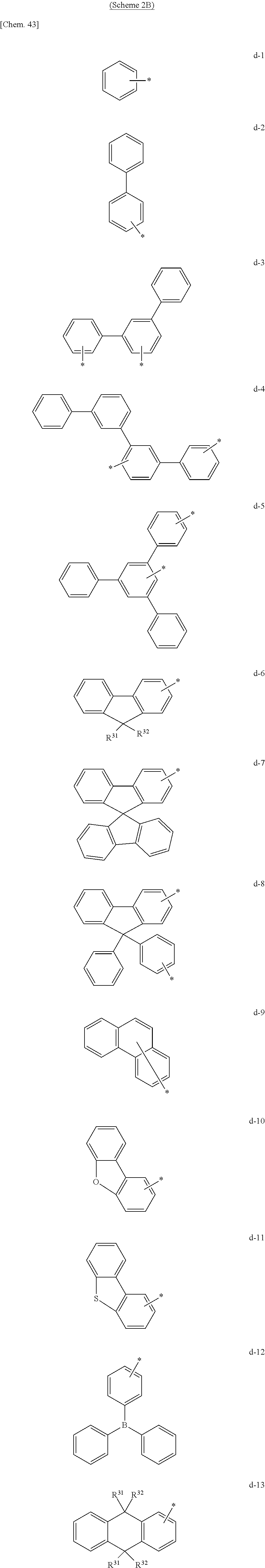

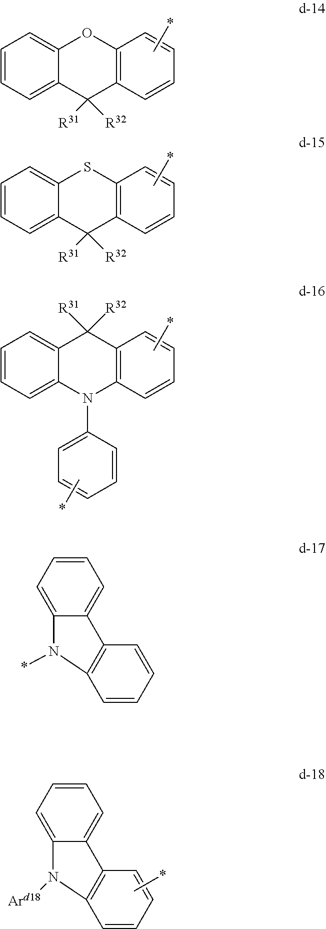

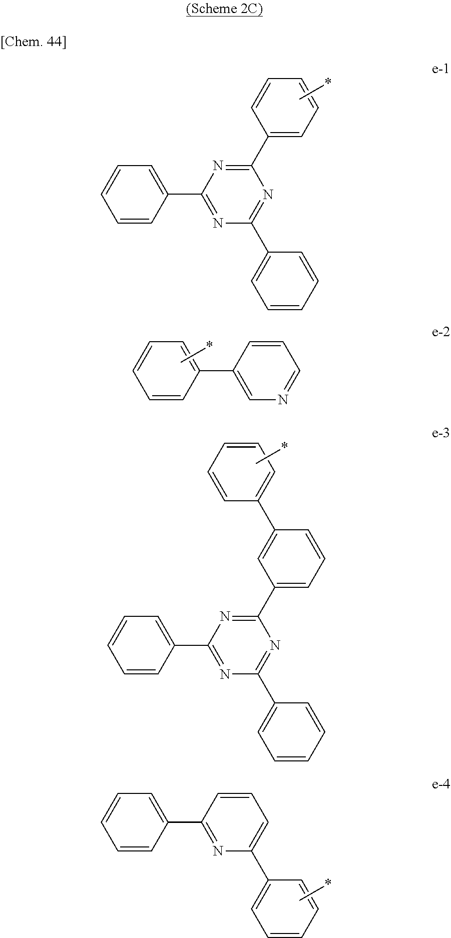

In schemes 2A to 2C above, * represents a position of bonding to Ar⁵⁴. When a plurality of *'s are present, one of them represents a position of bonding to Ar⁵⁴.

These structures may each optionally have a substituent and/or a crosslinking group. The optional substituent on each of these structures is preferably a group selected from the substituent group Z, particularly from the substituent group X. The optional crosslinking group is preferably a group selected from the group T of crosslinking groups.

(R³¹ and R³²)

R³¹ and R³² in schemes 2A and 2B are each independently preferably a linear, branched, or cyclic alkyl group optionally having a substituent. No particular limitation is imposed on the number of carbon atoms in the alkyl group. To maintain the solubility of the polymer, the number of carbon atoms is preferably 1 or more and 6 or less and more preferably 3 or less, and the alkyl group is still more preferably a methyl group or an ethyl group.

R³¹(s) and R³²(s) may be the same or different. Preferably, R³¹(s) and R³²(s) are all the same because charges can be uniformly distributed around nitrogen atoms and the polymer can be easily synthesized.

### (Ar^{d18})

Ar^{d18} in scheme 2B is each independently an aromatic hydrocarbon group or an aromatic heterocyclic group. From the viewpoint of stability, Ar^{d18} is preferably an aromatic hydrocarbon group and more preferably a phenyl group. These groups may each optionally have a substituent or a crosslinking group. The optional substituent is preferably a group selected from the substituent group Z, particularly from the substituent group X. The optional crosslinking group is preferably a group selected from the group T of crosslinking groups.

From the viewpoint of the distribution of the LUMO of the molecule, Ar⁵⁵ is preferably a structure selected from a-1 to a-4, b-1 to b-9, c-1 to c-4, d-1 to d-18, and e-1 to e-4 shown above. From the viewpoint of facilitating the spreading of the LUMO when an electron-withdrawing group is present, Ar⁵⁵ is preferably a structure selected from a-1 to a-4, b-1 to b-9, d-1 to d-12, d-17, d-18, and e-1 to e-4. From the viewpoint of the effect of confining excitons having a high triplet level and formed in a light-emitting layer, Ar⁵⁵ is preferably a structure selected from a-1 to a-4, d-1 to d-12, d-17, d-18, and e-1 to e-4. From the viewpoint of the ease of synthesis and high stability, Ar⁵⁵ is more preferably a structure selected from d-1, d-10, d-17, d-18, and e-1 and particularly preferably a benzene ring structure in d-1, a fluorene ring structure in d-6, or a carbazole structure in d-17.

When Ar⁵⁵ is a fluorene structure represented by d-6, Ar⁵⁵ is preferably a 2-fluorenyl group. The 2-fluorenyl group may optionally have a substituent and/or a crosslinking group at each of the 9- and 9′-positions. The optional substituent is preferably a group selected from the substituent group Z, particularly from the substituent group X. The optional crosslinking group is preferably a group selected from the group T of crosslinking groups. The substituent is particularly preferably an alkyl group.

### (Ar⁵⁶)

Ar⁵⁶ represents a hydrogen atom, a substituent, or a crosslinking group. When Ar⁵⁶ is a substituent, no particular limitation is imposed on the substituent. The substituent is preferably an aromatic hydrocarbon group or an aromatic heterocyclic group and may further optionally have a substituent selected from the substituent group Z and preferably from the substituent group X and/or a crosslinking group selected from the group T of crosslinking groups. When Ar⁵⁶ is a crosslinking group, the crosslinking group is preferably a crosslinking group selected from the group T of crosslinking groups.

When Ar⁵⁶ is a substituent, it is preferable from the viewpoint of improving durability that Ar⁵⁶ is bonded to the 3-position of the carbazole structure in formula (51) to which Ar⁵⁶ is bonded. From the viewpoint of improving durability and of charge transportability, Ar⁵⁶ is preferably an aromatic hydrocarbon group optionally having a substituent or an aromatic heterocyclic group optionally having a substituent and more preferably an aromatic hydrocarbon group optionally having a substituent.

From the viewpoint of the ease of synthesis and charge transportability, Ar⁵⁶ is preferably a hydrogen atom.

### (Specific Examples of Group Represented by Formula (51))

Specific examples of the group represented by formula (51) are shown below. However, the group represented by formula (51) is not limited thereto.

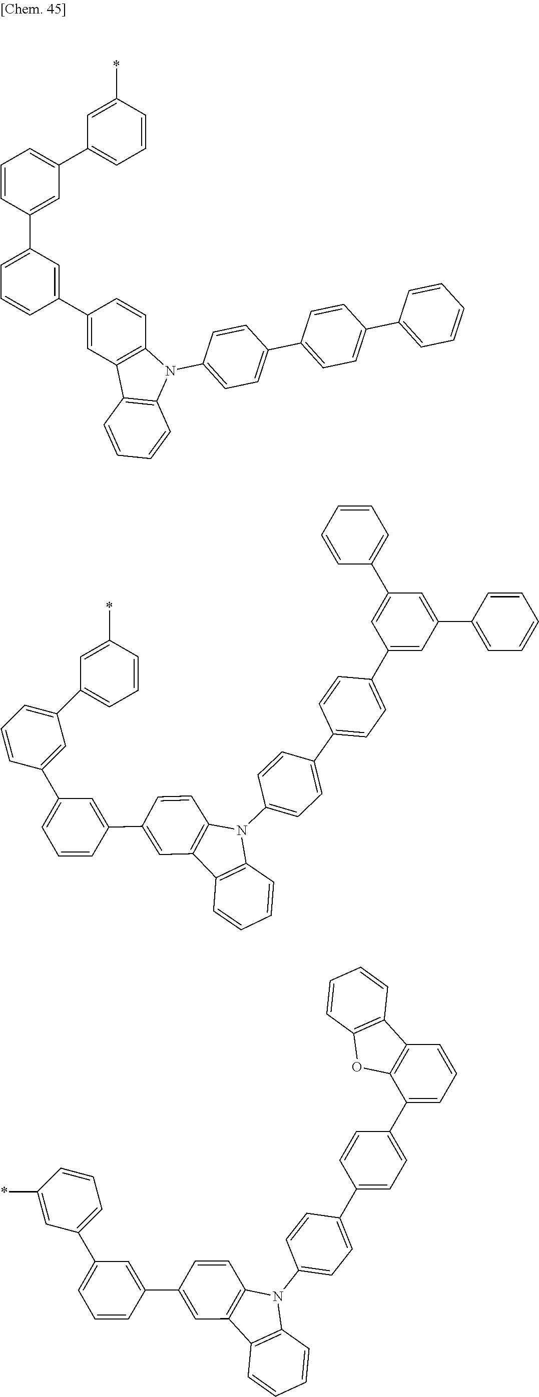 [SMILES: *c1cccc(-c2cccc(-c3cccc(-c4ccc5c(c4)c4ccccc4n5-c4ccc(-c5ccc(-c6ccccc6)cc5)cc4)c3)c2)c1 ; *c1cccc(-c2cccc(-c3cccc(-c4ccc5c(c4)c4ccccc4n5-c4ccc(-c5ccc(-c6cc(-c7ccccc7)cc(-c7ccccc7)c6)cc5)cc4)c3)c2)c1 ; *c1cccc(-c2cccc(-c3ccc4c(c3)c3ccccc3n4-c3ccc(-c4ccc(-c5cccc6c5oc5ccccc56)cc4)cc3)c2)c1]

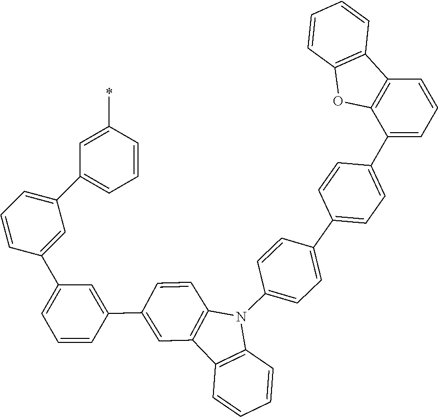 [SMILES: *c1cccc(-c2cccc(-c3cccc(-c4ccc5c(c4)c4ccccc4n5-c4ccc(-c5ccc(-c6cccc7c6oc6ccccc67)cc5)cc4)c3)c2)c1]

### <Group Represented by Formula (52)>

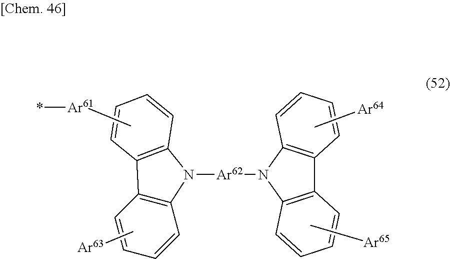

(In formula (52),

Ar⁶¹ and Ar⁶² each independently represent a divalent aromatic hydrocarbon group optionally having a substituent and/or a crosslinking group, a divalent aromatic heterocyclic group optionally having a substituent and/or a crosslinking group, or a divalent group in which a plurality of aromatic hydrocarbon groups each optionally having a substituent and/or a crosslinking group or a plurality of aromatic heterocyclic groups each optionally having a substituent or a crosslinking group are linked together directly or via a linking group.

Ar⁶³ to Ar⁶⁵ are each independently a hydrogen atom, a substituent, or a crosslinking group.

* represents a position of bonding to the nitrogen atom in the main chain in formula (50).)

The optional substituent on each aromatic hydrocarbon group, the optional substituent on each aromatic heterocyclic group, and Ar⁶³ to Ar⁶⁵ when they are each a substituent are each preferably a group selected from the substituent group Z, particularly from the substituent group X.

The optional substituent on each aromatic hydrocarbon group, the optional crosslinking group on each aromatic heterocyclic group, and Ar⁶³ to Ar⁶⁵ when they are each a crosslinking group are each preferably a group selected from the group T of crosslinking groups.

(Ar⁶³ to Ar⁶⁵)

Ar⁶³ to Ar⁶⁵ are each independently the same as Ar⁵⁶ described above.

Ar⁶³ to Ar⁶⁴ are each preferably a hydrogen atom.

### (Ar⁶²)

Ar⁶² is a divalent aromatic hydrocarbon group optionally having a substituent and/or a crosslinking group, a divalent aromatic heterocyclic group optionally having a substituent and/or a crosslinking group, or a divalent group in which a plurality of aromatic hydrocarbon groups each optionally having a substituent and/or a crosslinking group or a plurality of aromatic heterocyclic groups each optionally having a substituent and/or a crosslinking group are linked together directly or via a linking group. Preferably, Ar⁶² is a divalent aromatic hydrocarbon group optionally having a substituent and/or a crosslinking group or a group in which a plurality of divalent aromatic hydrocarbon groups each optionally having a substituent and/or a crosslinking group are linked together. The optional substituent on each aromatic hydrocarbon group and the optional substituent on each aromatic heterocyclic group are each preferably a group selected from the substituent group Z, particularly from the substituent group X. The optional crosslinking group on each aromatic hydrocarbon group and the optional crosslinking group on each aromatic heterocyclic group are each preferably a group selected from the group T of crosslinking groups.

The specific structure of Ar⁶² is the same as that of Ar⁵4.

A specific group represented by Ar⁶² is preferably a divalent group including a benzene ring, a naphthalene ring, an anthracene ring, or a fluorene ring or a group in which a plurality of groups selected from these groups are linked together, more preferably a divalent group including a benzene ring or a group in which a plurality of groups each including a benzene ring are linked together, particularly preferably a 1,4-phenylene group including a divalent benzene ring bonded at its 1- and 4-positions, a 2,7-fluorenylene group including a fluorene ring bonded at its 2- and 7-positions, or a group including a plurality of these groups linked together, and most preferably a group including “1,4-phenylene group-2,7-fluorenylene group-1,4-phenylene group-.”

In the preferred structures of Ar⁶², it is preferable that the phenylene group has no substituent and no crosslinking group at positions other than the bonding positions because Ar⁶² is not twisted due to the steric effect of the substituent. It is preferable from the viewpoint of improving the solubility and the durability of the fluorene structure that the fluorenylene group has substituents or crosslinking groups at the 9- and 9′ positions. The substituents are each preferably a substituent selected from the substituent group Z, particularly from the substituent group X and are each more preferably an alkyl group. Each substituent may be further substituted with a crosslinking group. The crosslinking group is preferably a crosslinking group selected from the group T of crosslinking groups. The substituents are preferred.

### (Ar⁶¹)

Ar⁶¹ is the same group as Ar⁵³ described above, and its preferred structures are also the same as those of Ar⁵³.

### (Specific Example of Group Represented by Formula (52))

A specific example of the group represented by formula (52) is shown below. However, the group represented by formula (52) is not limited to the following group.

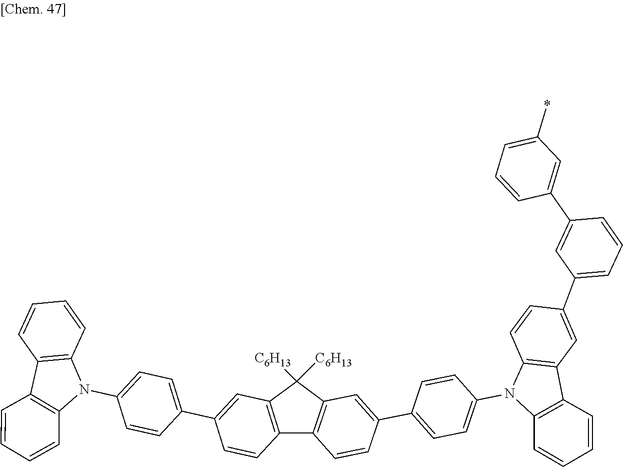

### <Group Represented by Formula (53)>

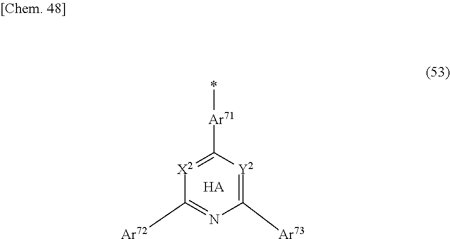

(In formula (53),

* represents a bond to the nitrogen atom in the main chain in formula (50).

Ar⁷¹ represents a divalent aromatic hydrocarbon group.

Ar⁷² and Ar⁷³ each independently represent an aromatic hydrocarbon group, an aromatic heterocyclic group, or a monovalent group in which two or more groups selected from aromatic hydrocarbon groups and aromatic heterocyclic groups are linked together directly or via a linking group. Each of these groups may optionally have a substituent and/or a crosslinking group.

The ring HA is an aromatic heterocycle including a nitrogen atom.

X² and Y² each independently represent a carbon atom or a nitrogen atom. When at least one of X² and Y² is a carbon atom, the carbon atom may optionally have a substituent and/or a crosslinking group.)

The optional substituent is preferably a group selected from the substituent group Z, particularly from the substituent group X. The optional crosslinking group is preferably a group selected from the group T of crosslinking groups.

### <Ar⁷¹>

Ar⁷¹ is the same group as Ar⁵³ described above.

Ar⁷¹ is particularly preferably a group in which 2 to 6 benzene rings each optionally having a substituent are linked together and most preferably a quaterphenylene group in which 4 benzene rings each optionally having a substituent are linked together.

Ar⁷¹ includes preferably at least one benzene ring linked at its 1- and 3-positions, which are non-conjugated sites, and more preferably at least two such benzene rings.

When Ar⁷¹ is a group in which a plurality of divalent aromatic hydrocarbon groups each optionally having a substituent are linked together, it is preferable from the viewpoint of charge transportability or durability that all the divalent aromatic hydrocarbon groups are bonded and linked directly.

Therefore, preferred examples of Ar⁷¹ serving as the structure that connects the nitrogen atom in the main chain of the polymer to the ring HA in formula (53) include those shown in schemes 2-1 and 2-2 below. In schemes 2-1 and 2-2 below, each * represents a position of bonding to the nitrogen atom in the main chain of the polymer or to the ring HA in formula (53). Any one of the two *s may be bonded to the nitrogen atom in the main chain of the polymer or the ring HA.

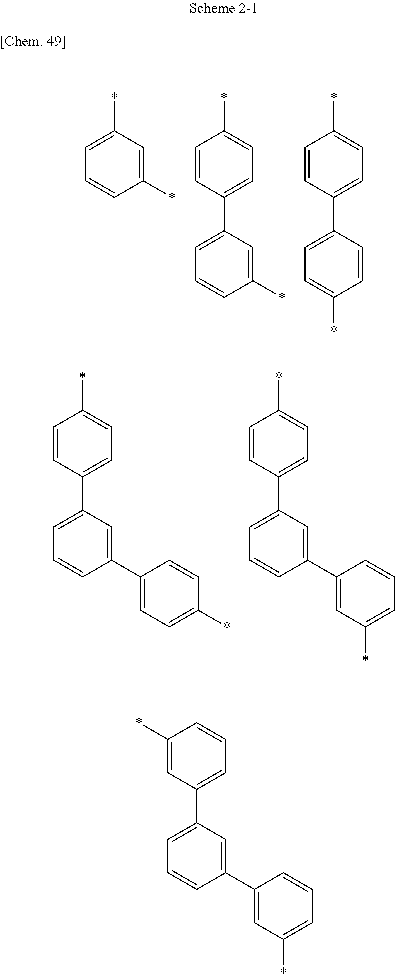

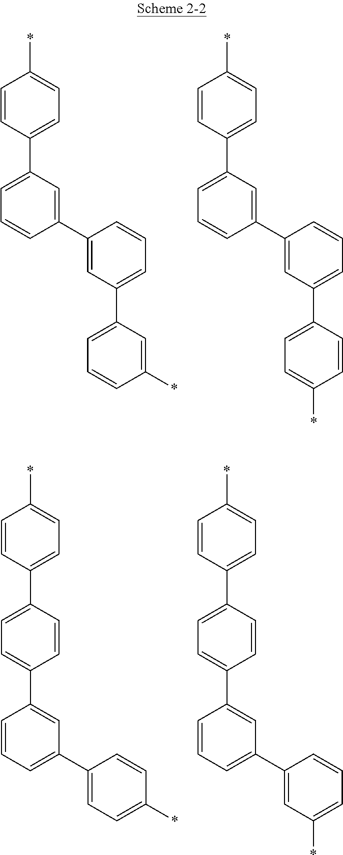 [SMILES: *c1ccc(-c2cccc(-c3cccc(-c4cccc(*)c4)c3)c2)cc1 ; *c1ccc(-c2cccc(-c3cccc(-c4ccc(*)cc4)c3)c2)cc1 ; *c1ccc(-c2ccc(-c3cccc(-c4ccc(*)cc4)c3)cc2)cc1 ; *c1ccc(-c2ccc(-c3cccc(-c4cccc(*)c4)c3)cc2)cc1]

The optional substituent on Ar⁷¹ may be selected from the substituent group Z, particularly from the substituent group X, or may be a combination of substituents selected therefrom. A preferred range of the optional substituent on Ar⁷¹ is the same as that of the optional substituent when Ar⁵³ described above is an aromatic hydrocarbon group.

<X² and Y²>

X² and Y² each independently represent a C (carbon) atom or a N (nitrogen) atom. When at least one of X² and Y² is a carbon atom, the carbon atom may optionally have a substituent.

From the viewpoint of the ease of localizing the LUMO around the ring HA, it is preferable that X² and Y² are each a N atom.

The optional substituent when at least one of X² and Y² is a C atom may be selected from the substituent group Z, particularly from the substituent group X, or may be a combination of substituents selected therefrom. From the viewpoint of charge transportability, it is preferable that X² and Y² have no substituent.

<Ar⁷² and Ar⁷³>

Ar⁷² and Ar⁷³ are each independently an aromatic hydrocarbon group, an aromatic heterocyclic group, or a monovalent group in which two or more groups selected from aromatic hydrocarbon groups and aromatic heterocyclic groups are linked together directly or via a linking group. Each of these groups may optionally have a substituent and/or a crosslinking group. The optional substituent is preferably a group selected from the substituent group Z, particularly from the substituent group X. The optional crosslinking group is preferably a group selected from the group T of crosslinking groups.

From the viewpoint of the distribution of the LUMO, it is preferable that Ar⁷² and Ar⁷³ each independently have a structure selected from a-1 to a-4, b-1 to b-9, c-1 to c-4, d-1 to d-16, and e-1 to e-4 shown in schemes 2A to 2C above.

From the viewpoint of facilitating the spreading of the LUMO when an electron-withdrawing group is present, Ar⁷² and Ar⁷³ are each more preferably a structure selected from a-1 to a-4, b-1 to b-9, c-1 to c-5, d-1 to d-12, and e-1 to e-4.

From the viewpoint of the effect of confining excitons having a high triplet level and formed in a light-emitting layer, Ar⁷² and Ar⁷³ are each more preferably a structure selected from a-1 to a-4, d-1 to d-12, and e-1 to e-4.

To prevent aggregation of molecules, Ar⁷² and Ar⁷³ are each still more preferably a structure selected from d-1 to d-12 and e-1 to e-4. From the viewpoint of the ease of synthesis and high stability, it is preferable that Ar⁷²=Ar⁷³=d-1 or d-10, and the benzene ring structure represented by d-1 is particularly preferred.

Each of these structures may optionally have a substituent.

### (Specific Examples of Group Represented by Formula (53))

Specific examples of the group represented by formula (53) are shown below. However, the group represented by formula (53) is not limited thereto.

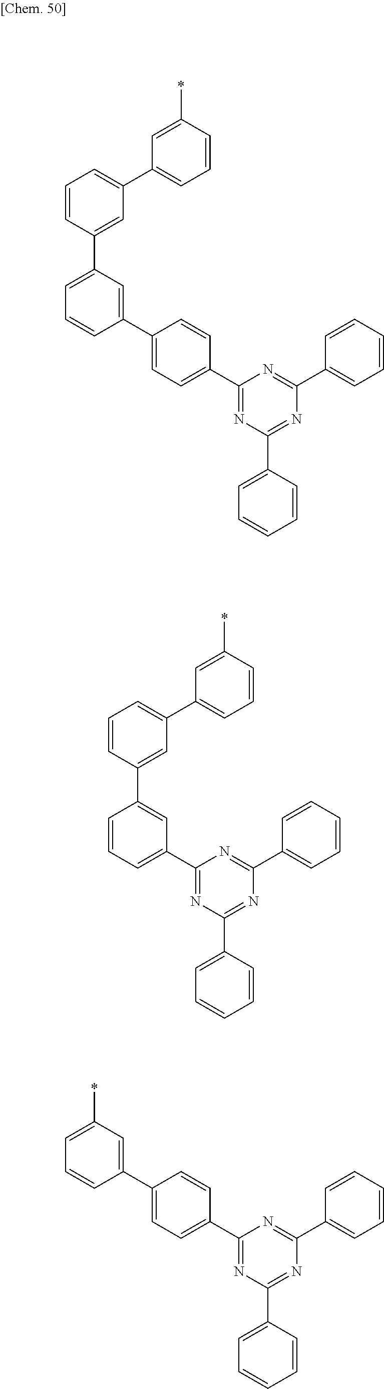 [SMILES: *c1cccc(-c2cccc(-c3cccc(-c4ccc(-c5nc(-c6ccccc6)nc(-c6ccccc6)n5)cc4)c3)c2)c1 ; *c1cccc(-c2cccc(-c3cccc(-c4nc(-c5ccccc5)nc(-c5ccccc5)n4)c3)c2)c1 ; *c1cccc(-c2ccc(-c3nc(-c4ccccc4)nc(-c4ccccc4)n3)cc2)c1]

### (Preferred Repeating Units Represented by Formula (50))

The repeating unit represented by formula (50) is preferably a repeating unit selected from a repeating unit represented by formula (54) below, a repeating unit represented by formula (55) below, a repeating unit represented by formula (56) below, a repeating unit represented by formula (57) below, and a repeating unit represented by formula (60) below.

In particular, the repeating unit represented by formula (54) below is preferred because of high heat resistance due to its structure including aromatic hydrocarbon rings condensed together.

In particular, the repeating unit represented by formula (55) below is preferred because a phenylene ring having R³⁰⁴ and R³⁰⁵ has a structure twisted relative to adjacent phenylene rings and therefore the extension of conjugation of the polymer is suppressed, so that the T1 level of the polymer is improved.

In particular, the repeating unit represented by formula (56) below is preferred because it has a carbazole structure and therefore increases the heat resistance.

In particular, the repeating unit represented by formula (57) below is preferred because the LUMO of the polymer can be easily spread and therefore the electron durability tends to increase.

In particular, the repeating unit represented by formula (60) below is preferred because its hole transportability is high.

The polymer in the invention includes preferably a repeating unit selected from the repeating unit represented by formula (54) below, the repeating unit represented by formula (55) below, the repeating unit represented by formula (56) below, and the repeating unit represented by formula (57) below and includes more preferably the repeating unit represented by formula (54) below or the repeating unit represented by formula (57) below.

Preferably, the polymer in the invention includes at least one selected from the repeating unit represented by formula (54) below, the repeating unit represented by formula (55) below, the repeating unit represented by formula (56) below, and the repeating unit represented by formula (57) below and further includes the repeating unit represented by formula (60) below. More preferably, the polymer in the invention includes the repeating unit represented by formula (54) below or the repeating unit represented by formula (57) below and further includes the repeating unit represented by formula (60) below.

### <Repeating Unit Represented by Formula (54)>

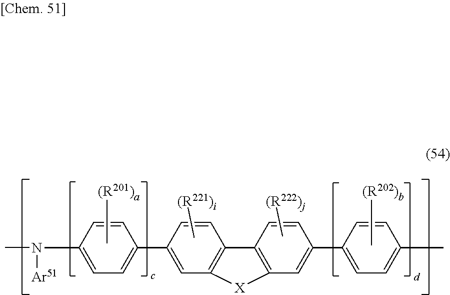

(In formula (54),

Ar⁵¹ is the same as Ar⁵¹ in formula (50) above.

X is —C(R²⁰⁷)(R²⁰⁸)—, —N(R²⁰⁹)—, or —C(R²¹¹)(R²¹²)—C(R²¹³)(R²¹⁴)—.

R²⁰¹, R²⁰², R²²¹, and R²²² are each independently an alkyl group optionally having a substituent and/or a crosslinking group.

R²⁰⁷ to R²⁰⁹ and R²¹¹ to R²¹⁴ are each independently a hydrogen atom, an alkyl group optionally having a substituent and/or a crosslinking group, an aralkyl group optionally having a substituent and/or a crosslinking group, or an aromatic hydrocarbon group optionally having a substituent and/or a crosslinking group.

a and b are each independently an integer of 0 to 4.

c is an integer of 0 to 3.

d is an integer of 0 to 4.

i and j are each independently an integer of 0 to 3.)

(R²⁰¹, R²⁰², R²²¹, and R²²²)

R²⁰¹, R²⁰², R²²¹, and R²²² in the repeating unit represented by formula (54) are each independently an alkyl group optionally having a substituent and/or a crosslinking group.

The alkyl group is a linear, branched, or cyclic alkyl group. No particular limitation is imposed on the number of carbon atoms in the alkyl group. To maintain the solubility of the polymer, the number of carbon atoms is preferably 1 or more and 8 or less, more preferably 6 or less, and still more preferably 3 or less. The alkyl group is more preferably a methyl group or an ethyl group.

When a plurality of R²⁰¹'s are present, the plurality of R²⁰¹'s may be the same or different. When a plurality of R²⁰2's are present, the plurality of R²⁰²'s may be the same or different. Preferably, all of R²⁰¹'s and R²⁰²'s are the same because charges can be distributed uniformly around the nitrogen atom and the polymer can be easily synthesized.

When a plurality of R²²¹'s are present, the plurality of R²²¹'s may be the same or different. When a plurality of R²²²'s are present, the plurality of R²²²'s may be the same or different. Preferably, all of R²²¹'s and R²²²'s are the same because the polymer can be easily synthesized.

(R²⁰⁷ to R²⁰⁹ and R²¹¹ to R²¹⁴)

R²⁰⁷ to R²⁰⁹ and R²¹¹ to R²¹⁴ are each independently a hydrogen atom, an alkyl group optionally having a substituent and/or a crosslinking group, an aralkyl group optionally having a substituent and/or a crosslinking group, or an aromatic hydrocarbon group optionally having a substituent and/or a crosslinking group.

No particular limitation is imposed on the alkyl group. However, the number of carbon atoms in the alkyl group is preferably 1 or more and 24 or less, more preferably 8 or less, and still more preferably 6 or less, because the solubility of the polymer tends to increase. The alkyl group may have a linear, branched, or cyclic structure.

Specific examples of the alkyl group include a methyl group, an ethyl group, a n-propyl group, an i-propyl group, a n-butyl group, an i-butyl group, a sec-butyl group, a tert-butyl group, a n-hexyl group, a n-octyl group, a cyclohexyl group, and a dodecyl group.

No particular limitation is imposed on the aralkyl group. However, the number of carbon atoms in the aralkyl group is preferably 5 or more and 60 or less and more preferably 40 or less, because the solubility of the polymer tends to increase.

Specific examples of the aralkyl group include a 1,1-dimethyl-1-phenylmethyl group, a 1,1-di(n-butyl)-1-phenylmethyl group, a 1,1-di(n-hexyl)-1-phenylmethyl group, a 1,1-di(n-octyl)-1-phenylmethyl group, a phenylmethyl group, a phenylethyl group, a 3-phenyl-1-propyl group, a 4-phenyl-1-n-butyl group, a 1-methyl-1-phenylethyl group, a 5-phenyl-1-n-propyl group, a 6-phenyl-1-n-hexyl group, a 6-naphthyl-1-n-hexyl group, a 7-phenyl-1-n-heptyl group, an 8-phenyl-1-n-octyl group, and a 4-phenylcyclohexyl group.

No particular limitation is imposed on the aromatic hydrocarbon group. However, the number of carbon atoms in the aromatic hydrocarbon group is preferably 6 or more and is preferably 60 or less and 30 or less, because the solubility of the polymer tends to increase.

Specific examples of the aromatic hydrocarbon group include: 6-membered monocyclic rings and monovalent groups including 2 to 5 rings condensed together such as a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, and a fluorene ring; and groups in which a plurality of groups selected from the above groups are linked together.

From the viewpoint of improving the charge transportability and durability, R²⁰⁷ and R²⁰⁸ are each preferably a methyl group or an aromatic hydrocarbon group. R²⁰⁷ and R²⁰⁸ are each more preferably a methyl group, and R²⁰⁹ is more preferably a phenyl group.

The alkyl groups represented by R²⁰¹, R²⁰², R²²¹, and R²²² and the alkyl groups, aralkyl groups, and aromatic hydrocarbon groups represented by R²⁰⁷ to R²⁰⁹ and R²¹¹ to R²¹⁴ may each optionally have a substituent and/or a crosslinking group. Examples of the substituent include those described as the preferred groups for the alkyl groups, aralkyl groups, and aromatic hydrocarbon groups represented by R²⁰⁷ to R²⁰⁹ and R²¹¹ to R²¹⁴. The crosslinking group is a crosslinking group selected from the group T of crosslinking groups.

From the viewpoint of lowering voltage, it is most preferable that the alkyl groups represented by R²⁰¹, R²⁰², R²²¹, and R²²² and the alkyl groups, aralkyl groups, and aromatic hydrocarbon groups represented by R²⁰⁷ to R²⁰⁹ and R²¹¹ to R²¹⁴ each have no substituent and no crosslinking group.

When a crosslinking group is bonded to the main chain structure of the repeating unit represented by formula (54), it is preferable that the crosslinking group is bonded to one of R²⁰⁷ to R²⁰⁹, R²¹¹ to R²¹³, and R²¹⁴ that is an alkyl group, an aralkyl group, or an aromatic hydrocarbon group.

(a, b, c, and d)

In the repeating unit represented by formula (54), a and b are each independently an integer of 0 to 4. a+b is preferably 1 or more. Moreover, a and b are each preferably 2 or less, and it is more preferable that both a and b are 1. When b is 1 or more, d is also 1 or more. When c is 2 or more, a plurality of a's may be the same or different. When d is 2 or more, a plurality of b's may be the same or different.

When a+b is 1 or more, the aromatic rings in the main chain are twisted due to steric hindrance. In this case, the solubility of the polymer in a solvent tends to be high, and a coating film formed by a wet deposition method and subjected to heat treatment tends to have high insolubility in a solvent. Therefore, in the case where a+b is 1 or more, when another organic layer (e.g., a light-emitting layer) is formed on this coating film by a wet deposition method, elution of the polymer to the composition for forming the other organic layer containing an organic solvent can be reduced.

In the repeating unit represented by formula (54), c is an integer of 0 to 3, and d is an integer of 0 to 4. c and d are each preferably 2 or less and are more preferably the same. Particularly preferably, both c and d are 1, or both c and d are 2.

When both c and d in the repeating unit represented by formula (54) are 1 or 2 and both a and b are 2 or 1, it is most preferable that R²⁰¹(s) and R²⁰²(s) are bonded to symmetric positions.

The phrase “R²⁰¹(s) and R²⁰²(s) are bonded to symmetric positions” means that the bonding positions of R²⁰¹(s) and R²⁰²(s) are symmetric with respect to the fluorene ring, carbazole ring, or 9,10-dihydrophenanthrene derivative structure in formula (54). In this case, a structure rotated 180° about the main chain is regarded as the same structure as the original structure.

When R²²¹ and R²²² are present, it is preferable that they are each independently present at the 1-, 3-, 6-, or 8-position with respect to a carbon atom of a benzene ring to which X is bonded. When R²²¹ and/or R²²² is present at any of these positions, the condensed ring to which R²²¹ and/or R²²² is bonded and adjacent benzene rings on the main chain are twisted relative to each other due to steric hindrance. This is preferable because the solubility of the polymer in a solvent becomes high and a coating film formed by a wet deposition method and subjected to heat treatment tends to have good insolubility in a solvent.

(i and j)

In the repeating unit represented by formula (54), i and j are each independently an integer of 0 to 3. i and j are each independently preferably an integer of 0 to 2 and more preferably 0 or 1. Preferably, i and j are the same integer. To twist the main chain of the polymer, it is preferable that i and j are each preferably 1 or 2 and that R²²¹(s) and/or R²²²(s) is(are) bonded to the 1- and/or 3-position(s) of the benzene rings. For ease of synthesis, i and j are each preferably 0. As for the bonding positions of a benzene ring, the position of a carbon atom to which R²²¹ or R²²² can be bonded and which is adjacent to the carbon atom to which X is bonded is defined as the 1-position, and the position of a carbon atom included in the main chain and bonded to an adjacent structure is defined as the 2-position.

### (X)

X in formula (54) above is —C(R²⁰⁷)(R²⁰⁸)—, —N(R²⁰⁹)—, or —C(R²¹¹)(R²¹²)—C(R²¹³)(R²¹⁴)—. It is preferable that at least one of R²⁰⁷ and R²⁰⁸, R²⁰⁹, or at least one of R²¹¹ to R²¹⁴ is an alkyl group having a crosslinking group, an aralkyl group having a crosslinking group, or an aromatic hydrocarbon group having a crosslinking group because aggregation of polymer molecules tends to be prevented.

X is preferably —C(R²⁰⁷)(R²⁰⁸)— or —N(R²⁰⁹)— and more preferably —C(R²⁰⁷)(R²⁰⁸)— because stability during charge transport is high.

### (Preferred Repeating Units)

The repeating unit represented by formula (54) is particularly preferably a repeating unit represented by any of the following formulas (54-1) to (54-8).

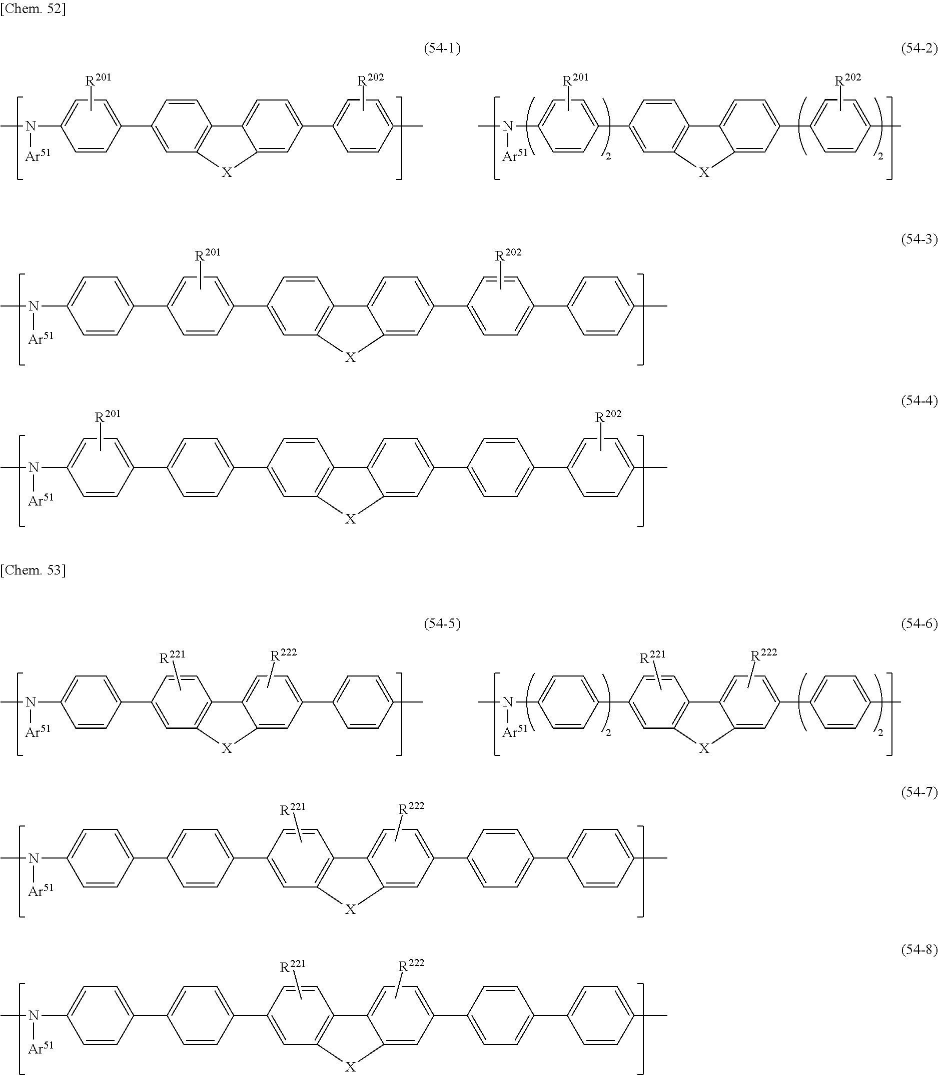

In the above formulas, R²⁰¹ and R²⁰² are the same, and R²⁰¹ and R²⁰² are bonded to positions symmetric to each other.

### <Preferred Examples of Main Chain of Repeating Unit Represented by Formula (54)>

No particular limitation is imposed on the structure of the main chain in formula (54) except for the nitrogen atom. However, for example, the following structures are preferred.

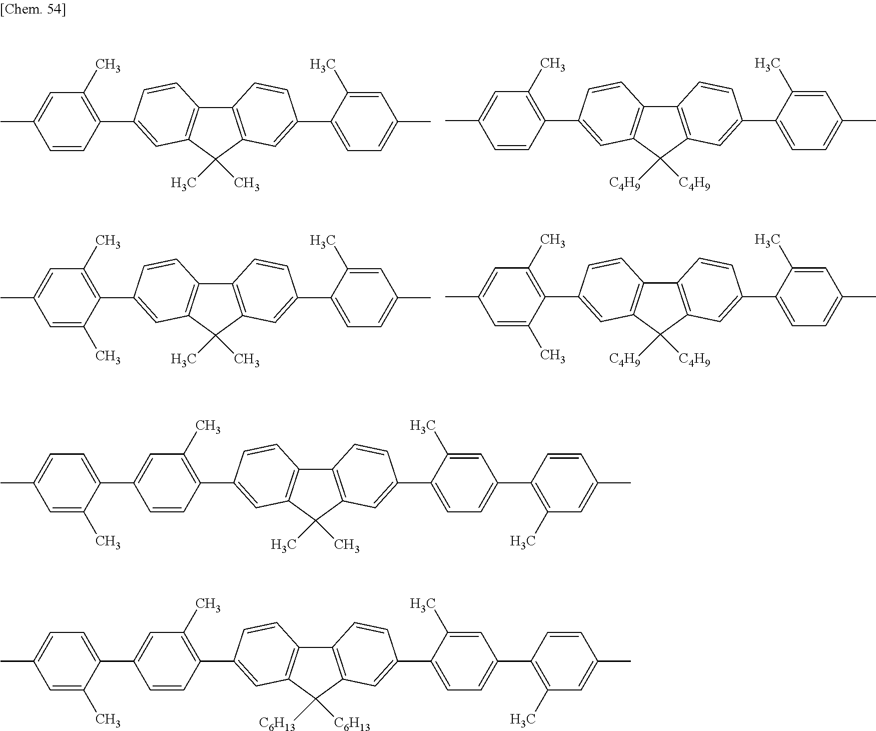

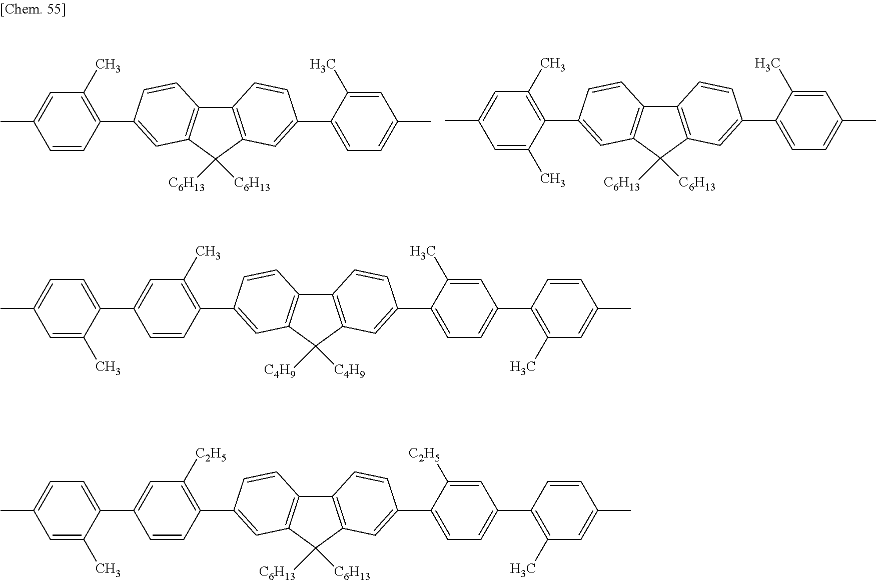

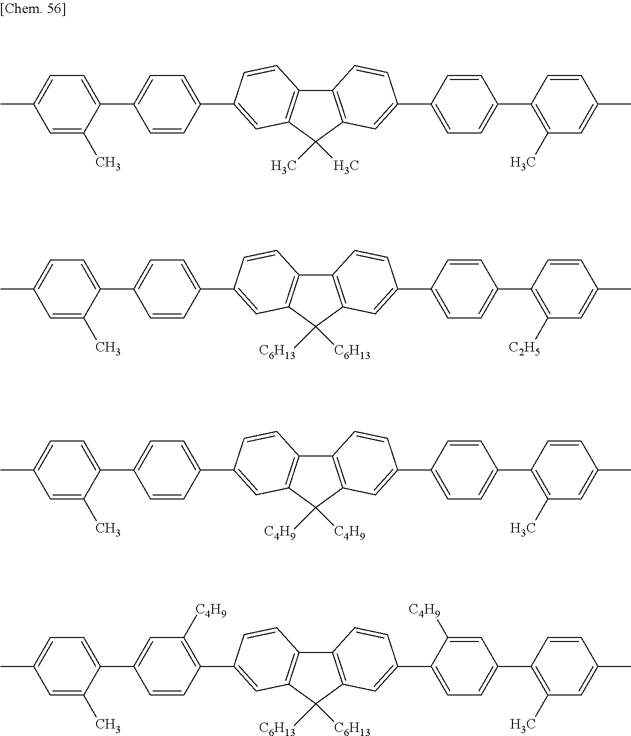

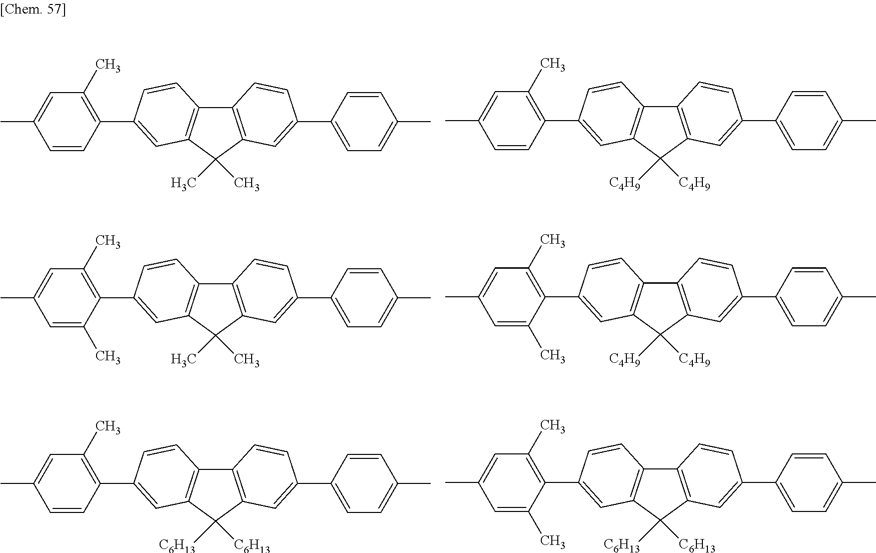

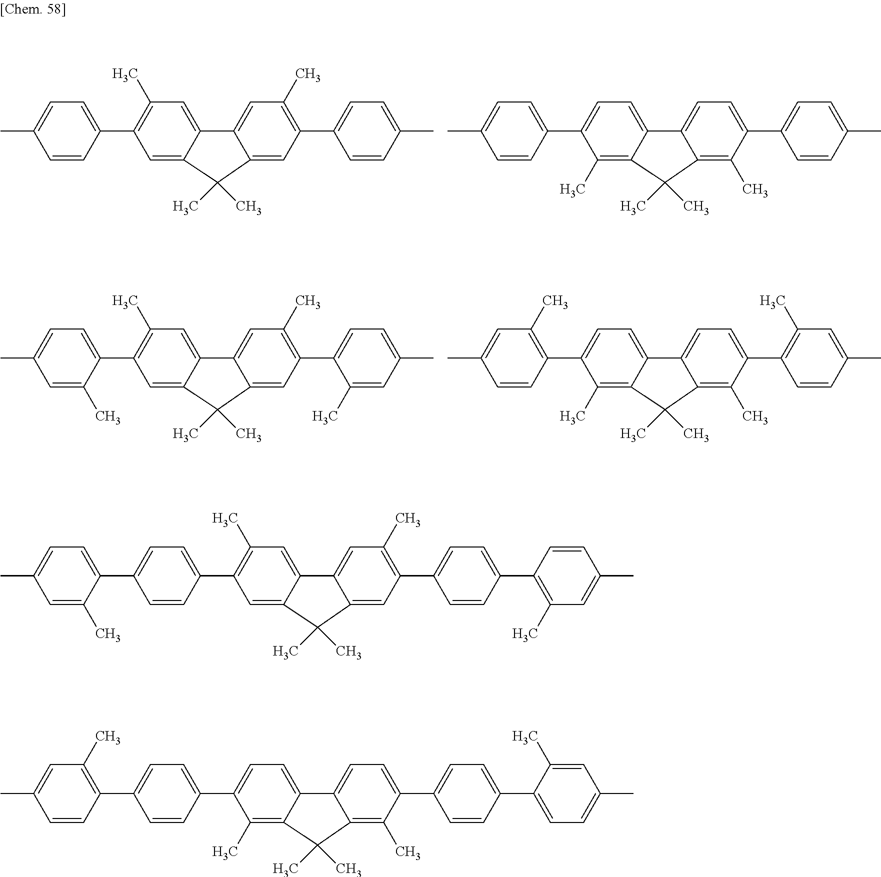

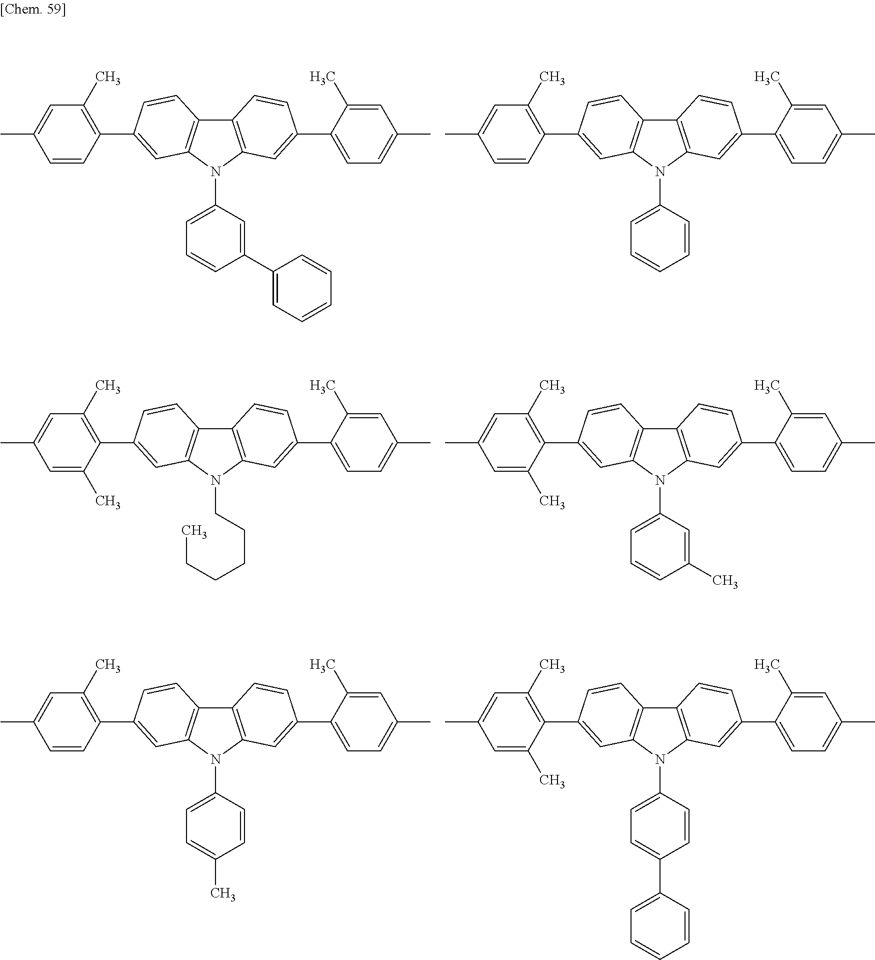

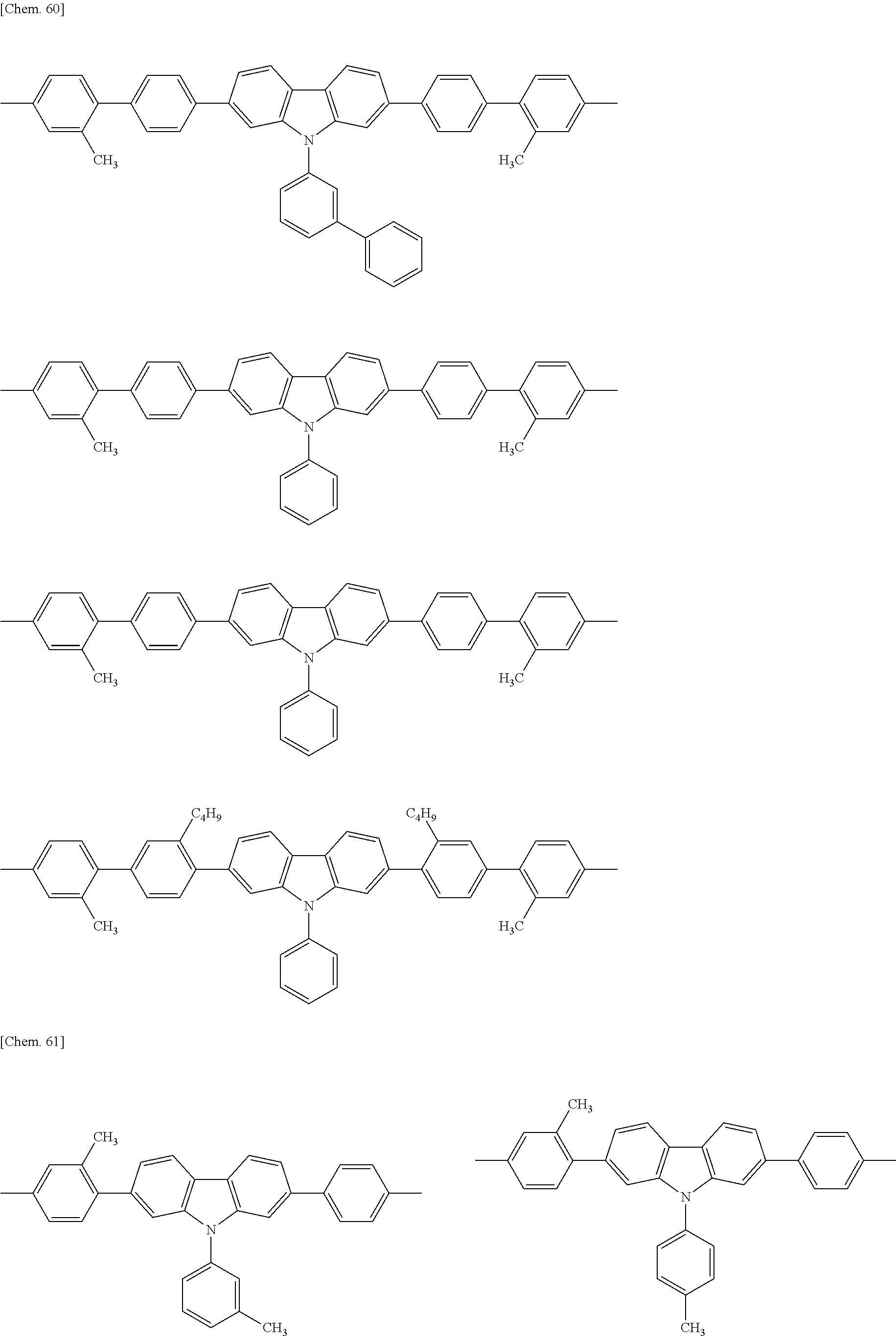

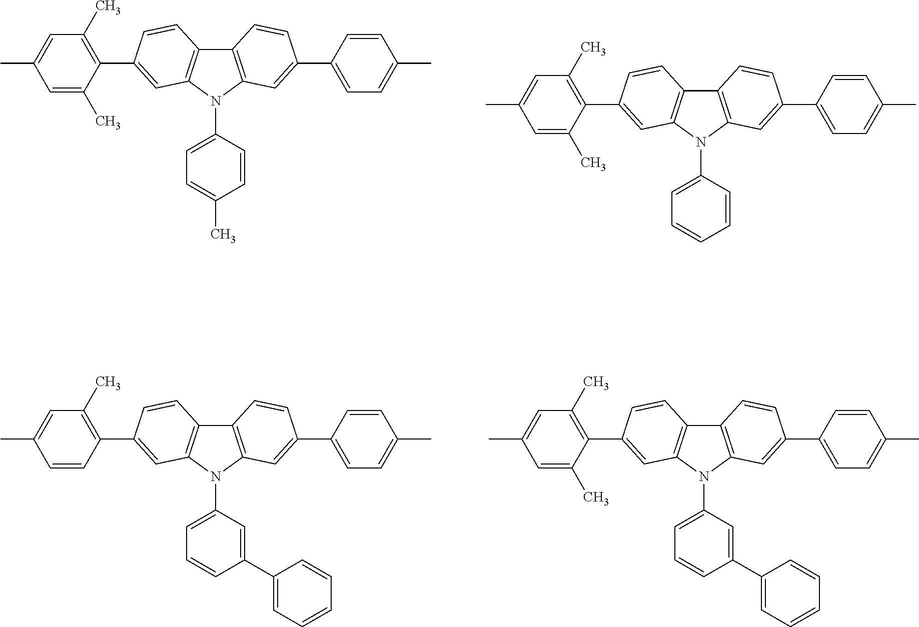

### <Repeating Unit Represented by Formula (55)>

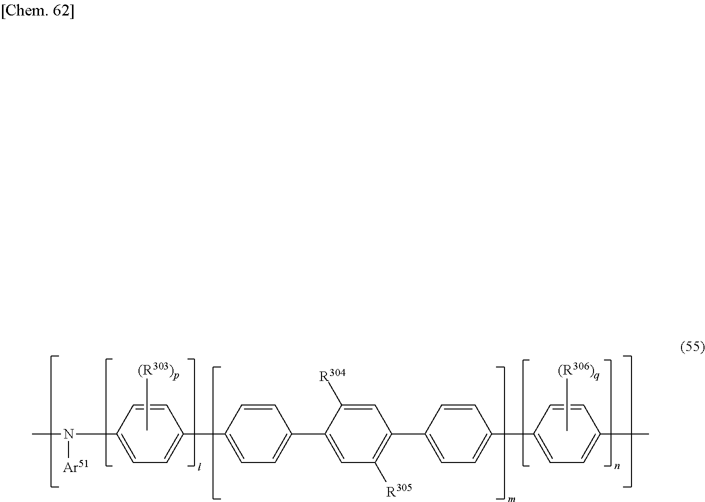

(In formula (55),

Ar⁵¹ is the same as Ar⁵¹ in formula (54) above.

R³⁰³ and R³⁰⁶ each independently represent an alkyl group optionally having a substituent and/or a crosslinking group.

R³⁰⁴ and R³⁰⁵ each independently represent an alkyl group optionally having a substituent and/or a crosslinking group, an alkoxy group optionally having a substituent and/or a crosslinking group, or an aralkyl group optionally having a substituent and/or a crosslinking group.

l is 0 or 1.

m is 1 or 2.

n is 0 or 1.

p is 0 or 1.

q is 0 or 1.)

(R³⁰³ and R³⁰⁶)

In the repeating unit represented by formula (55) above, R³⁰³ and R³⁰⁶ are each independently an alkyl group optionally having a substituent and/or a crosslinking group.

Examples of the alkyl group are the same as those for R²⁰¹ and R²⁰² in formula (54) above, and examples of the optional substituent, the optional crosslinking group, and the preferred structures are also the same as those for R²⁰¹ and R²⁰²

When a plurality of R³⁰³'s are present, the plurality of R³⁰³'s may be the same or different. When a plurality of R³⁰⁶'s are present, the plurality of R³⁰⁶'s may be the same or different.

(R³⁰⁴ and R³⁰⁵)

In the repeating unit represented by formula (55), R³⁰⁴ and R³⁰⁵ are each independently an alkyl group optionally having a substituent and/or a crosslinking group, an alkoxy group optionally having a substituent and/or a crosslinking group, or an aralkyl group optionally having a substituent and/or a crosslinking group. Preferably, R³⁰⁴ and R³⁰⁵ are each independently an alkyl group optionally having a substituent and/or a crosslinking group.

Preferably, R³⁰⁴ and R³⁰⁴ are the same.

The alkyl group is a linear, branched, or cyclic alkyl group. No particular limitation is imposed on the number of carbon atoms in the alkyl group. The number of carbon atoms is preferably 1 or more and 24 or less, more preferably 8 or less, and still more preferably 6 or less because the solubility of the polymer tends to be improved.

Specific examples of the alkyl group include a methyl group, an ethyl group, a n-propyl group, an i-propyl group, a n-butyl group, an i-butyl group, a sec-butyl group, a tert-butyl group, a n-hexyl group, a n-octyl group, a cyclohexyl group, and a dodecyl group.

No particular limitation is imposed on the alkoxy group. The alkyl group represented by R¹⁰ in an alkoxy group (—OR¹⁰) may have a linear, branched, or cyclic structure, and the number of carbon atoms in the alkyl group is preferably 1 or more and 24 or less and more preferably 12 or less because the solubility of the polymer tends to be improved.

Specific examples of the alkoxy group include a methoxy group, an ethoxy group, a n-propoxy group, a n-butoxy group, a hexyloxy group, a 1-methylpentyloxy group, and a cyclohexyloxy group.

No particular limitation is imposed on the aralkyl group. However, the number of carbon atoms in the aralkyl group is preferably 5 or more and is preferably 60 or less and more preferably 40 or less because the solubility of the polymer tends to be improved.

Specific examples of the aralkyl group include a 1,1-dimethyl-1-phenylmethyl group, a 1,1-di(n-butyl)-1-phenylmethyl group, a 1,1-di(n-hexyl)-1-phenylmethyl group, a 1,1-di(n-octyl)-1-phenylmethyl group, a phenylmethyl group, a phenylethyl group, a 3-phenyl-1-propyl group, a 4-phenyl-1-n-butyl group, a 1-methyl-1-phenylethyl group, a 5-phenyl-1-n-propyl group, a 6-phenyl-1-n-hexyl group, a 6-naphthyl-1-n-hexyl group, a 7-phenyl-1-n-heptyl group, an 8-phenyl-1-n-octyl group, and a 4-phenylcyclohexyl group.

Examples of the optional substituents on the alkyl, alkoxy, and aralkyl groups represented by R³⁰⁴ and R³⁰⁵ include those described as the preferred groups for the alkyl, aralkyl, and aromatic hydrocarbon groups represented by R²⁰⁷ to R²⁰⁹ and R²¹¹ to R²¹⁴. The optional crosslinking group is a crosslinking group selected from the group T of crosslinking groups.

From the viewpoint of lowering voltage, it is most preferable that the alkyl, alkoxy, and aralkyl groups represented by R³⁰⁴ and R³⁰⁵ each have no substituent and no crosslinking group.

When crosslinking groups are bonded to the main chain structure of the repeating unit represented by formula (55), it is preferable that the crosslinking groups are bonded to R³⁰⁴ and R³⁰⁵

(l, m, and n)

l represents 0 or 1. n represents 0 or 1.

l and n are independently set. l+n is preferably 1 or more, more preferably 1 or 2, and still more preferably 2. When l+n falls within the above range, the solubility of the polymer increases, and precipitation from the composition of the invention containing the polymer tends to be prevented.

m represents 1 or 2 and is preferably 1 because an organic electroluminescent element produced using the composition of the invention can be driven at a low voltage and the hole injectability, hole transportability, and durability tend to be improved.

(p and q)

p represents 0 or 1. q represents 0 or 1. When 1 is 2 or more, a plurality of p's may be the same or different. When n is 2 or more, a plurality of q's may be the same or different. When l=n=1, p and q are not simultaneously 0. When p and q are not simultaneously 0, the solubility of the polymer can be high, and precipitation from the composition of the invention containing the polymer tends to be prevented. For the same reason as for a and b, when p+q is 1 or more, the aromatic rings in the main chain are twisted due to steric hindrance. In this case, the solubility of the polymer in a solvent becomes high, and a coating film formed by a wet deposition method and subjected to heat treatment tends to have good insolubility in a solvent. Therefore, in the case where p+q is 1 or more, when another organic layer (e.g., a light-emitting layer) is formed on this coating film by a wet deposition method, elution of the polymer to the composition for forming the other organic layer containing an organic solvent can be reduced.

### <Specific Examples of Main Chain of Repeating Unit Represented by Formula (55)>

No particular limitation is imposed on the structure of the main chain in formula (55) except for the nitrogen atom. However, for example, the following structures are preferred.

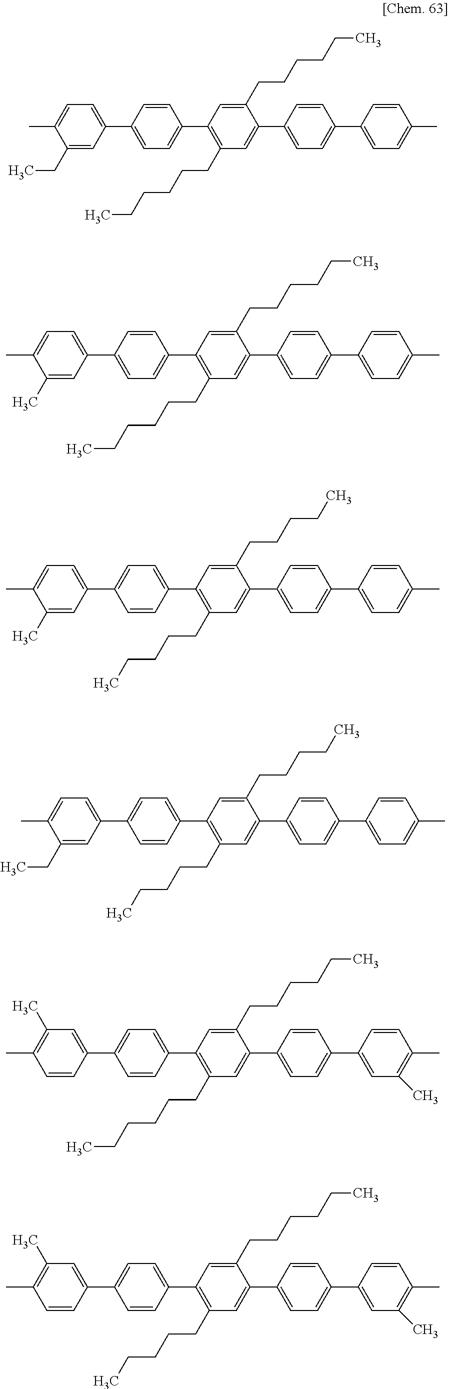

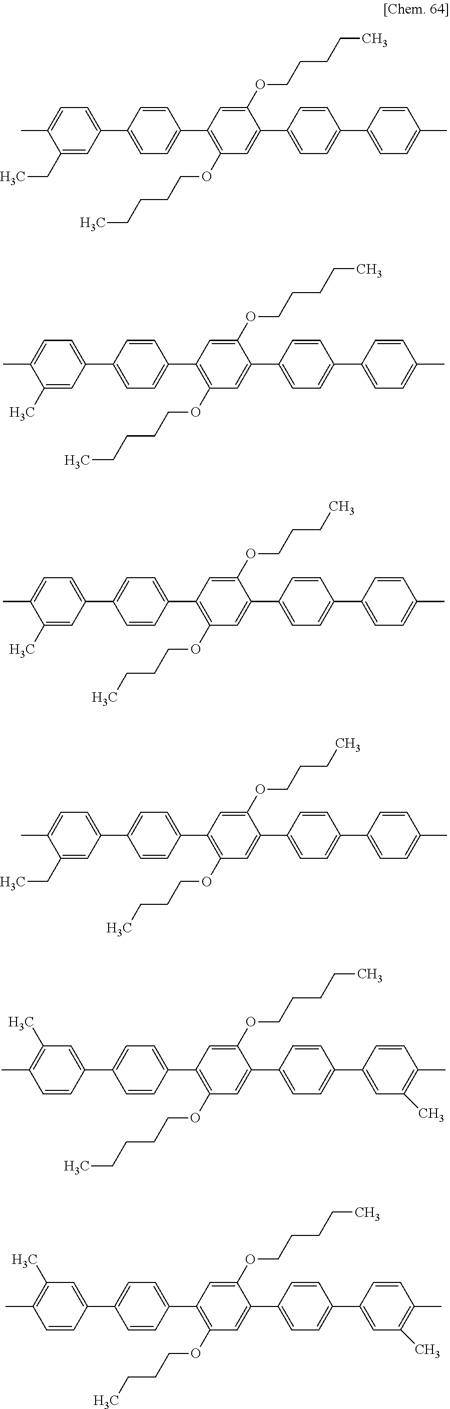

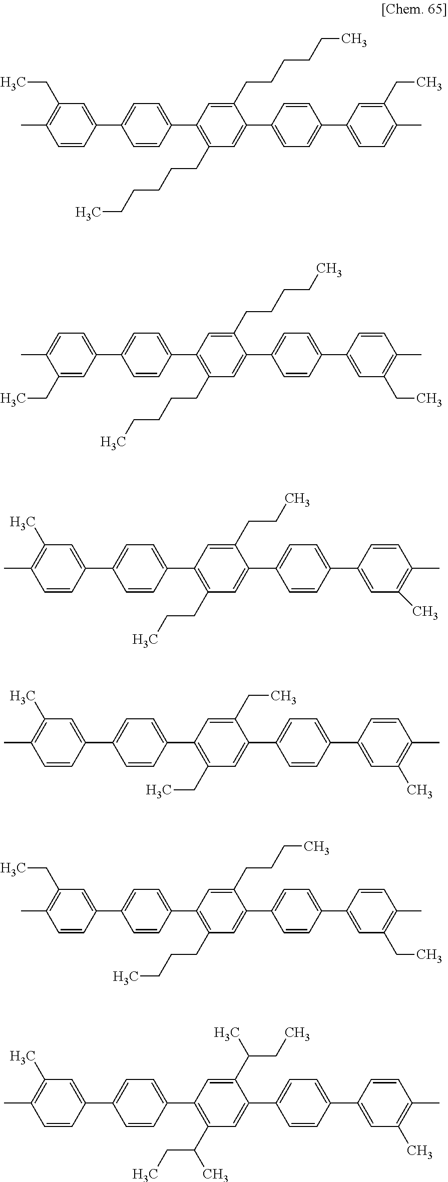

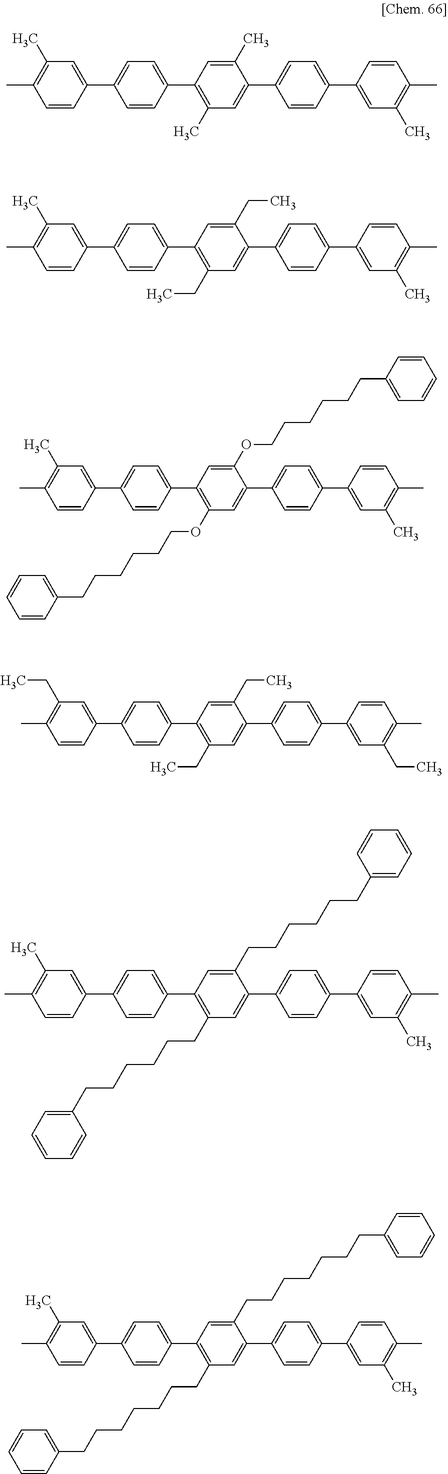

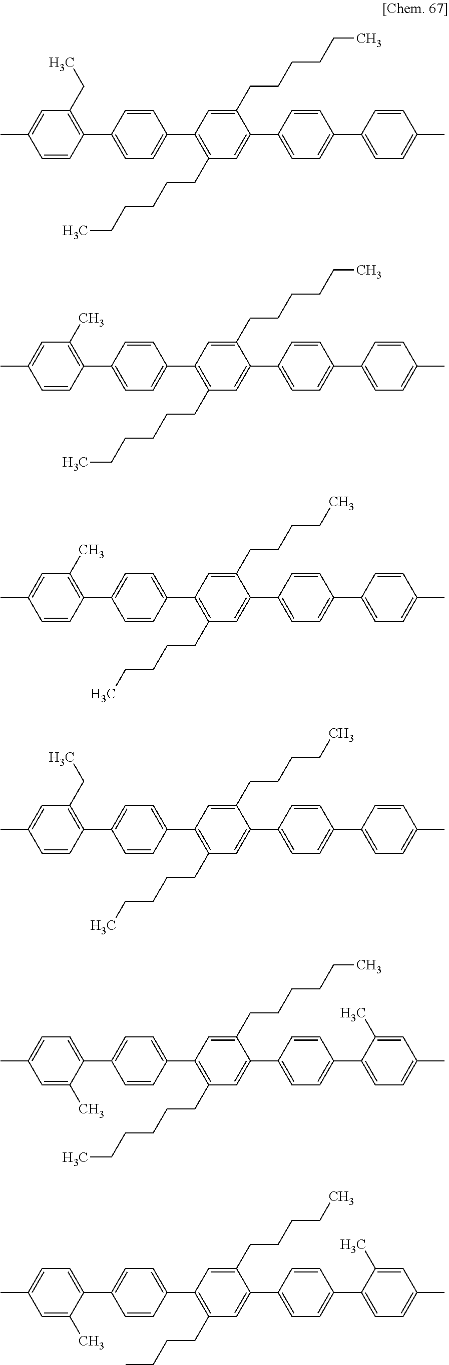

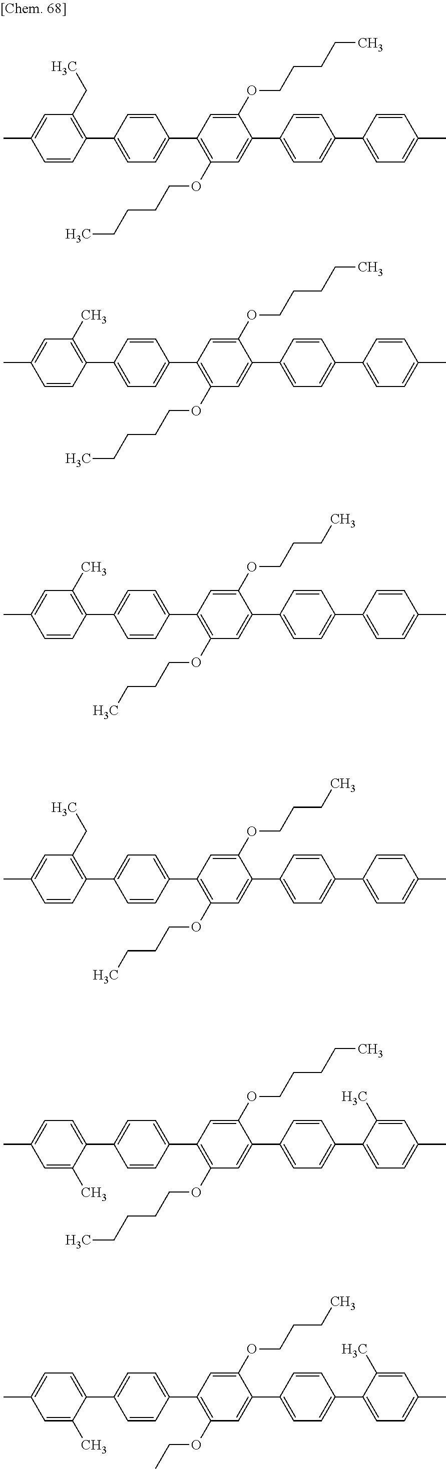

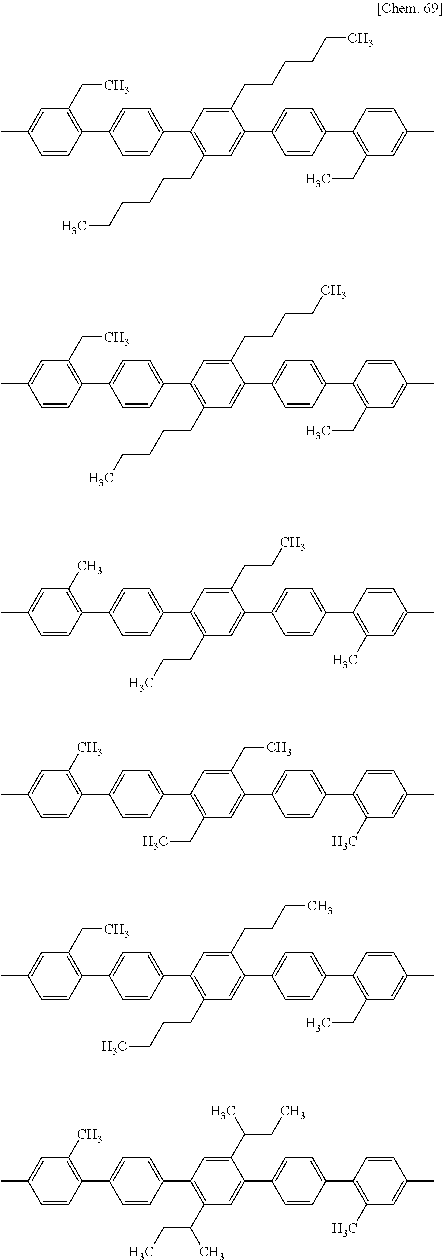

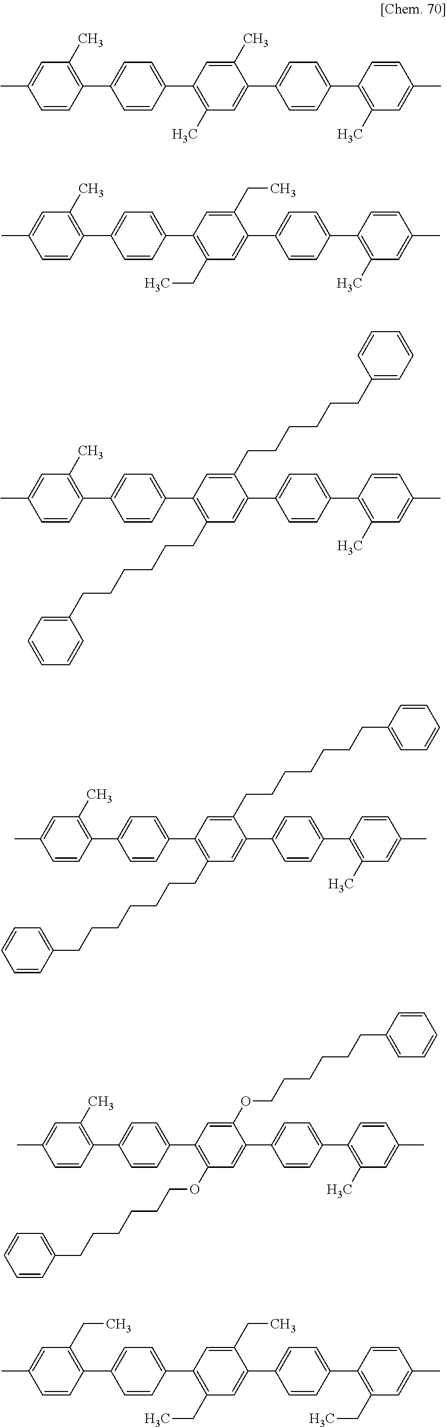

### <Repeating Unit Represented by Formula (56)>

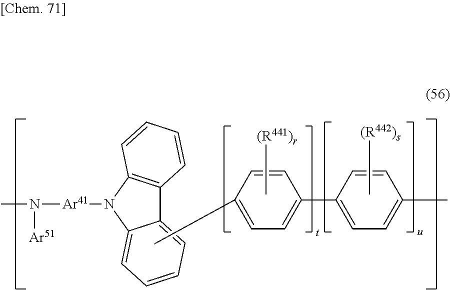

(In formula (56),

Ar⁵¹ is the same as Ar⁵¹ in formula (54) above.

Ar⁴¹ represents a divalent aromatic hydrocarbon group optionally having a substituent, a divalent aromatic heterocyclic group optionally having a substituent, or a divalent group in which a plurality of groups selected from the group consisting of divalent aromatic hydrocarbon groups each optionally having a substituent and divalent aromatic heterocyclic groups each optionally having a substituent are linked together directly or via a linking group.

R⁴⁴¹ and R⁴⁴² each independently represent an alkyl group optionally having a substituent.

t is 1 or 2.

u is 0 or 1.

r and s are each independently an integer of 0 to 4.)

(R⁴⁴¹ and R⁴⁴²)

In the repeating unit represented by formula (56) above, R⁴⁴¹ and R⁴⁴² are each independently an alkyl group optionally having a substituent.

The alkyl group is a linear, branched, or cyclic alkyl group. No particular limitation is imposed on the number of carbon atoms in the alkyl group. To maintain the solubility of the polymer, the number of carbon atoms is preferably 1 or more and 10 or less, more preferably 8 or less, and still more preferably 6 or less. The alkyl group is more preferably a methyl group or a hexyl group.

When a plurality of R⁴⁴¹'s and a plurality of R⁴⁴²'s are present in the repeating unit represented by formula (56), the plurality of R⁴⁴¹'s may be the same or different, and the plurality of R⁴⁴²'s may be the same or different.

(r, s, t, and u)

In the repeating unit represented by formula (56), r and s are each independently an integer of 0 to 4. When t is 2 or more, a plurality of r's may be the same or different. When u is 2 or more, a plurality of s's may be the same or different. r+s is preferably 1 or more, and r and s are each preferably 2 or less. When r+s is 1 or more, the driving lifetime of the organic electroluminescent element may be further extended for the same reason as for a and b in formula (54) above.

In the repeating unit represented by formula (56) above, t is 1 or 2. u is 0 or 1. t is preferably 1. u is preferably 1.

### (Ar⁴¹)

Ar⁴¹ is a divalent aromatic hydrocarbon group optionally having a substituent, a divalent aromatic heterocyclic group optionally having a substituent, or a divalent group in which a plurality of groups selected from the group consisting of divalent aromatic hydrocarbon groups each optionally having a substituent and divalent aromatic heterocyclic groups each optionally having a substituent are linked together directly or via a linking group.

Examples of the aromatic hydrocarbon and aromatic hydrocarbon groups represented by Ar⁴¹ include the same groups as those for Ar⁵² in formula (50) above. The optional substituents on the aromatic hydrocarbon and aromatic hydrocarbon groups are each preferably a group selected from the substituent group Z, particularly from the substituent group X, and the optional additional substituents are each also preferably a group selected from the substituent group Z, particularly the substituent group X.

### <Specific Examples of Repeating Unit Represented by Formula (56)>

No particular limitation is imposed on the repeating unit represented by formula (56), and examples thereof include the following structures.

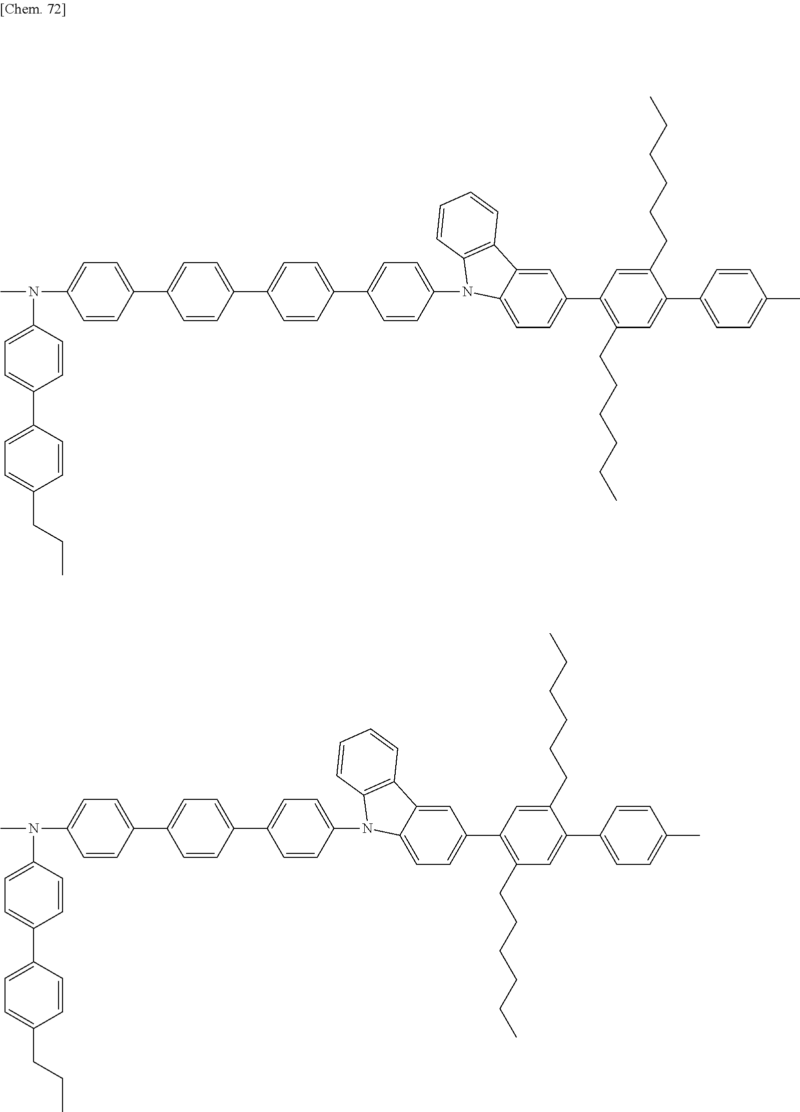

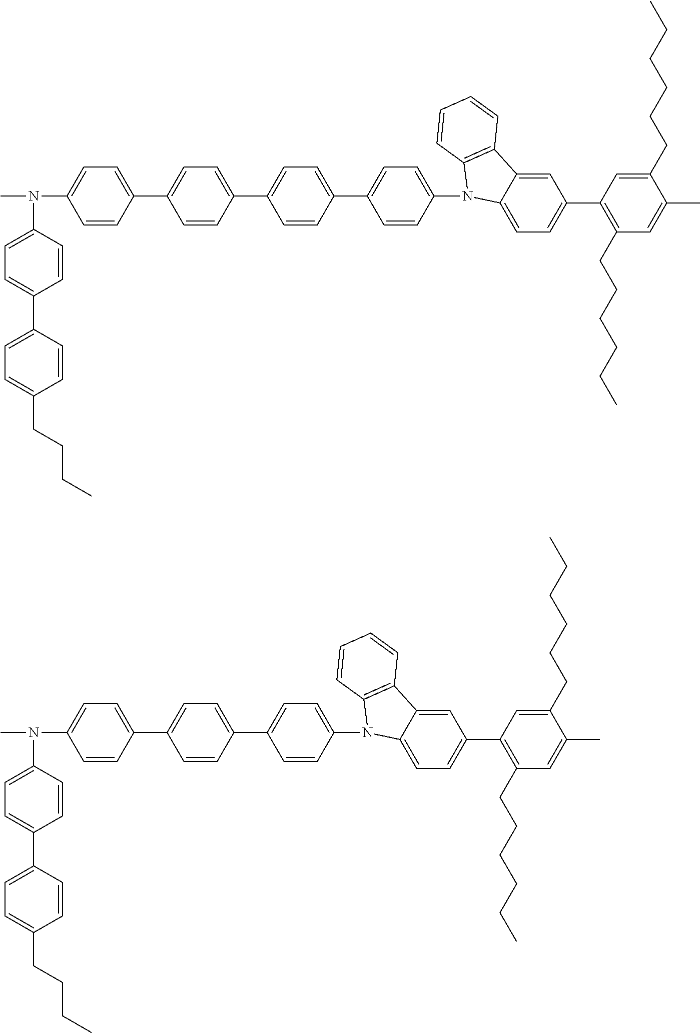

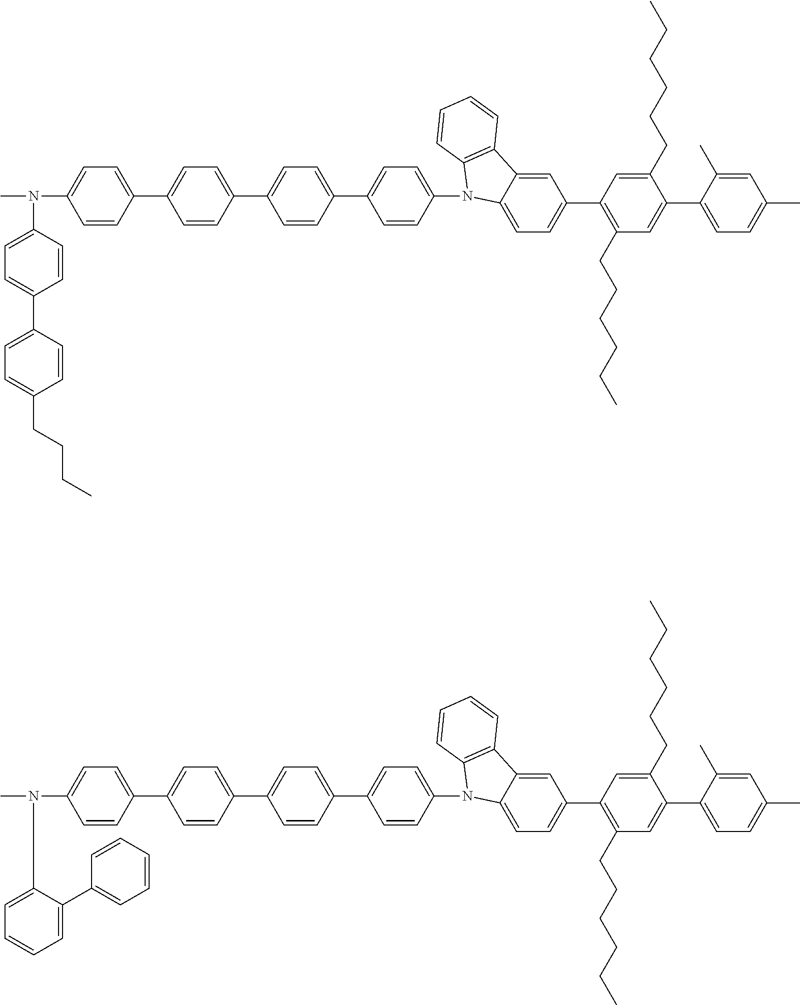

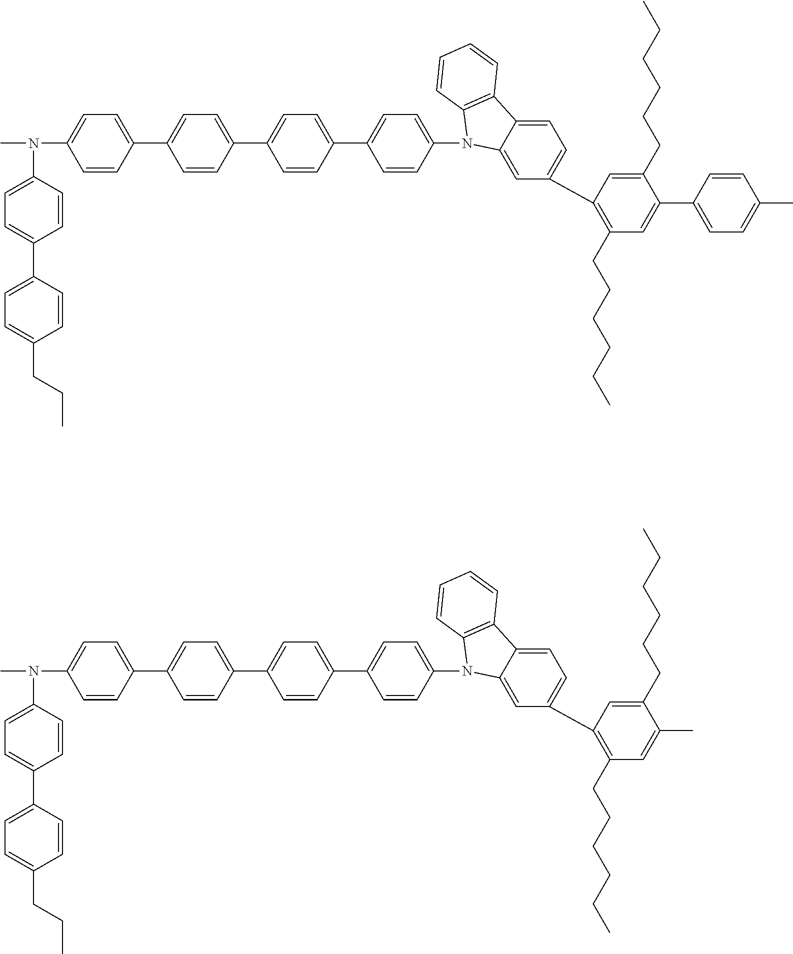

### <Repeating Unit Represented by Formula (57)>

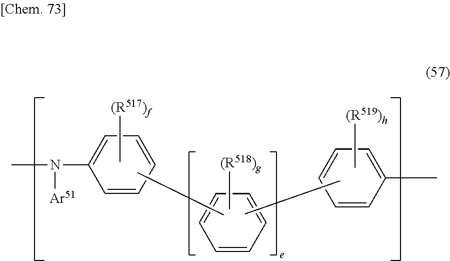

(In formula (57),

Ar⁵¹ is the same as Ar⁵¹ in formula (50) above.

R⁵¹⁷ to R⁵¹⁹ each independently represent an alkyl group optionally having a substituent and/or a crosslinking group, an alkoxy group optionally having a substituent and/or a crosslinking group, an aralkyl group optionally having a substituent and/or a crosslinking group, an aromatic hydrocarbon group optionally having a substituent and/or a crosslinking group, or an aromatic heterocyclic group optionally having a substituent and/or a crosslinking group.

f, g, and h each independently represent an integer of 0 to 4.

e represents an integer of 0 to 3.

When g is 1 or more, e is 1 or more.)

(R⁵¹⁷ to R⁵¹⁹)

The aromatic hydrocarbon and aromatic heterocyclic groups represented by R⁵¹⁷ to R⁵¹⁹ are each independently the same as those described for Ar⁵¹. The optional substituents on these groups are preferably the same groups as those in the substituent group Z, particularly in the substituent group X. The crosslinking groups are each preferably a crosslinking group selected from the group T of crosslinking groups.

Preferably, the alkyl and aralkyl groups represented by R⁵¹⁷ to R⁵¹⁹ are the same as those described above for R²⁰⁷. The optional substituents are each preferably the same group as that for R²⁰⁷ described above, and the crosslinking groups are each preferably a crosslinking group selected from the group T of crosslinking groups.

The alkoxy groups represented by R⁵¹⁷ to R⁵¹⁹ are preferably alkoxy groups selected from the substituent group Z, particularly from the substituent group X, and the optional substituents are each substituents in the substituent group Z and preferably substituents in the substituent group X. The optional crosslinking groups are each preferably a crosslinking group selected from the group T of crosslinking groups.

(f, g, and h)

f, g, and h each independently represent an integer of 0 to 4.

When e is 2 or more, a plurality of g's may be the same or different.

f+g+h is preferably 1 or more.

It is preferable that f+h is 1 or more;

it is more preferable that f+h is 1 or more and that f, g, and h are each 2 or less;

it is still more preferable that f+h is 1 or more and that f and h are each 1 or less; and

it is most preferable that f and h are each 1.

When f and h are each 1, it is preferable that R⁵¹⁷ and R⁵¹⁹ are bonded at positions symmetric to each other.

Preferably, R⁵¹⁷ and R⁵¹⁹ are the same.

More preferably, g is 2.

When g is 2, it is most preferable that the two R⁵¹⁸'s are bonded at para positions.

When g is 2, it is most preferable that the two R⁵¹⁸'s are the same.

The phrase “R⁵¹⁷ and R⁵¹⁹ are bonded at positions symmetric to each other” means bonding positions shown below. However, for notational purposes, a structure rotated 180° about the main chain is regarded as the same structure as the original structure.

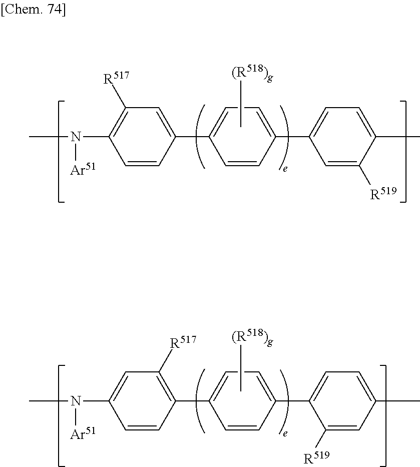

When the polymer in the present embodiment includes the repeating unit represented by formula (54) and the repeating unit represented by formula (57), the ratio of the repeating unit represented by formula (57) to the repeating unit represented by formula (54), i.e., (the number of moles of the repeating unit represented by formula (57)/the number of moles of the repeating unit represented by formula (54)), is preferably 0.1 or more, more preferably 0.3 or more, still more preferably 0.5 or more, yet more preferably 0.9 or more, and particularly preferably 1.0 or more. The ratio is preferably 2.0 or less, more preferably 1.5 or less, and still more preferably 1.2 or less.

The repeating unit represented by formula (57) is preferably a repeating unit represented by the following formula (58).

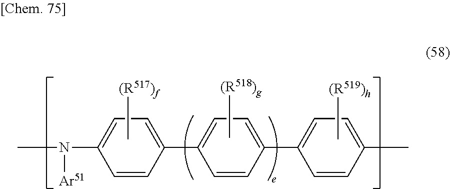

In the repeating unit represented by formula (58), it is preferable that g=0 or 2. When g=2, the bonding positions are the 2- and 5-positions. When g=0, i.e., when there is no steric hindrance by R⁵¹⁸, and when g=2 and the bonding positions are the 2- and 5-positions, i.e., when there is steric hindrance due to the two R⁵¹⁸'s bonded to the diagonal positions of the benzene ring, R⁵¹⁷ and R⁵¹⁹ can be bonded to positions symmetric to each other.

The repeating unit represented by formula (58) is more preferably a repeating unit represented by the following formula (59) with e=3.

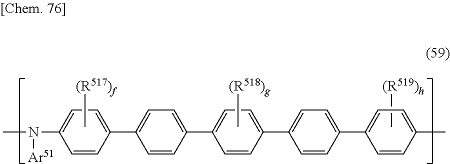

In the repeating unit represented by formula (59) above, it is preferable that g=0 or 2. When g=2, the bonding positions are the 2- and 5-positions. When g=0, i.e., there is no steric hindrance due to R⁵¹⁸, and when g=2 and the bonding positions are the 2- and 5-positions, i.e., when there is steric hindrance due to the two R⁵¹⁸'S bonded to the diagonal positions of the benzene ring, R⁵¹⁷ and R⁵¹⁹ can be bonded to positions symmetric to each other.

### <Specific Examples of Main Chain of Repeating Unit Represented by Formula (57)>

No particular limitation is imposed on the structure of the main chain of the repeating unit represented by formula (57). However, examples thereof include the following structures.

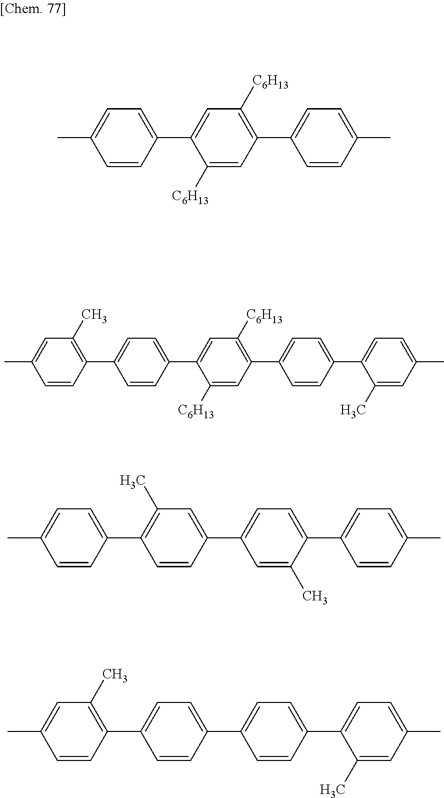

Preferably, the repeating units represented by formulas (50) to (59) above each have no crosslinking group. It is preferable that no crosslinking group is included because the polymer chain is unlikely to be distorted by heat drying or baking (heat firing) after wet deposition. This is because, when crosslinking groups undergo a reaction, a volume change may occur and therefore the polymer chain may be distorted. Even when no volume change occurs, the polymer chain may be distorted.

### <Repeating Unit Represented by Formula (60)>

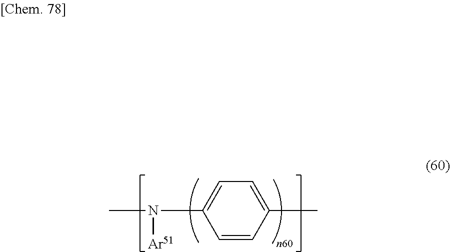

(In formula (60),

Ar⁵¹ is the same as Ar⁵¹ in formula (50) above.

n60 represents an integer of 1 to 5.)

(n60)

n60 represents an integer of 1 to 5 and is preferably an integer of 1 to 4 and more preferably an integer of 1 to 3.

### <Molecular Weights of Polymer>

The molecular weights of the polymer contained in the composition of the invention will be described.

The weight average molecular weight (Mw) of the polymer having the above-described arylamine structure as a repeating unit is generally 1,000,000 or less, preferably 500,000 or less, more preferably 100,000 or less, still more preferably 70,000 or less, and particularly preferably 50,000 or less. The weight average molecular weight is 10,000 or more, more preferably 12,000 or more, and particularly preferably 15,000 or more.

When the weight average molecular weight of the polymer having the above-described arylamine structure as a repeating unit is equal to or less than the above upper limit, the polymer exhibits solubility in a solvent. Moreover, the film formability tends to be good, and the viscosity of an ink prepared can fall within a preferred range. When the weight average molecular weight of the polymer is equal to or more than the above lower limit, reductions in the glass transition temperature, melting point, and vaporization temperature of the polymer are prevented, and the heat resistance may be improved. In addition, insolubility of a coating film in an organic solvent after a crosslinking reaction may be sufficient. Moreover, stable charge transport can be achieved.

The number average molecular weight (Mn) of the polymer having the above-described arylamine structure as a repeating unit is generally 750,000 or less, preferably 250,000 or less, more preferably 100,000 or less, and particularly preferably 50,000 or less. The number average molecular weight is generally 2,000 or more, preferably 4,000 or more, more preferably 6,000 or more, and still more preferably 8,000 or more.

The polydispersity (Mw/Mn) of the polymer having the above-described arylamine structure as a repeating unit is preferably 3.5 or less, more preferably 2.5 or less, and particularly preferably 2.0 or less. The smaller the polydispersity, the better. Therefore, the lower limit of the polydispersity is ideally 1. When the polydispersity of the polymer is equal to or lower than the above upper limit, the polymer can be easily purified, and the solubility in a solvent and the charge transportability are good.

Generally, the weight average molecular weight and number average molecular weight of the polymer are determined by SEC (size exclusion chromatography) measurement. In the SEC measurement, the elution time is shorter for a higher molecular weight component and longer for a lower molecular weight component. A calibration curve computed from the elution times of polystyrenes (standard specimens) with known molecular weights is used to convert the elution time of a sample to its molecular weights. The weight average molecular weight and the number average molecular weight of the sample are thereby computed.

### <Content of Repeating Unit Represented by Formula (50)>

No particular limitation is imposed on the content of the repeating unit represented by formula (50) in the polymer. However, the content of the repeating unit represented by formula (50) with respect to 100% by mole of all the repeating units in the polymer is generally 10% by mole or more, preferably 30% by mole or more, still more preferably 40% by mole or more, and yet more preferably 50% by mole or more.

The polymer may include only the repeating unit represented by formula (50). However, for the purpose of balancing the performance capabilities of the organic electroluminescent element prepared, the polymer may include a repeating unit different from the repeating unit represented by formula (50). In this case, the content of the repeating unit represented by formula (50) in the polymer is generally 99% by mole or less and preferably 95% by mole or less.

### <Repeating Unit Represented by Formula (61)>

The polymer in the invention including the arylamine structure as a repeating unit may further include, in the main chain, a structure represented by the following formula (61).

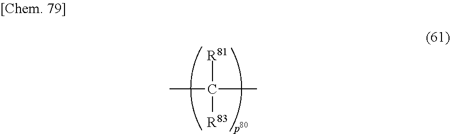

(In formula (61),

R⁸¹ and R⁸² each independently represent a hydrogen atom, an alkyl group, an aromatic hydrocarbon group, or an aromatic heterocyclic group. When a plurality of R⁸¹'s are present, they may be the same or different. When a plurality of R⁸²'s are present, they may be the same or different.

p⁸⁰ represents an integer of 1 to 5.)

When R⁸¹ and R⁸² are each an alkyl group, the alkyl group is a linear, branched, or cyclic alkyl group. No particular limitation is imposed on the number of carbon atoms in the alkyl group. To maintain the solubility of the polymer, the number of carbon atoms is preferably 1 or more and 8 or less, more preferably 6 or less, and still more preferably 3 or less. The alkyl group is more preferably a methyl group or an ethyl group.

When R⁸¹ and R⁸² are each an aromatic hydrocarbon group or an aromatic heterocyclic group, they are preferably any of the structures described above in the “Definitions” section.

R⁸¹ and R⁸² may each optionally have a substituent and/or a crosslinking group. The substituent is preferably a substituent selected from the substituent group Z, particularly from the substituent group X. The crosslinking group is preferably a crosslinking group selected from the crosslinking group Z.

From the viewpoint of the durability and charge transportability of the polymer, p⁸⁰ is preferably 3 or less, more preferably 2 or less, and most preferably 1.

When the structure represented by formula (61) is included, conjugation in the main chain of the polymer is cut, and the S1 energy level and T1 energy level of the polymer increase. Therefore, when a composition containing this polymer is used for a hole transport layer of an organic electroluminescent element, excitons in the light-emitting layer are unlikely to be deactivated. This is preferred because the luminous efficiency may increase.

### <Preferred Repeating Unit Structures in Polymer>

Specific structures of the repeating units represented by the above formulas are referred to as “repeating unit structures.” The specific structure is a structure obtained by assigning specific structures and numerical values to all the symbols in a general formula. Specifically, the polymer having the arylamine structure as a repeating unit may include only one repeating unit structure or two or more repeating unit structures selected from a repeating unit structure included in formula (54) above, a repeating unit structure included in formula (55) above, a repeating unit structure included in formula (56) above, a repeating unit structure included in formula (57) above, and a repeating unit structure included in formula (60) above. When two or more repeating unit structures are included, these two or more repeating unit structures may be repeating unit structures included in the same formula or repeating unit structures included in different formulas. From the viewpoint of charge transportability and durability, it is preferable that the polymer having the arylamine structure as a repeating unit includes 1 or 2 specific repeating unit structures represented by any of the above formulas and includes no other repeating unit structure.

### SPECIFIC EXAMPLES

Specific examples of the polymer are shown below. However, the polymer is not limited to these examples. Numerical values in the chemical formulas represent the molar ratios of repeating units.

These polymers may each be a random copolymer, an alternating copolymer, a block copolymers, or a graft copolymer, and no limitation is imposed on the order of arrangement of monomers.

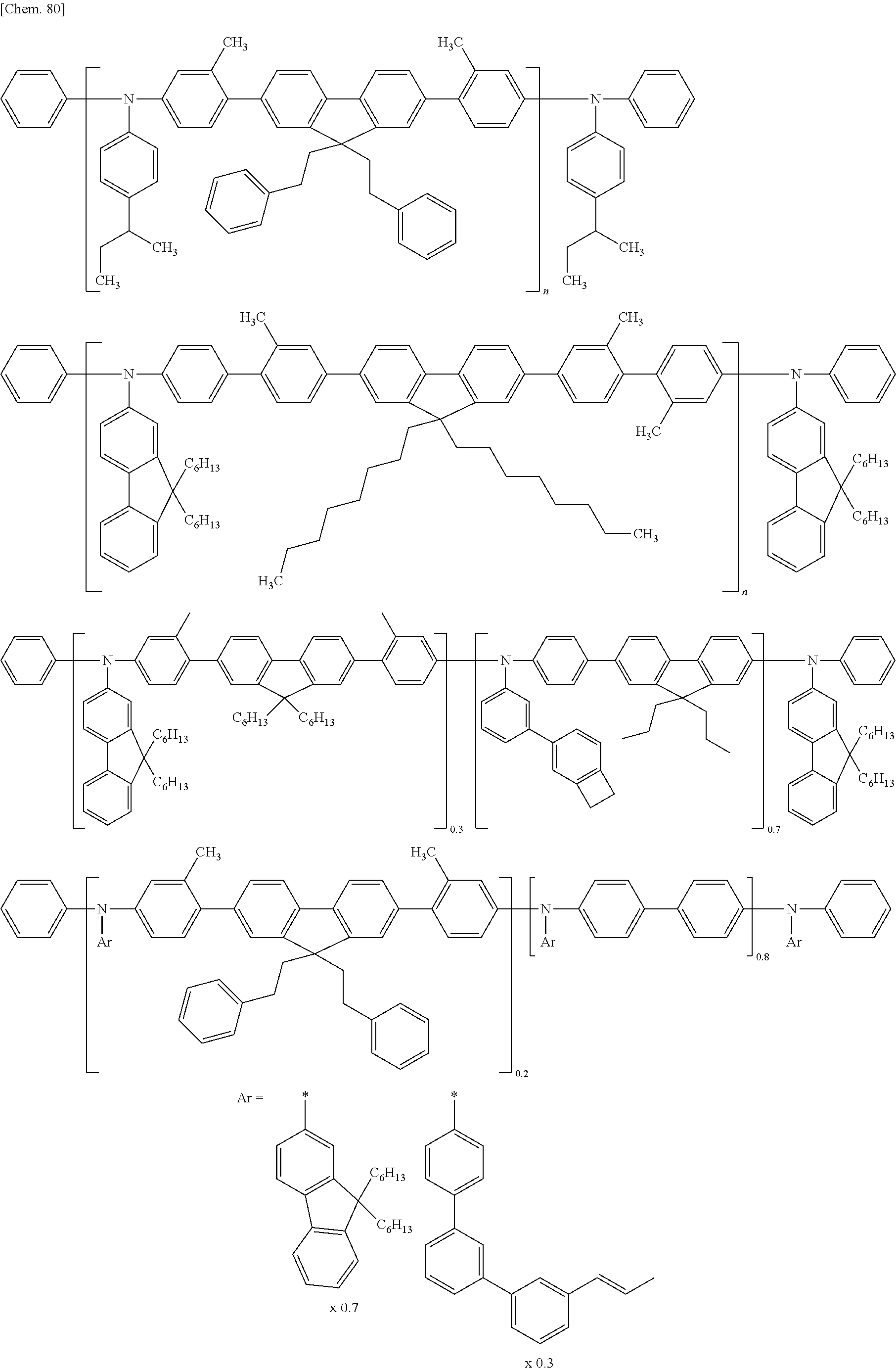

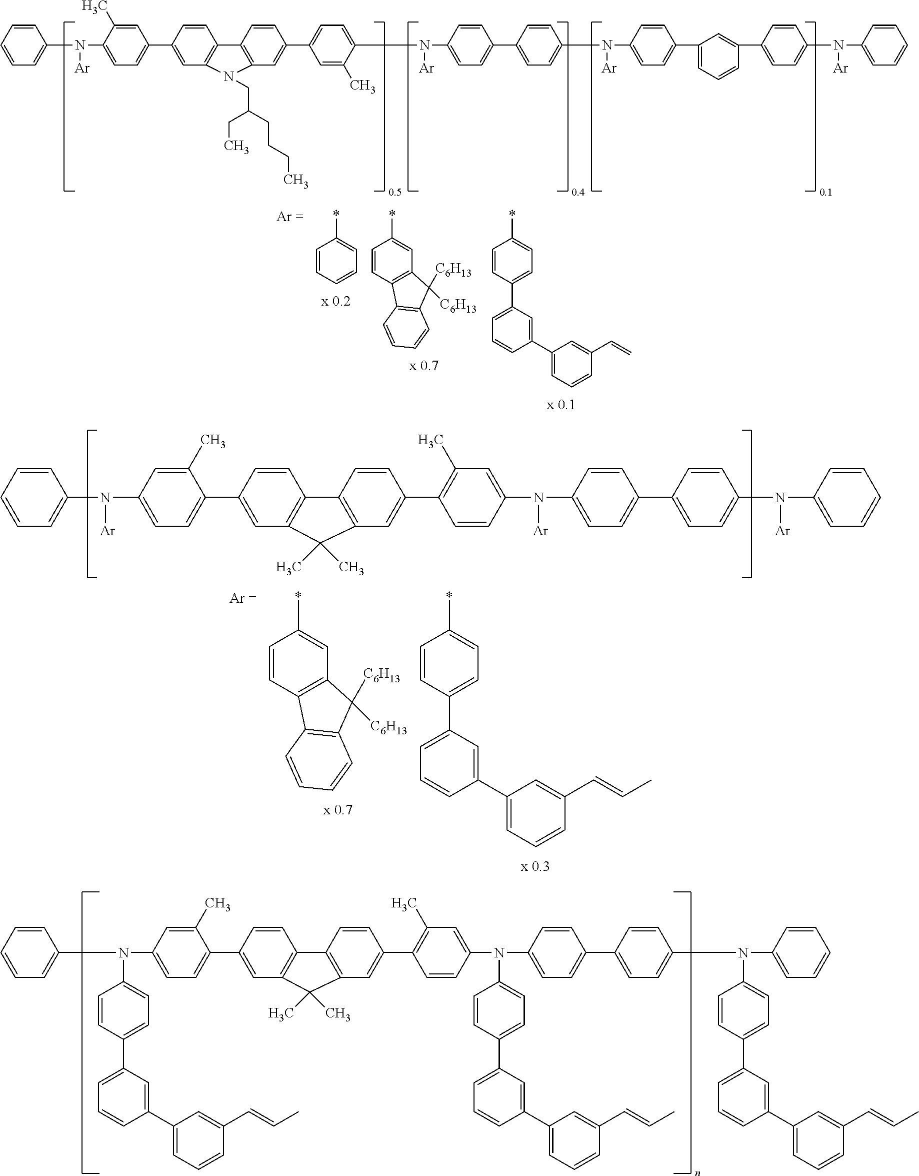

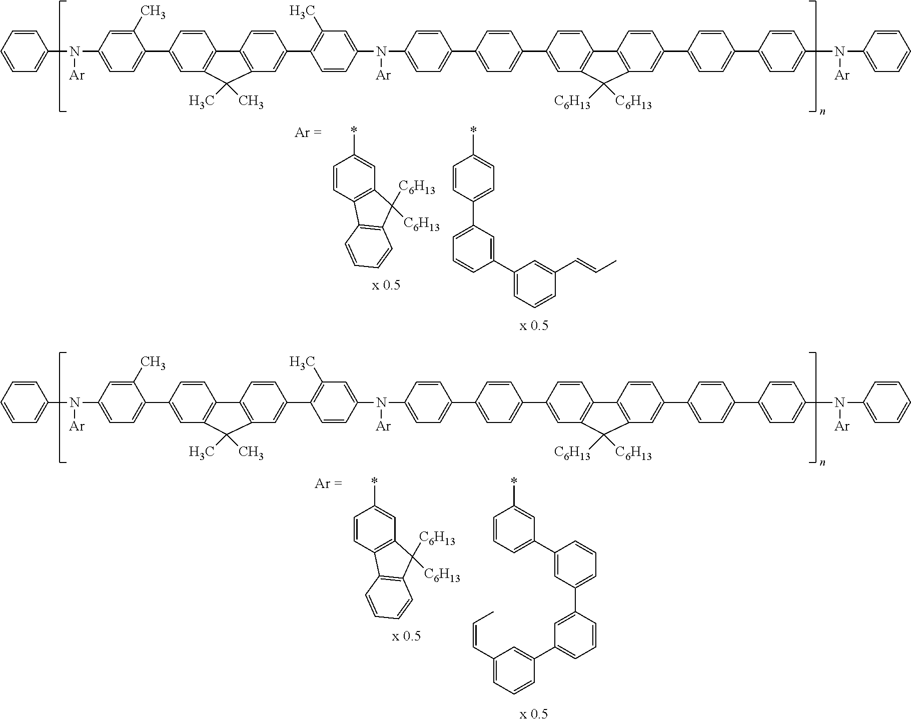

<Method for Producing Polymer>

No particular limitation is imposed on the method for producing the polymer contained in the composition of the invention, and any method may be used. Examples of the production method include a polymerization method using the Suzuki reaction, a polymerization method using the Grignard reaction, a polymerization method using the Yamamoto reaction, a polymerization method using the Ullmann reaction, and a polymerization method using the Buchwald-Hartwig reaction. The polymer can also be produced using production methods similar to polymer production methods described in WO2019/177175, WO2020/171190, and WO2021/125011.

With the polymerization method using the Ullmann reaction and the polymerization method using the Buchwald-Hartwig reaction, for example, dihalogenated aryl represented by the following formula (2a) (Z represents a halogen atom such as I, Br, Cl, or F) and primary aminoaryl represented by the following formula (2b) are reacted to synthesize a polymer including the repeating unit represented by formula (54) above.

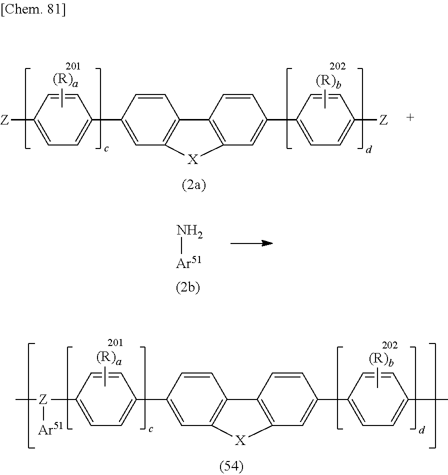

(In the above reaction formula, the definitions of Ar⁵¹, R²⁰¹, R²⁰², X, and a to d are the same as those for formula (54).)

With the polymerization method using the Ullmann reaction and the polymerization method using the Buchwald-Hartwig reaction, for example, dihalogenated aryl represented by formula (3a) (Z represents a halogen atom such as I, Br, Cl, or F) and primary aminoaryl represented by formula (3b) are reacted to synthesize a polymer including the repeating unit represented by formula (55) above.

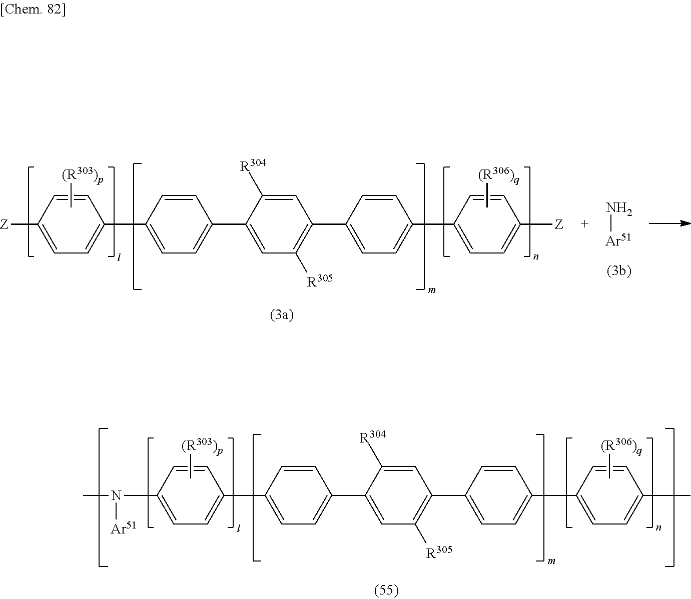

(In the above reaction formula, the definitions of Ar⁵¹, R³⁰³ to R³⁰⁶, n, m, 1, p, and q are the same as those for formula (55).)

In the above polymerization methods, the reaction for forming N-aryl bonds is generally performed in the presence of a base such as potassium carbonate, sodium tert-butoxide, or triethylamine. The polymerization methods can also be performed in the presence of a transition metal catalyst such as a copper or palladium complex.

### [Low-Molecular Weight Charge Transport Compound]

A preferred low-molecular weight charge transport compound in the invention will be described. Hereinafter, the low-molecular weight charge transport compound in the invention may be referred to simply as a low-molecular weight compound.

The low-molecular weight compound in the invention is a compound having a single molecular weight. The molecular weight of the low-molecular weight compound in the invention is generally 500 or more, preferably 600 or more, and more preferably 800 or more and is generally 5,000 or less, preferably 4,000 or less, more preferably 3,000 or less, still more preferably 2,500 or less, and particularly preferably 2,000 or less.

In the following description of the structure of the low-molecular weight compound, the substituent used can be any group, unless otherwise specified. The substituent is preferably a group selected from the substituent group Z, particularly from the substituent group X, and preferred substituents are also the preferred groups in the substituent group Z, particularly in the substituent group X. The crosslinking group used can be any of the groups described for the above crosslinking group and is preferably a group selected from the group T of crosslinking groups, and preferred substituents are also the preferred groups in the group T of crosslinking groups.

The low-molecular weight compound in the invention is a low-molecular weight compound selected from the group consisting of a low-molecular weight compound represented by formula (71) below (which may be hereinafter referred to as a “low-molecular weight compound (71)”), a low-molecular weight compound represented by formula (72) (which may be hereinafter referred to as a “low-molecular weight compound (72)”), a low-molecular weight compound represented by formula (73) (which may be hereinafter referred to as a “low-molecular weight compound (73)”), a low-molecular weight compound represented by formula (74) (which may be hereinafter referred to as a “low-molecular weight compound (74)”), a low-molecular weight compound represented by formula (75) (which may be hereinafter referred to as a “low-molecular weight compound (75)”), a low-molecular weight compound represented by formula (1) (which may be hereinafter referred to as a “low-molecular weight compound (1)”), and a low-molecular weight compound represented by formula (2) (which may be hereinafter referred to as a “low-molecular weight compound (72)”).

### [Low-Molecular Weight Compound (71)]

The low-molecular weight compound (71) in the invention is the compound represented by the following formula (71) and is contained as a charge transport material in the composition of the invention.

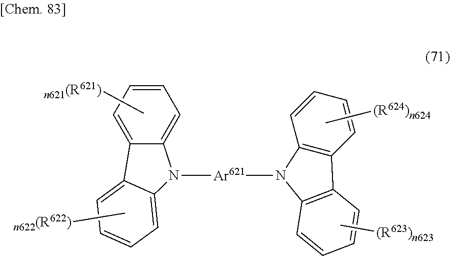

(In formula (71),

Ar⁶²¹ represents a divalent aromatic hydrocarbon group having 6 to 50 carbon atoms and optionally having a substituent.

R⁶²¹, R⁶²², R⁶²³, and R⁶²⁴ are each independently a deuterium atom, a halogen atom, a monovalent aromatic hydrocarbon group having 6 to 50 carbon atoms and optionally having and/or a crosslinking group, or a crosslinking group.

Formula (71) has at least two crosslinking groups.

n621, n622, n623, and n624 are each independently an integer of 0 to 4.

However, the sum of n621, n622, n633, and n624 is 1 or more.)

### (Ar⁶²¹)

Ar⁶²¹ represents a divalent aromatic hydrocarbon group optionally having a substituent, and the number of carbon atoms in Ar⁶²¹ is 6 to 50.

The number of carbon atoms in the aromatic hydrocarbon group is preferably 6 to 50, more preferably 6 to 30, and still more preferably 6 to 18. Specific examples of the aromatic hydrocarbon group include: divalent groups each including an aromatic hydrocarbon ring structure having generally 6 or more carbon atoms and having generally 30 or less carbon atoms, preferably 18 or less carbon atoms, and still more preferably 14 or less carbon atoms such as a benzene ring, a naphthalene ring, a fluorene ring, an anthracene ring, a tetraphenylene ring, a phenanthrene ring, a chrysene ring, a pyrene ring, a benzanthracene ring, and a perylene ring; and divalent groups each having a structure obtained by bonding a plurality of structures selected from the above structures in a linear or branched manner. The structure including a plurality of aromatic hydrocarbon rings linked together is generally a structure including 2 to 8 rings linked together and preferably a structure including 2 to 5 rings linked together. When a plurality of aromatic hydrocarbon rings are linked together, the aromatic hydrocarbon rings linked together may have the same structure or may have different structures.

The aromatic hydrocarbon group is preferably a divalent group formed by bonding, in any order in a linear or branched manner, a plurality of structures selected from 1 to 4 benzene rings, 1 or 2 naphthalene rings, 1 or 2 fluorene rings, 1 or 2 phenanthrene rings, and one tetraphenylene ring, a 1,4-phenylene group, a 1,3-phenylene group, a 2,7-fluorenylene group, or a divalent spirofluorene group, more preferably a divalent group formed by bonding, in any order in a linear or branched manner, a plurality of structures selected from 1 to 4 benzene rings and 1 or 2 fluorene rings, and particularly preferably a divalent group formed by bonding, in the following order in a linear manner, 1 or 2 phenylene groups, a 2,7-fluorenylene group, and 1 or 2 phenylene groups, a phenylene group, a biphenylene group, a p-terphenylene group, or a 2,7-fluorenylene group. The fluorene structure may optionally have substituents at the 9- and 9′ positions, and the optional substituents are each preferably a group selected from the substituent group Z, particularly from the substituent group X.

Each of the above aromatic hydrocarbon structures may optionally have a substituent. The optional substituent is as described above. Specifically, the substituent can be selected from the substituent group Z and preferably from the substituent group X. Preferred substituents are the preferred substituents in the substituent group Z, particularly in the substituent group X.

### (Partial Structure of Ar⁶²¹)

Ar⁶²¹ has preferably at least one partial structure selected from the following formulas (71-1) to (71-11) and (71-21) to (71-24) from the viewpoint that the stability of the compound against electric charges tends to be improved and has more preferably at least one partial structure selected from the following formula (71-1) to (71-7) from the viewpoint of the solubility and durability of the compound.

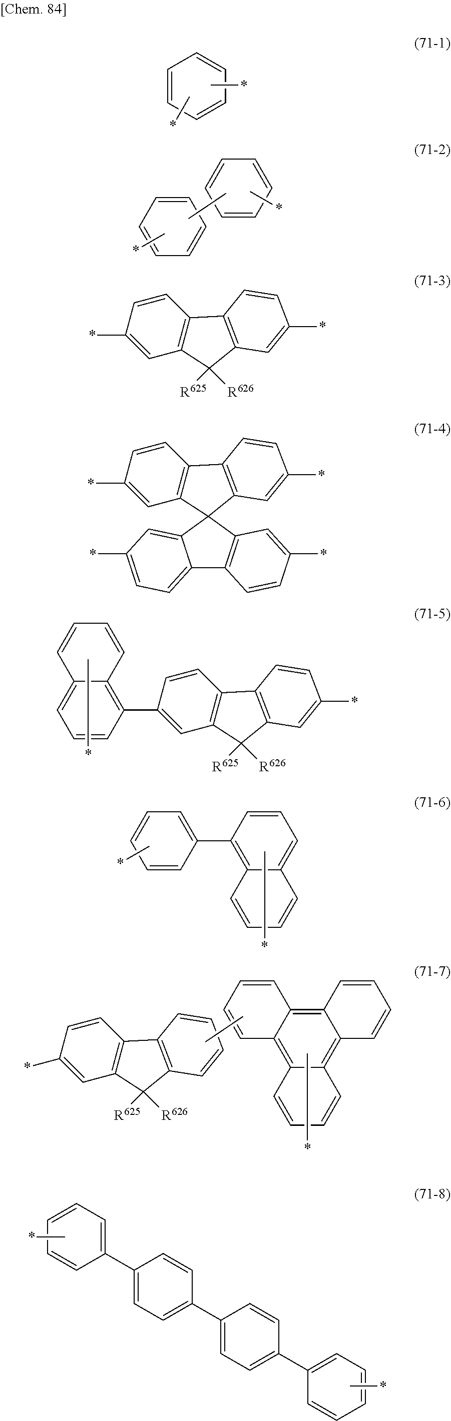

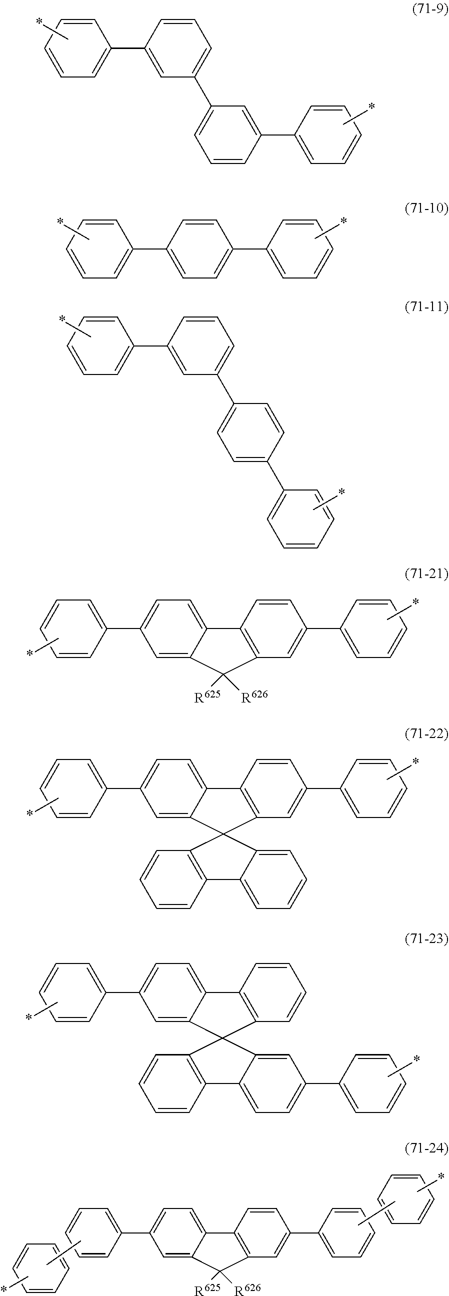

(In each of formulas (71-1) to (71-11) and (71-21) to (71-24) above,

each * represents a bond to an adjacent structure or a hydrogen atom; when two *'s are present, at least one of them represents a position of bonding to an adjacent structure; when four *'s are present, at least one of any two of the four *'s represents a position of bonding to an adjacent structure.

R⁶²⁵ and R⁶²⁶ each independently represent an alkyl group having 6 to 12 carbon atoms, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, a cyano group, an aralkyl group, or a monovalent aromatic hydrocarbon group having 6 to 30 carbon atoms. R⁶²⁵ and R⁶²⁶ may be bonded together to form a ring.)

The aromatic hydrocarbon ring structures represented by R⁶²⁵ and R⁶²⁶ are each more preferably a phenyl group or a group including a plurality of phenyl groups linked together.

Each of these groups may optionally have a substituent. The optional substituent is as described above. Specifically, the substituent can be selected from the substituent group Z and preferably from the substituent group X. Preferred substituents are the preferred substituents in the substituent group Z, particularly in the substituent group X.

The partial structure is more preferably a structure selected from formulas (71-1) to (71-7), still more preferably a structure selected from formulas (71-1) to (71-5), and particularly preferably a structure selected from formulas (71-1) to (71-4). The structure represented by formula (71-3) is most preferred because good charge transportability is obtained.

Formula (71-1) is preferably a 1,3-phenylene group or a 1,4-phenylene group.

Formula (71-2) is preferably the following formula (71-2-2).

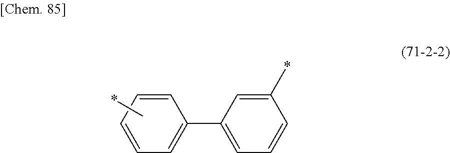

Formula (71-2) is more preferably the following formula (71-2-3).

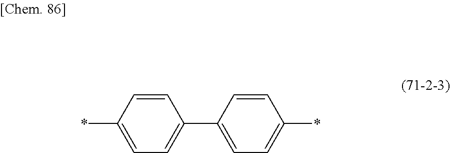 [SMILES: *c1ccc(-c2ccc(*)cc2)cc1]

From the viewpoint of the solubility and durability of the compound, it is preferable that Ar⁶²¹ has, as a partial structure, a partial structure represented by formula (71-1) and a partial structure represented by formula (71-2).

The partial structure including a partial structure represented by formula (71-1) and a partial structure represented by formula (71-2) is more preferably a partial structure represented by at least one selected from formulas (71-8) to (71-11) above, each of which represents a structure including a plurality of structures selected from partial structures represented by formula (71-1) and partial structures represented by formula (71-2).

A partial structure including a partial structure represented by formula (71-1) and a partial structure represented by formula (71-3) or (71-4) is more preferably a partial structure represented by at least one selected from formulas (71-21) to (71-24) above, each of which represents a structure including a plurality of structures selected from partial structures represented by formula (71-1) and partial structures represented by formulas (71-3) and (71-4).

In the present invention, a compound including, between the carbazole rings, a fluorene ring having a substituent having good charge transportability is preferred, and it is preferable to include a fluorene ring as Ar⁶²¹.

(R⁶²¹, R⁶²², R⁶²³, and R⁶²⁴)

R⁶²¹, R⁶²², R⁶²³, and R⁶²⁴ each independently represent a deuterium atom, a halogen atom, a monovalent aromatic hydrocarbon group having 6 to 50 carbon atoms and optionally having a substituent and/or a crosslinking group, or a crosslinking group.

The halogen atom is particularly preferably a fluorine atom.

When R⁶²¹, R⁶²², R⁶²³, and R⁶²⁴ are each independently a monovalent aromatic hydrocarbon group having 6 to 50 carbon atoms and optionally having a substituent and/or a crosslinking group, R⁶²¹, R⁶²², R⁶²³, and R⁶²⁴ may each be independently an aromatic hydrocarbon group having 6 to 50 carbon atoms and having both a substituent and a crosslinking group.

Preferably, R⁶²¹, R⁶²², R⁶²³, and R⁶²⁴ are each independently an aromatic hydrocarbon group having 6 to 50 carbon atoms and optionally having a crosslinking group or a crosslinking group.

The number of carbon atoms in the aromatic hydrocarbon group is preferably 6 to 50, more preferably 6 to 30, and still more preferably 6 to 18. Specific examples of the aromatic hydrocarbon group include: monovalent groups each including an aromatic hydrocarbon ring structure having generally 6 or more carbon atoms and having generally 30 or less carbon atoms, preferably 18 or less carbon atoms, and still more preferably 14 or less carbon atoms such as a benzene ring, a naphthalene ring, an anthracene ring, a tetraphenylene ring, a phenanthrene ring, a chrysene ring, a pyrene ring, a benzanthracene ring, and a perylene ring; and monovalent groups each having a structure obtained by bonding a plurality of structures selected from the above structures in a linear or branched manner. The structure including a plurality of aromatic hydrocarbon rings linked together is generally a structure including 2 to 8 aromatic hydrocarbon rings linked together and is preferably a structure including 2 to 5 aromatic hydrocarbon rings linked together. When a plurality of aromatic hydrocarbon rings are linked together, the aromatic hydrocarbon rings linked together may have the same structure or may have different structures.

Each of these aromatic hydrocarbon groups may optionally have a substituent and/or a crosslinking group. The optional substituent on each aromatic hydrocarbon group is as described above. Specifically, the optional substituent can be selected from the substituent group Z and preferably from the substituent group X. Preferred substituents are the preferred substituents in the substituent group Z, particularly in the substituent group X. The optional crosslinking group on each aromatic hydrocarbon group is as described above. Specifically, the optional crosslinking group can be selected from the group T of crosslinking groups. Preferred crosslinking groups are the preferred crosslinking groups in the group T of crosslinking groups.

From the viewpoint of the solubility and durability of the compound, R⁶²¹, R⁶²², R⁶²³, and R⁶²⁴ each have preferably at least one partial structure selected from formulas (71-1) to (71-3) above, more preferably at least one partial structure selected from a 1,3-phenylene group, a 1,4-phenylene group, and formulas (71-1) and (71-2), and particularly preferably a 1,3-phenylene group, a 1,4-phenylene group, or a partial structure represented by formula (71-2-2).

### (Crosslinking Groups)

The compound represented by formula (71) has at least two crosslinking groups. The crosslinking groups are as described above. Specifically, each crosslinking group can be selected from the group T of crosslinking groups. Preferred crosslinking groups are the preferred crosslinking groups in the group T of crosslinking groups.

As for the positions of the crosslinking groups on the compound represented by formula (71), it is preferable that at least one R⁶²¹ and at least one R⁶²³ are each substituted with a crosslinking group or are each a crosslinking group, and it is more preferable that only two, i.e., one R⁶²¹ and one R⁶²³, are each substituted with a crosslinking group or are each a crosslinking group.

A structure in which R⁶²¹ and R⁶²³ each have a crosslinking group is the same as a structure in which R⁶²² and R⁶²⁴ each have a crosslinking group because of the symmetry of the compound represented by formula (71).

(n621, n622, n623, and n624)

n621, n622, n623, and n624 are each independently an integer of 0 to 4. However, n621+n622+n623+n624 is 1 or more.

n621, n622, n623, and n624 are each independently an integer of 0 to 2 and are each more preferably 0 or 1.

Since the compound represented by formula (71) has crosslinking groups, n621 and n623 are each preferably 1 or more and are each preferably 2 or less and still more preferably 1. It is particularly preferable that n621 and n623 are each 1 and n622 and n624 are each 0.

In the compound represented by formula (71), it is particularly preferable that n621 and n623 are each 1, that n622 and n624 are each 0, and that R⁶²¹ and R⁶²³ are each independently an aromatic hydrocarbon group having 6 to 50 carbon atoms and substituted with a crosslinking group or a crosslinking group.

### (Specific Examples of Low-Molecular Weight Compound (71))

Specific examples of the low-molecular weight compound (71) are shown below. However, the present invention is not limited thereto.

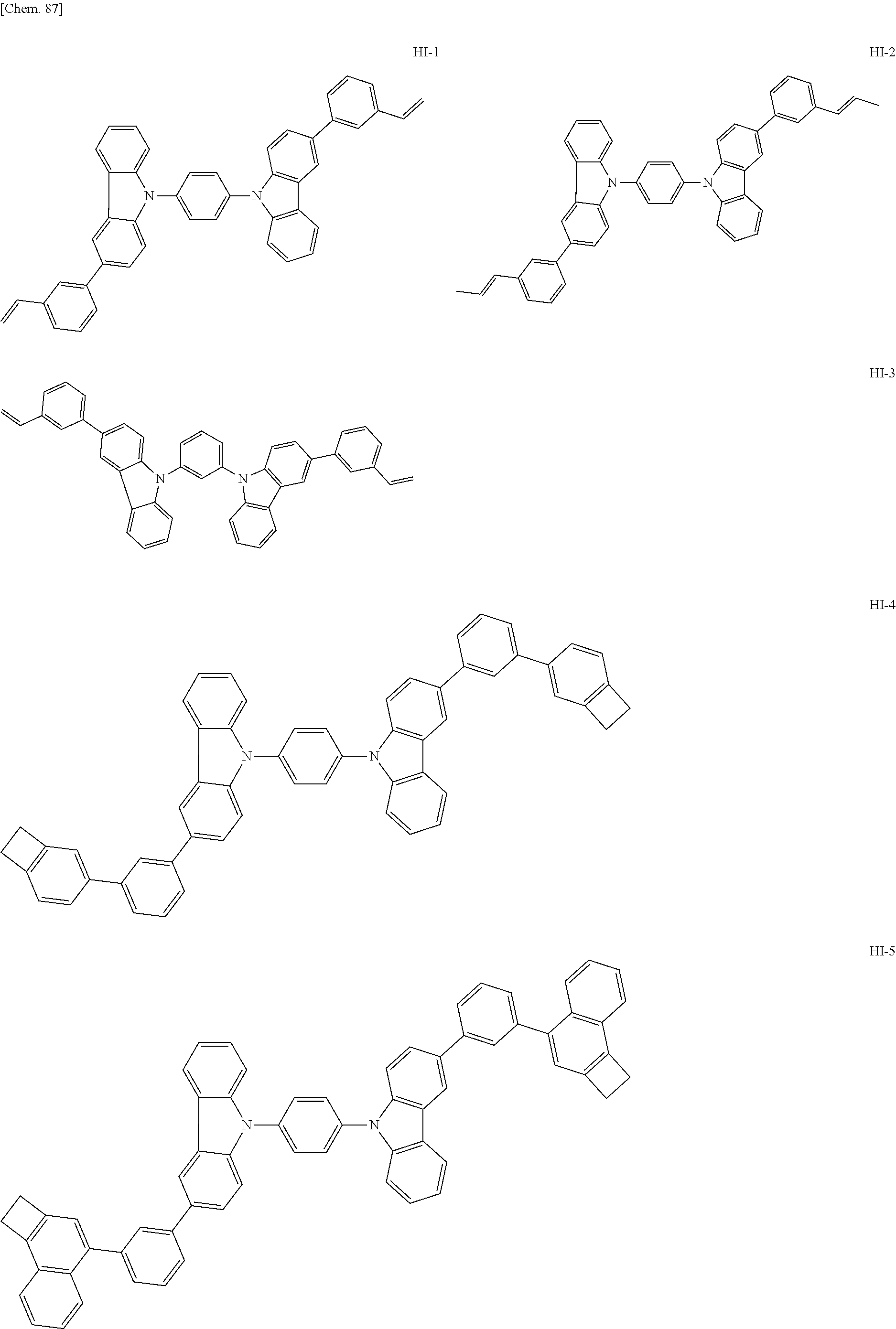 [SMILES: C=Cc1cccc(-c2ccc3c(c2)c2ccccc2n3-c2ccc(-n3c4ccccc4c4cc(-c5cccc(C=C)c5)ccc43)cc2)c1 ; C/C=C/c1cccc(-c2ccc3c(c2)c2ccccc2n3-c2ccc(-n3c4ccccc4c4cc(-c5cccc(/C=C/C)c5)ccc43)cc2)c1 ; C=Cc1cccc(-c2ccc3c(c2)c2ccccc2n3-c2cccc(-n3c4ccccc4c4cc(-c5cccc(C=C)c5)ccc43)c2)c1 ; c1cc(-c2ccc3c(c2)CC3)cc(-c2ccc3c(c2)c2ccccc2n3-c2ccc(-n3c4ccccc4c4cc(-c5cccc(-c6ccc7c(c6)CC7)c5)ccc43)cc2)c1 ; c1cc(-c2ccc3c(c2)c2ccccc2n3-c2ccc(-n3c4ccccc4c4cc(-c5cccc(-c6cc7c(c8ccccc68)CC7)c5)ccc43)cc2)cc(-c2cc3c(c4ccccc24)CC3)c1]

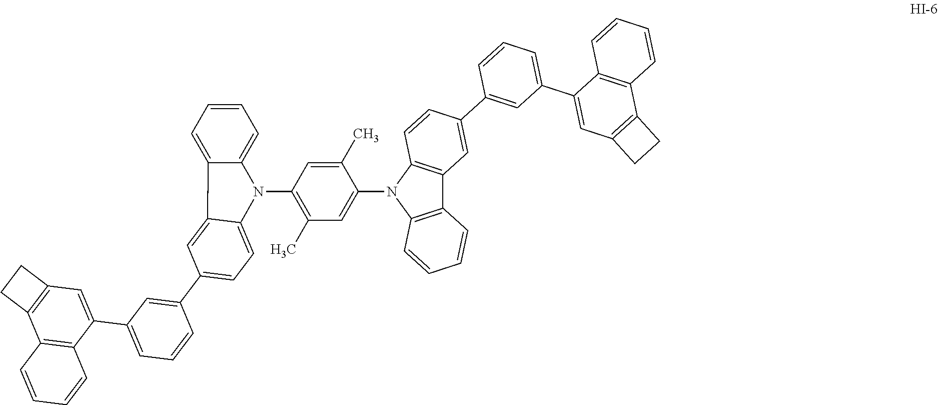 [SMILES: Cc1cc(-n2c3ccccc3c3cc(-c4cccc(-c5cc6c(c7ccccc57)CC6)c4)ccc32)c(C)cc1-n1c2ccccc2c2cc(-c3cccc(-c4cc5c(c6ccccc46)CC5)c3)ccc21]

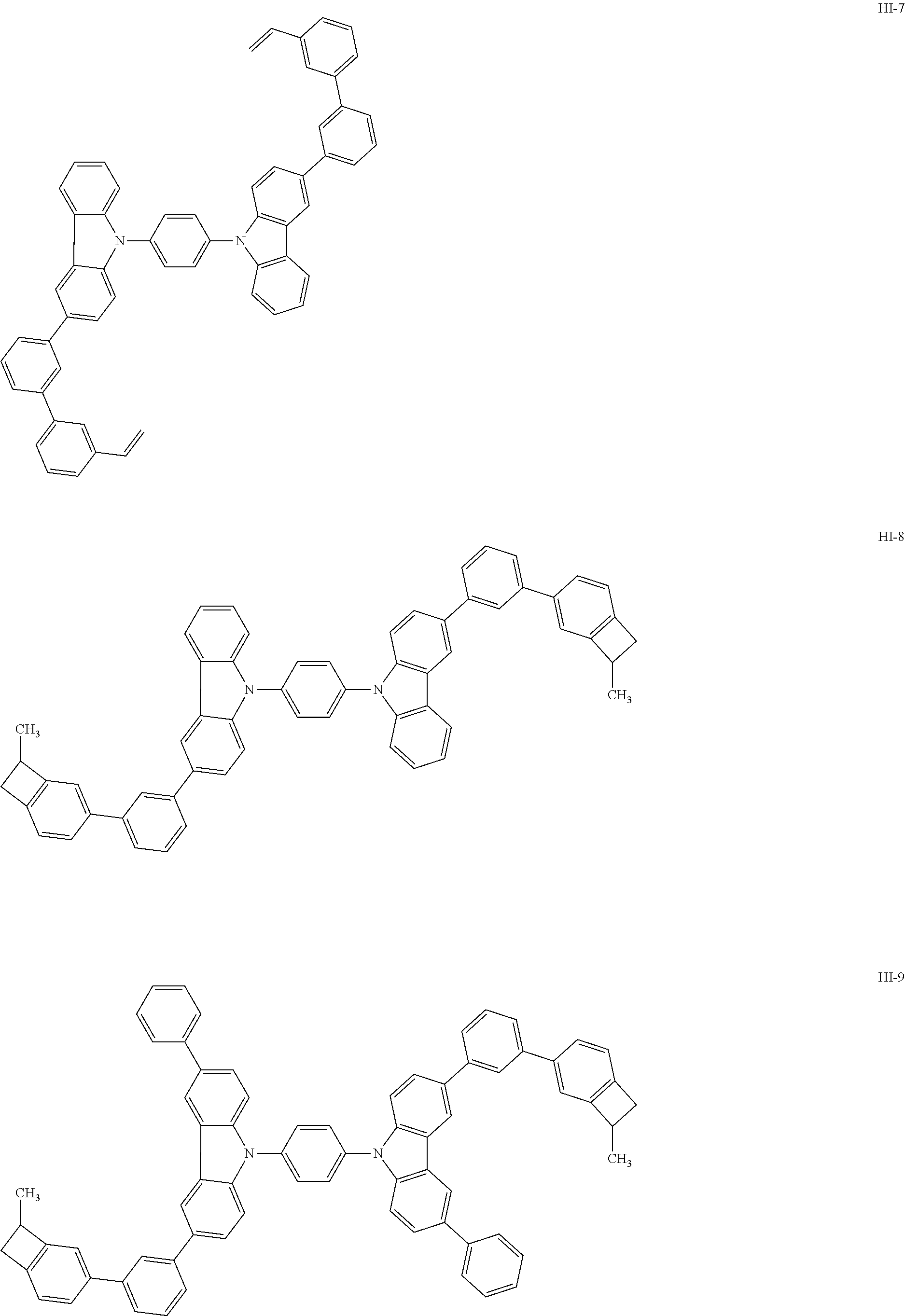 [SMILES: C=Cc1cccc(-c2cccc(-c3ccc4c(c3)c3ccccc3n4-c3ccc(-n4c5ccccc5c5cc(-c6cccc(-c7cccc(C=C)c7)c6)ccc54)cc3)c2)c1 ; CC1Cc2ccc(-c3cccc(-c4ccc5c(c4)c4ccccc4n5-c4ccc(-n5c6ccccc6c6cc(-c7cccc(-c8ccc9c(c8)C(C)C9)c7)ccc65)cc4)c3)cc21 ; CC1Cc2ccc(-c3cccc(-c4ccc5c(c4)c4cc(-c6ccccc6)ccc4n5-c4ccc(-n5c6ccc(-c7ccccc7)cc6c6cc(-c7cccc(-c8ccc9c(c8)C(C)C9)c7)ccc65)cc4)c3)cc21]

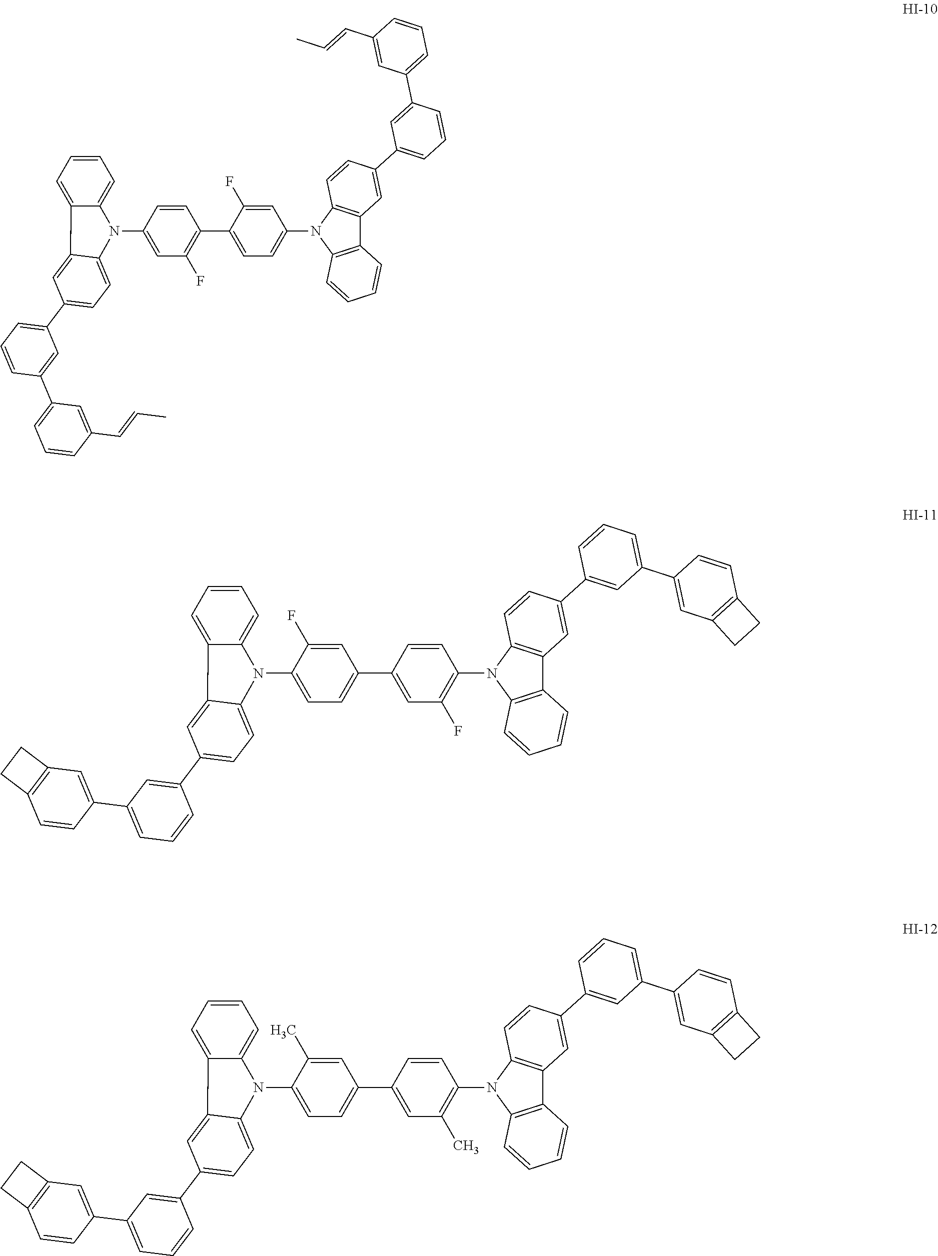 [SMILES: C/C=C/c1cccc(-c2cccc(-c3ccc4c(c3)c3ccccc3n4-c3ccc(-c4ccc(-n5c6ccccc6c6cc(-c7cccc(-c8cccc(/C=C/C)c8)c7)ccc65)cc4F)c(F)c3)c2)c1 ; Fc1cc(-c2ccc(-n3c4ccccc4c4cc(-c5cccc(-c6ccc7c(c6)CC7)c5)ccc43)c(F)c2)ccc1-n1c2ccccc2c2cc(-c3cccc(-c4ccc5c(c4)CC5)c3)ccc21 ; Cc1cc(-c2ccc(-n3c4ccccc4c4cc(-c5cccc(-c6ccc7c(c6)CC7)c5)ccc43)c(C)c2)ccc1-n1c2ccccc2c2cc(-c3cccc(-c4ccc5c(c4)CC5)c3)ccc21]

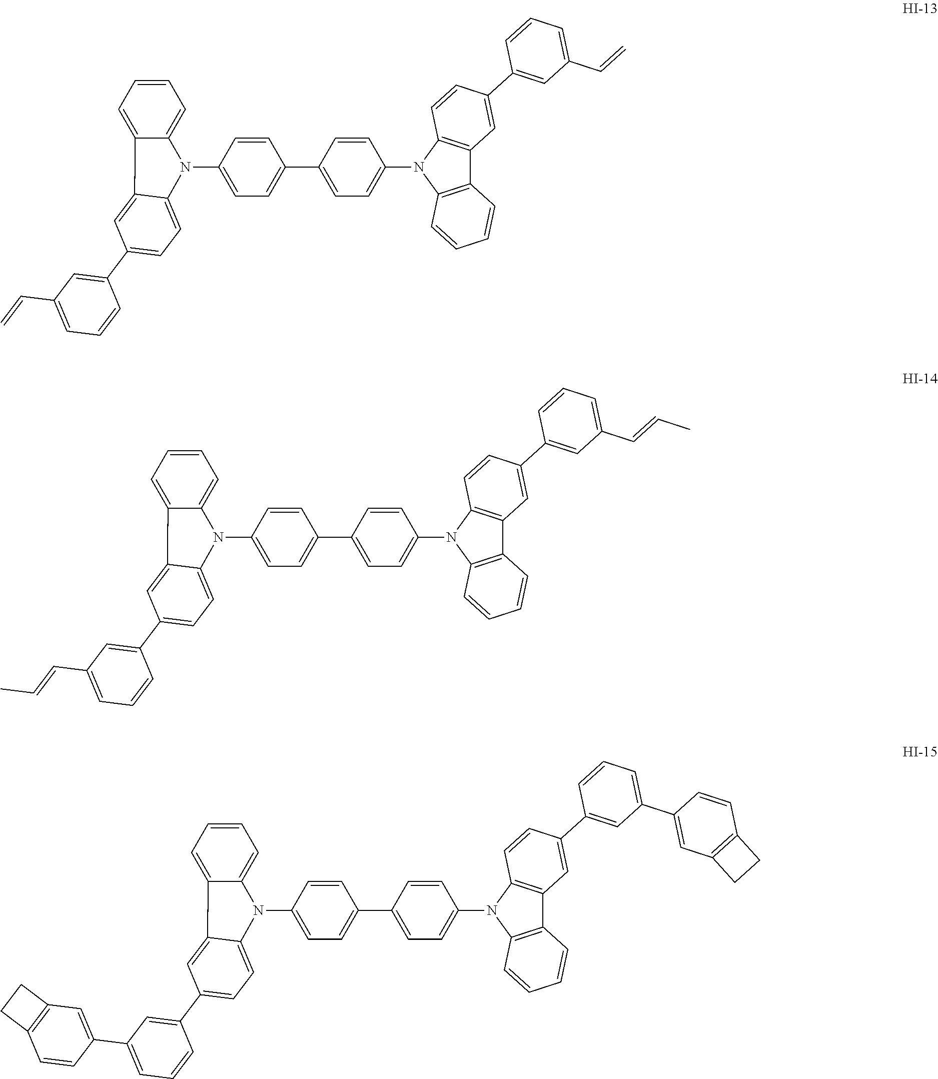

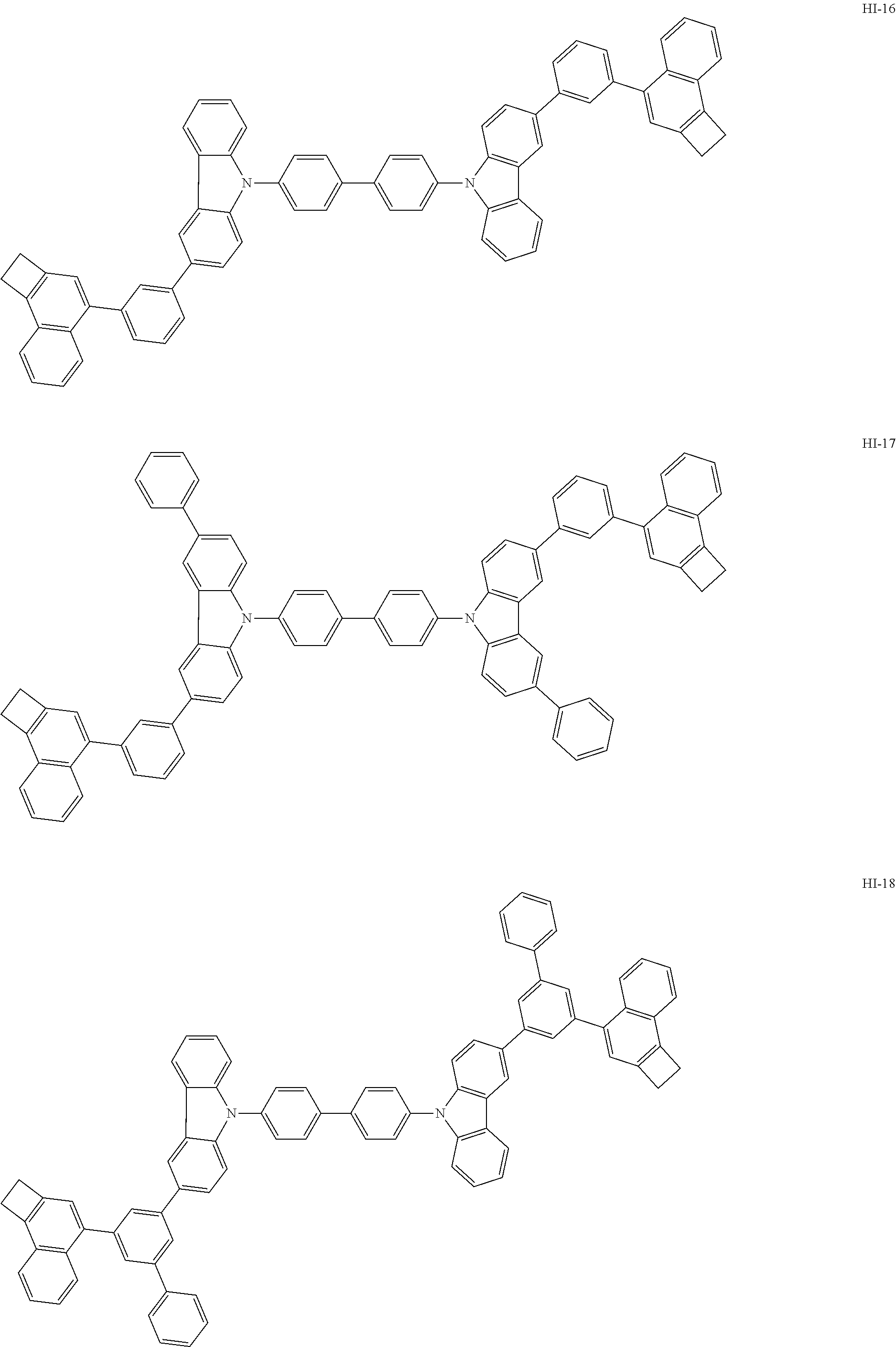 [SMILES: c1cc(-c2ccc3c(c2)c2ccccc2n3-c2ccc(-c3ccc(-n4c5ccccc5c5cc(-c6cccc(-c7cc8c(c9ccccc79)CC8)c6)ccc54)cc3)cc2)cc(-c2cc3c(c4ccccc24)CC3)c1 ; c1ccc(-c2ccc3c(c2)c2cc(-c4cccc(-c5cc6c(c7ccccc57)CC6)c4)ccc2n3-c2ccc(-c3ccc(-n4c5ccc(-c6ccccc6)cc5c5cc(-c6cccc(-c7cc8c(c9ccccc79)CC8)c6)ccc54)cc3)cc2)cc1 ; c1ccc(-c2cc(-c3ccc4c(c3)c3ccccc3n4-c3ccc(-c4ccc(-n5c6ccccc6c6cc(-c7cc(-c8ccccc8)cc(-c8cc9c(c%10ccccc8%10)CC9)c7)ccc65)cc4)cc3)cc(-c3cc4c(c5ccccc35)CC4)c2)cc1]

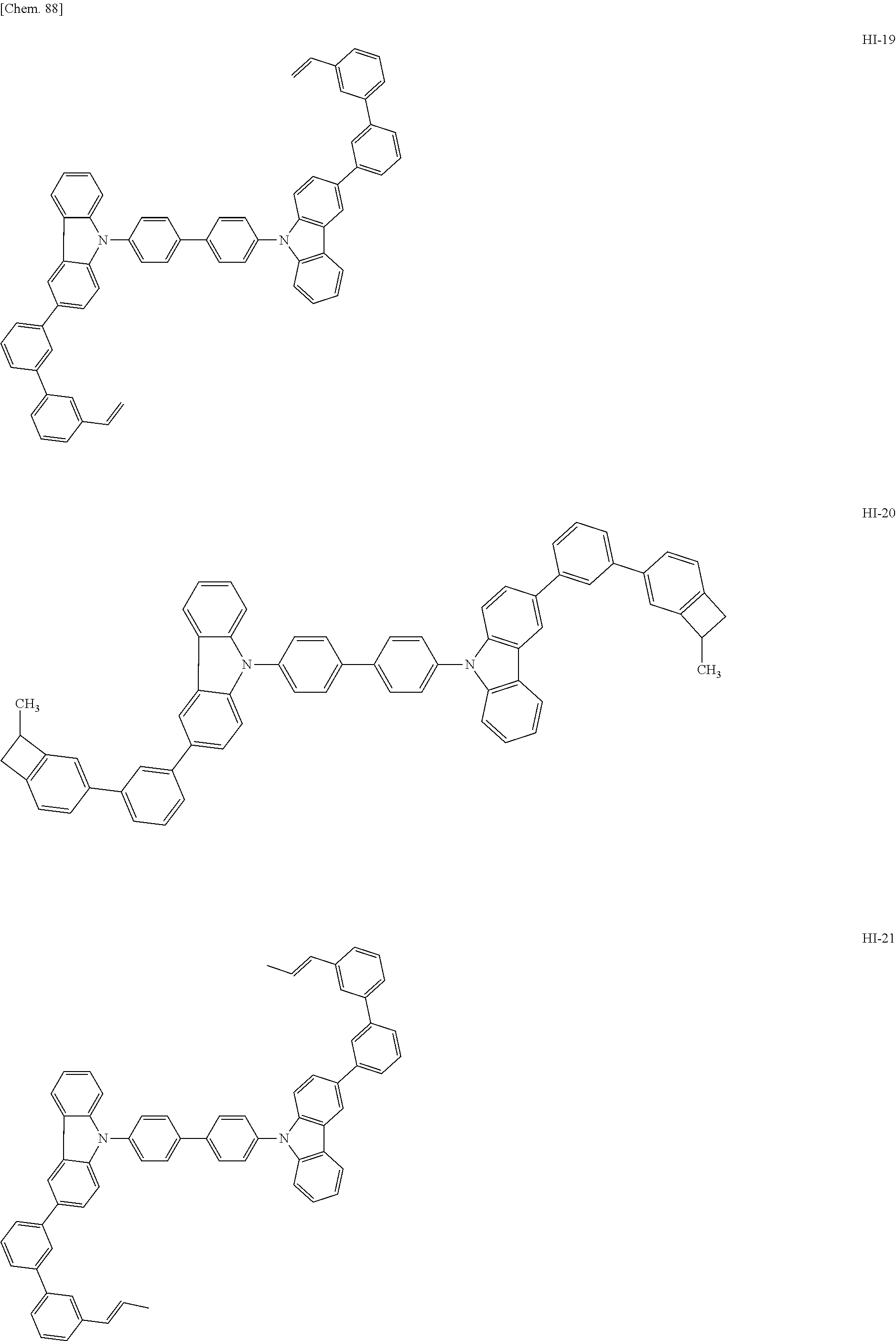 [SMILES: C=Cc1cccc(-c2cccc(-c3ccc4c(c3)c3ccccc3n4-c3ccc(-c4ccc(-n5c6ccccc6c6cc(-c7cccc(-c8cccc(C=C)c8)c7)ccc65)cc4)cc3)c2)c1 ; CC1Cc2ccc(-c3cccc(-c4ccc5c(c4)c4ccccc4n5-c4ccc(-c5ccc(-n6c7ccccc7c7cc(-c8cccc(-c9ccc%10c(c9)C(C)C%10)c8)ccc76)cc5)cc4)c3)cc21 ; C/C=C/c1cccc(-c2cccc(-c3ccc4c(c3)c3ccccc3n4-c3ccc(-c4ccc(-n5c6ccccc6c6cc(-c7cccc(-c8cccc(/C=C/C)c8)c7)ccc65)cc4)cc3)c2)c1]

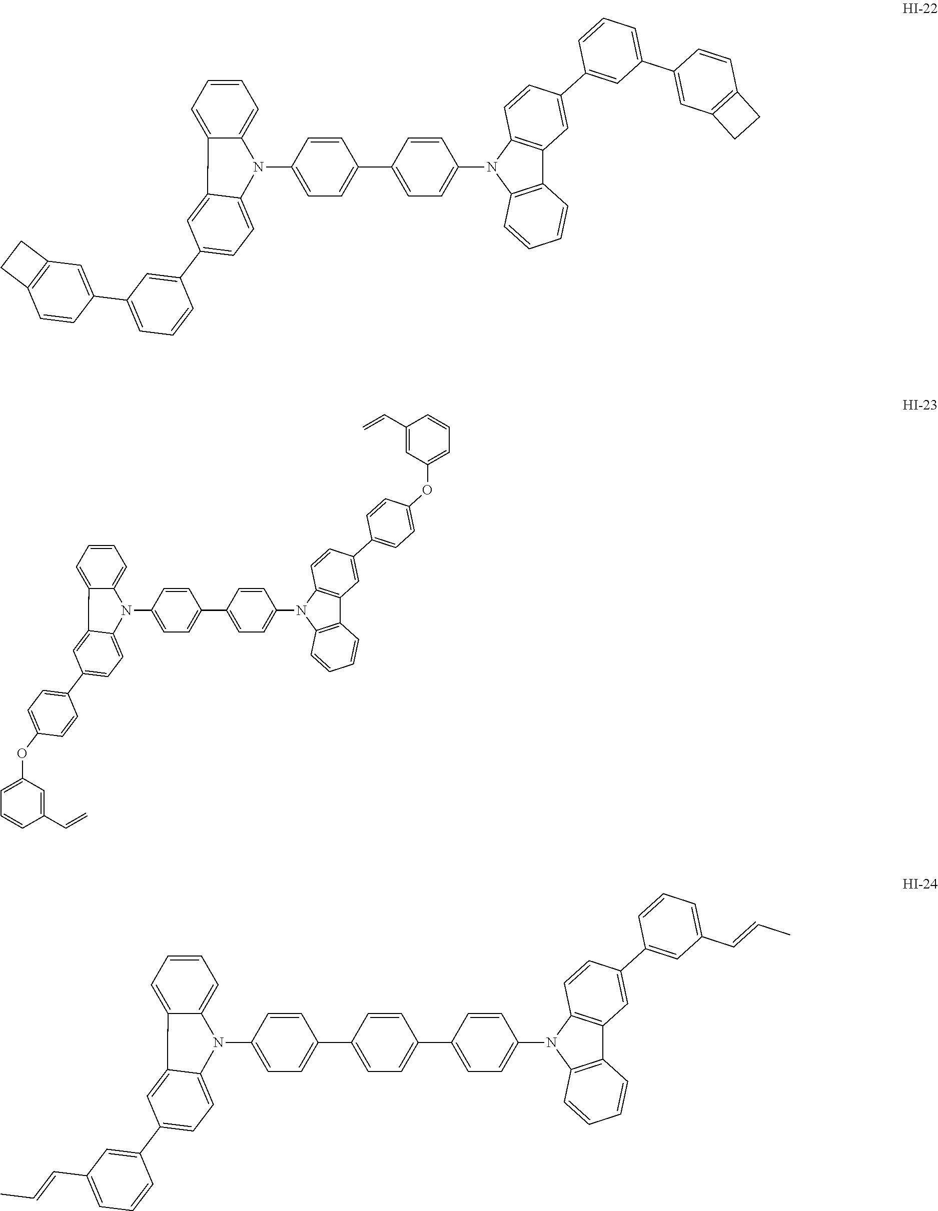 [SMILES: c1cc(-c2ccc3c(c2)CC3)cc(-c2ccc3c(c2)c2ccccc2n3-c2ccc(-c3ccc(-n4c5ccccc5c5cc(-c6cccc(-c7ccc8c(c7)CC8)c6)ccc54)cc3)cc2)c1 ; C=Cc1cccc(Oc2ccc(-c3ccc4c(c3)c3ccccc3n4-c3ccc(-c4ccc(-n5c6ccccc6c6cc(-c7ccc(Oc8cccc(C=C)c8)cc7)ccc65)cc4)cc3)cc2)c1 ; C/C=C/c1cccc(-c2ccc3c(c2)c2ccccc2n3-c2ccc(-c3ccc(-c4ccc(-n5c6ccccc6c6cc(-c7cccc(/C=C/C)c7)ccc65)cc4)cc3)cc2)c1]

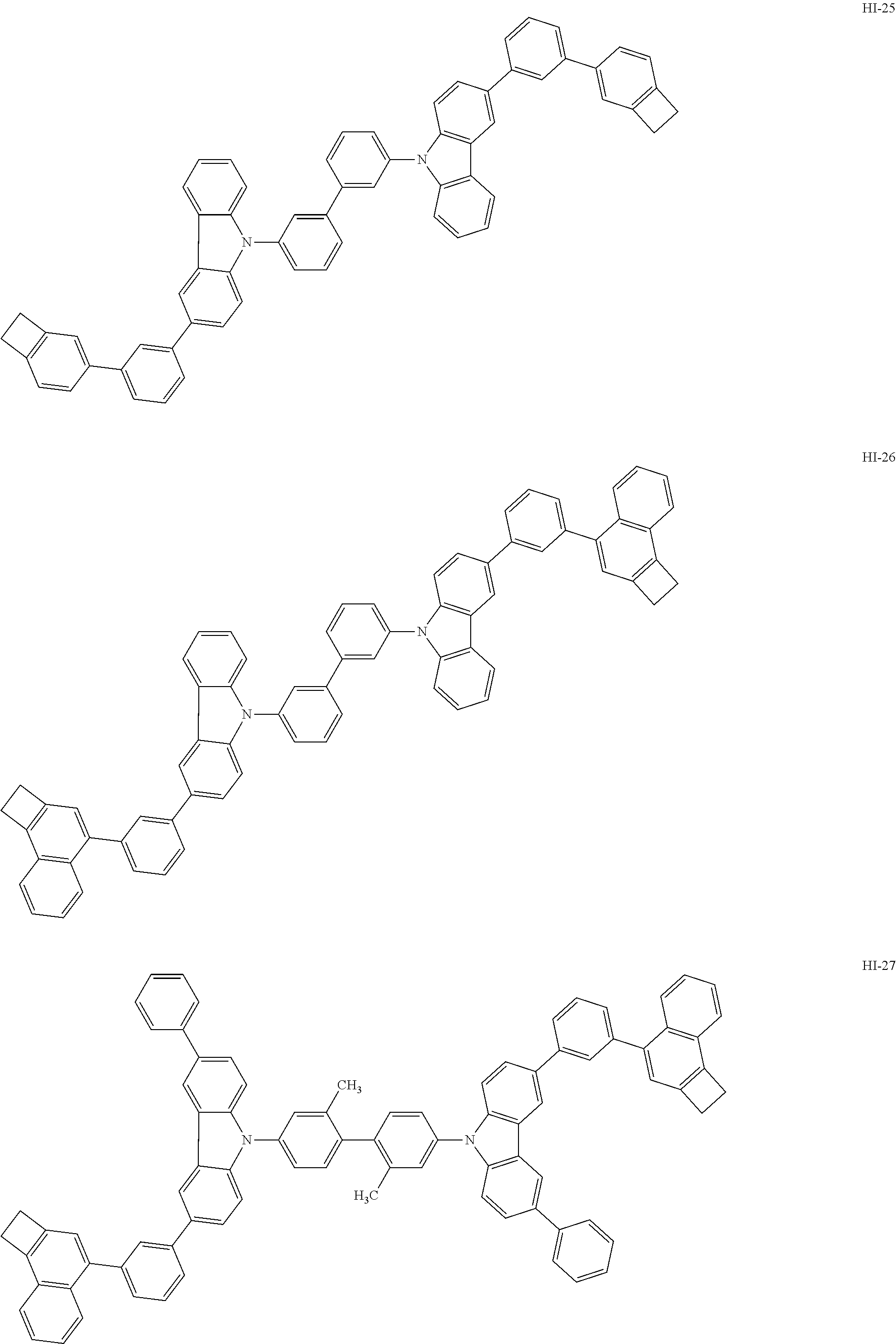 [SMILES: c1cc(-c2ccc3c(c2)CC3)cc(-c2ccc3c(c2)c2ccccc2n3-c2cccc(-c3cccc(-n4c5ccccc5c5cc(-c6cccc(-c7ccc8c(c7)CC8)c6)ccc54)c3)c2)c1 ; c1cc(-c2ccc3c(c2)c2ccccc2n3-c2cccc(-c3cccc(-n4c5ccccc5c5cc(-c6cccc(-c7cc8c(c9ccccc79)CC8)c6)ccc54)c3)c2)cc(-c2cc3c(c4ccccc24)CC3)c1 ; Cc1cc(-n2c3ccc(-c4ccccc4)cc3c3cc(-c4cccc(-c5cc6c(c7ccccc57)CC6)c4)ccc32)ccc1-c1ccc(-n2c3ccc(-c4ccccc4)cc3c3cc(-c4cccc(-c5cc6c(c7ccccc57)CC6)c4)ccc32)cc1C]

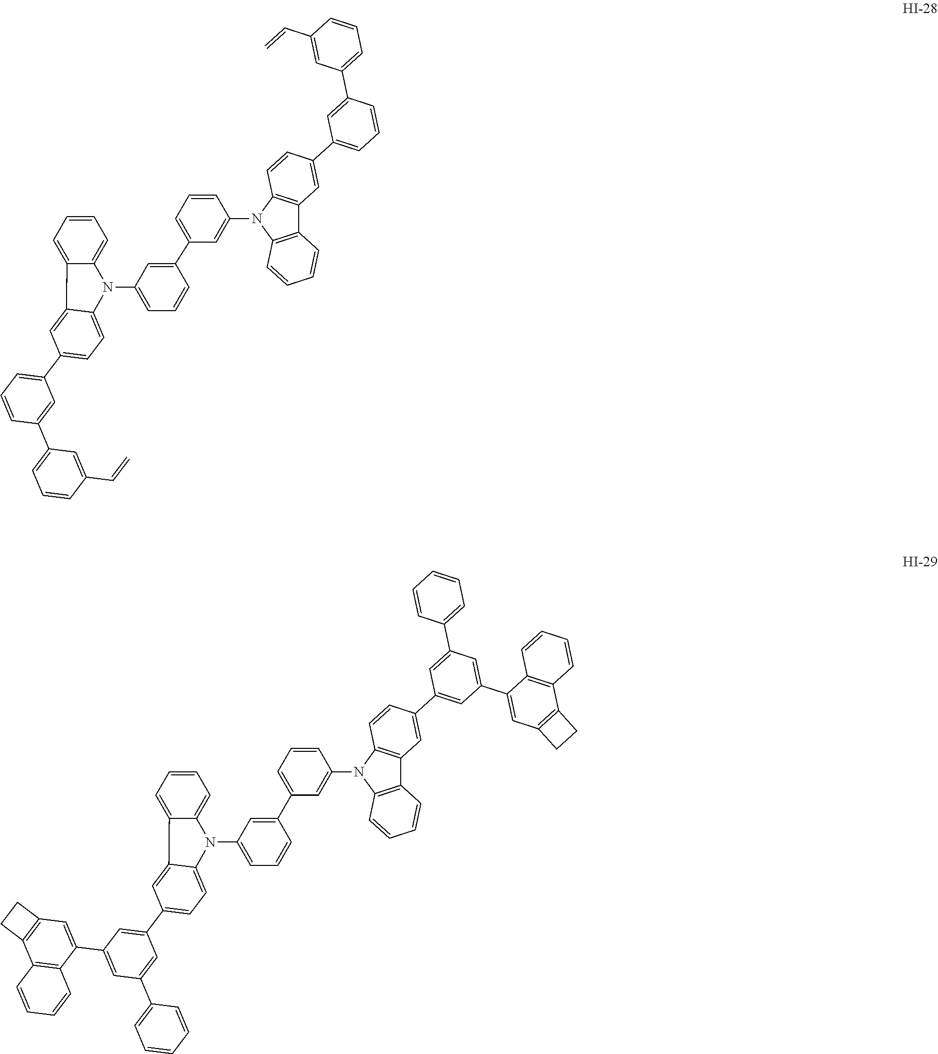 [SMILES: C=Cc1cccc(-c2cccc(-c3ccc4c(c3)c3ccccc3n4-c3cccc(-c4cccc(-n5c6ccccc6c6cc(-c7cccc(-c8cccc(C=C)c8)c7)ccc65)c4)c3)c2)c1 ; c1ccc(-c2cc(-c3ccc4c(c3)c3ccccc3n4-c3cccc(-c4cccc(-n5c6ccccc6c6cc(-c7cc(-c8ccccc8)cc(-c8cc9c(c%10ccccc8%10)CC9)c7)ccc65)c4)c3)cc(-c3cc4c(c5ccccc35)CC4)c2)cc1]

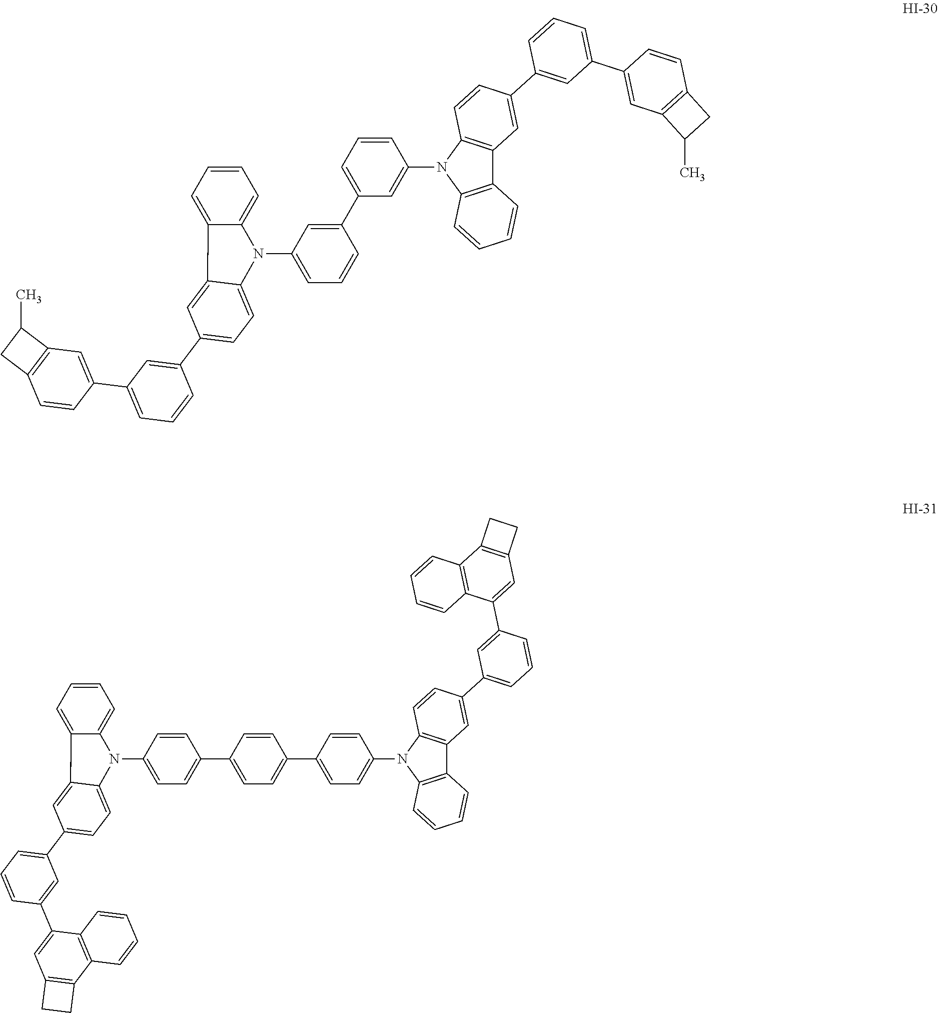 [SMILES: CC1Cc2ccc(-c3cccc(-c4ccc5c(c4)c4ccccc4n5-c4cccc(-c5cccc(-n6c7ccccc7c7cc(-c8cccc(-c9ccc%10c(c9)C(C)C%10)c8)ccc76)c5)c4)c3)cc21 ; c1cc(-c2ccc3c(c2)c2ccccc2n3-c2ccc(-c3ccc(-c4ccc(-n5c6ccccc6c6cc(-c7cccc(-c8cc9c(c%10ccccc8%10)CC9)c7)ccc65)cc4)cc3)cc2)cc(-c2cc3c(c4ccccc24)CC3)c1]

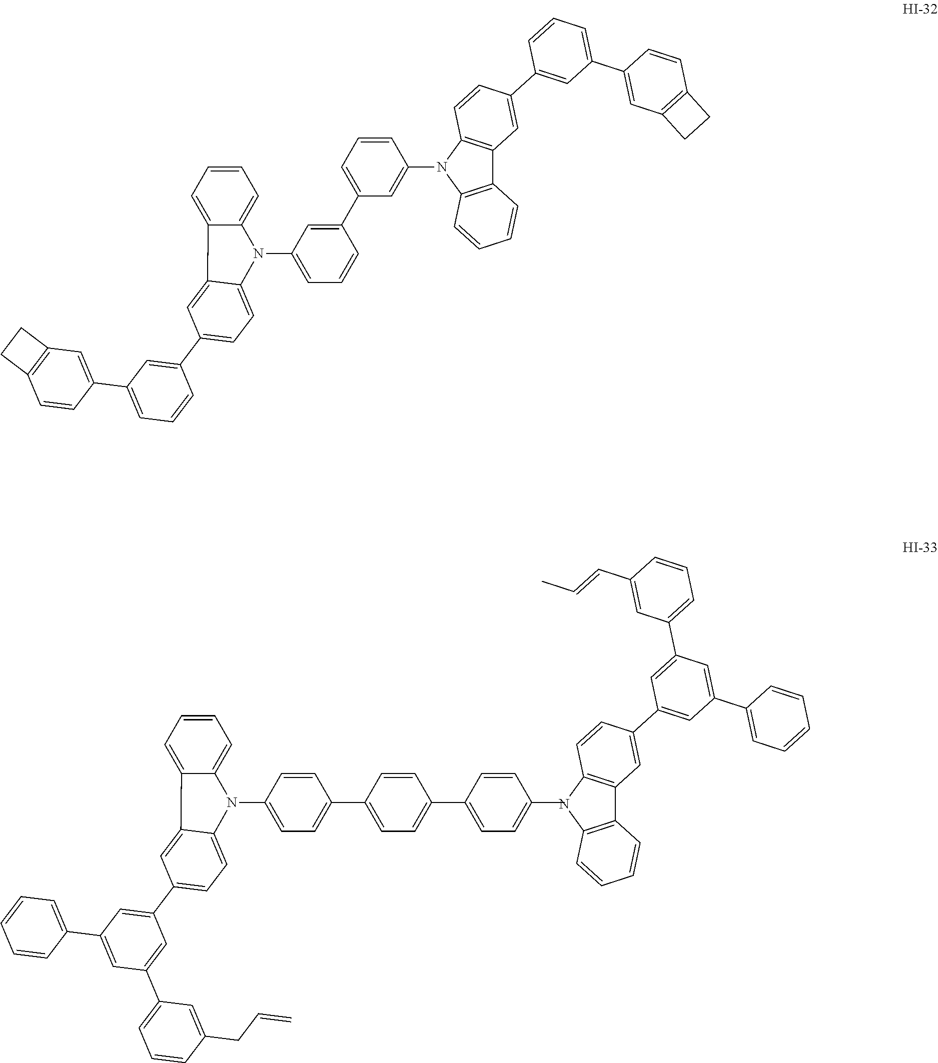

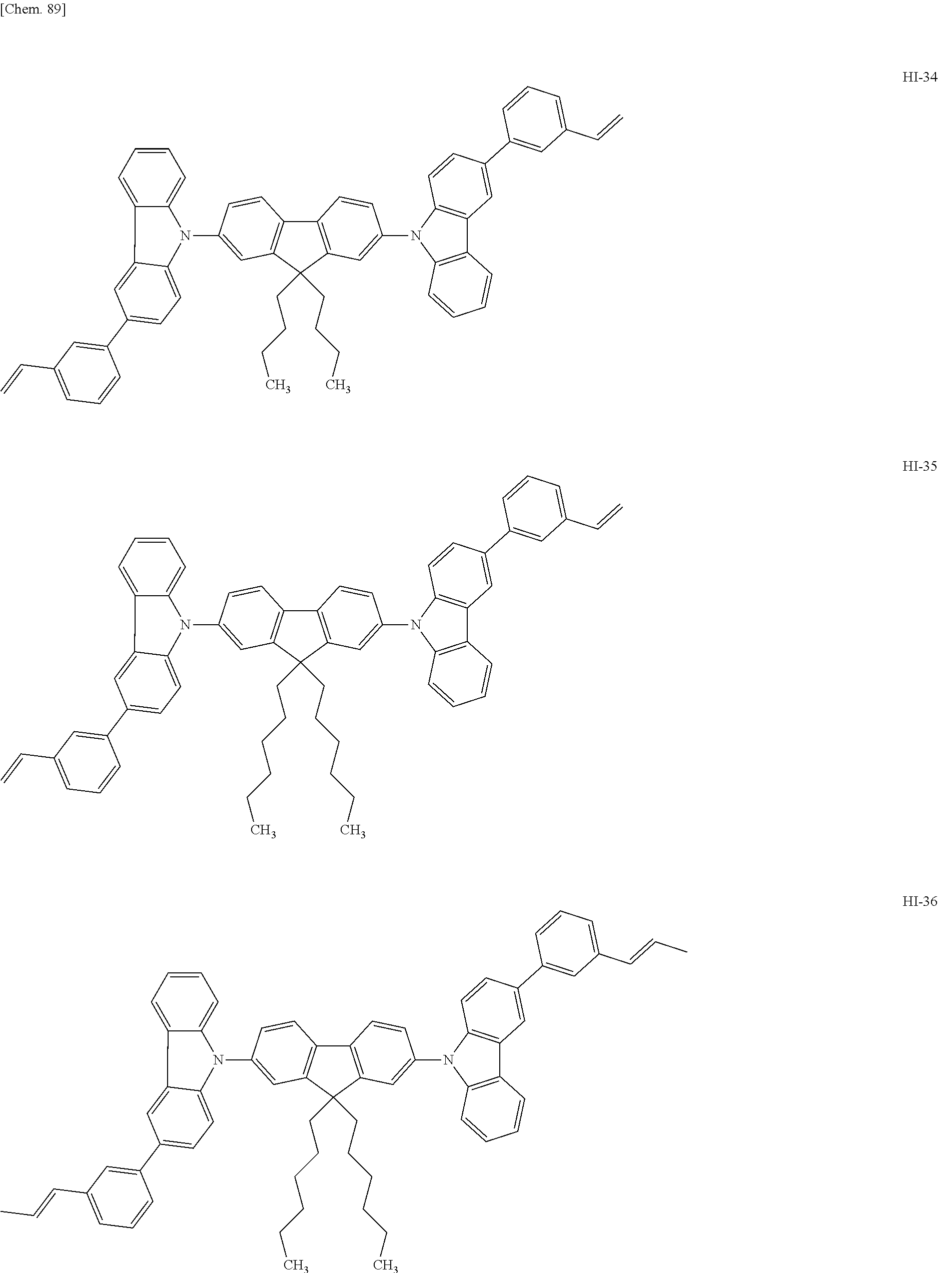

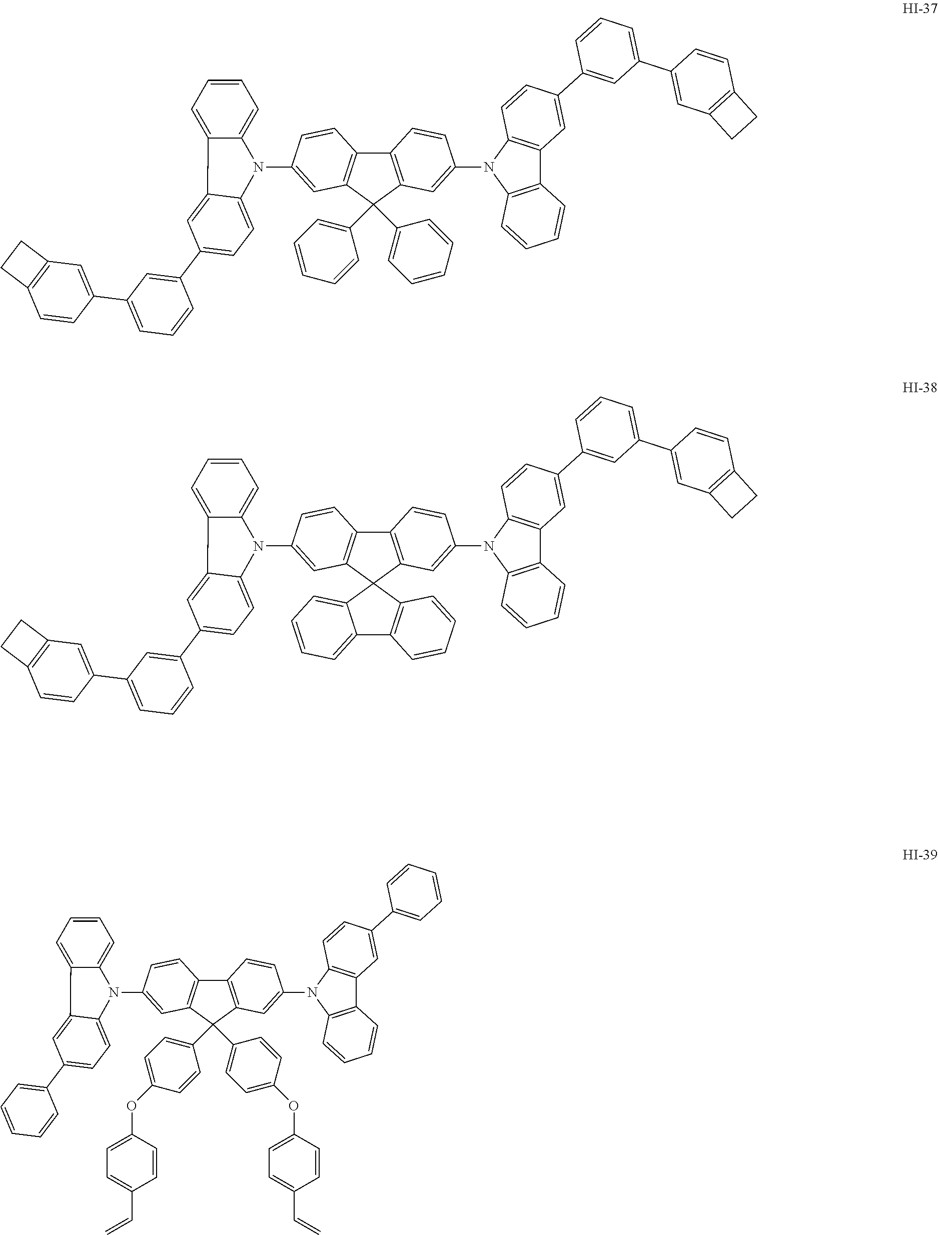 [SMILES: c1ccc(C2(c3ccccc3)c3cc(-n4c5ccccc5c5cc(-c6cccc(-c7ccc8c(c7)CC8)c6)ccc54)ccc3-c3ccc(-n4c5ccccc5c5cc(-c6cccc(-c7ccc8c(c7)CC8)c6)ccc54)cc32)cc1 ; c1cc(-c2ccc3c(c2)CC3)cc(-c2ccc3c(c2)c2ccccc2n3-c2ccc3c(c2)C2(c4ccccc4-c4ccccc42)c2cc(-n4c5ccccc5c5cc(-c6cccc(-c7ccc8c(c7)CC8)c6)ccc54)ccc2-3)c1 ; C=Cc1ccc(Oc2ccc(C3(c4ccc(Oc5ccc(C=C)cc5)cc4)c4cc(-n5c6ccccc6c6cc(-c7ccccc7)ccc65)ccc4-c4ccc(-n5c6ccccc6c6cc(-c7ccccc7)ccc65)cc43)cc2)cc1]

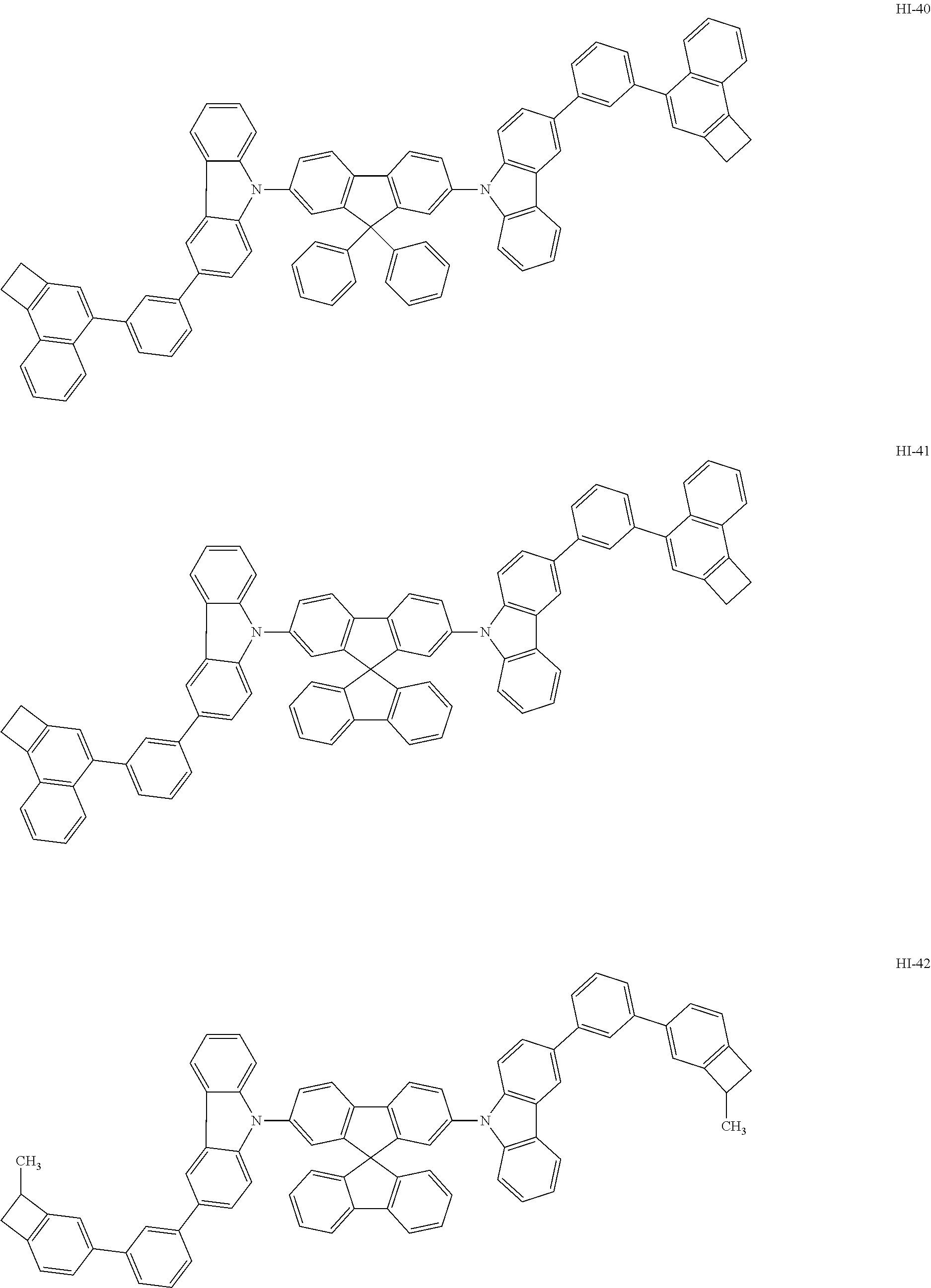 [SMILES: c1ccc(C2(c3ccccc3)c3cc(-n4c5ccccc5c5cc(-c6cccc(-c7cc8c(c9ccccc79)CC8)c6)ccc54)ccc3-c3ccc(-n4c5ccccc5c5cc(-c6cccc(-c7cc8c(c9ccccc79)CC8)c6)ccc54)cc32)cc1 ; c1cc(-c2ccc3c(c2)c2ccccc2n3-c2ccc3c(c2)C2(c4ccccc4-c4ccccc42)c2cc(-n4c5ccccc5c5cc(-c6cccc(-c7cc8c(c9ccccc79)CC8)c6)ccc54)ccc2-3)cc(-c2cc3c(c4ccccc24)CC3)c1 ; CC1Cc2ccc(-c3cccc(-c4ccc5c(c4)c4ccccc4n5-c4ccc5c(c4)C4(c6ccccc6-c6ccccc64)c4cc(-n6c7ccccc7c7cc(-c8cccc(-c9ccc%10c(c9)C(C)C%10)c8)ccc76)ccc4-5)c3)cc21]

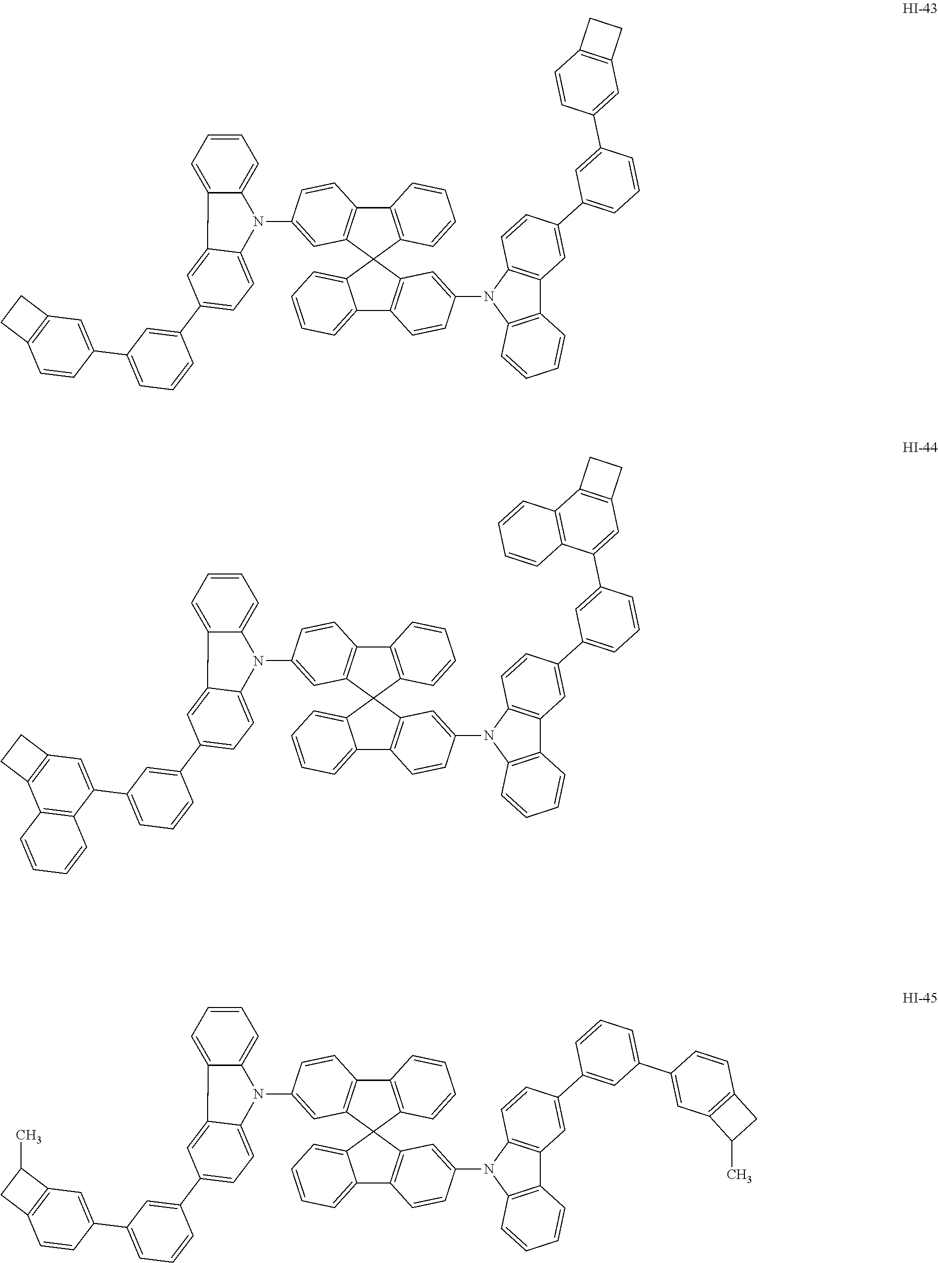 [SMILES: c1cc(-c2ccc3c(c2)CC3)cc(-c2ccc3c(c2)c2ccccc2n3-c2ccc3c(c2)C2(c4ccccc4-3)c3ccccc3-c3ccc(-n4c5ccccc5c5cc(-c6cccc(-c7ccc8c(c7)CC8)c6)ccc54)cc32)c1 ; c1cc(-c2ccc3c(c2)c2ccccc2n3-c2ccc3c(c2)C2(c4ccccc4-3)c3ccccc3-c3ccc(-n4c5ccccc5c5cc(-c6cccc(-c7cc8c(c9ccccc79)CC8)c6)ccc54)cc32)cc(-c2cc3c(c4ccccc24)CC3)c1 ; CC1Cc2ccc(-c3cccc(-c4ccc5c(c4)c4ccccc4n5-c4ccc5c(c4)C4(c6ccccc6-5)c5ccccc5-c5ccc(-n6c7ccccc7c7cc(-c8cccc(-c9ccc%10c(c9)C(C)C%10)c8)ccc76)cc54)c3)cc21]

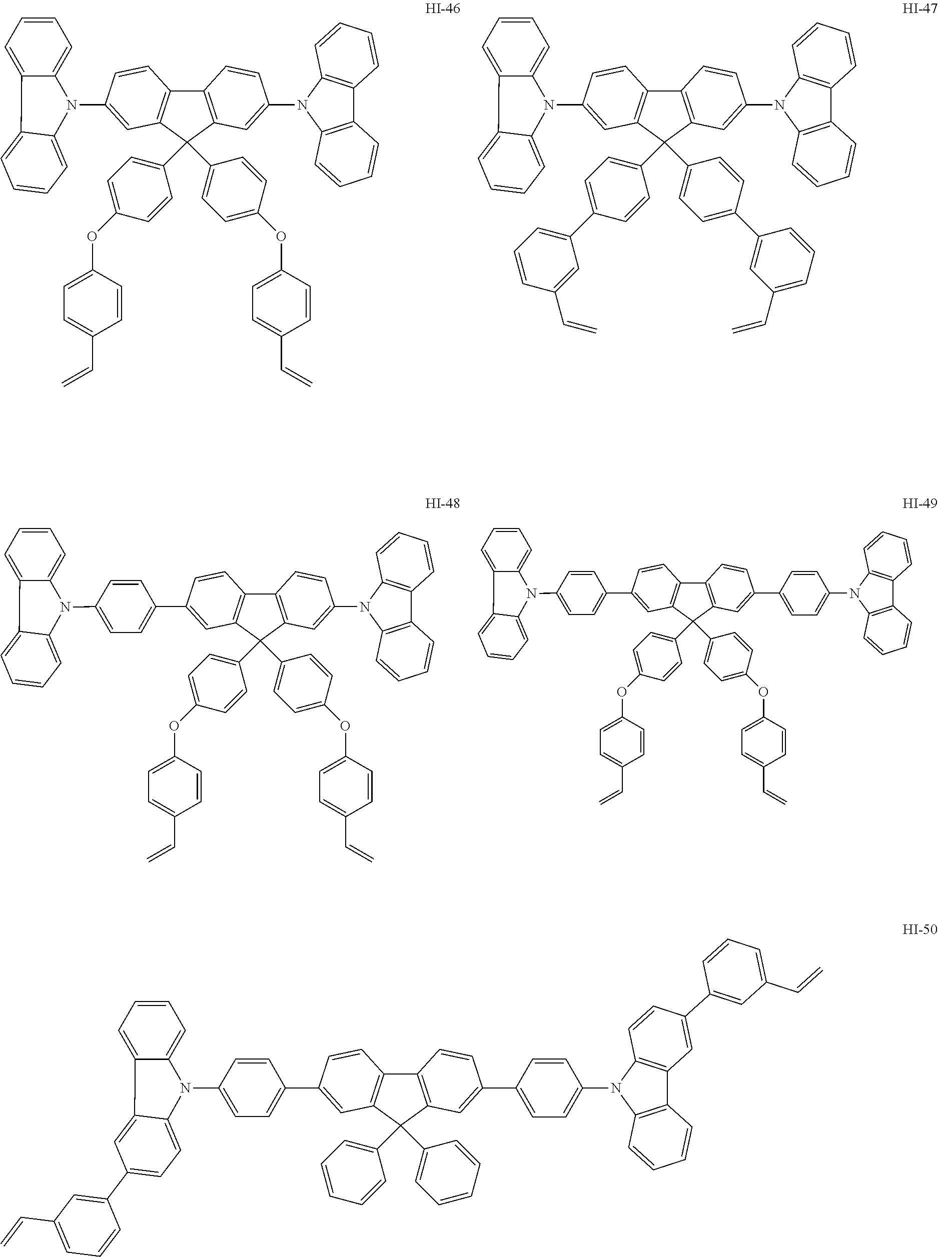

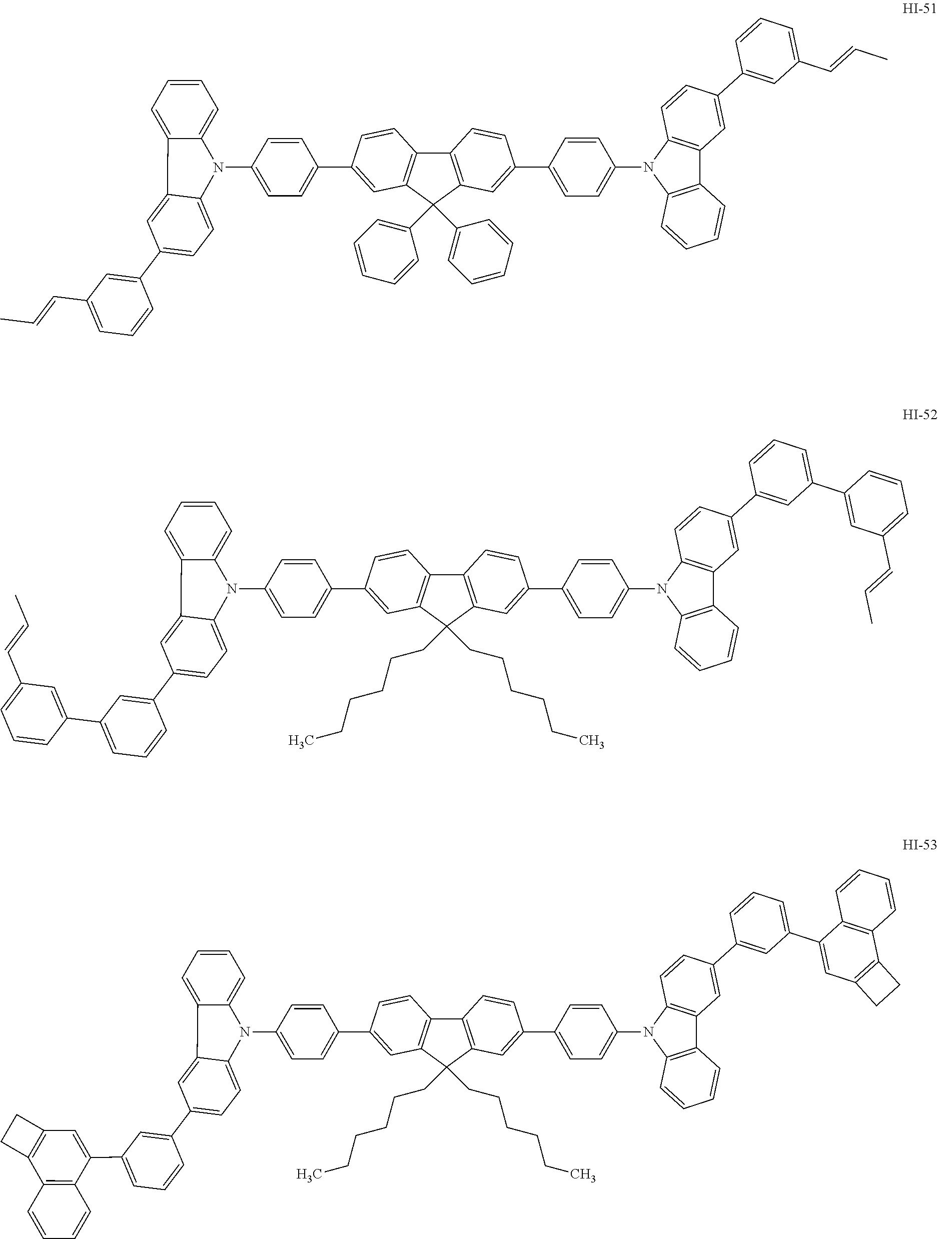 [SMILES: C/C=C/c1cccc(-c2ccc3c(c2)c2ccccc2n3-c2ccc(-c3ccc4c(c3)C(c3ccccc3)(c3ccccc3)c3cc(-c5ccc(-n6c7ccccc7c7cc(-c8cccc(/C=C/C)c8)ccc76)cc5)ccc3-4)cc2)c1 ; C/C=C/c1cccc(-c2cccc(-c3ccc4c(c3)c3ccccc3n4-c3ccc(-c4ccc5c(c4)C(CCCCCC)(CCCCCC)c4cc(-c6ccc(-n7c8ccccc8c8cc(-c9cccc(-c%10cccc(/C=C/C)c%10)c9)ccc87)cc6)ccc4-5)cc3)c2)c1 ; CCCCCCC1(CCCCCC)c2cc(-c3ccc(-n4c5ccccc5c5cc(-c6cccc(-c7cc8c(c9ccccc79)CC8)c6)ccc54)cc3)ccc2-c2ccc(-c3ccc(-n4c5ccccc5c5cc(-c6cccc(-c7cc8c(c9ccccc79)CC8)c6)ccc54)cc3)cc21]

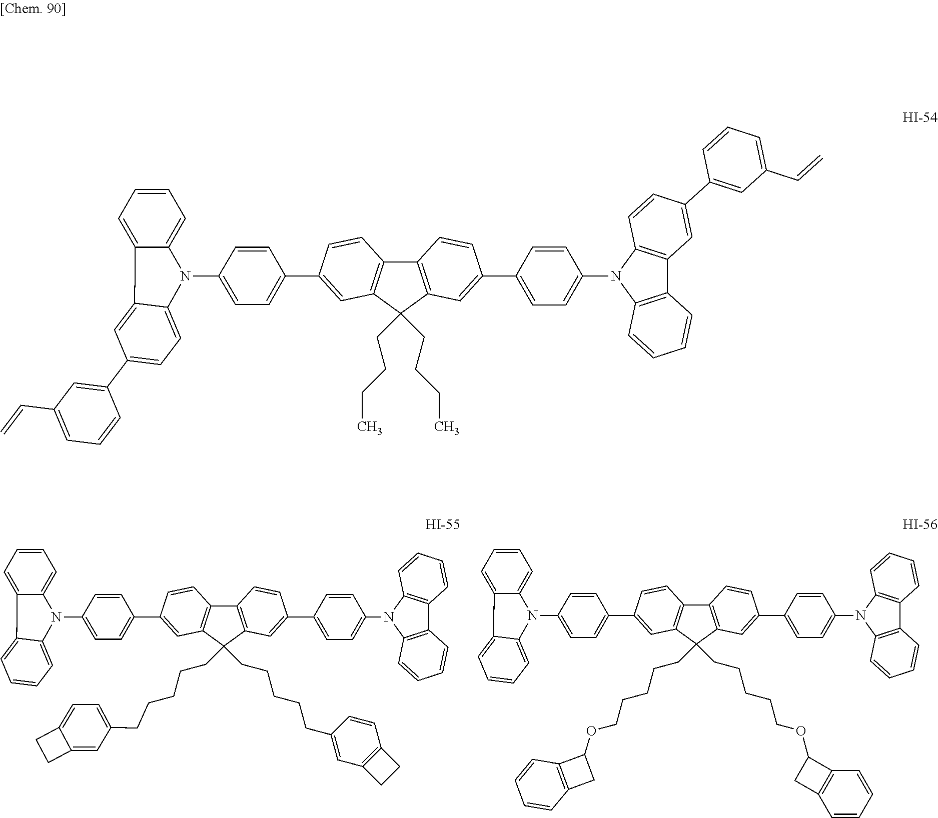

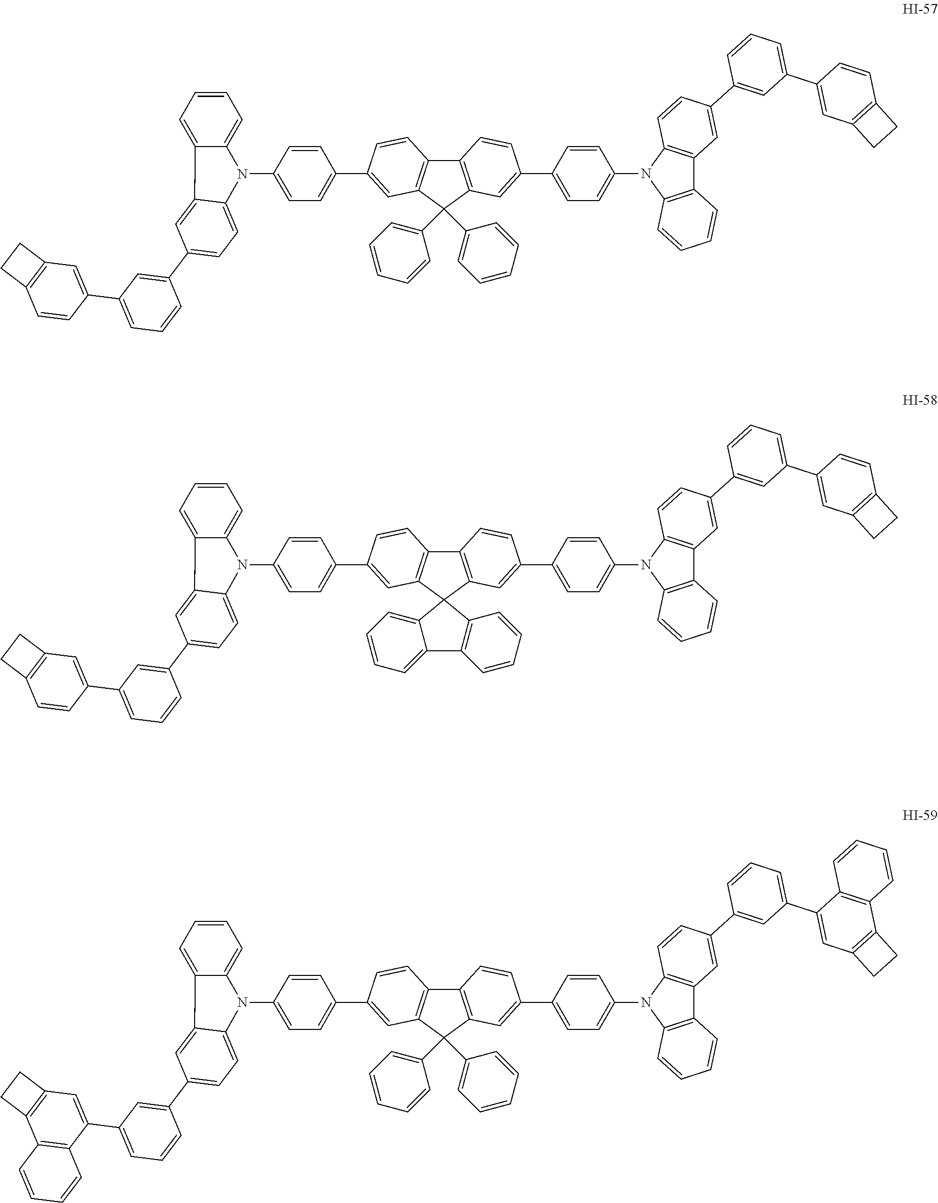

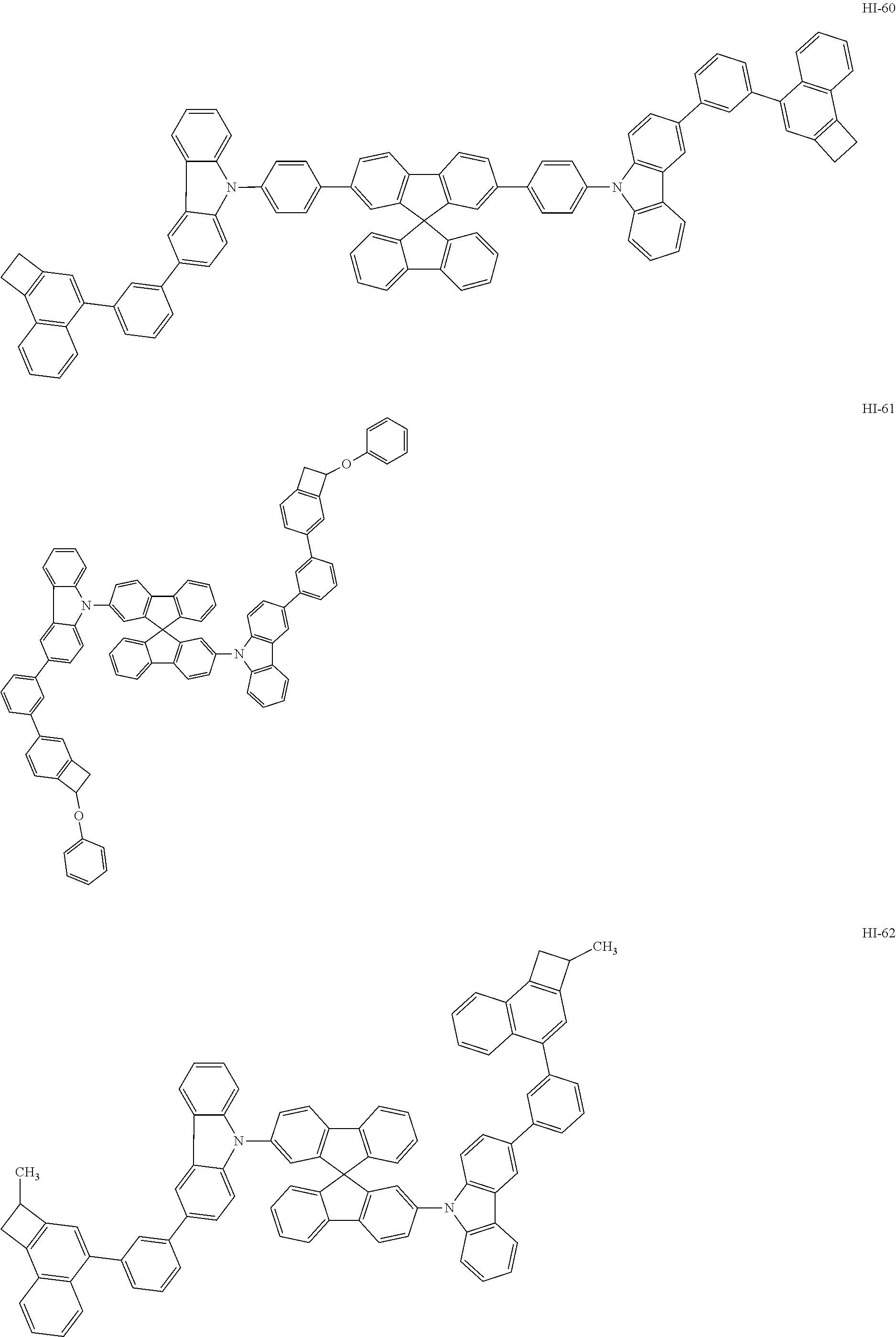

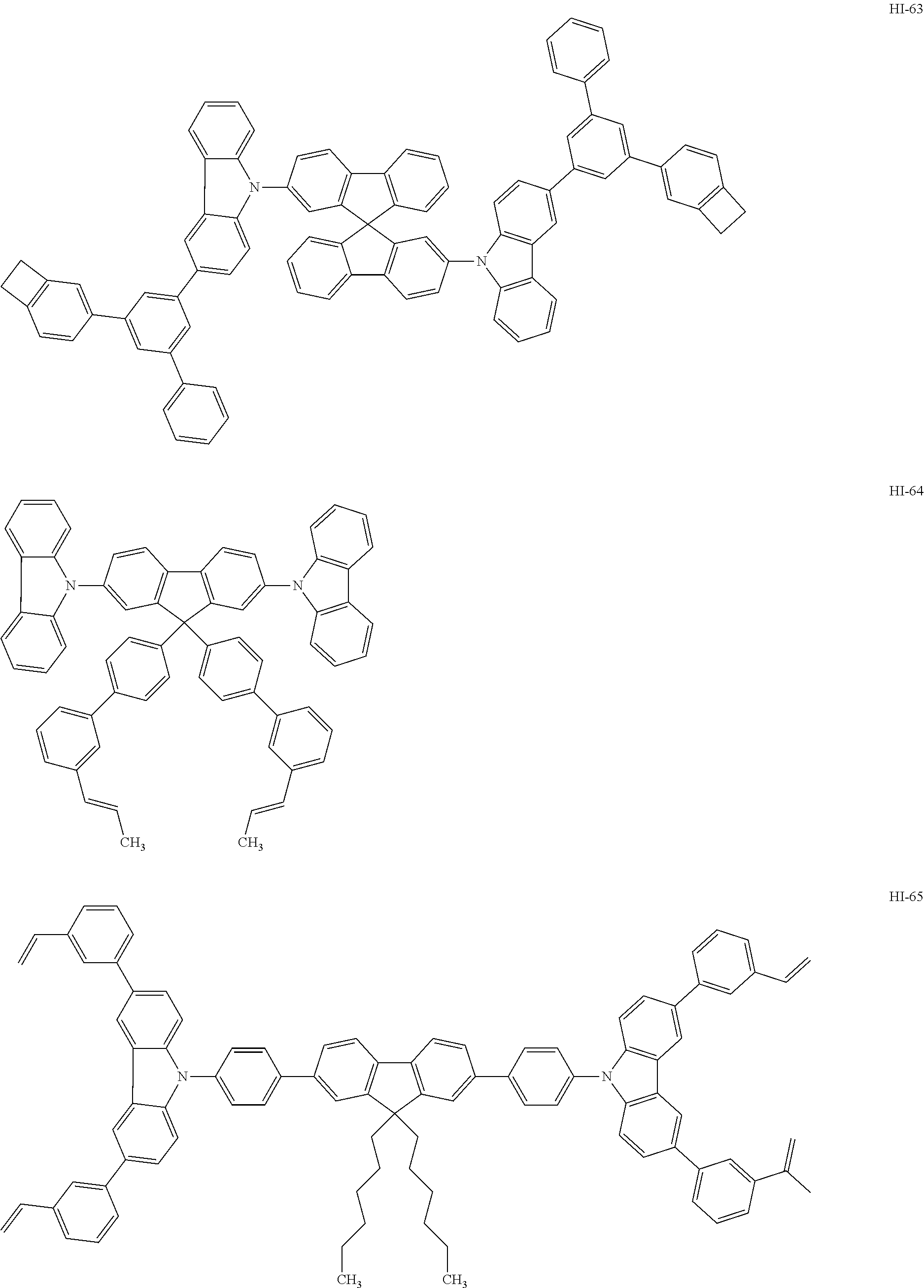 [SMILES: c1ccc(-c2cc(-c3ccc4c(c3)CC4)cc(-c3ccc4c(c3)c3ccccc3n4-c3ccc4c(c3)C3(c5ccccc5-4)c4ccccc4-c4ccc(-n5c6ccccc6c6cc(-c7cc(-c8ccccc8)cc(-c8ccc9c(c8)CC9)c7)ccc65)cc43)c2)cc1 ; C/C=C/c1cccc(-c2ccc(C3(c4ccc(-c5cccc(/C=C/C)c5)cc4)c4cc(-n5c6ccccc6c6ccccc65)ccc4-c4ccc(-n5c6ccccc6c6ccccc65)cc43)cc2)c1 ; C=Cc1cccc(-c2ccc3c(c2)c2cc(-c4cccc(C=C)c4)ccc2n3-c2ccc(-c3ccc4c(c3)C(CCCCCC)(CCCCCC)c3cc(-c5ccc(-n6c7ccc(-c8cccc(C=C)c8)cc7c7cc(-c8cccc(C(=C)C)c8)ccc76)cc5)ccc3-4)cc2)c1]

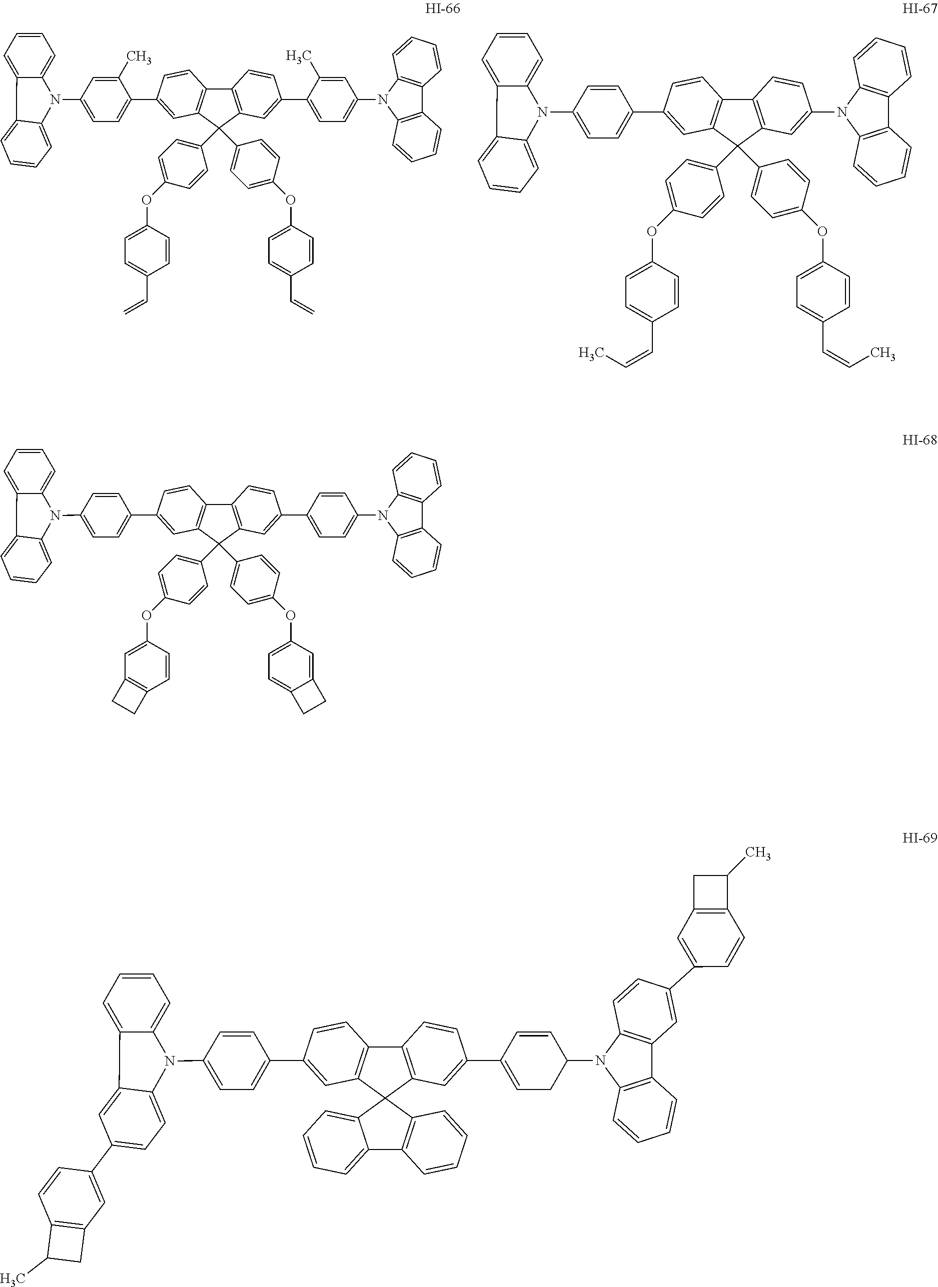

### [Low-Molecular Weight Compound (72)]

The low-molecular weight compound (72) is a compound represented by the following formula (72) and is contained as a charge transport material in the composition of the invention.

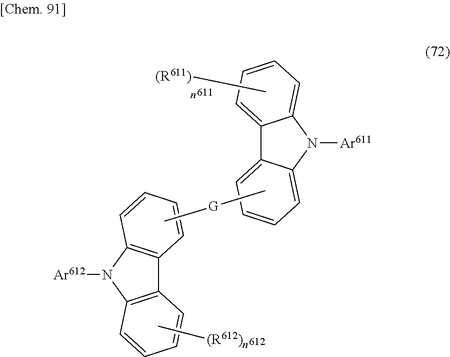

(In formula (72),

Ar⁶¹¹ and Ar⁶¹² each independently represent a divalent aromatic hydrocarbon group having 6 to 50 carbon atoms and optionally having a substituent and/or a crosslinking group.

R⁶¹¹ and R⁶¹² are each independently a deuterium atom, a halogen atom, a monovalent aromatic hydrocarbon group having 6 to 50 carbon atoms and optionally having a substituent and/or a crosslinking group, or a crosslinking group.

G represents a single bond or a divalent aromatic hydrocarbon group having 6 to 50 carbon atoms and optionally having a substituent and/or a crosslinking group.

The compound represented by formula (72) has at least two crosslinking groups.

n⁶¹¹ and n⁶¹² are each independently an integer of 0 to 4.)

(Ar⁶¹¹ and Ar⁶¹²)

Ar⁶¹¹ and Ar⁶¹² each independently represent a divalent aromatic hydrocarbon group having 6 to 50 carbon atoms and optionally having a substituent and/or a crosslinking group.

The number of carbon atoms in the aromatic hydrocarbon group is preferably 6 to 50, more preferably 6 to 30, and still more preferably 6 to 18. Specific examples of the aromatic hydrocarbon group include: monovalent groups each including an aromatic hydrocarbon structure having generally 6 or more carbon atoms and having generally 30 or less carbon atoms, preferably 18 or less carbon atoms, and still more preferably 14 or less carbon atoms such as a benzene ring, a naphthalene ring, an anthracene ring, a tetraphenylene ring, a phenanthrene ring, a chrysene ring, a pyrene ring, a benzanthracene ring, and a perylene ring; and monovalent groups in which a plurality of structures selected from the above structures are bonded together in a linear or branched manner. The structure including a plurality of aromatic hydrocarbon rings linked together is generally a structure including 2 to 8 aromatic hydrocarbon rings linked together and preferably a structure including 2 to 5 aromatic hydrocarbon rings linked together. When a plurality of aromatic hydrocarbon rings are linked together, the aromatic hydrocarbon rings linked together may have the same structure or different structures.

Ar⁶¹¹ and Ar⁶¹² are each independently preferably
a phenyl group,
a monovalent group in which one or a plurality of benzene rings and at least one naphthalene ring are bonded together in a linear or branched manner,
a monovalent group in which one or a plurality of benzene rings and at least one phenanthrene ring are bonded together in a linear or branched manner, or
a monovalent group in which one or a plurality of benzene rings and at least one tetraphenylene ring are bonded together in a linear or branched manner, and
more preferably a monovalent group in which one or a plurality of benzene rings are bonded together in a linear or branched manner. In all the cases, the rings may be bonded in any order.

As described above, the number of benzene, naphthalene, phenanthrene, and tetraphenylene rings bonded together is generally 2 to 8 and preferably 2 to 5. Particularly preferred are a monovalent structure in which 1 to 4 benzene rings are linked together, a monovalent structure in which 1 to 4 benzene rings and a naphthalene ring are linked together, a monovalent structure in which 1 to 4 benzene rings and a phenanthrene ring are linked together, and a monovalent structure in which 1 to 4 benzene rings and a tetraphenylene ring are linked together.

Each of these aromatic hydrocarbon groups may optionally have a substituent and/or a crosslinking group. The optional substituent on each aromatic hydrocarbon group is as described above. Specifically, each optional substituent can be selected from the substituent group Z and preferably from the substituent group X. Preferred substituents are the preferred substituents in the substituent group Z, particularly in the substituent group X. The optional crosslinking groups on the aromatic hydrocarbon groups are as described above. Specifically, each crosslinking group can be selected from the group T of crosslinking groups. Preferred crosslinking groups are the preferred crosslinking groups in the group T of crosslinking groups.

Ar⁶¹¹ and Ar⁶¹² are each independently preferably a phenyl group having a crosslinking group or a monovalent group that includes a plurality of benzene rings bonded together in a linear or branched manner and that has a crosslinking group because the stability of the film quality is high.

From the viewpoint of the solubility and durability of the compound, it is preferable that at least one of Ar⁶¹¹ and Ar⁶¹² has at least one partial structure selected from the following formulas (72-1) to (72-6).

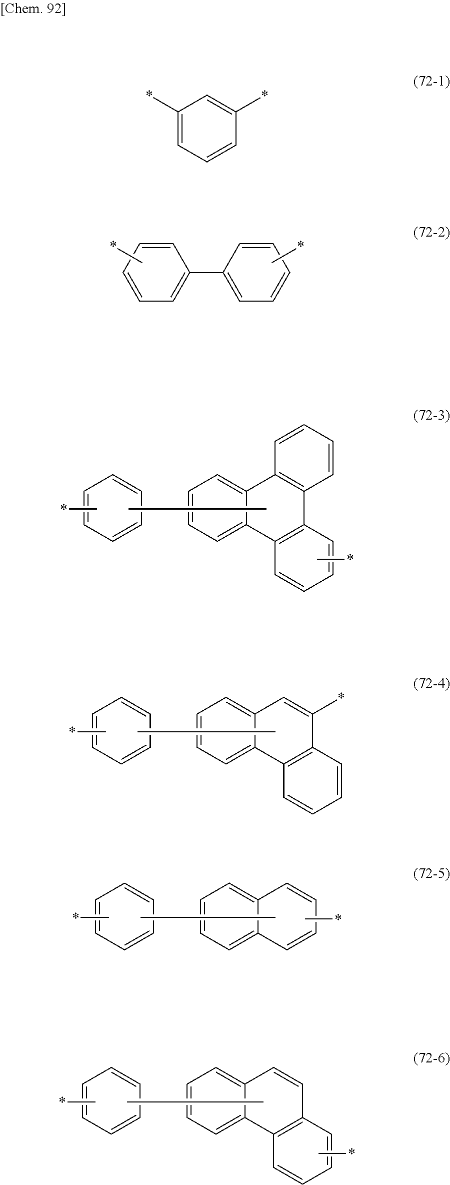

(In each of formulas (72-1) to (72-6) above, two *'s each represent a bond to an adjacent structure or a hydrogen atom, and at least one of the two *'s represents a position of bonding to an adjacent structure.)

In the following description, the definition of the * is the same unless otherwise specified.

More preferably, at least one of Ar⁶¹¹ and Ar⁶¹² has at least one partial structure selected from formulas (72-1) to (72-4).

Still more preferably, each of Ar⁶¹¹ and Ar⁶¹² has at least one partial structure selected from formulas (72-1) to (72-3).

Particularly preferably, each of Ar⁶¹¹ and Ar⁶¹² has at least one partial structure selected from formulas (72-1) to (72-2).

Formula (72-2) is preferably the following formula (72-2-2).

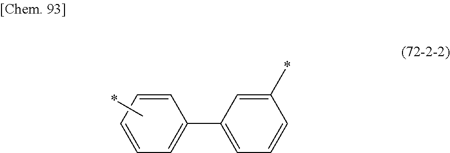

Formula (72-2) is still more preferably the following formula (72-2-3).

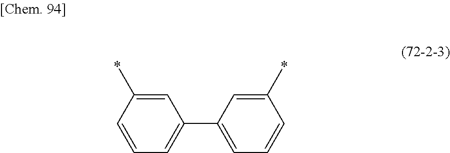 [SMILES: *c1cccc(-c2cccc(*)c2)c1]

From the viewpoint of the solubility and durability of the compound, a preferred partial structure included in at least one of Ar⁶¹¹ and Ar⁶¹² is a partial structure including a partial structure represented by formula (72-1) and a partial structure represented by formula (72-2).

(R⁶¹¹ and R⁶¹²)

R⁶¹¹ and R⁶¹² are each independently a deuterium atom, a halogen atom such as a fluorine atom, or a monovalent aromatic hydrocarbon having 6 to 30 carbon atoms and optionally having a substituent and/or a crosslinking group.

The aromatic hydrocarbon group is a monovalent group having an aromatic hydrocarbon structure having preferably 6 to 30 carbon atoms, more preferably 6 to 18 carbon atoms, and still more preferably 6 to 10 carbon atoms.

The aromatic hydrocarbon group may optionally have a substituent and/or a crosslinking group. The optional substituent on the aromatic hydrocarbon group is as described above. Specifically, the optional substituent can be selected from the substituent group Z and preferably from the substituent group X. Preferred substituents are the preferred substituents in the substituent group Z, particularly in the substituent group X. The optional crosslinking group on the aromatic hydrocarbon group is as described above. Specifically, the crosslinking group can be selected from the group T of crosslinking groups. Preferred crosslinking groups are the preferred crosslinking groups in the group T of crosslinking groups.

(n⁶¹¹ and n⁶¹²)

n⁶¹¹ and n⁶¹² are each independently an integer of 0 to 4. n⁶¹ and n⁶¹² are each independently preferably 0 to 2 and more preferably 0 or 1.

### (Substituents and Crosslinking Groups)

When Ar⁶¹¹, Ar⁶¹², R⁶¹¹, and R⁶¹² are each a monovalent or divalent aromatic hydrocarbon group, the optional substituent is preferably a substituent selected from the substituent group Z and particularly preferably from the substituent group X. The optional crosslinking group is preferably a crosslinking group selected from the group T of crosslinking groups. As for the positions of the crosslinking groups, it is preferable that Ar⁶¹¹ and a structure selected from Ar⁶¹¹ and R⁶¹¹ when n⁶¹¹ is 1 or more each have at least one crosslinking group and that Ar⁶¹² and a structure selected from Ar⁶¹² and R⁶¹² when n⁶¹² is 1 or more each have at least one crosslinking group, and it is more preferable that Ar⁶¹¹ and Ar⁶¹² each have at least one crosslinking group. The number of crosslinking groups included in the compound represented by formula (72) is preferably 2 or more and 4 or less, more preferably 2 or more and 3 or less, and most preferably 2.

### (G)

G represents a single bond or a divalent aromatic hydrocarbon group having 6 to 50 carbon atoms and optionally having a substituent and/or a crosslinking group.

The number of carbon atoms in the aromatic hydrocarbon group is preferably 6 to 50, more preferably 6 to 30, and still more preferably 6 to 18. Specific examples of the aromatic hydrocarbon group include: divalent groups each having an aromatic hydrocarbon structure having generally 6 or more carbon atoms and having generally 30 or less carbon atoms, preferably 18 or less carbon atoms, and still more preferably 14 or less carbon atoms such as a benzene ring, a naphthalene ring, an anthracene ring, a tetraphenylene ring, a phenanthrene ring, a chrysene ring, a pyrene ring, a benzanthracene ring, and a perylene ring; and divalent groups in which a plurality of structures selected from the above structures are bonded together in a linear or branched manner. The structure including a plurality of aromatic hydrocarbon rings linked together is generally a structure including 2 to 8 aromatic hydrocarbon rings linked together and preferably a structure including 2 to 5 aromatic hydrocarbon rings linked together. When a plurality of aromatic hydrocarbon rings are linked together, the plurality of aromatic hydrocarbon rings may have the same structure or different structures.

G is preferably
a single bond,
a phenylene group,
a divalent group in which a plurality of benzene rings are bonded together in a linear or branched manner,
a divalent group in which one or a plurality of benzene rings and at least one naphthalene ring are bonded together in a linear or branched manner,
a divalent group in which one or a plurality of benzene rings and at least one phenanthrene ring are bonded together in a linear or branched manner, or
a divalent group in which one or a plurality of benzene rings and at least one tetraphenylene ring are bonded together in a linear or branched manner, and
more preferably a divalent group in which a plurality of benzene rings are bonded together in a linear or branched manner. In all the cases, the rings may be bonded in any order.

As described above, the number of benzene, naphthalene, phenanthrene, and tetraphenylene rings bonded together is generally 2 to 8 and preferably 2 to 5. Particularly preferred are a divalent structure in which 1 to 4 benzene rings are linked together, a divalent structure in which 1 to 4 benzene rings and a naphthalene ring are linked together, a divalent structure in which 1 to 4 benzene rings and a phenanthrene ring are linked together, and a divalent structure in which 1 to 4 benzene rings and a tetraphenylene ring are linked together.

Each of these aromatic hydrocarbon groups may optionally have a substituent and/or a crosslinking group. The optional substituent on each aromatic hydrocarbon group is as described above. Specifically, the optional substituent can be selected from the substituent group Z and preferably from the substituent group X. Preferred substituents are the preferred substituents in the substituent group Z, particularly in the substituent group X. The optional crosslinking group on each aromatic hydrocarbon group is as described above. Specifically, the crosslinking group can be selected from the group T of crosslinking groups. Preferred crosslinking groups are the preferred crosslinking groups in the group T of crosslinking groups.

G is preferably a single bond because the stability and transportability during charge transport are good and the performance of the element is improved.

### (Specific Examples of Low-Molecular Weight Compound (72))

Preferred specific examples of the low-molecular weight compound (72) are shown below. However, the invention is not limited thereto.

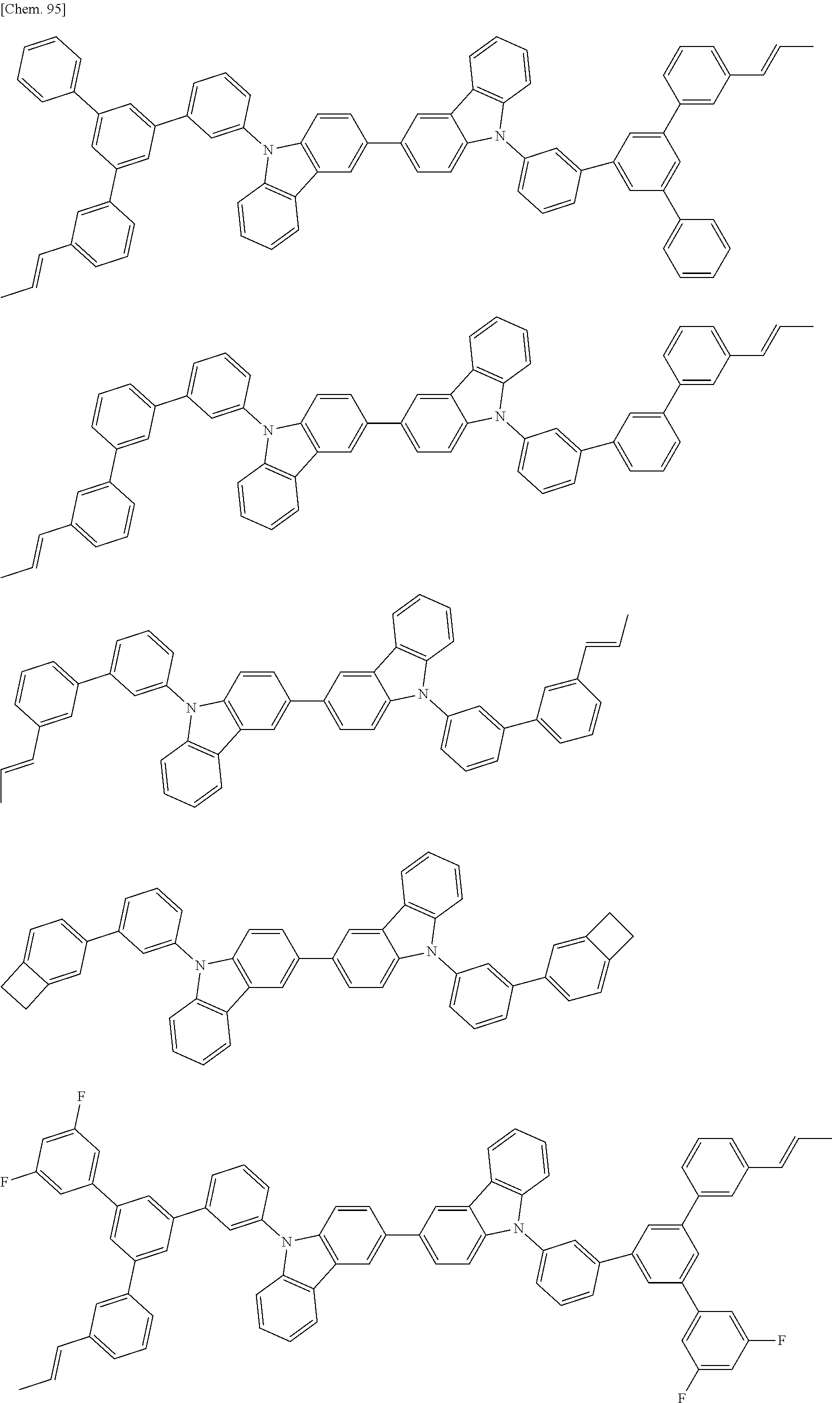

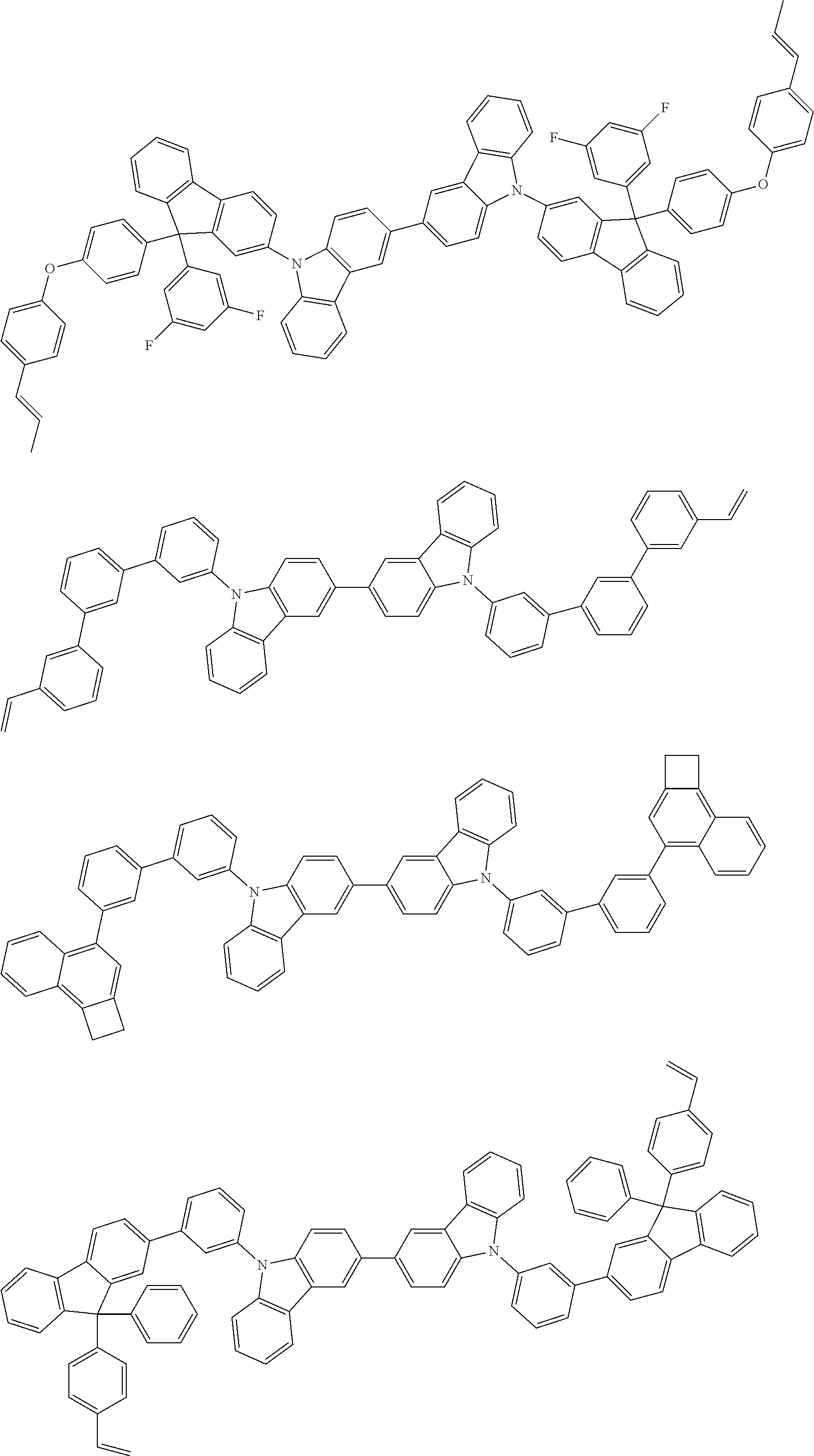

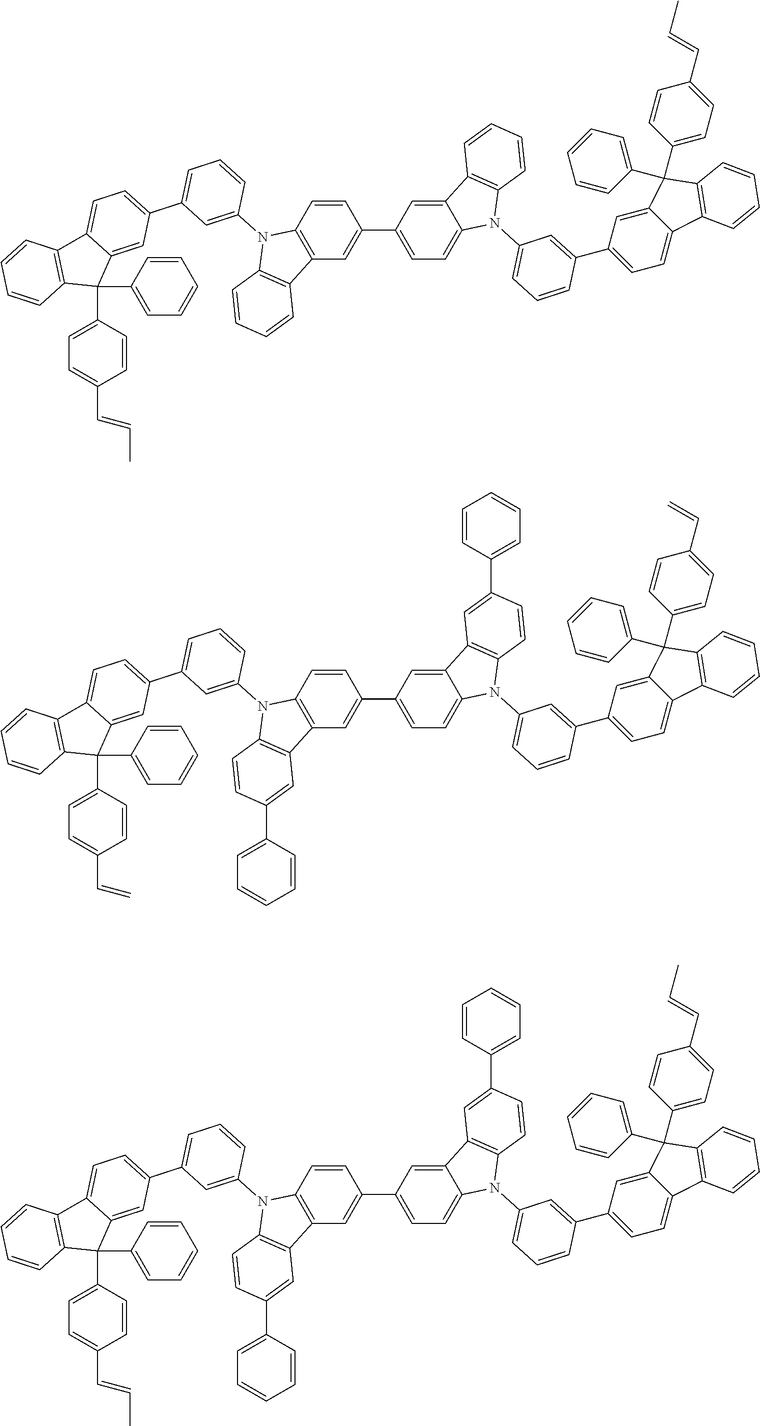

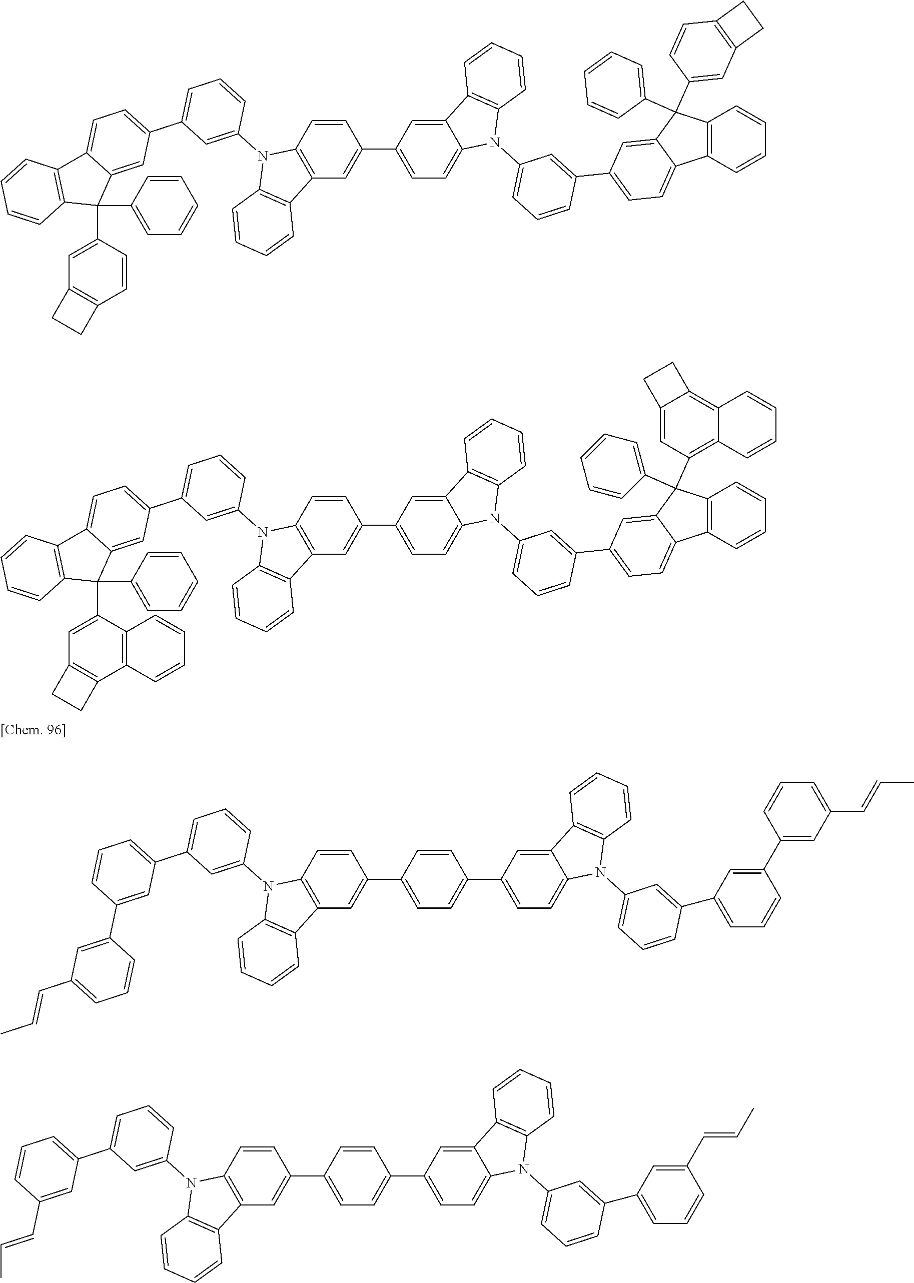

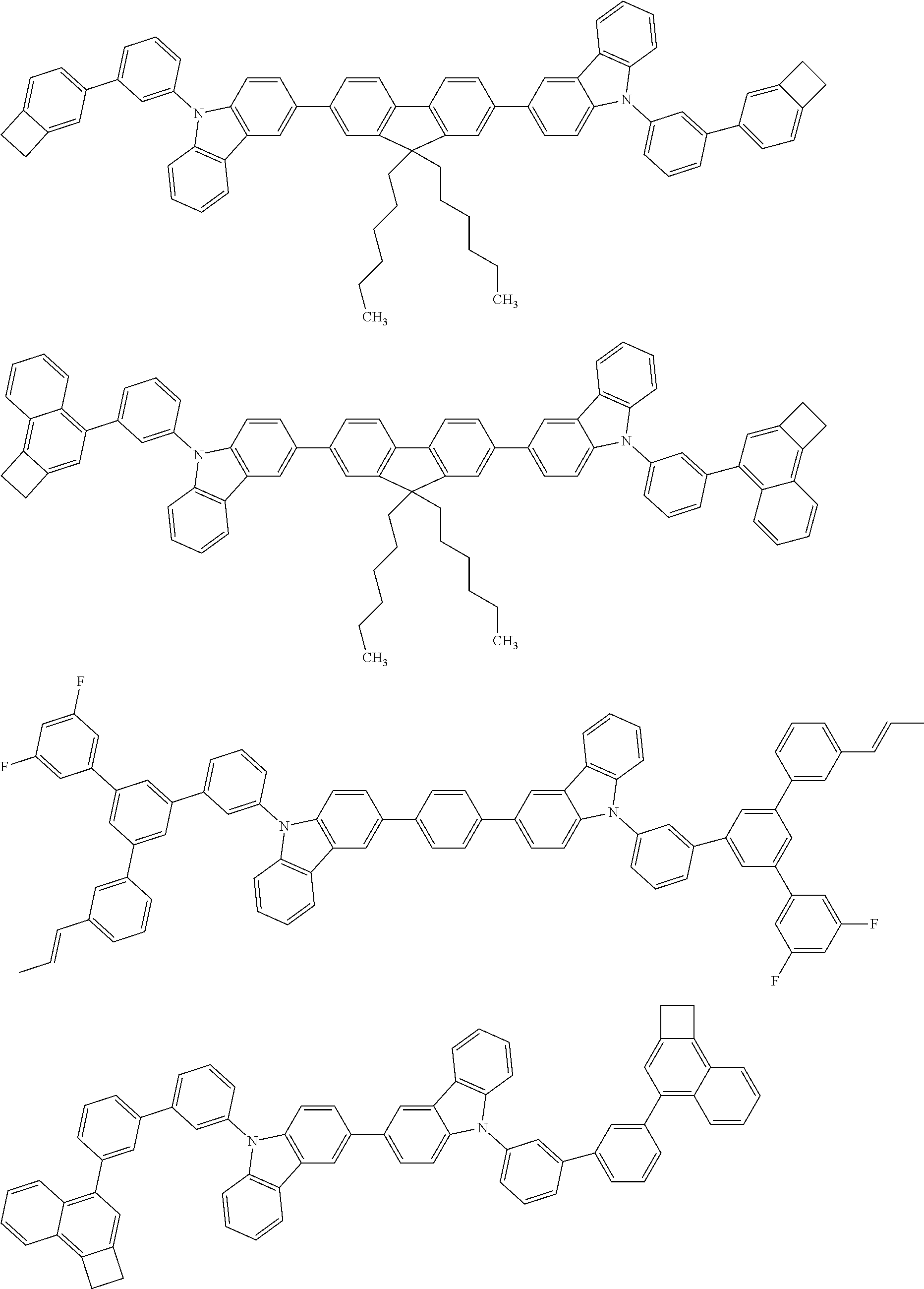

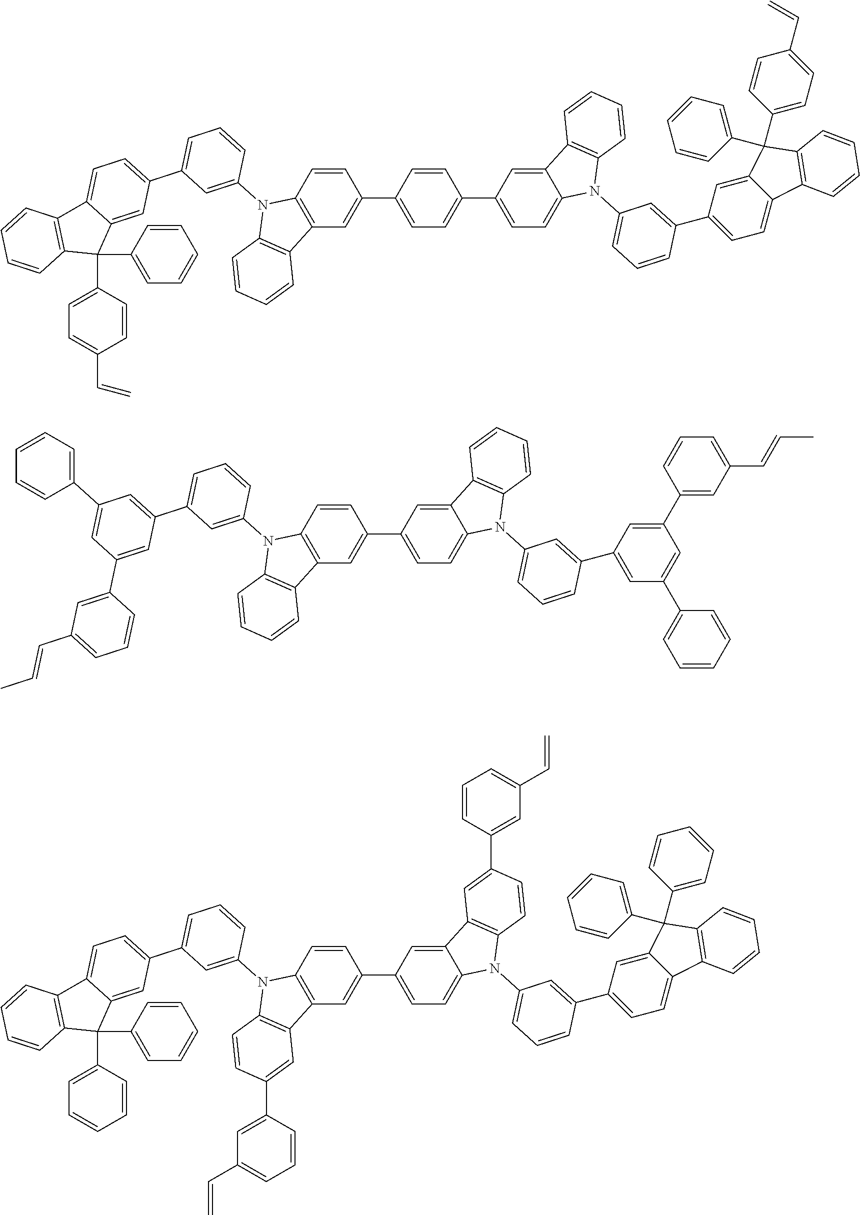

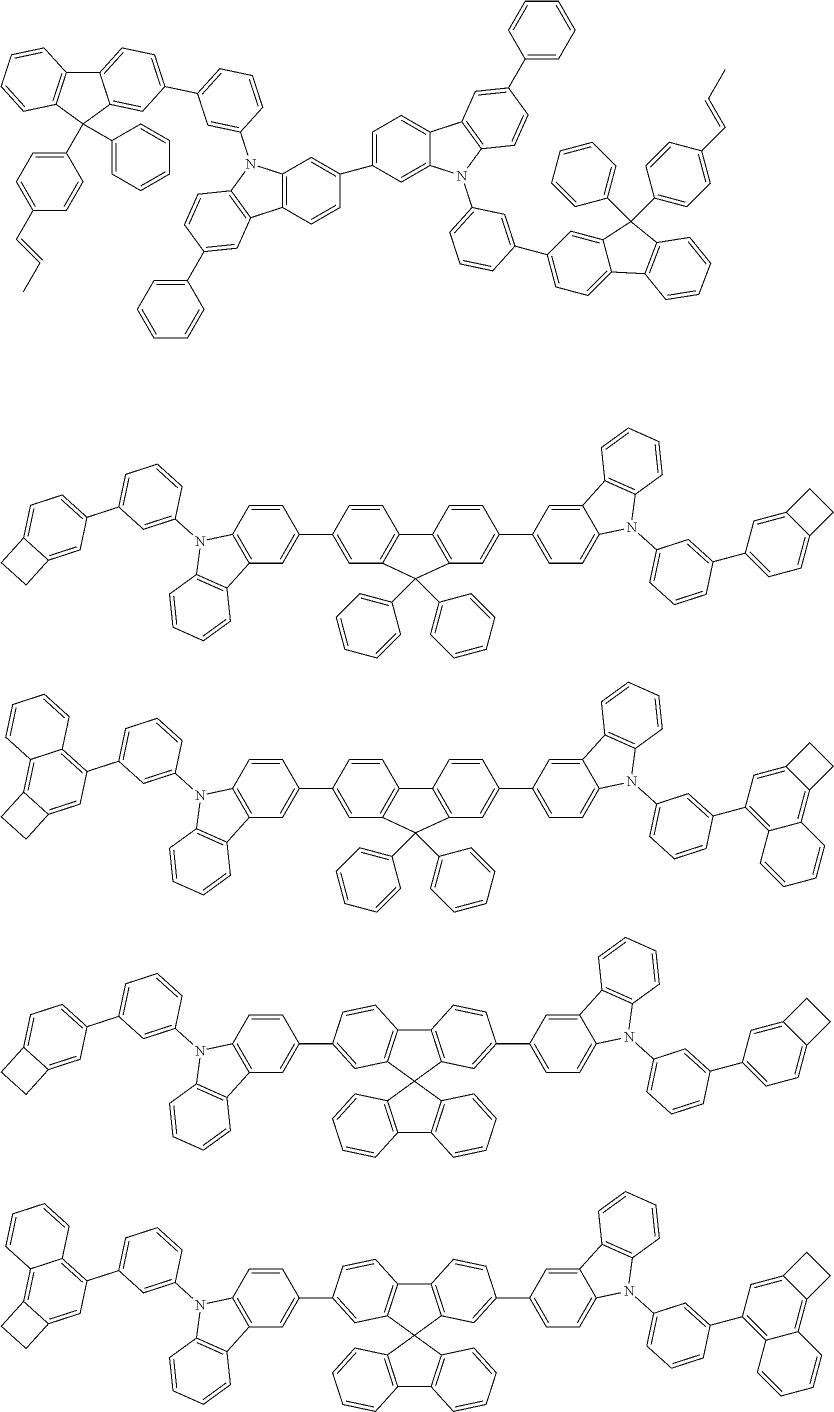

### [Low-Molecular Weight Compound (73)]

The low-molecular weight compound (73) is a compound represented by the following formula (73) and is contained as an electron transport material in the composition of the invention.

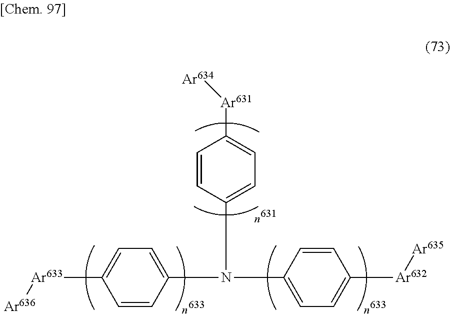

(In formula (73),

Ar⁶³¹, Ar⁶³², and Ar⁶³³ are each independently a direct bond or an aromatic hydrocarbon group having 6 to 30 carbon atoms optionally having a monovalent substituent.

Ar⁶³⁴, Ar⁶³⁵, and Ar⁶³⁶ are each independently a monovalent aromatic hydrocarbon group having 6 to 30 carbon atoms or a monovalent aromatic heterocyclic group having 3 to 24 carbon atoms, and each of these groups may optionally have a substituent or a crosslinking group.

At least two of Ar⁶³⁴, Ar⁶³⁵, and Ar⁶³⁶ each have a crosslinking group.

n⁶³¹, n⁶³², and n⁶³³ each independently represent an integer of 0 to 3.

The optional crosslinking groups on Ar⁶³⁴, Ar⁶³⁵, and Ar⁶³⁶ are each independently the following formula (a) or (b).)

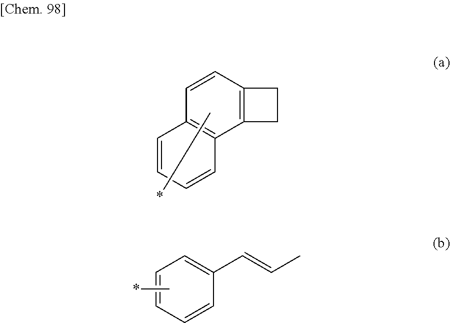

(In formulas (a) and (b), * represents a position of bonding to Ar⁶³⁴, Ar⁶³⁵, or Ar⁶³⁶.)
(Ar⁶³¹, Ar⁶³², and Ar⁶³³)

Ar⁶³¹, Ar⁶³², and Ar⁶³³ are each independently a direct bond or a divalent aromatic hydrocarbon group optionally having a substituent having 6 to 30 carbon atoms. The number of carbon atoms in the aromatic hydrocarbon group is preferably 6 to 50, more preferably 6 to 30, and still more preferably 6 to 18.

Specific examples of the aromatic hydrocarbon group include: divalent groups each having an aromatic hydrocarbon structure having generally 6 or more carbon atoms and having generally 30 or less carbon atoms, preferably 18 or less carbon atoms, and still more preferably 14 or less carbon atoms such as a benzene ring, a naphthalene ring, an anthracene ring, a tetraphenylene ring, a phenanthrene ring, a chrysene ring, a pyrene ring, a benzanthracene ring, and a perylene ring; and divalent groups in which a plurality of structures selected from the above structures are bonded together in a linear or branched manner. The structure including a plurality of aromatic hydrocarbon rings linked together is generally a structure including 2 to 5 aromatic hydrocarbon rings linked together and preferably a structure including 2 to 3 aromatic hydrocarbon rings linked together. When a plurality of aromatic hydrocarbon rings are linked together, the plurality of aromatic hydrocarbon rings may have the same structure or may have different structures.

Ar⁶³¹, Ar⁶³², and Ar⁶³³ are each independently preferably a phenylene group or a divalent group in which a plurality of benzene rings are bonded together in a linear or branched manner.

(Ar⁶³⁴, Ar⁶³⁵, and Ar⁶³⁶)

Ar⁶³⁴, Ar⁶³⁵, and Ar⁶³⁶ are each independently a monovalent aromatic hydrocarbon group having 6 to 30 carbon atoms or a monovalent aromatic heterocyclic group having 3 to 24 carbon atoms.

Specific examples of the monovalent aromatic hydrocarbon group include monovalent groups such as a benzene ring, a naphthalene ring, an anthracene ring, a phenanthrene ring, a fluorene ring, a perylene ring, a tetracene ring, a pyrene ring, a benzpyrene ring, a chrysene ring, a triphenylene ring, a fluoranthene ring, and an indenofluorene ring. The monovalent aromatic hydrocarbon group is more preferably a monovalent group such as a benzene ring, a naphthalene ring, a phenanthrene ring, a fluorene ring, or an indenofluorene ring, still more preferably a monovalent groups such as a benzene ring, a naphthalene ring, or a fluorene ring, and most preferably a monovalent group such as a benzene ring or a naphthalene ring.

Specific examples of the monovalent aromatic heterocyclic group include monovalent groups such as a pyridine ring, a pyrimidine ring, a triazine ring, a quinoline ring, a quinazoline ring, a carbazole ring, a dibenzofuran ring, a dibenzothiophene ring, an indolocarbazole ring, and an indenocarbazole ring. The monovalent aromatic heterocyclic group is preferably a monovalent ring such as a carbazole ring, a dibenzofuran ring, a dibenzothiophene ring, an indolocarbazole ring, or an indenocarbazole ring or a monovalent group formed by directly bonding two or three groups selected form the above groups.

Each of these aromatic hydrocarbon and aromatic heterocyclic groups may optionally have a substituent. The optional substituent is as described above. Specifically, the optional substituent can be selected from the substituent group Z and preferably from the substituent group X. Preferred substituents are the preferred substituents in the substituent group Z, particularly in the substituent group X.

At least two of Ar⁶³⁴, Ar⁶³⁵, and Ar⁶³⁶ each have a crosslinking group. The crosslinking groups are bonded to the aromatic hydrocarbon and aromatic heterocyclic groups.

The crosslinking groups are the crosslinking groups represented by formula (a) or (b) above.

(n⁶³¹, n⁶³², and n⁶³³)

n⁶³¹, n⁶³², and n⁶³³ each independently represent an integer of 0 to 3. Preferably, at least one of n⁶³¹, n⁶³², and n⁶³³ is equal to or more than 1. Preferably, at least two of n⁶³¹, n⁶³², and n⁶³³ are equal to or more than 1. Still more preferably, n⁶³¹, n⁶³², and n⁶³³ are each independently 1 to 3. Particularly preferably, n⁶³¹, n⁶³², and n⁶³³ are each independently 1 or 2.

### [Low-Molecular Weight Compound (74)]

The low-molecular weight compound (74) is a compound represented by the following formula (74) and is contained as a charge transport material in the composition of the invention.

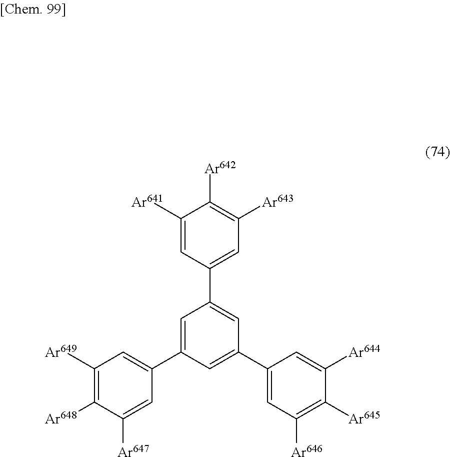

(In formula (74),

Ar⁶⁴¹ to Ar⁶⁴⁹ each independently represent a hydrogen atom, a benzene ring structure optionally having a substituent and/or a crosslinking group, or a structure in which 2 to 10 benzene ring structures each optionally having a substituent and/or a crosslinking group are linked together in a non-branched or branched manner.

The compound represented by formula (74) has at least two crosslinking groups.)

In formula (74), when Ar⁶⁴¹ to Ar⁶⁴⁹ are each a benzene ring structure optionally having a substituent and/or a crosslinking group or a structure in which 2 to 10 benzene ring structures each optionally having a substituent and/or a crosslinking group are linked together in a non-branched or branched manner, the optional substituent on each benzene ring is preferably an alkyl group.

### (Alkyl Group Serving as Substituent)

The alkyl group serving as a substituent is a linear, branched, or cyclic alkyl group having generally 1 or more and 12 or less carbon atoms, preferably 8 or less carbon atoms, more preferably 6 or less carbon atoms, and still more preferably 4 or less carbon atoms. Specific examples of the alkyl group include a methyl group, an ethyl group, a n-propyl group, an i-propyl group, a n-butyl group, an i-butyl group, a sec-butyl group, a tert-butyl group, a n-hexyl group, a cyclohexyl group, and a 2-ethylhexyl group.

### (Crosslinking Group)

The crosslinking groups are as described above. A specific structure of each crosslinking group can be selected from the group T of crosslinking groups. Preferred crosslinking groups are the preferred crosslinking groups in the group T of crosslinking groups.

In formula (74) above, it is preferable that at least one of Ar⁶⁴¹ to Ar⁶⁴⁹ is a structure represented by the following formula (74-2) or (74-3).

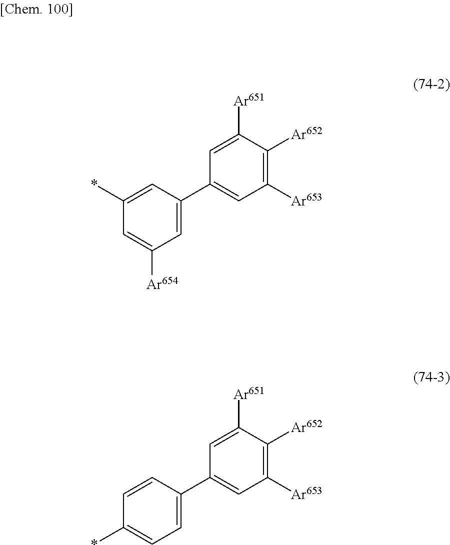

(In formulas (74-2) and (74-3), Ar⁶⁵¹ to Ar⁶⁵⁴ each independently represent a hydrogen atom, a benzene ring structure optionally having a substituent and/or a crosslinking group, or a structure in which 2 to 8 benzene ring structures each optionally having a substituent and/or a crosslinking group are linked together in a non-branched or branched manner.)

In formulas (74-2) and (74-3), when Ar⁶⁵¹ to Ar⁶⁵⁴ are each a benzene ring structure optionally having a substituent and/or a crosslinking group or a structure in which 2 to 8 benzene ring structures each optionally having a substituent and/or a crosslinking group are linked together in a non-branched or branched manner, the substituent on each benzene ring is preferably the above-described alkyl group serving as a substituent.

In formula (74) above, it is preferable that any one of Ar⁶⁴¹ to Ar⁶⁴³, any one of Ar⁶⁴⁴ to Ar⁶⁴⁶, and any one of Ar⁶⁴⁷ to Ar⁶⁴⁹ are each a structure represented by formula (74-2) or (74-3) above, and it is more preferable that Ar⁶⁴¹, Ar⁶⁴⁴, and Ar⁶⁴⁷ are each a structure represented by formula (74-2) or (74-3) above.

It is still more preferable that the structure represented by formula (74-2) above is a structure represented by formula (74-2-1), (74-2-2), (74-2-3), (74-2-4), or (74-2-5) below and that the structure represented by formula (74-3) above is a structure represented by formula (74-3-1), (74-3-2), (74-3-3), or (74-3-4) below. Each of these structures may be optionally substituted with the above-described alkyl group serving as a substituent. From the viewpoint of improving the solubility, it is preferable that each structure is substituted with an alkyl group. From the viewpoint of the charge transportability and the durability during driving of the element, it is preferable that each structure has no substituent.

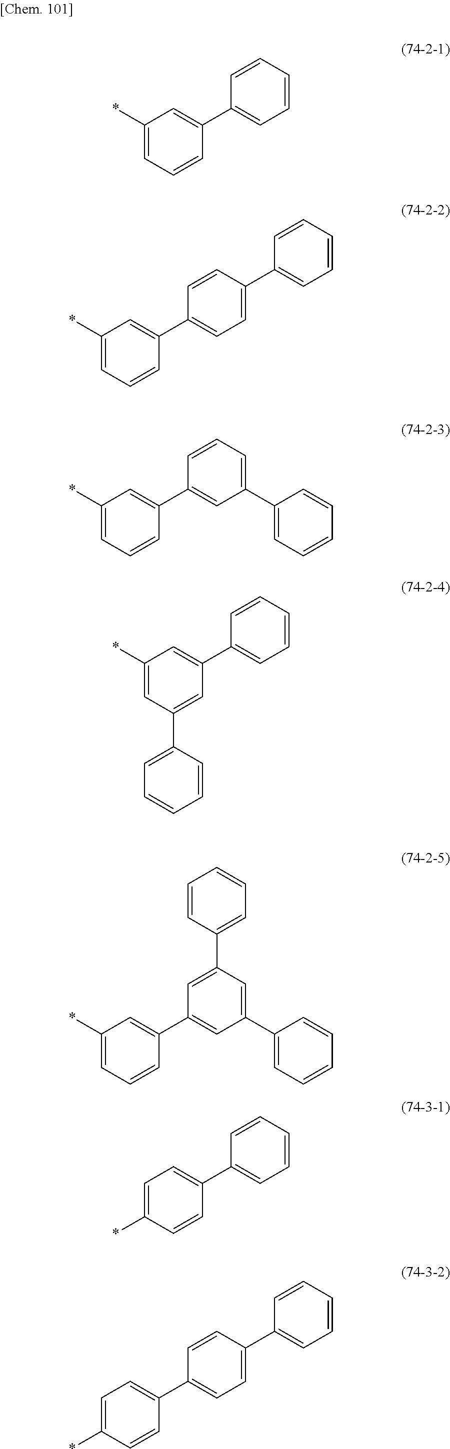

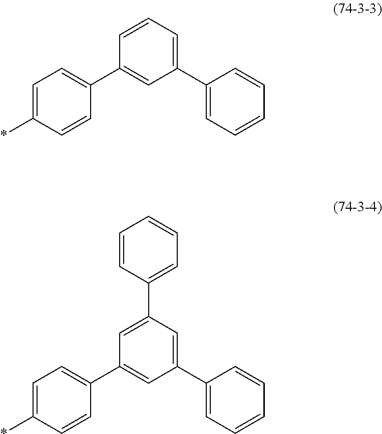 [SMILES: *c1ccc(-c2cccc(-c3ccccc3)c2)cc1 ; *c1ccc(-c2cc(-c3ccccc3)cc(-c3ccccc3)c2)cc1]

In particular, the structure represented by formula (74-2) above is preferably a structure represented by formula (74-2-1), (74-2-3), (74-2-4), or (74-2-5) above, and the structure represented by formula (74-3) above is more preferably a structure represented by formula (74-3-1) above. It is particularly preferable that the structure represented by formula (74-2-1) above or the structure represented by formula (74-3-3) is included as at least one of the structures represented by formulas (74-2) and (74-3) above.

### [Low-Molecular Weight Compound (75)]

The low-molecular weight compound (75) is a compound represented by the following formula (75) and is contained as a charge transport material in the composition of the invention.

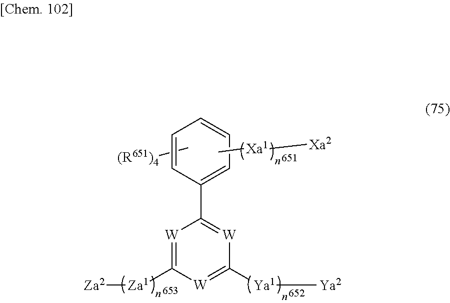

(In formula (75),

W's each independently represent CH or N, and at least one W is N.

Xa¹, Ya¹, and Za¹ each independently represent a divalent aromatic hydrocarbon group having 6 to 30 carbon atoms and optionally having a substituent or a divalent aromatic heterocyclic group having 3 to 30 carbon atoms and optionally having a substituent.

Xa², Ya², and Za² each independently represent a hydrogen atom, an aromatic hydrocarbon group having 6 to 30 carbon atoms and optionally having a substituent and/or a crosslinking group, an aromatic heterocyclic group having 3 to 30 carbon atoms and optionally having a substituent and/or a crosslinking group, or a crosslinking group.

n651, n652, and n653 each independently represent an integer of 0 to 6.

At least one of n651, n652, and n653 is an integer of 1 or more.

When n651 is 2 or more, a plurality of Xa¹'s present may be the same or different.

When n652 is 2 or more, a plurality of Ya¹'s present may be the same or different.

When n653 is 2 or more, a plurality of Za¹'s present may be the same or different.

At least two of Xa², Ya², and Za² each have a crosslinking group.

Each of four R⁶⁵¹'s represents a hydrogen atom or a substituent, and the four R⁶⁵¹'s may be the same or different.

When n651, n652, or n653 is 0, the corresponding one of Xa², Ya², and Za² is not a hydrogen atom.)

### (W)

In formula (75) above, each W represents CH or N, and at least one W is N. From the viewpoint of electron transportability and electron durability, it is preferable that at least two W's are each N, and it is more preferable that all W's are each N.

(Xa¹, Ya¹, Za¹, Xa², Ya², and Za²)

In formula (75) above, when Xa¹, Ya¹, and Za¹ are each a divalent aromatic hydrocarbon group having 6 to 30 carbon atoms and optionally having a substituent and when Xa², Ya², and Za² are each an aromatic hydrocarbon group having 6 to 30 carbon atoms and optionally having a substituent and/or a crosslinking group, the aromatic hydrocarbon ring in each aromatic hydrocarbon group having 6 to 30 carbon atoms is preferably a 6-membered monocycle or a condensed ring including 2 to 5 rings. Specific examples include a benzene ring, a naphthalene ring, an anthracene ring, a phenanthrene ring, a fluorene ring, a perylene ring, a tetracene ring, a pyrene ring, a benzpyrene ring, a chrysene ring, a triphenylene ring, a fluoranthene ring, and an indenofluorene ring. Of these, a benzene ring, a naphthalene ring, an anthracene ring, a phenanthrene ring, and a fluorene ring are preferred. A benzene ring, a naphthalene ring, a phenanthrene ring, and a fluorene ring are more preferred, and a benzene ring, a naphthalene ring, and a fluorene ring are still more preferred.

In formula (75) above, when Xa¹, Ya¹, and Za¹ are each a divalent aromatic heterocyclic group having 3 to 30 carbon atoms and optionally having a substituent and when Xa², Ya², and Za² are each an aromatic heterocyclic group having 3 to 30 carbon atoms and optionally having a substituent and/or a crosslinking group, the aromatic heterocycle in each aromatic heterocyclic group having 3 to 30 carbon atoms is preferably a 5- or 6-membered monocycle or a condensed ring including 2 to 5 rings. Specific examples include a furan ring, a benzofuran ring, a dibenzofuran ring, a thiophene ring, a benzothiophene ring, a dibenzothiophene ring, a pyrrole ring, a pyrazole ring, an imidazole ring, an oxadiazole ring, an indole ring, a carbazole ring, an indolocarbazole ring, an indenocarbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a perimidine ring, a quinazoline ring, and a quinazolinone ring. Of these, a thiophene ring, a pyrrole ring, an imidazole ring, a pyridine ring, a pyrimidine ring, a triazine ring, a quinoline ring, a quinazoline ring, a carbazole ring, a dibenzofuran ring, a dibenzothiophene ring, an indolocarbazole ring, a phenanthroline ring, and an indenocarbazole ring are preferred. A pyridine ring, a pyrimidine ring, a triazine ring, a quinoline ring, quinazoline ring, a carbazole ring, a dibenzofuran ring, and a dibenzothiophene ring are more preferred, and a carbazole ring, a dibenzofuran ring, and a dibenzothiophene ring are still more preferred.

In formula (75) above, the aromatic hydrocarbon ring in each of Xa¹, Ya¹, Za¹, Xa², Ya², and Za² is particularly preferably a benzene ring, a naphthalene ring, or a phenanthrene ring, and the aromatic heterocycle is particularly preferably a carbazole ring, a dibenzofuran ring, or a dibenzothiophene ring.

Each of these aromatic hydrocarbon and aromatic heterocyclic groups may optionally have a substituent. The optional substituent is as described above. Specifically, the optional substituent can be selected from the substituent group Z and preferably from the substituent group X. Preferred substituents are the preferred substituents in the substituent group Z, particularly in the substituent group X.

### (Crosslinking Groups)

The compound represented by formula (75) has at least two crosslinking groups. Specifically, at least two of Xa², Ya², and Za² each have a crosslinking group. The phrase “Xa², Ya², or Za² has a crosslinking group” means that Xa², Ya², or Za² is a crosslinking group, or Xa², Ya², or Za² is an aromatic hydrocarbon group having a crosslinking group or an aromatic heterocyclic group having a crosslinking group. The crosslinking group is as described above. Specifically, the crosslinking group can be selected from the group T of crosslinking groups. Preferred crosslinking groups are the preferred crosslinking groups in the group T of crosslinking groups.

(n651, n652, and n653)

n651, n652, and n653 each independently represent an integer of 0 to 6, and at least one of n651, n652, and n653 is an integer of 1 or more. From the viewpoint of charge transportability and durability, it is preferable that n651 is equal to or more than 2 or at least one of n652 and n653 is equal to or more than 3.

From the viewpoint of charge transportability, durability, and solubility in an organic solvent, it is preferable that the compound represented by formula (75) has a total of 8 to 18 rings including the center ring having 3 W's.

### (R⁶⁵¹)

Each R⁶⁵¹ when it is a substituent is preferably an aromatic hydrocarbon group having 6 to 30 carbon atoms and optionally having a substituent or an aromatic heterocyclic group having 3 to 30 carbon atoms and optionally having a substituent. From the viewpoint of improving the durability and of charge transportability, R⁶⁵¹ is more preferably an aromatic hydrocarbon group optionally having a substituent. When the number of R⁶⁵¹'s each serving as a substituent is two or more, they may be different.

The optional substituent on the aromatic hydrocarbon group having 6 to 30 carbon atoms, the optional substituent on the aromatic heterocyclic group having 3 to 30 carbon atoms, and the optional substituent on R⁶⁵¹ can each be selected from the substituent group Z, particularly from the substituent group X.

### [Low-Molecular Weight Compound (1)]

The low-molecular weight compound (1) is a compound represented by the following formula (1) and is contained as a charge transport material in the composition of the invention.

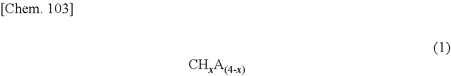

(In formula (1),

C represents a carbon atom, and H represents a hydrogen atom.

A's each independently represent a substituent represented by formula (2′) below.

x represents an integer of 0 to 2.)

[Chem. 104]

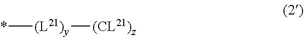

(In formula (2′),

L²¹'s each independently represent a bonding group optionally having a substituent.

CL²¹'s each independently represent a crosslinking group represented by formula (3) below.

* represents a direct bond to the carbon atom in formula (1).

y represents an integer of 1 to 6, and z represents an integer of 0 to 4.

When z is 0, a hydrogen atom instead of CL²¹ is bonded to a bonding group L²¹.

Three or more CL²¹'s are present in the compound represented by formula (1).)

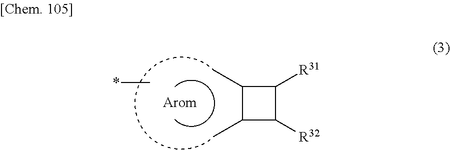

(In formula (3),

Arom represents an aromatic ring having 3 to 30 carbon atoms and optionally having a substituent.

R³¹ and R³² each independently represent a hydrogen atom or an alkyl group.

* represents a direct bond to L²¹ in formula (2′), and the direct bond to formula (2′) is bonded to Arom.)

When x in formula (1) is 2 and two L²¹'s, two CL²¹'s, two y's, and two z's are present, the two L²¹'s and the two CL²¹'s may be the same or different, and the two y's and the two z's may be the same number or different numbers.

### (L²¹)

Each bonding group L²¹ in substituent (2′) is preferably a chalcogen atom, an alkylene group, or a divalent aromatic group.

The aromatic group is an aromatic hydrocarbon group, an aromatic heterocyclic group, or a structure in which a plurality of rings selected from these groups are linked together. The structure including a plurality of aromatic hydrocarbon groups or aromatic heterocyclic groups linked together is generally a structure including 2 to 10 groups linked together and preferably a structure including 2 to 5 groups linked together. When a plurality of groups selected from aromatic hydrocarbon groups and aromatic heterocyclic groups are linked together, groups having the same structure may be linked together, or groups having different structures may be linked together.

The structure in which a plurality of groups selected from aromatic hydrocarbon groups and aromatic heterocyclic groups are linked together is preferably a group derived from a phenylpyridine ring, a group derived from a diphenylpyridine ring, a group derived from a phenylcarbazole ring, or a group derived from a diphenylcarbazole ring.

The aromatic hydrocarbon group and the aromatic heterocyclic group are as described above in the “Definitions.”

Specific examples of the bonding group L²¹ include the following groups.

Examples of the chalcogen atom include an oxygen atom and a sulfur atom, and an oxygen atom is preferred.

The alkylene group is linear, branched, or cyclic, and the number of carbon atoms is 1 or more and preferably 4 or more and is 24 or less, preferably 12 or less, more preferably 8 or less, and still more preferably 6 or less. Specific examples include divalent groups derived from methane, ethane, propane, butane, isobutane, hexane, cyclohexane, and dodecane.

The aromatic group is an aromatic hydrocarbon group or an aromatic heterocyclic group and is preferably an aromatic hydrocarbon group. Specific examples include divalent groups derived from benzene, biphenyl, terphenyl, and fluorene. The aromatic group can have 1 to 4 CL²¹'s, preferably 1 to 2 CL²¹'s, on a terminal aromatic ring. In this case, the aromatic group can be regarded as a divalent to trivalent group.

### (CL²¹)

Each CL²¹ in formula (2′) is a crosslinking group represented by formula (3) above.

### (Arom)

Arom in formula (3) represents an aromatic ring having 3 to 30 carbon atoms and optionally having a substituent.

The aromatic ring having 3 to 30 carbon atoms is preferably a monocycle or condensed ring including the aromatic hydrocarbon ring described above or a monocycle or condensed ring including the aromatic heterocycle described above. The aromatic ring is preferably an aromatic hydrocarbon ring and more preferably a benzene ring or a naphthalene ring.

(x and z)

x in formula (1) is an integer of 0 to 2, z in formula (2′) is an integer of 0 to 4. However, 3 or more CL²¹'s are present in the low-molecular weight compound (1). Since 3 or more CL²¹'s are present in the compound, a network structure is formed during a crosslinking reaction. In this case, the composition has high thermal stability, and a functional film and an organic electroluminescent element to be formed also have high thermal stability.

When x is 0 or 1, the following structures are preferred.

Specifically, when x is 0, it is preferable that one of the four z's is 0 and three z's are 1 or that all the z's are 1. When x is 1, it is preferable that all the three z's are 1.

When x is 2, one of the two z's is 2 and the other is 1 or that all the z's are 2.

In formula (2′), when z is 0, a hydrogen atom instead of CL²¹ is bonded to L²¹.

(y)

y in formula (2′) is an integer of 1 to 6. From the viewpoint of improving thermal properties, y is preferably an integer of 1 to 3.

(R³¹ and R³²)

R³¹ and R³² in formula (3) are each independently a hydrogen atom or an alkyl group.

The alkyl group is selected from the alkyl groups in the substituent group Z above and preferably in the substituent group X, and preferred alkyl groups are also the same as those for these alkyl groups.

From the viewpoint of reactivity, R³¹ and R³² are each preferably a hydrogen atom because steric hindrance decreases. From the viewpoint of improving the solubility to obtain a uniform composition, R³¹ and R³² are each preferably an alkyl group having 1 to 10 carbon atoms.

### [Low-Molecular Weight Compound (2)]

The low-molecular weight compound (2) is a compound represented by the following formula (2) and is contained as a charge transport material in the composition of the invention.

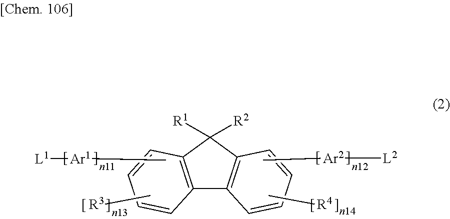

(In formula (2),

Ar¹ and Ar² each independently represent a divalent aromatic group having 6 to 60 carbon atoms and optionally having a substituent.

R¹, R², R³, and R⁴ each independently represent an alkyl group optionally having a substituent or an aromatic group optionally having a substituent.

R¹ and R², R³'s, or R⁴'s may be bonded together to form a ring.

L¹ and L² each independently represent a crosslinking group.

n11 and n12 each independently represent an integer of 0 to 5.

n13, and n14 each independently represent an integer of 0 to 3.)

(Ar¹ and Ar²)

Ar¹ and Ar² each independently represent a divalent aromatic group having 6 to 60 carbon atoms and optionally having a substituent.

Examples of the aromatic group include the divalent groups shown for the aromatic group in formula (1) above.

The aromatic hydrocarbon group and the aromatic heterocyclic group are as described above in the “Definitions.”

(R¹, R², R³, and R⁴)

R¹, R², R³, and R⁴ each independently represent an alkyl group optionally having a substituent or a monovalent aromatic group optionally having a substituent.

The aromatic group is as described above for formula (1).

The aromatic hydrocarbon group and the aromatic heterocyclic group are as described above in the “Definitions.”

Examples of the alkyl group include a methyl group, an ethyl group, branched and linear propyl groups, branched and linear butyl groups, branched and linear hexyl groups, branched and linear octyl groups, and branched and linear decyl groups. The alkyl group is preferably a branched or linear hexyl group or a branched or linear octyl group because the solubility is improved and the film properties are improved.

R¹ and R², R³'s, or R⁴'s may be bonded together to form a ring.

(L¹ and L²)

Specifically, each of the crosslinking groups represented by L¹ and L² can be selected from the group T of crosslinking groups. Preferred crosslinking groups are the preferred crosslinking groups in the group T of crosslinking groups.

### (Substituents)

Ar¹ and Ar² are each a divalent aromatic group having 6 to 60 carbon atoms and optionally having a substituent, and R¹, R², R³, and R⁴ are each an alkyl group optionally having a substituent or an aromatic group optionally having a substituent. The optional substituents on these groups are as described above. Specifically, each optional substituent can be selected from the substituent group Z and preferably from the substituent group X. Preferred substituents are the preferred substituents in the substituent group Z, particularly in the substituent group X.

(n11, n12, n13, and n14)

n11 and n12 each independently represent an integer of 0 to 5. n11 and n12 are each preferably 0 to 3 and more preferably 1 to 2.

n13 and n14 each independently represent an integer of 0 to 3. n13 and n14 are each preferably 0 to 2 and more preferably 0 to 1.

### [Electron Accepting Compound]

It is preferable that the composition of the invention contains an electron accepting compound in addition to the above-described high-molecular weight charge transport compound and the above-described low-molecular weight charge transport compound. It is preferable that the electron accepting compound has a fluorine atom and a crosslinking group in its molecular structure.

The electron accepting compound will be described.

The electron accepting compound is an electron accepting ionic compound including a tetraarylborate ion and a counter cation. Specific examples thereof include an electron accepting ionic compound represented by formula (81) below and including a counter anion that is a non-coordinating anion and a counter cation.

Formula (81) has, as the anion, a tetraarylborate ion represented by formula (82) described later. The electron accepting compound in the invention may be referred to as an electron accepting ionic compound.

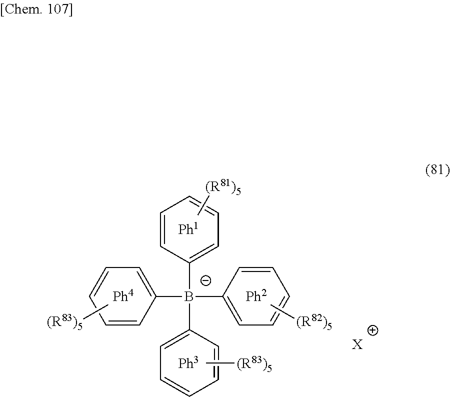

(In formula (81), five R⁸¹'s, five R⁸²'s, five R⁸³'s, five R⁸⁴'s are each independent, and R⁸¹'s to R⁸⁴'s each independently represent a hydrogen atom, a deuterium atom, a halogen atom, an aromatic hydrocarbon group having 6 to 50 carbon atoms and optionally having a substituent and/or a crosslinking group, an aromatic heterocyclic group having 3 to 50 carbon atoms and optionally having a substituent and/or a crosslinking group, a fluorine-substituted alkyl group having 1 to 12 carbon atoms, or a crosslinking group.

Ph¹, Ph², Ph³, are Ph⁴ are symbols representing four benzene rings.

X⁺ represents the counter cation.)

The halogen atoms in R⁸¹'s to R⁸⁴'s are each selected from an iodine atom, a boron atom, a chlorine atom, and a fluorine atom.

The electron accepting compound represented by formula (81) above includes preferably a crosslinking group and includes more preferably 2 or more crosslinking groups. Preferably, each crosslinking group is present in an anionic portion of the electron accepting compound represented by formula (81), i.e., in formula (82) that is a tetraarylborate ion described below.

### [Tetraarylborate Ion]

The mother skeleton of the electron accepting compound is preferably an ionic compound including a counter cation and a tetraarylborate ion that is an anion having an ionic valence of 1 in which a boron atom is substituted with four aromatic hydrocarbon rings each optionally having a substituent or four aromatic heterocycles each optionally having a substituent, because the stability of this ionic compound is high.

The tetraarylborate ion is an anion of formula (81) that is represented by the following formula (82).

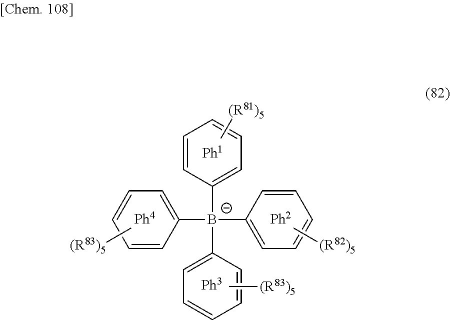

(In formula (82), R⁸¹ to R⁸⁴ are the same as R⁸¹ to R⁸⁴, respectively, in formula (81).

Ph¹ to Ph⁴ are the same as Ph¹ to Ph⁴, respectively, in formula (81) and represent the four benzene rings.)

The number of carbon atoms in each of the aromatic hydrocarbon groups used as R⁸¹ to R⁸⁴ is preferably 6 to 50. The aromatic hydrocarbon ring structure is preferably a monocycle, a condensed ring including 2 to 6 rings, or a structure in which 2 to 8 of them are linked together. Specific examples of the aromatic hydrocarbon group include: monovalent groups each including one of a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, a fluorene ring, a biphenyl structure, a terphenyl structure, and a quaterphenyl structure; and monovalent groups in which 2 to 8 groups selected from of the above groups are linked together.

The number of carbon atoms in each of the aromatic heterocyclic groups used as R⁸¹ to R⁸⁴ is preferably 3 to 50. The aromatic heterocyclic structure is preferably a monocycle, a condensed ring including 2 to 6 rings, or a structure in which 2 to 8 of them are linked together. Specific examples of the aromatic heterocyclic group include: monovalent groups each including one of a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a perimidine ring, a quinazoline ring, a quinazolinone ring, and an azulene ring; and monovalent groups in which 2 to 8 groups selected from of the above groups are linked together. It is only necessary that the aromatic heterocyclic group contain at least one of these single structures, and the linked structure may include an aromatic hydrocarbon ring structure. When the linked structure includes an aromatic hydrocarbon ring structure, the linked structure may include 2 to 8 linked rings including the aromatic heterocycle and the aromatic hydrocarbon ring. The aromatic hydrocarbon ring used can be any of the above-described structures used for R⁸¹ to R⁸⁴ and each including one aromatic hydrocarbon ring.

In particular, a monovalent group including a benzene ring, a naphthalene ring, a fluorene ring, a pyridine ring, or a carbazole ring or a monovalent group in which 2 to 5 of the above groups are linked together such as a biphenyl group is more preferred because of their high stability and heat resistance. A monovalent group including a benzene ring or a group including 2 to 5 benzene rings linked together is particularly preferred, and specific examples thereof include a phenyl group, a biphenyl group, and a terphenyl group.

The number of aromatic hydrocarbon and aromatic heterocyclic groups included in the monovalent group in which a plurality of structures selected from aromatic hydrocarbon groups each optionally having a substituent and aromatic heterocyclic groups each optionally having a substituent are linked together is preferably 2 or more and 8 or less, more preferably 4 or less, and still more preferably 3 or less. When a biphenyl group, a terphenyl group, and a quaterphenyl group are used as aromatic hydrocarbon groups, these aromatic hydrocarbon groups are regarded as structures in which 2, 3, and 4 phenyl groups, respectively, are linked together.

Each of the optional substituents on R⁸¹ to R⁸⁴ is preferably a group selected from the substituent group Z, particularly from the substituent group X.

R⁸¹ to R⁸⁴ are each preferably a fluorine atom or a fluorine-substituted alkyl group because the stability of the anion increases and the effect of stabilizing the cation is improved. It is preferable that two or more fluorine atoms or two or more fluorine-substituted alkyl groups are included. It is more preferable that three or more fluorine atoms or three or more fluorine-substituted alkyl groups are included, and it is most preferable that four fluorine atoms or four fluorine-substituted alkyl groups are included.

Each of the fluorine-substituted alkyl groups used for R⁸¹ to R⁸⁴ is preferably a linear or branched alkyl group having 1 to 12 carbon atoms and substituted with a fluorine atom, more preferably a perfluoroalkyl group, still more preferably a linear or branched perfluoroalkyl group having 1 to 5 carbon atoms, particularly preferably a linear or branched perfluoroalkyl group having 1 to 3 carbon atoms, and most preferably a perfluoromethyl group. The reason for this is that a charge injection layer containing a crosslinked product of the electron accepting compound having a crosslinking group and a coating film formed on this film are stabilized. Preferably, the fluorine-substituted alkyl group is boned at the para position with respect to the boron atom.

Preferably, in the tetraarylborate ion, at least one of -Ph¹-(R⁸¹)₅, -Ph²-(R⁸²)₅, -Ph³-(R⁸³)₅, and -Ph⁴-(R⁸⁴)₅ in formula (82) above is a group represented by formula (84) below and having four fluorine atoms because the stability of the anion further increases and the effect of stabilizing the cation is further improved. It is more preferable that at least two of them are the same group represented by formula (84) because the stability of the anion is improved, and it is most preferable that at least three of them are the same group represented by formula (84) because the stability of the anion is further improved.

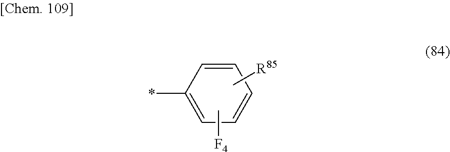

(In formula (84), * represents a bond to boron B in formula (81).

F₄ represents substitution with four fluorine atoms.

R⁸⁵ represents an aromatic hydrocarbon group optionally having a substituent and/or a crosslinking group or a crosslinking group.)

The number of carbon atoms in the aromatic hydrocarbon group usable for R⁸⁵ is preferably 3 to 40. The aromatic hydrocarbon ring structure is preferably a monocycle, a condensed ring including 2 to 6 rings, or a structure including 2 to 5 of these groups linked together. Specific examples include: monovalent groups including one of a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, a fluorene ring, a biphenyl structure, a terphenyl structure, and a quaterphenyl structure; and monovalent groups in which 2 to 6 groups selected from of the above groups are linked together. The optional crosslinking group on the aromatic hydrocarbon group is a crosslinking group selected from the group T of crosslinking groups.

The crosslinking group usable for R⁸⁵ is a crosslinking group selected from the group T of crosslinking groups.

Each of the optional substituents on the aromatic hydrocarbon and aromatic hydrocarbon groups is preferably a substituent selected from the substituent group Z, particularly from the substituent group X. In particular, an aromatic hydrocarbon group is preferred in terms of stability, and an alkyl group is preferred in terms of solubility.

### [Electron Accepting Ionic Compound Containing Tetraarylborate Ion]

The tetraarylborate ion is used preferably as an electron accepting ionic compound including the tetraarylborate ion serving as an anion and a counter cation.

### (Counter Cation)

The counter cation is preferably an iodonium cation, a sulfonium cation, a carbocation, an oxonium cation, an ammonium cation, a phosphonium cation, a cycloheptyltrienyl cation, or a ferrocenium cation having a transition metal, more preferably an iodonium cation, a sulfonium cation, a carbocation, or an ammonium cation, and particularly preferably an iodonium cation.

The iodonium cation has preferably a structure represented by formula (83) below, and a more preferred structure is also the same as the structure represented by formula (83).

Specifically, the iodonium cation is preferably a diphenyliodonium cation, a bis(4-tert-butylphenyl)iodonium cation, a 4-tert-butoxyphenylphenyliodonium cation, a 4-methoxyphenylphenyliodonium cation, a 4-isopropylphenyl-4-methylphenyliodonium cation, etc.

Specifically, the sulfonium cation is preferably a triphenylsulfonium cation, a 4-hydroxyphenyldiphenylsulfonium cation, a 4-cyclohexylphenyldiphenylsulfonium cation, a 4-methanesulfonylphenyldiphenylsulfonium cation, a (4-tert-butoxyphenyl)diphenylsulfonium cation, a (4-tert-butoxyphenyl)diphenylsulfonium cation, a bis(4-tert-butoxyphenyl)phenylsulfonium cation, a 4-cyclohexylsulfonylphenyldiphenylsulfonium cation, etc.

Specifically, the carbocation is preferably a trisubstituted carbocation such as a triphenyl carbocation, a tri(methylphenyl) carbocation, or a tri(dimethylphenyl) carbocation.

Specifically, the ammonium cation is preferably: a trialkylammonium cation such as a trimethylammonium cation, a triethylammonium cation, a tripropylammonium cation, a tributylammonium cation, or a tri(n-butyl)ammonium cation; an N,N-dialkylanilinium cation such as an N,N-diethylanilinium cation or an N,N-2,4,6-pentamethylanilinium cation; a dialkylammonium cation such as a di(isopropyl)ammonium cation or a dicyclohexylammonium cation; etc.

Specifically, the phosphonium cation is preferably: a tetraarylphosphonium cation such as a tetraphenylphosphonium cation, a tetrakis(methylphenyl)phosphonium cation, or a tetrakis(dimethylphenyl)phosphonium cation; a tetraalkylphosphonium cation such as a tetrabutylphosphonium cation or a tetrapropylphosphonium cation; etc.

Of these, the iodonium cation, the carbocation, and the sulfonium cation are preferred in terms of the stability of a film of the compound, and the iodonium cation is more preferred.

### (X⁺: (Iodonium Cation))

X⁺, which is the counter cation in formula (81) above, is preferably the iodonium cation having a structure represented by formula (83) below.

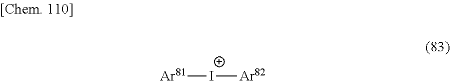

In formula (83), Ar⁸¹ and Ar⁸² are each independently an aromatic hydrocarbon group having 6 to 30 carbon atoms and optionally having a substituent.

The aromatic hydrocarbon group is preferably an aromatic hydrocarbon group having 6 to 18 carbon atoms, more preferably an aromatic hydrocarbon group having 6 to 12 carbon atoms, and most preferably a phenyl group. The optional substituent is a group selected from the substituent group Z, particularly from the substituent group X and is most preferably an alkyl group.

The aromatic hydrocarbon group is preferably a phenyl group, a biphenyl group, a terphenyl group, a quaterphenyl group, a naphthyl group, a phenanthrenyl group, a triphenylene group, or a naphthylphenyl group and is most preferably a phenyl group in terms of the stability of the compound.

### (Molecular Weight)

The molecular weight of the electron accepting ionic compound having the tetraarylborate ion is generally 900 or more, preferably 1000 or more, and more preferably 1200 or more and is generally 10000 or less, preferably 5000 or less, and more preferably 3000 or less. If the molecular weight is excessively low, delocalization of positive charges and negative charges is insufficient, so that the electron-accepting ability may deteriorate. If the molecular weight is excessively large, the charge transport may be inhibited.

### SPECIFIC EXAMPLES

Specific examples of an ionic compound including an iodonium cation and serving as the electron accepting ionic compound represented by formula (81) are shown below. However, the invention is not limited thereto.

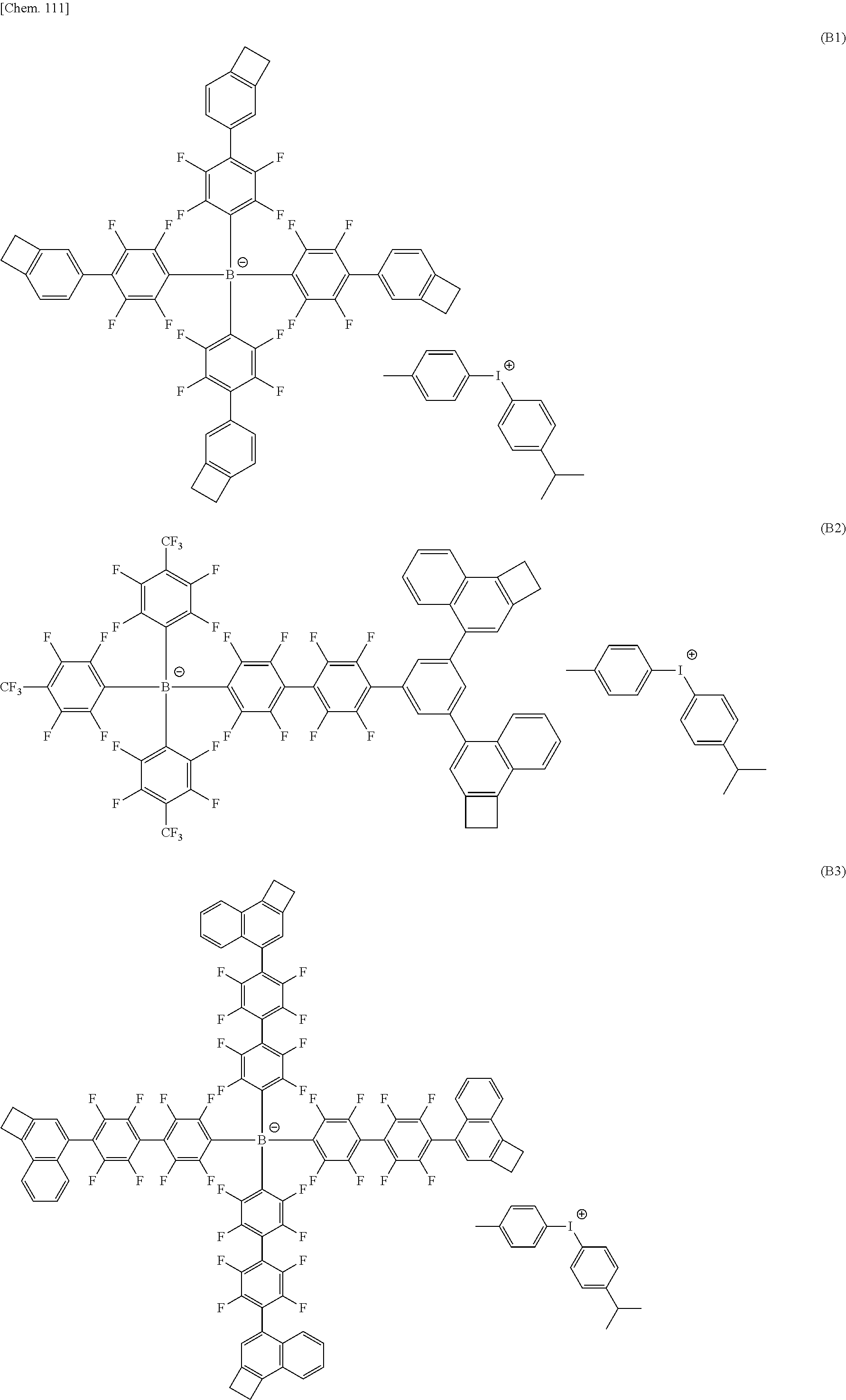

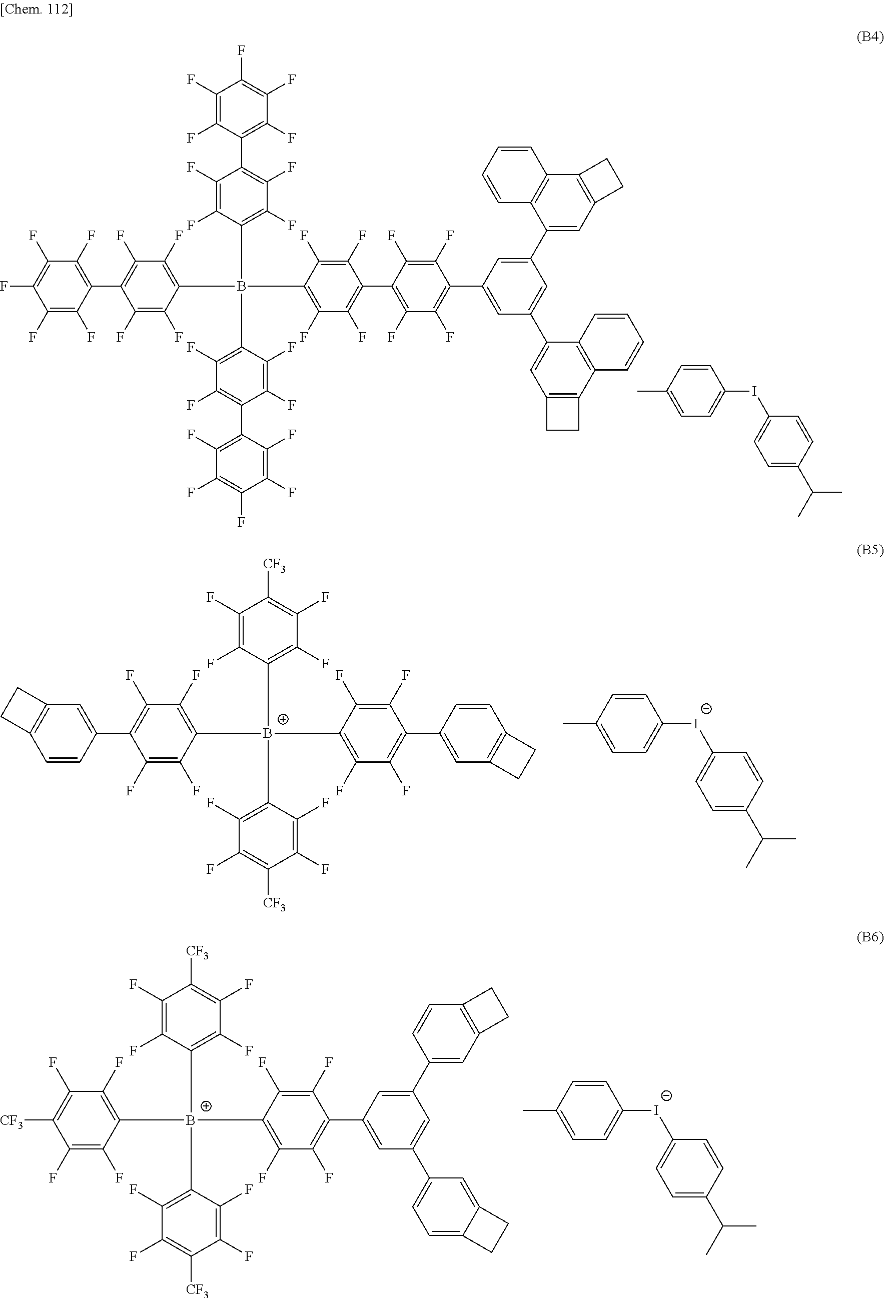

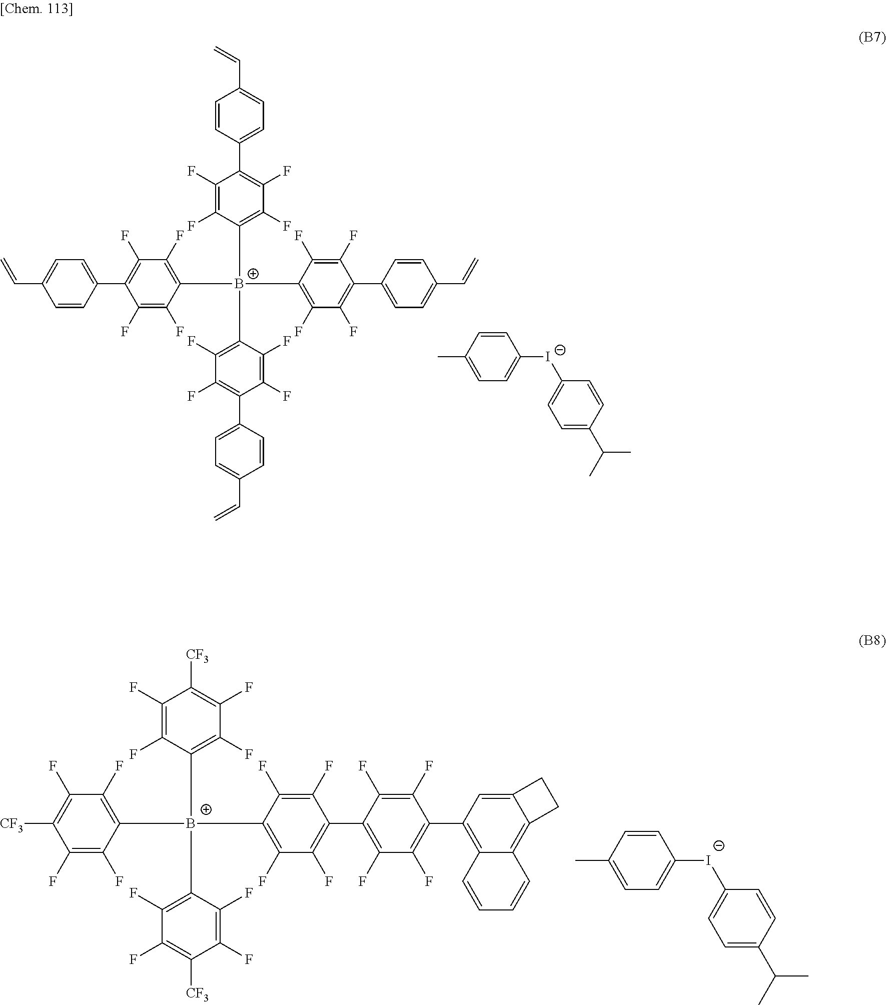

### [Contents of Solvent and Functional Materials]

No particular limitation is imposed on the content of the functional materials in the composition of the invention. However, to form a functional film having a thickness preferred for the organic electroluminescent element, the content of the functional materials is preferably 0.1% by weight or more, more preferably 0.5% by weight or more, and still more preferably 1.0% by weight or more. From the viewpoint of reducing the occurrence of precipitation in the composition, the content is preferably 20% by weight or less, more preferably 15% by weight or less, and still more preferably 10% by weight or less.

Therefore, the content of the solvent in the composition of the invention is preferably 99.9% by weight or less, more preferably 99.5% by weight or less, and still more preferably 99.0% by weight or less and is preferably 80% by weight or more, more preferably 85% by weight or more, and still more preferably 90% by weight or more.

In the present invention, the low-molecular weight charge transport compound is a material used to improve the uniformity of the thickness of the functional film in regions separated by banks. The content of the low-molecular weight charge transport compound with respect to the total amount of the functional materials is preferably 10% by weight or more, more preferably 15% by weight or more, and still more preferably 20% by weight or more. If the content of the low-molecular weight charge transport compound is large, the problem with heat resistance occurs as described above. Therefore, the content of the low-molecular weight charge transport compound with respect to the total amount of the functional materials is preferably 75% by weight or less, more preferably 60% by weight or less, and still more preferably 50% by weight or less.

In the present invention, the high-molecular weight charge transport compound is a material used mainly for charge transport, and the content of the high-molecular weight charge transport compound with respect to the total amount of the functional materials is preferably 20% by weight or more, more preferably 25% by weight or more, and still more preferably 30% by weight or more. If the content of the high-molecular weight charge transport compound is high, it is difficult to form a flat film because of the increase in viscosity in a drying process. Therefore, the content of the high-molecular weight charge transport compound with respect to the total amount of the functional materials is preferably 90% by weight or less, more preferably 85% by weight or less, and still more preferably 80% by weight or less.

The weight ratio of the low-molecular weight compound to the high-molecular weight compound is preferably the low-molecular weight compound: the high-molecular weight compound=1:0.3 to 3 and particularly preferably 1:1 to 2, in comprehensive consideration of the above.

When the composition of the invention contains the electron accepting compound, the content of the electron accepting compound with respect to the total amount of the functional materials is preferably 1% by weight or more, more preferably 3% by weight or more, and still more preferably 5% by weight or more, from the viewpoint of generating carriers in the charge transport compounds to thereby improve electric conductivity. However, if the amount of the electron accepting compound containing fluorine is excessively large, the surface energy of the functional film decreases, so that it is difficult to apply the compound to deposit a film. Therefore, the content of the electron accepting compound with respect to the total amount of the functional materials is preferably 50% by weight or less, more preferably 30% by weight or less, and still more preferably 20% by weight or less.

The weight ratio of the charge transport compounds (preferably the high-molecular weight charge transport compound and the low-molecular weight charge transport compound) to the electron accepting compound is preferably the charge transport compounds: the electron accepting compound=1:0.01 to 1 and particularly preferably 1 0.05 to 0.2, from the viewpoint described above.

### [Preparation of Composition]

The composition of the invention can be prepared by mixing the functional materials and the solvent and heating the mixture for a given time to dissolve or disperse the functional materials. To dissolve or disperse the functional materials uniformly in the solvent, the heating temperature is preferably 80° C. or higher, more preferably 90° C. or higher, and still more preferably 100° C. or higher, for example, 100 to 115° C. The heating time is preferably 30 minutes or longer, more preferably 45 minutes or longer, and still more preferably 60 minutes or longer, for example, 60 to 180 minutes.

The composition after heating is filtered using a membrane filter, a depth filter, etc. to remove coarse particles before use. Since the composition is ejected from a nozzle of an inkjet head for the application of the composition, the pore diameter of the filter is preferably 0.5 μm or less, more preferably 0.2 μm or less, and still more preferably 0.1 μm or less.

### [Formation of Film by Wet Deposition Method]

In the manufacture of an organic electroluminescent element, the composition of the invention is preferably used to form a functional film. The structure of the organic electroluminescent element will be described later.

In the organic electroluminescent element in the invention, light-emitting pixels are generally formed on a substrate having electrodes formed thereon and are disposed in small regions separated by liquid repellent partition walls called a partition wall layer (banks). The composition of the invention is ejected into the small regions separated by the partition wall layer, dried, and appropriately heated to form a functional film.

The ejection method used is a method in which droplets smaller than the small regions separated by the partition wall layer are ejected from a small nozzle. It is preferable that, by ejecting a plurality of droplets, the small regions separated by the partition wall layer are filled with the composition of the invention. The ejection method is preferably an inkjet method.

In a wet deposition method, the small regions separated by the banks are filled with the functional film-forming composition, and the solvent is volatilized by appropriate means to dry the composition to thereby obtain the functional film. The volatilizing and drying means may be heat drying or vacuum drying but is not limited thereto. For example, in the vacuum drying, a substrate coated with the composition is placed in a metal- or glass-made openable/closable vacuum chamber, and the pressure inside the chamber is reduced using, for example, a vacuum pump to volatilize the solvent. The vacuum pump used is generally a rotary oil pump, a mechanical booster pump, a dry scroll pump, a dry roots pump, a turbo molecular pump, a cryopump, etc.

When the boiling point of the organic solvent is within the preferred range in the invention, the organic solvent can be sufficiently volatilized using any of the above pumps. However, to further remove the residual solvent present in a small amount by drying, heat drying may be performed subsequently.

To crosslink the crosslinking groups in the high-molecular weight charge transport compound and the low-molecular weight compound in the invention and, if present, in functional materials such as the electron accepting compound, they are heated. In the heating step, the heating may be performed for drying and also for crosslinking. Preferably, the heating for drying is used also for crosslinking. Specifically, it is preferable to perform drying and crosslinking by heating, from the viewpoint of reducing the number of steps. It is preferable to set the heating temperature and time such that the functional film is not crystalized or aggregation does not occur at the heating temperature.

The heating temperature of the functional materials is generally 80° C. or higher, preferably 100° C. or higher, more preferably 150° C. or higher, and still more preferably 200° C. or higher and is generally 300° C. or lower, preferably 270° C. or lower, and more preferably 240° C. or lower. The heating time is generally 1 minute or longer, preferably 3 minutes or longer, and more preferably 5 minutes or longer and is generally 120 minutes or shorter, preferably 90 minutes or shorter, and more preferably 60 minutes or shorter.

The heating method can be performed using a hot plate, an oven, infrared irradiation, etc. In the infrared irradiation in which molecular vibrations are directly imparted, the heating time close to the lower limit described above is long enough. In the hot plate heating in which the substrate is in direct contact with a heat source or is disposed very close to the heat source, the time required is longer than that for the infrared irradiation. In the oven heating, i.e., in the heating by gas inside the oven, which is generally air, nitrogen, or an inert gas such as argon, the time required to increase the temperature is long, and therefore the heating time is preferably close to the upper limit of the heating time described above. The heating time is appropriately controlled according to the heating method.

It is important that the heating step be performed under such conditions that the crosslinking groups in the functional materials in the invention such as the high-molecular weight charge transport compound and the low-molecular weight compound undergo a crosslinking reaction. To achieve this, the heating temperature is preferably equal to or higher than the crosslinking onset temperature of the crosslinking groups in the high-molecular weight charge transport compound and the low-molecular weight compound in the invention and, if present, in the electron accepting compound etc.

During the process of volatilizing the solvent in the composition to dry the composition, pinned positions of the composition on the side surfaces of the banks are lowered. However, if the rate of drying is excessively high, the time required to sufficiently lower the pinned positions is not obtained, and the effect of the composition is not achieved. Therefore, it is preferable that the time required for the pressure to reach a pressure lower than the vapor pressure of an organic solvent having the lowest vapor pressure among the organic solvents contained in the composition of the invention is 60 seconds or longer. If the composition remains in continuous contact with the side surfaces of the banks, a problem occurs in that a material forming the banks gradually dissolves from the banks into the solvents of the composition. Therefore, it is preferable that the time required for the pressure to reach a pressure lower than the vapor pressure of the organic solvent having the lowest vapor pressure among the organic solvents contained in the composition of the invention is 1800 seconds or shorter.

Generally, when functional films having different thicknesses are formed simultaneously, the composition is dropped into the small regions separated by the banks such that different amounts of the composition are dropped into different regions, and then the solvent component is volatilized by vacuum drying to form the functional films. As the concentration of the composition increases in the drying process, its viscosity increases. In this case, different initial amounts of the dropped composition give different pinned positions as a result of the increase in viscosity. This causes a problem in that the pinned positions are not sufficiently lowered to appropriate positions and therefore some small regions separated by the banks are not flat. However, in the composition of the invention, the increase in viscosity when the temperature increases is small. When the composition of the invention is applied by printing to form films having two different thicknesses of 10 nm or more, e.g., 15 to 30 nm, and vacuum-dried in a single vacuum chamber, the composition is dropped such that different amounts of the composition are used for different thicknesses. Even in this case, the change in pinned positions due to the increase in viscosity in this step is small, so that the films may be flat irrespective of thickness.

### [Functional Film]

The functional film formed of the composition of the invention is a film in which the crosslinking groups included in the high-molecular weight charge transport compound and the low-molecular weight compound used as the functional materials are crosslinked together.

The content of the functional materials in the functional film is generally 70% by weight or more, preferably 80% by weight or more, still more preferably 90% by weight or more, particularly preferably 95% by weight or more, and most preferably substantially 100% by weight, and the upper limit is 100% by weight. The phrase “substantially 100% by weight” means that the functional film may contain trace amounts of additives, remaining solvents, and impurities. When the content of the functional materials in the functional film is within the above range, the functions of the functional materials can be obtained more effectively.

### [Layer Structure of Organic Electroluminescent Element and its Formation Method]

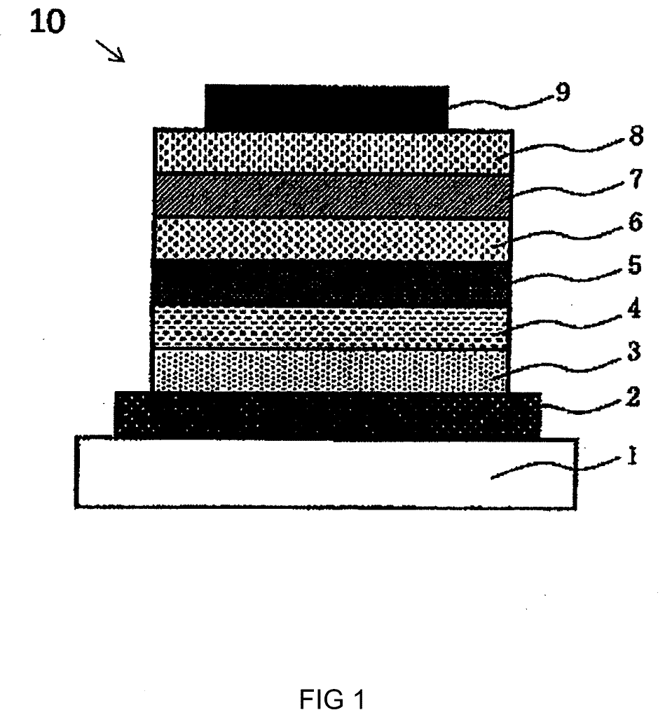

The layer structure of an organic electroluminescent element manufactured using the composition of the invention (which may be hereinafter referred to as the “organic electroluminescent element of the invention”) and preferred examples of an embodiment of a method for forming the organic electroluminescent element will be described with reference to FIG. 1.

FIG. 1 is a schematic illustration of a cross section showing a structural example of the organic electroluminescent element 10 of the invention. In FIG. 1, 1 represents a substrate; 2 represents an anode; 3 represents a hole injection layer; 4 represents a hole transport layer; 5 represents a light-emitting layer; 6 represents a hole blocking layer; 7 represents an electron transport layer; 8 represents an electron injection layer; and 9 represents a cathode.

In the organic electroluminescent element of the invention, the anode, the light-emitting layer, and the cathode are essential constituent layers. However, if necessary, other functional layers may be disposed between the anode 2 and the light-emitting layer 5 and between the cathode 9 and the light-emitting layer 5 as shown in FIG. 1.

### [Substrate]

The substrate 1 is a support for the organic electroluminescent element. The substrate 1 used is a quartz or glass plate, a metal plate, a metal foil, a plastic film, a plastic sheet, etc. In particular, a glass plate or a plate of a transparent synthetic resin such as polyester, polymethacrylate, polycarbonate, or polysulfone is preferred. When a synthetic resin substrate is used, it is preferable to take into account its gas barrier properties. It is preferable that the substrate has high gas barrier properties because deterioration of the organic electroluminescent element due to outside air passing through the substrate is unlikely to occur. Therefore, in one preferred method, a dense silicon oxide film etc. is disposed on at least one side of the synthetic resin substrate to ensure gas barrier properties.

### [Anode]

The anode 2 is an electrode for hole injection to layers on the light-emitting layer 5 side.

The anode 2 is generally formed of a metal such as aluminum, gold, silver, nickel, palladium, or platinum, an alloy of any of these metals with indium, copper, tellurium, palladium, or aluminum, a metal oxide such as indium and/or tin oxide, a halogenated metal such as copper iodide, carbon black, or an electrically conductive macromolecule such as poly(3-methylthiophene), polypyrrole, or polyaniline.

The anode 2 is often formed using a sputtering method, a vacuum vapor deposition method, etc.

When the anode 2 is formed using fine metal particles such as silver particles, fine particles of copper iodide etc., carbon black, fine electrically conductive metal oxide particles, fine electrically conductive macromolecular particles, etc., these fine particles etc. may be dispersed in an appropriate binder resin solution, and the resulting solution may be applied to the substrate 1 to form the anode 2.

When an electrically conductive macromolecule is used, a thin film may be formed directly on the substrate 1 by electrolytic polymerization.

The anode 2 may be formed by applying an electrically conductive macromolecule to the substrate 1 (Appl. Phys. Lett., Vol. 60, 2711, 1992).

The anode 2 has generally a monolayer structure but may have a layered structure formed of a plurality of materials.

The thickness of the anode 2 may be approximately selected according to the required transparency etc. When transparency is required, the visible light transmittance is set to generally 60% or more and preferably 80% or more. In this case, the thickness of the anode 2 is generally about 5 nm or more and preferably about 10 nm or more and is generally about 1000 nm or less and preferably about 500 nm or less. When the anode 2 can be opaque, the anode 2 can have any thickness. A substrate 1 having the function of the anode 2 can be used. A different electrically conductive material may be stacked on the anode 2.

For the purpose of removing impurities adhering to the anode 2 to control the ionization potential to thereby improve the hole injectability, it is preferable that the surface of the anode 2 is subjected to ultraviolet (UV)/ozone treatment, oxygen plasma treatment, or argon plasma treatment.

### [Pixel Separating Layer]

When the composition is applied to individual separated pixels using, for example, an inkjet printer, liquid-repellent partition walls called banks are formed on the anode to form a layer capable of forming the separated pixels. The separating layer can be formed by applying a photosensitive resist by spin coating, die coating, inkjet application, etc. and forming a dividing pattern by general photolithography. However, this formation method is not a limitation.

Preferably, the surface of the substrate after the pattern formation is again subjected to ultraviolet (UV)/ozone treatment, oxygen plasma treatment, or argon plasma treatment in order to remove residues formed by the application of the resist and photolithography.

### [Hole Injection Layer]

The hole injection layer 3 is a layer that transports holes from the anode 2 to the light-emitting layer 5. When the hole injection layer 3 is provided, the hole injection layer 3 is generally formed on the anode 2.

No particular limitation is imposed on the method of forming the hole injection layer 3, and a vacuum vapor deposition method or a wet deposition method may be used. From the viewpoint of reducing dark spots, it is preferable to form the hole injection layer 3 by the wet deposition method.

The thickness of the hole injection layer 3 is generally 5 nm or more and preferably 10 nm or more and is generally 1000 nm or less and preferably 500 nm or less.

### <Hole Transport Material>

The hole injection layer-forming composition generally contains a hole transport material and a solvent as constituent materials of the hole injection layer 3.

The hole transport material is generally used for the hole injection layer 3 of the organic electroluminescent element. The hole transport material may be any compound having hole transportability and may be a high-molecular weight compound such as a polymer or may be a low-molecular weight compound such as a monomer. The hole transport material is preferably a high-molecular weight compound. When the composition of the invention is used for the hole injection layer 3, the composition is a composition containing at least one high-molecular weight hole transport material having a weight average molecular weight of 10,000 or more and having a crosslinking group, at least one low-molecular weight hole transport material having a molecular weight of 5,000 or less and having a crosslinking group, and at least one aromatic organic solvent.

From the viewpoint of the barrier for charge injection from the anode 2 to the hole injection layer 3, each hole transport material is preferably a material having an ionization potential of 4.5 eV to 6.0 eV. Examples of the hole transport material include aromatic amine derivatives, phthalocyanine derivatives, porphyrin derivatives, oligothiophene derivatives, polythiophene derivatives, benzylphenyl derivatives, compounds including a tertiary amine linked via a fluorene group, hydrazone derivatives, silazane derivatives, silanamine derivatives, phosphamine derivatives, quinacridone derivatives, polyaniline derivatives, polypyrrole derivatives, polyphenylenevinylene derivatives, polythienylenevinylene derivatives, polyquinoline derivatives, polyquinoxaline derivative, and carbon.

In the present invention, the derivative is as follows. In the case of, for example, an aromatic amine derivative, the derivative is intended to encompass the aromatic amine itself and compounds including the aromatic amine as a main skeleton and may be a polymer or a monomer.

The hole transport material used as a material of the hole injection layer 3 may contain only one of the above compounds or may contain two or more compounds. When two or more hole transport materials are contained, any combination of hole transport materials may be used. However, it is preferable to use a combination of one or two or more high-molecular weight aromatic tertiary compounds and one or two or more other hole transport materials.

Among the above-exemplified hole transport materials, aromatic amine compounds are preferred, and aromatic tertiary amine compounds are particularly preferred in terms of non-crystallinity and visible light transmittance. The aromatic tertiary amine compound is a compound having an aromatic tertiary amine structure and is intended to encompass compounds having a group derived from an aromatic tertiary amine.

No particular limitation is imposed on the type of aromatic tertiary amine compound. In terms of uniform light emission due to a surface smoothing effect, a high-molecular weight compound having a weight average molecular weight of 1000 or more and 1000000 or less (a polymerized compound including repeating units linked together) is more preferred. Preferred examples of the high-molecular weight aromatic tertiary amine compound include high-molecular weight compounds having a repeating unit represented by formula (10A) or (11) below.

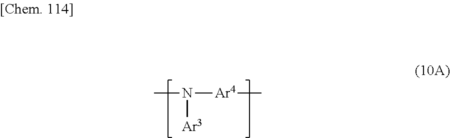

(In formula (10A),

Ar³ represents an aromatic hydrocarbon or aromatic heterocyclic group optionally having a substituent.

Ar⁴ represents a divalent aromatic hydrocarbon or divalent aromatic heterocyclic group optionally having a substituent or a divalent group in which a plurality of aromatic hydrocarbon and aromatic heterocyclic groups are linked together directly or via a linking group.)

In formula (10A) above, when a plurality of aromatic hydrocarbon and aromatic heterocyclic groups are linked together via a linking group, the linking group is a divalent linking group, and examples thereof include groups in which 1 to 30 groups, preferably 1 to 5 groups, and still more preferably 1 to 3 groups selected from an —O— group, a —C(═O)— group, and a —CH₂— group (optionally having a substituent) are linked together in any order.

As for the linking group, it is preferable that Ar⁴ in formula (10A) is a plurality of aromatic hydrocarbon groups or aromatic heterocyclic groups that are linked together via a linking group represented by the following formula (10B) because hole injectability into the light-emitting layer is high.

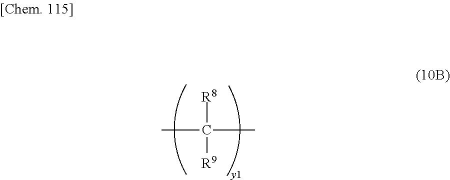

(In formula (10B),

y1 represents an integer of 1 to 10.

R⁸ and R⁹ each independently represent a hydrogen atom, an alkyl group optionally having a substituent, an aromatic hydrocarbon group optionally having a substituent, or an aromatic heterocyclic group optionally having a substituent.

When a plurality of Ra's are present, they may be the same or different. When a plurality of R⁹'s are present, they may be the same or different.)

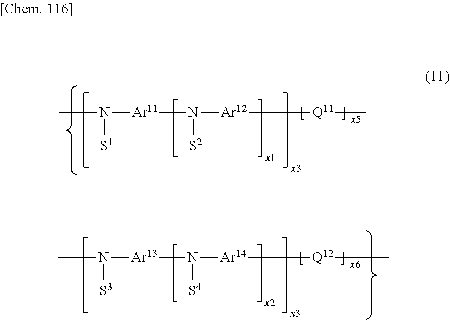

In formula (11) above, x1, x2, x3, x4, x5, and x6 each independently represent an integer of 0 or more. However, x3+x4≥1. Ar¹¹, Ar¹², and Ar¹⁴ each independently represent a divalent aromatic ring group having 30 or less carbon atoms and optionally having a substituent. Ar¹³ represents a divalent aromatic ring group having 30 or less carbon atoms and optionally having a substituent or a divalent group represented by formula (12) below. Q¹¹ and Q¹² each independently represent an oxygen atom, a sulfur atom, or a hydrocarbon chain having 6 or less carbon atoms and optionally having a substituent, and S¹ to S⁴ each independently represent a group represented by formula (13) below.

The aromatic ring group is intended to encompass an aromatic hydrocarbon group and an aromatic heterocyclic group.

Examples of the aromatic ring groups represented by Ar¹¹, Ar¹², and Ar¹⁴ include monocycles, condensed rings each including 2 to 6 rings, and groups including any of these aromatic rings linked together. Specific examples of the aromatic monocyclic ring groups and condensed aromatic ring groups including 2 to 6 rings include divalent groups derived from a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, a fluorene ring, a biphenyl group, a terphenyl group, a quaterphenyl group, a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a benzimidazole ring, a perimidine ring, a quinazoline ring, a quinazolinone ring, and an azulene ring. In particular, divalent groups derived from a benzene ring, a naphthalene ring, a fluorene ring, a pyridine ring, and a carbazole ring and a biphenyl group are preferred because negative charges are non-localized efficiently and high stability and good heat resistance are obtained.

Examples of the aromatic ring group represented by Ar¹³ are the same as those for Ar¹¹, Ar¹², and Ar¹⁴.

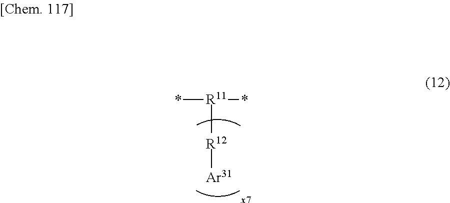

In formula (12) above, R¹¹ represents an alkyl group, an aromatic ring group, or a trivalent group including an alkyl group having 40 or less carbon atoms and an aromatic ring group, and each of these groups may optionally have a substituent. R¹² represents an alkyl group, an aromatic ring group, or a divalent group including an alkyl group having 40 or less carbon atoms and an aromatic ring group, and each of these groups may optionally have a substituent. Ar³¹ represents a monovalent aromatic ring group or a monovalent crosslinking group, and each of these groups may optionally have a substituent. x7 represents 1 to 4. When x7 is 2 or more, a plurality of R¹²'s may be the same or different, and a plurality of Ar³¹'s may be the same or different. * represents a direct bond to a nitrogen atom in formula (11).

The aromatic ring group represented by R¹¹ is preferably one aromatic ring group that is a monocycle or condensed ring having 3 to 30 carbon atoms or a group including 2 to 6 of these groups linked together. Specific examples thereof include a benzene ring, a fluorene ring, a naphthalene ring, a carbazole ring, a dibenzofuran ring, a dibenzothiophene ring, and trivalent groups in which 2 to 6 groups selected from these groups are linked together.

The alkyl group represented by R¹¹ is preferably a linear, branched, or ring-containing alkyl group having 1 to 12 carbon atoms, and specific examples thereof include groups derived from methane, ethane, propane, isopropane, butane, isobutane, pentane, hexane, and octane.

The group represented by R¹¹ and including an alkyl group having 40 or less carbon atoms and an aromatic ring group is preferably a group in which a linear, branched, or ring-containing alkyl group having 1 to 12 carbon atoms and one aromatic ring group including a monocycle or condensed ring having 3 to 30 carbon atoms or 2 to 6 aromatic ring groups linked together are linked together.

Specific examples of the aromatic ring group represented by R¹² include divalent groups derived from a benzene ring, a fluorene ring, a naphthalene ring, a carbazole ring, a dibenzofuran ring, a dibenzothiophene ring, and linked rings having 30 or less carbon atoms in which rings selected from these rings are linked together.

Specific examples of the alkyl group represented by R¹² include divalent groups derived from methane, ethane, propane, isopropane, butane, isobutane, pentane, hexane, and octane.

Specific examples of the aromatic ring group represented by Ar³¹ include monovalent groups derived from a benzene ring, a fluorene ring, a naphthalene ring, a carbazole ring, a dibenzofuran ring, a dibenzothiophene ring, and linked rings having 30 or less carbon atoms in which rings selected from these rings are linked together.

Preferred examples of the structure of formula (12) include structures shown below. Benzene rings and fluorene rings in the main chains in the following structures that are partial structures of R¹¹ may each optionally have a substituent.

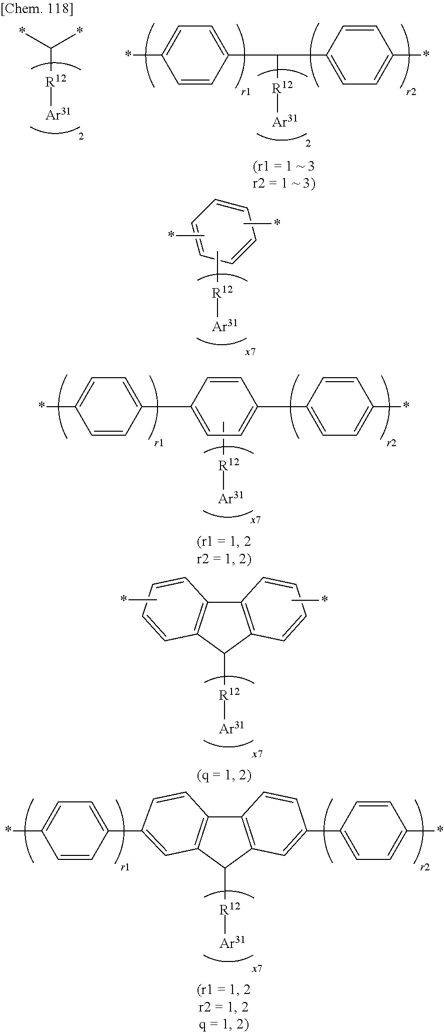

Examples of the crosslinking group represented by Ar³¹ include groups derived from a benzocyclobutene ring, a naphthocyclobutene ring, and an oxetane ring, a vinyl group, and an acrylic group. In terms of the stability of the compound, a group derived from a benzocyclobutene ring or a naphthocyclobutene ring is preferred.

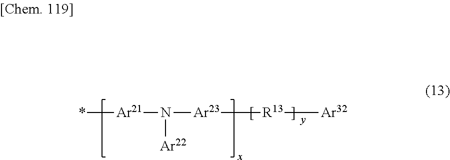

In formula (13) above, x and y each represent an integer of 0 or more. Ar²¹ and Ar²³ each independently represent a divalent aromatic ring group, and each of these groups may optionally have a substituent. Ar²² represents a monovalent aromatic ring group optionally having a substituent, and R¹³ represents an alkyl group, an aromatic ring group, or a divalent group including an alkyl group and an aromatic ring group. Each of these groups may optionally have a substituent. Ar³² represents a monovalent aromatic ring group or a monovalent crosslinking group. Each of these groups may optionally have a substituent. * represents a direct bond to a nitrogen atom in formula (11).

Examples of the aromatic ring group represented by Ar²¹ and Ar²³ are the same as those for Ar¹¹, Ar¹², and Ar¹⁴.

Examples of the aromatic ring groups represented by Ar²² and Ar³² include monocycles, condensed rings each including 2 to 6 rings, and groups including two or more of these aromatic rings liked together. Specific examples include monovalent groups derived from a benzene ring, a naphthalene ring, an anthracene ring, a phenanthrene ring, a perylene ring, a tetracene ring, a pyrene ring, a benzpyrene ring, a chrysene ring, a triphenylene ring, an acenaphthene ring, a fluoranthene ring, a fluorene ring, a biphenyl group, a terphenyl group, a quaterphenyl group, a furan ring, a benzofuran ring, a thiophene ring, a benzothiophene ring, a pyrrole ring, a pyrazole ring, an imidazole ring, an oxadiazole ring, an indole ring, a carbazole ring, a pyrroloimidazole ring, a pyrrolopyrazole ring, a pyrrolopyrrole ring, a thienopyrrole ring, a thienothiophene ring, a furopyrrole ring, a furofuran ring, a thienofuran ring, a benzisoxazole ring, a benzisothiazole ring, a benzimidazole ring, a pyridine ring, a pyrazine ring, a pyridazine ring, a pyrimidine ring, a triazine ring, a quinoline ring, an isoquinoline ring, a cinnoline ring, a quinoxaline ring, a phenanthridine ring, a benzimidazole ring, a perimidine ring, a quinazoline ring, a quinazolinone ring, and an azulene ring. Of these, monovalent groups derived from a benzene ring, a naphthalene ring, a fluorene ring, a pyridine ring, and a carbazole ring and a biphenyl group are preferred because negative charges are non-localized efficiently and high stability and good heat resistance are obtained.

Examples of the alkyl group or aromatic ring group represented by R¹³ are the same as those for R¹².

No particular limitation is imposed on the crosslinking group represented by Ar³². Preferred examples thereof include groups derived from a benzocyclobutene ring, a naphthocyclobutene ring, and an oxetane ring, a vinyl group, and an acrylic group.

Ar¹¹ to Ar¹⁴, R¹¹ to R¹³, Ar²¹ to Ar²³, Ar³¹ to Ar³², Q¹¹, and Q¹² may each optionally have a substituent so long as the gist of the invention is retained. The molecular weight of the substituent is preferably 400 or less and more preferably 250 or less. No particular limitation is imposed on the type of substituent. For example, one or two or more selected from the following substituent group W are used.

### [Substituent Group W]

Alkyl groups having 1 or more carbon atoms and having preferably 10 or less carbon atoms and more preferably 8 or less carbon atoms such as a methyl group and an ethyl group;
alkenyl groups having 2 or more carbon atoms and having preferably 11 or less carbon atoms and more preferably 5 or less carbon atoms such as a vinyl group;
alkynyl groups having 2 or more carbon atoms and having preferably 11 or less carbon atoms and more preferably 5 or less carbon atoms such as an ethynyl group;
alkoxy groups having 1 or more carbon atoms and having preferably 10 or less carbon atoms and more preferably 6 or less carbon atoms such as a methoxy group and an ethoxy group;
aryloxy groups having 4 or more carbon atoms and preferably 5 or more carbon atoms and having preferably 25 or less carbon atoms and more preferably 14 or less carbon atoms such as a phenoxy group, a naphthoxy group, and a pyridyloxy group;
alkoxycarbonyl groups having 2 or more carbon atoms and having preferably 11 or less carbon atoms and more preferably 7 or less carbon atoms such as a methoxycarbonyl group and an ethoxycarbonyl group;
dialkylamino groups having 2 or more carbon atoms and having preferably 20 or less carbon atoms and more preferably 12 or less carbon atoms such as a dimethylamino group and a diethylamino group;
diarylamino groups having 10 or more carbon atoms and preferably 12 or more carbon atoms and having preferably 30 or less carbon atoms and more preferably 22 or less carbon atoms such as a diphenylamino group, a ditolylamino group, and an N-carbazolyl group;
arylalkylamino groups having 6 or more carbon atoms and preferably 7 or more carbon atoms and having preferably 25 or less carbon atoms and more preferably 17 or less carbon atoms such as a phenylmethylamino group;
acyl groups having 2 or more carbon atoms and having preferably 10 or less carbon atoms and more preferably 7 or less carbon atoms such as an acetyl group and a benzoyl group;
halogen atoms such as a fluorine atom and a chlorine atom;
haloalkyl groups having 1 or more carbon atoms and having preferably 8 or less carbon atoms and more preferably 4 or less carbon atoms such as a trifluoromethyl group;
alkylthio groups having 1 or more carbon atoms and having preferably 10 or less carbon atoms and more preferably 6 or less carbon atoms such as a methylthio group and an ethylthio group;
arylthio groups having 4 or more carbon atoms and preferably 5 or more carbon atoms and having preferably 25 or less carbon atoms and more preferably 14 or less carbon atoms such as a phenylthio group, a naphthylthio group, and a pyridylthio group;
silyl groups having 2 or more carbon atoms and preferably 3 or more carbon atoms and having preferably 33 or less carbon atoms and more preferably 26 or less carbon atoms such as a trimethylsilyl group and a triphenylsilyl group;
siloxy groups having 2 or more carbon atoms and preferably 3 or more carbon atoms and having preferably 33 or less carbon atoms and more preferably 26 or less carbon atoms such as a trimethylsiloxy group and a triphenylsiloxy group;
a cyano group;
aromatic hydrocarbon groups having 6 or more carbon atoms and having preferably 30 or less carbon atoms and more preferably 18 or less carbon atoms such as a phenyl group and a naphthyl group; and
aromatic heterocyclic groups having 3 or more carbon atoms and preferably 4 or more carbon atoms and having preferably 28 or less carbon atoms and more preferably 17 or less carbon atoms such as a thienyl group and a pyridyl group.

In the substituent group W, alkyl groups and alkoxy groups are preferred from the viewpoint of improving the solubility, and aromatic hydrocarbon groups and aromatic heterocyclic groups are preferred from the viewpoint of charge transportability and stability.

In particular, among high-molecular weight compounds each having the repeating unit represented by formula (11), a high-molecular weight compound having a repeating unit represented by the following formula (14) is preferred because hole injectability and transferability are very high.

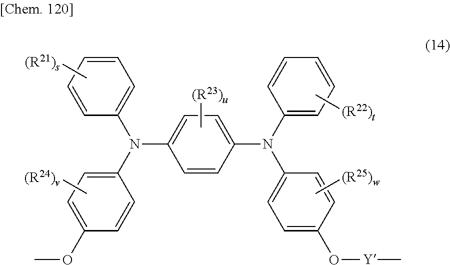

In formula (14) above, R²¹ to R²⁵ each independently represent a substituent. Specific examples of the substituents on R²¹ to R²⁵ are the same as those described above in [Substituent group W].

s and t each independently represent an integer of 0 or more and 5 or less.

u, v, and w each independently represent an integer of 0 or more and 4 or less.

Preferred examples of the high-molecular weight aromatic tertiary amine compound include high-molecular weight compounds each having a repeating unit represented by the following formula (15) and/or a repeating unit represented by the following formula (16).

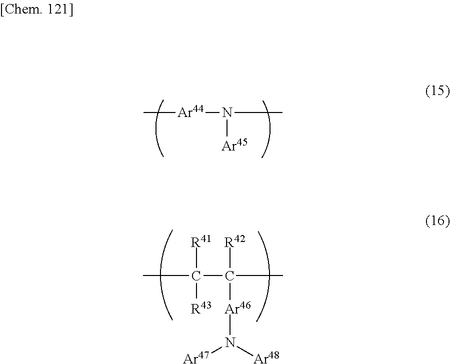

In formulas (15) and (16) above, Ar⁴⁵, Ar⁴⁷, and Ar⁴⁸ each independently represent a monovalent aromatic hydrocarbon group optionally having a substituent or a monovalent aromatic heterocyclic group optionally having a substituent. Ar⁴⁴ and Ar⁴⁶ each independently represent a divalent aromatic hydrocarbon group optionally having a substituent or a divalent aromatic heterocyclic group optionally having a substituent. R⁴¹ to R⁴³ each independently represent a hydrogen atom or a substituent.

Specific examples and preferred examples of Ar⁴⁵, Ar⁴⁷, and Ar⁴⁸, examples of the optional substituents thereon, and examples of the preferred substituents are the same as those for Ar²². Specific examples and preferred examples of Ar⁴⁴ and Ar⁴⁶, examples of the optional substituents thereon, and examples of the preferred substituents are the same as those for Ar¹¹, Ar¹², and Ar¹⁴. R⁴¹ to R⁴³ are each preferably a hydrogen atom or any of the substituents in [Substituent group W] described above and are each more preferably a hydrogen atom, an alkyl group, an alkoxy group, an amino group, an aromatic hydrocarbon group, or an aromatic heterocyclic group.

Preferred specific examples of the repeating units represented by formulas (15) and (16) that are applicable to the present invention are described below. However, the present invention is not limited thereto.

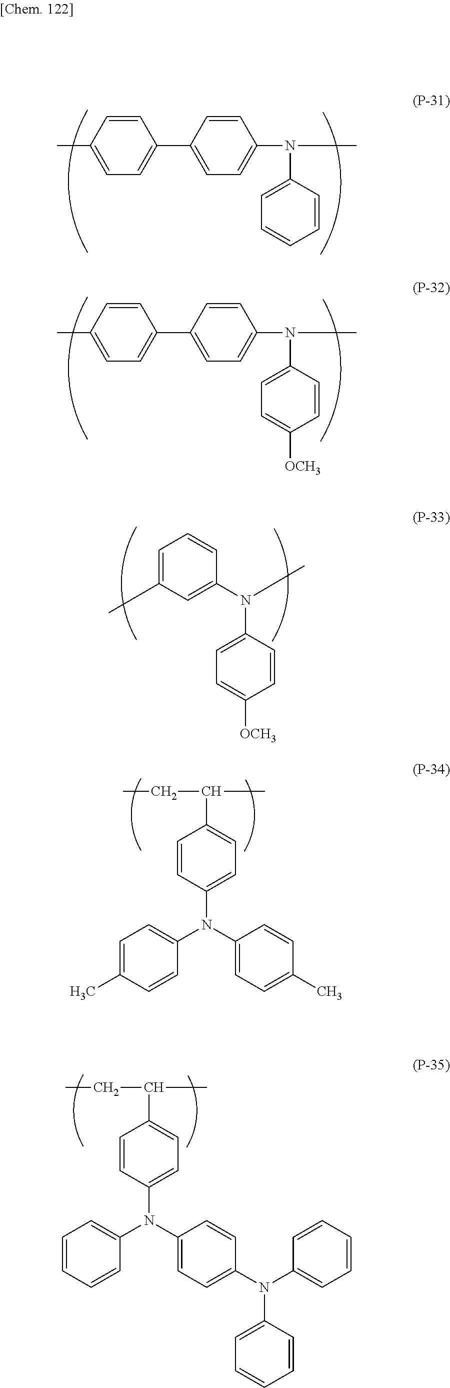

### <Electron Accepting Compound>

Preferably, the hole injection layer-forming composition contains an electron accepting compound as a constituent material of the hole injection layer 3.

The electron accepting compound is preferably an oxidative compound having the ability to receive one electron from the hole transport material described above. Specifically, the electron accepting compound is preferably a compound having an electron affinity of 4.0 eV or more and more preferably a compound having an electron affinity of 5.0 eV or more.

The electron accepting compound is, for example, one or two or more compounds selected from the group consisting of triarylboron compounds, halogenated metals, Lewis acids, organic acids, onium salts, salts of arylamines and halogenated metals, and salts of arylamines and Lewis acids. Specific examples of the electron accepting compound include: onium salts substituted with organic acids such as 4-isopropyl-4′-methyldiphenyliodonium tetrakis(pentafluorophenyl)borate and triphenylsulfonium tetrafluoroborate (WO2005/089024 and WO2017/164268); high-valent inorganic compounds such as iron(III) chloride (JP11-251067A) and ammonium peroxodisulfate; cyano compounds such as tetracyanoethylene; aromatic boron compounds such as tris(pentafluorophenyl)borane (JP2003-31365A); fullerene derivatives; iodine; and sulfonic acid ions such as polystyrenesulfonic acid ions, alkylbenzenesulfonic acid ions, and camphorsulfonic acid ions.

The electron accepting compound oxidizes the hole transport material, and the electrical conductivity of the hole injection layer 3 can thereby be improved.

### <Additional Constituent Materials>

Additional components other than the hole transport material and the electron accepting compound may be contained as materials of the hole injection layer 3 so long as the effects of the invention are not significantly impaired.

### <Solvent>

It is preferable that at least one solvent in the hole injection layer-forming composition used for the wet deposition method is a compound capable of dissolving the constituent materials of the hole injection layer 3.

Examples of the solvent include ether-based solvents, ester-based solvents, aromatic hydrocarbon-based solvents, and amide-based solvents.

Examples of the ether-based solvents include: aliphatic ethers such as ethylene glycol dimethyl ether, ethylene glycol diethyl ether, and propylene glycol-1-monomethyl ether acetate (PGMEA); and aromatic ethers such as 1,2-dimethoxybenzene, 1,3-dimethoxybenzene, anisole, phenetole, 2-methoxytoluene, 3-methoxytoluene, 4-methoxytoluene, 2,3-dimethylanisole, 2,4-dimethylanisole, 3-phenoxytoluene, diphenyl ether, and dibenzyl ether.

Examples of the ester-based solvents include aromatic esters such as phenyl acetate, phenyl propionate, methyl benzoate, ethyl benzoate, propyl benzoate, n-butyl benzoate, isobutyl benzoate, pentyl benzoate, isopentyl benzoate, methyl toluate, ethyl toluate, methyl anisate, ethyl anisate, dimethyl phthalate, diethyl phthalate, phenoxyethyl acetate, and phenoxyethyl butyrate.

Examples of the aromatic hydrocarbon-based solvents include toluene, xylene, cyclohexylbenzene, trimethylbenzene, tetramethylbenzene, diisopropylbenzene, triisopropylbenzene, methylnaphthalene, ethylnaphthalene, isopropylnaphthalene, diisopropylnaphthalene, ethylbiphenyl, isopropylbiphenyl, butylbiphenyl, diisopropylbiphenyl, triisopropylbiphenyl, tetralin, 1,1-diphenylethane, 1,1-diphenylpropane, 1,1-diphenylbutane, 1,1-diphenylpentane, and 1,1-diphenylhexane.

Examples of the amide-based solvents include N,N-dimethylformamide and N,N-dimethylacetamide.

In addition, dimethyl sulfoxide etc. may be used.

In particular, the solvent is preferably an aromatic ester or an aromatic ether.

One of these solvents may be used alone, or a combination of two or more at any ratio may be used.

The hole injection layer-forming composition may contain the hole transport material at any concentration so long as the effects of the invention are not significantly impaired. From the viewpoint of the uniformity of thickness of the film, the concentration of the hole transport material in the hole injection layer-forming composition is preferably 0.01% by weight or more, more preferably 0.1% by weight or more, and still more preferably 0.5% by weight or more. The concentration of the hole transport material in the hole injection layer-forming composition is preferably 70% by weight or less, more preferably 60% by weight or less, and still more preferably 50% by weight or less. It is preferable that the concentration is small so that unevenness in the thickness is unlikely to occur. It is preferable that the concentration is large so that defects are unlikely to be formed in the hole injection layer formed.

### <Formation of Hole Injection Layer by Wet Deposition Method>

When the hole injection layer 3 is formed by a wet deposition method, the hole injection layer 3 is generally formed by mixing the materials forming the hole injection layer 3 and an appropriate solvent (a hole injection layer-forming solvent) to prepare a film-forming composition (hole injection layer-forming composition), applying the composition for forming the hole injection layer 3 to a layer (generally the anode 2) corresponding to a layer disposed below the hole injection layer using an appropriate method to thereby form a film, and then drying the film.

### <Formation of Hole Injection Layer 3 by Vacuum Vapor Deposition Method>

When the hole injection layer 3 is formed by a vacuum vapor deposition method, the hole transport layer 3 can be formed, for example, as follows. One or two or more materials forming the hole injection layer 3 (the hole transport material, the electron accepting compound, etc.) are placed in a crucible disposed in a vacuum chamber (when two or more materials are used, they are placed in different crucibles), and the vacuum chamber is evacuated using an appropriate vacuum pump to about 10⁻⁴ Pa. Then the crucible is heated (when two or more materials are used, the respective crucibles are heated) to evaporate the material while the evaporation amount is controlled (when two or more materials are used, the materials are evaporated while their evaporation amounts are each independently controlled), and the hole injection layer 3 is thereby formed on the anode 2 on the substrate 1 disposed so as to face the crucible. When two or more materials are used, a mixture of these materials may be placed in a crucible, heated, and evaporated to thereby form the hole injection layer 3.

No particular limitation is imposed on the degree of vacuum during vapor deposition so long as the effects of the invention are not significantly impaired. The degree of vacuum during vapor deposition is generally 0.1×10⁻⁶ Torr (0.13×10⁻⁴ Pa) or higher and 9.0×10⁻⁶ Torr (12.0×⁻⁴ Pa) or lower. No particular limitation is imposed on the evaporation rate so long as the effects of the invention are not significantly impaired. The evaporation rate is generally 0.1 Å/second or more and 5.0 Å/second or less. No particular limitation is imposed on the film deposition temperature during vapor deposition so long as the effects of the invention are not significantly impaired. The film deposition temperature during vapor deposition is preferably 10° C. or higher and 50° C. or lower.

### [Hole Transport Layer]

The hole transport layer 4 is a layer for transportation from the anode 2 to the light-emitting layer 5. The hole transport layer 4 is not an essential layer of the organic electroluminescent element of the invention. When the hole transport layer 4 is provided, the hole transport layer 4 is generally disposed on the hole injection layer 3 when the hole injection layer 3 is present and on the anode 2 when the hole injection layer 3 is not present.

No particular limitation is imposed on the method for forming the hole transport layer 4, and a vacuum vapor deposition method or a wet deposition method may be used. From the viewpoint of reducing dark spots, it is preferable to form the hole transport layer 4 using a wet deposition method.

A material for forming the hole transport layer 4 is preferably a material having high hole transportability and capable of transporting injected holes efficiently. Therefore, it is preferable that the material forming the hole transport layer 4 has a small ionization potential, is highly transparent to visible light, has large hole mobility, and is highly stable and that impurities serving as traps are unlikely to be mixed into the material during production and use. In many cases, the hole transport layer 4 is in contact with the light-emitting layer 5. It is therefore preferable that the hole transport layer 4 does not attenuate the light emitted from the light-emitting layer 5 and does not allow exciplexes to be formed between the hole transport layer 4 and the light-emitting layer 5 so that the efficiency is not reduced.

The material of the hole transport layer 4 may be any material conventionally used as the material forming the hole transport layer 4. Examples of the material of the hole transport layer 4 include arylamine derivatives, fluorene derivatives, spiro derivatives, carbazole derivatives, pyridine derivatives, pyrazine derivatives, pyrimidine derivatives, triazine derivatives, quinoline derivatives, phenanthroline derivatives, phthalocyanine derivatives, porphyrin derivatives, silole derivatives, oligothiophene derivatives, polycyclic aromatic ring derivatives, and metal complexes.

Examples of the material of the hole transport layer 4 include polyvinylcarbazole derivatives, polyarylamine derivatives, polyvinyltriphenylamine derivatives, polyfluorene derivatives, polyarylene derivatives, polyarylene ether sulfone derivatives containing tetraphenylbenzidine, polyarylenevinylene derivatives, polysiloxane derivatives, polythiophene derivatives, and poly(p-phenylenevinylene) derivatives. These may each be an alternating copolymer, a random polymers, a block polymer, of a graft copolymer. Moreover, polymers having a branched main chain with three or more terminal ends and so-called dendrimers may also be used.

In particular, the material of the hole transport layer 4 is preferably a polyarylamine derivative or a polyarylene derivative.

Specific examples of the polyarylamine derivative and the polyarylene derivative include those described in JP2008-98619A.

The polyarylamine derivative used is preferably the high-molecular weight aromatic tertiary amine compound described above.

When the hole transport layer 4 is formed using a wet deposition method, a hole transport layer-forming composition is prepared in the same manner as for the hole injection layer 3, and a film is formed by wet deposition and then dried.

The hole transport layer-forming composition contains a solvent in addition to the hole transport material described above. The solvent used is the same as that used for the hole injection layer-forming composition. The film deposition conditions, the drying conditions, etc. are also the same as those for forming the hole injection layer 3.

When the hole transport layer-forming composition is the composition of the invention, the solvent is the aromatic organic solvent in the invention.

When the hole transport layer 4 is formed by a vacuum vapor deposition method, the film deposition conditions etc. are also the same as those for the formation of the hole injection layer 3.

The thickness of the hole transport layer 4 is determined in consideration of soaking of a low-molecular weight material in the light-emitting layer and swelling of the hole transport material and is generally 5 nm or more and preferably 10 nm or more and is generally 300 nm or less and preferably 200 nm or less.

### [Light-Emitting Layer]

The light-emitting layer 5 is a layer serving as a main light-emitting source that is excited by recombination of holes injected from the anode 2 and electrons injected from the cathode 9 between the electrodes to which an electric field is applied. The light-emitting layer 5 is generally formed on the hole transport layer 4 when the hole transport layer 4 is present, on the hole injection layer 3 when the hole transport layer 4 is not present but the hole injection layer 3 is present, and on the anode 2 when both the hole transport layer 4 and the hole injection layer 3 are not present.

### <Light-Emitting Layer Material>

A light-emitting layer material generally contains a light-emitting material and a charge transport material serving as a host.

### <Light-Emitting Material>

No particular limitation is imposed on the light-emitting material. The light-emitting material used is any well-known material generally used as a light-emitting material of an organic electroluminescent element, and a material that emits light with a desired wavelength and has good luminous efficiency may be used. The light-emitting material may be a fluorescent light-emitting material or may be a phosphorescent light-emitting material. From the viewpoint of internal quantum efficiency, a phosphorescent light-emitting material is preferred. More preferably, a red light-emitting material and a green light-emitting material are phosphorescent light-emitting materials, and a blue light-emitting material is a fluorescent light-emitting material.

When the composition of the invention is a light-emitting layer-forming composition, it is preferable to use a phosphorescent light-emitting material, a fluorescent light-emitting material, and a charge transport material described below.

### <Phosphorescent Light-Emitting Material>

The phosphorescent light-emitting material is a material that emits light from an excited triplet state. Typical examples thereof include metal complex compounds containing Ir, Pt, Eu, etc., and it is preferable that the structure of the material contains a metal complex.

Among the metal complexes are phosphorescent light-emitting organic metal complexes that emit light through a triplet state, and examples thereof include Werner-type complex and organometallic complex compounds that contain, as the central metal, a metal selected from groups 7 to 11 of the long-form periodic table (hereinafter, the term “periodic table” refers to the long-form periodic table unless otherwise specified). Examples of such a phosphorescent light-emitting material include phosphorescent light-emitting materials described in WO2014/024889, WO2015-087961, WO2016/194784, and JP2014-074000A. The phosphorescent light-emitting material is preferably a compound represented by formula (201) below or a compound represented by formula (205) below and more preferably the compound represented by formula (201) below.

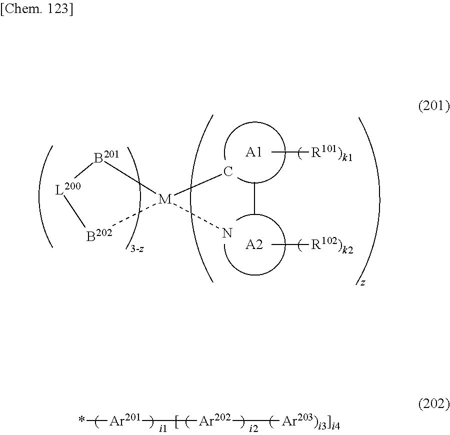

In formula (201), ring A1 represents an aromatic hydrocarbon ring structure optionally having a substituent or an aromatic heterocyclic structure optionally having a substituent.

Ring A2 represents an aromatic heterocyclic structure optionally having a substituent.

R¹⁰¹ and R¹⁰² are each independently a structure represented by formula (202), and * represents a position of bonding to ring A1 or A2. R¹⁰¹ and R¹⁰² may be the same or different. When a plurality of R¹⁰¹'s are present, they may be the same or different. When a plurality of R¹⁰²'s are present, they may be the same or different.

Ar²⁰¹ and Ar²⁰³ each independently represent an aromatic hydrocarbon ring structure optionally having a substituent or an aromatic heterocyclic structure optionally having a substituent.

Ar²⁰² represents an aromatic hydrocarbon ring structure optionally having a substituent, an aromatic heterocyclic structure optionally having a substituent, or an aliphatic hydrocarbon structure optionally having a substituent.

Substituents bonded to ring A1, substituents bonded to ring A2, or a substituent bonded to ring A1 and a substituent bonded to ring A2 may be bonded together to form a ring.

B²⁰¹-L²⁰⁰-B²⁰² represents an anionic bidentate ligand. B²⁰¹ and B²⁰² each independently represent a carbon atom, an oxygen atom, or a nitrogen atom, and these atoms may each be an atom included in a ring. L²⁰⁰ represents a single bond or an atomic group that, together with B²⁰¹ and B²⁰², forms the bidentate ligand. When a plurality of B²⁰¹-L²⁰⁰-B²⁰² ligands are present, they may be the same or different.

In formulas (201) and (202),

i1 and i2 each independently represent an integer of 0 or more and 12 or less.

i3 represents an integer of 0 or more, and its upper limit is set to the number of substituents that Ar²⁰² can have.

i4 represents an integer of 0 or more, and its upper limit is set to the number of substituents that Ar²⁰¹ can have.

k1 and k2 are each independently an integer of 0 or more, and their upper limits are set to the numbers of substituents that rings A1 and A2 can have.

z represents an integer of 1 to 3.

### (Substituent)

Preferably, the substituent is a group selected from the following substituent group S, unless otherwise specified.

### <Substituent Group S>

Alkyl groups, preferably alkyl groups having 1 to 20 carbon atoms, more preferably alkyl groups having 1 to 12 carbon atoms, still more preferably alkyl group having 1 to 8 carbon atoms, and particularly preferably alkyl groups having 1 to 6 carbon atoms.
Alkoxy groups, preferably alkoxy groups having 1 to 20 carbon atoms, more preferably alkoxy groups having 1 to 12 carbon atoms, and still more preferably alkoxy groups having 1 to 6 carbon atoms.
Aryloxy groups, preferably aryloxy groups having 6 to 20 carbon atoms, more preferably aryloxy groups having 6 to 14 carbon atoms, still more preferably aryloxy groups having 6 to 12 carbon atoms, and particularly preferably aryloxy groups having 6 carbon atoms.
Heteroaryloxy groups, preferably heteroaryloxy groups having 3 to 20 carbon atoms, and more preferably heteroaryloxy groups having 3 to 12 carbon atoms.
Alkylamino groups, preferably alkylamino groups having 1 to 20 carbon atoms, and more preferably alkylamino groups having 1 to 12 carbon atoms.
Arylamino groups, preferably arylamino groups having 6 to 36 carbon atoms, and more preferably arylamino groups having 6 to 24 carbon atoms.
Aralkyl groups, preferably aralkyl groups having 7 to 40 carbon atoms, more preferably aralkyl groups having 7 to 18 carbon atoms, and still more preferably aralkyl groups having 7 to 12 carbon atoms.
Heteroaralkyl groups, preferably heteroaralkyl groups having 7 to 40 carbon atoms, and more preferably heteroaralkyl groups having 7 to 18 carbon atoms.
Alkenyl groups, preferably alkenyl groups having 2 to 20 carbon atoms, more preferably alkenyl groups having 2 to 12 carbon atoms, still more preferably alkenyl groups having 2 to 8 carbon atoms, and particularly preferably alkenyl groups having 2 to 6 carbon atoms.
Alkynyl groups, preferably alkynyl groups having 2 to 20 carbon atoms, and more preferably alkynyl groups having 2 to 12 carbon atoms.
Aryl groups, preferably aryl groups having 6 to 30 carbon atoms, more preferably aryl groups having 6 to 24 carbon atoms, still more preferably aryl groups having 6 to 18 carbon atoms, and particularly preferably aryl groups having 6 to 14 carbon atoms.
Heteroaryl groups, preferably heteroaryl groups having 3 to 30 carbon atoms, more preferably heteroaryl groups having 3 to 24 carbon atoms, still more preferably heteroaryl groups having 3 to 18 carbon atoms, and particularly preferably heteroaryl groups having 3 to 14 carbon atoms.
Alkylsilyl groups, preferably alkylsilyl groups each having an alkyl group having 1 to 20 carbon atoms, and more preferably alkylsilyl groups each having an alkyl group having 1 to 12 carbon atoms.
Arylsilyl groups, preferably arylsilyl groups each having an aryl group having 6 to 20 carbon atoms, and more preferably arylsilyl groups each having an aryl group having 6 to 14 carbon atoms.
Alkylcarbonyl groups and preferably alkylcarbonyl groups having 2 to 20 carbon atoms.
Arylcarbonyl groups and preferably arylcarbonyl groups having 7 to 20 carbon atoms.

In the above groups, at least one hydrogen atom may be substituted with a fluorine atom, or at least one hydrogen atom may be substituted with a deuterium atom.

The aryl is an aromatic hydrocarbon ring, and the heteroaryl is an aromatic heterocycle, unless otherwise specified.
A hydrogen atom, a deuterium atom, a fluorine atom, a cyano group, and —SF₅.

The substituent selected from the substituent group S is preferably an alkyl group, an alkoxy group, an aryloxy group, an arylamino group, an aralkyl group, an alkenyl group, an aryl group, a heteroaryl group, an alkylsilyl group, an arylsilyl group, one of these groups in which at least one hydrogen atom is substituted with a fluorine atom, a fluorine atom, a cyano group, or —SF₅,
more preferably an alkyl group, an arylamino group, an aralkyl group, an alkenyl group, an aryl group, a heteroaryl group, one of these groups in which at least one hydrogen atom is substituted with a fluorine atom, a fluorine atom, a cyano group, or —SF₅,
still more preferably an alkyl group, an alkoxy group, an aryloxy group, an arylamino group, an aralkyl group, an alkenyl group, an aryl group, a heteroaryl group, an alkylsilyl group, or an arylsilyl group,
particularly preferably an alkyl group, an arylamino group, an aralkyl group, an alkenyl group, an aryl group, or a heteroaryl group, and
most preferably an alkyl group, an arylamino group, an aralkyl group, an aryl group, or a heteroaryl group.

The groups in the substituent group S may each optionally have a substituent selected from the substituent group S as a substituent. Preferred groups, more preferred groups, still more preferred groups, particularly preferred groups, and most preferred groups used as the optional substituents are the same as the preferred groups in the substituent group S.

### (Ring A1)

Ring A1 represents an aromatic hydrocarbon ring structure optionally having a substituent or an aromatic heterocyclic structure optionally having a substituent.

The aromatic hydrocarbon ring is preferably an aromatic hydrocarbon ring having 6 to 30 carbon atoms. Specifically, the aromatic hydrocarbon ring is preferably a benzene ring, a naphthalene ring, an anthracene ring, a triphenylyl ring, an acenaphthene ring, a fluoranthene ring, or a fluorene ring.

The aromatic heterocycle is preferably an aromatic heterocycle having 3 to 30 carbon atoms and containing, as a heteroatom, a nitrogen atom, an oxygen atom, or a sulfur atom. The aromatic heterocycle is more preferably a furan ring, a benzofuran ring, a thiophene ring, or a benzothiophene ring.

Ring A1 is more preferably a benzene ring, a naphthalene ring, or a fluorene ring, particularly preferably a benzene ring or a fluorene ring, and most preferably a benzene ring.

### (Ring A2)

Ring A2 represents an aromatic heterocyclic structure optionally having a substituent.

Preferably, the aromatic heterocycle is an aromatic heterocycle having 3 to 30 carbon atoms and containing, as a heteroatom, a nitrogen atom, an oxygen atom, or a sulfur atom. Specific examples of the aromatic heterocycle include a pyridine ring, a pyrimidine ring, a pyrazine ring, a triazine ring, an imidazole ring, an oxazole ring, a thiazole ring, a benzothiazole ring, a benzoxazole ring, a benzimidazole ring, a quinoline ring, an isoquinoline ring, a quinoxaline ring, a quinazoline ring, a naphthyridine ring, and a phenanthridine ring. The aromatic heterocycle is preferably a pyridine ring, a pyrazine ring, a pyrimidine ring, an imidazole ring, a benzothiazole ring, a benzoxazole ring, a quinoline ring, an isoquinoline ring, a quinoxaline ring, or a quinazoline ring, more preferably a pyridine ring, an imidazole ring, a benzothiazole ring, a quinoline ring, an isoquinoline ring, a quinoxaline ring, or a quinazoline ring, and most preferably a pyridine ring, an imidazole ring, a benzothiazole ring, a quinoline ring, a quinoxaline ring, or a quinazoline ring.

### (Combination of Ring A1 and Ring A2)

Preferred examples of the combination of ring A1 and ring A2 (denoted as ring A1-ring A2) include (benzene ring-pyridine ring), (benzene ring-quinoline ring), (benzene ring-quinoxaline ring), (benzene ring-quinazoline ring), (benzene ring-benzothiazole ring), (benzene ring-imidazole ring), (benzene ring-pyrrole ring), (benzene ring-diazole ring), and (benzene ring-thiophene ring).

### (Substituents on Ring A1 and Ring A2)

Optional substituents on rings A1 and A2 can be freely selected but are each preferably one or a plurality of substituents selected from the substituent group S.

(Ar²⁰¹, Ar²⁰², and Ar²⁰³)

Ar²⁰¹ and Ar²⁰³ each independently represent an aromatic hydrocarbon ring structure optionally having a substituent or an aromatic heterocyclic structure optionally having a substituent.

Ar²⁰² represents an aromatic hydrocarbon ring structure optionally having a substituent, an aromatic heterocyclic structure optionally having a substituent, or an aliphatic hydrocarbon structure optionally having a substituent.

When any of Ar²⁰¹, Ar²⁰², and Ar²⁰³ is an aromatic hydrocarbon ring structure optionally having a substituent, the aromatic hydrocarbon ring structure is preferably an aromatic hydrocarbon ring having 6 to 30 carbon atoms. Specifically, the aromatic hydrocarbon ring structure is preferably a benzene ring, a naphthalene ring, an anthracene ring, a triphenylyl ring, an acenaphthene ring, a fluoranthene ring, or a fluorene ring, more preferably a benzene ring, a naphthalene ring, or a fluorene ring, and most preferably a benzene ring.

When any of Ar²⁰¹ and Ar²⁰² is a benzene ring optionally having a substituent, it is preferable that at least one benzene ring is bonded to adjacent structures at its ortho or meta positions, and it is more preferable that at least one benzene ring is bonded to adjacent structures at its meta positions.

When any of Ar²⁰¹, Ar²⁰², and Ar²⁰³ is a fluorene ring optionally having a substituent, it is preferable that the fluorene ring has substituents at the 9- and 9′-positions or bonded to adjacent structures at the 9- and 9′-positions.

When any of Ar²⁰¹, Ar²⁰², and Ar²⁰³ is an aromatic heterocyclic structure optionally having a substituent, the aromatic heterocyclic structure is preferably an aromatic heterocycle having 3 to 30 carbon atoms and containing, as a heteroatom, a nitrogen atom, an oxygen atom, or a sulfur atom. Specific examples of the aromatic heterocyclic structure include a pyridine ring, a pyrimidine ring, a pyrazine ring, a triazine ring, an imidazole ring, an oxazole ring, a thiazole ring, a benzothiazole ring, a benzoxazole ring, a benzimidazole ring, a quinoline ring, an isoquinoline ring, a quinoxaline ring, a quinazoline ring, a naphthyridine ring, a phenanthridine ring, a carbazole ring, a dibenzofuran ring, and a dibenzothiophene ring. The aromatic heterocyclic structure is preferably a pyridine ring, a pyrimidine ring, a triazine ring, a carbazole ring, a dibenzofuran ring, or a dibenzothiophene ring.

When any of Ar²⁰¹, Ar²⁰², and Ar²⁰³ is a carbazole ring optionally having a substituent, the carbazole ring has a substituent at the N-position or bonded to an adjacent structure at the N-position.

When Ar²⁰² is an aliphatic hydrocarbon structure optionally having a substituent, the aliphatic hydrocarbon structure is a linear, branched, or cyclic structure-containing aliphatic hydrocarbon structure, and the number of carbon atoms in the aliphatic hydrocarbon structure is preferably 1 or more and 24 or less, more preferably 1 or more and 12 or less, and still more preferably 1 or more and 8 or less.

(i1, i2, i3, i4, k1, and k2)

i1 and i2 each independently represent an integer of 0 to 12 and is preferably 1 to 12, more preferably 1 to 8, and still more preferably 1 to 6. When they are within the above range, the solubility and charge transportability are expected to be improved.

i3 represents preferably an integer of 0 to 5 and is more preferably 0 to 2 and still more preferably 0 or 1.

i4 represents preferably an integer of 0 to 2 and is more preferably is 0 or 1.

k1 and k2 each independently represent preferably an integer of 0 to 3 and is more preferably 1 to 3, still more preferably 1 or 2, and particularly preferably 1.

(Preferred Substituents on Ar²⁰¹, Ar²⁰², and Ar²⁰³)

The optional substituents on Ar²⁰¹, Ar²⁰², and Ar²⁰³ can be freely selected but are each preferably one or a plurality of substituents selected from the substituent group S. Preferred groups are also selected from the substituent group S. More preferably, Ar²⁰¹, Ar²⁰², and Ar²⁰³ are unsubstituted (the substituents are each a hydrogen atom) or each substituted with an alkyl group or an aryl group. Particularly preferably, they are unsubstituted (the substituents are each a hydrogen atom) or each substituted with an alkyl group. Most preferably, they are unsubstituted (the substituents are each a hydrogen atom) or each substituted with a tertiary butyl group. It is preferable that, when Ar²⁰³ is present, Ar²⁰³ is substituted with a tertiary butyl group, that, when Ar²⁰³ is not present, Ar²⁰² is substituted with a tertiary butyl group, and that, when Ar²⁰² and Ar²⁰³ are not present, Ar²⁰¹ is substituted with a tertiary butyl group.

### (Preferred Modes of Compound Represented by Formula (201))

Preferably, the compound represented by formula (201) above is a compound satisfying at least one of the following (I) to (IV).

### (I) Phenylene Linked Type

The structure represented by formula (202) is preferably a structure having a group including benzene rings linked together, i.e., a benzene ring structure in which i1 is 1 to 6 and at least one of the benzene rings is bonded to adjacent structures at its ortho or metal positions.

With this structure, the solubility is expected to be improved, and the charge transportability is also expected to be improved.

(II) (Phenylene)-aralkyl(alkyl)

The compound represented by formula (201) has a structure in which an aromatic hydrocarbon or aromatic heterocyclic group to which an alkyl group or an aralkyl group is bonded is bonded to ring A1 or ring A2. Specifically, this is a structure in which Ar²⁰¹ is an aromatic hydrocarbon structure or an aromatic heterocyclic structure, in which i1 is 1 to 6, in which Ar²⁰² is an aliphatic hydrocarbon structure, in which i2 is 1 to 12 and preferably 3 to 8, in which Ar²⁰³ is a benzene ring structure, and in which i3 is 0 or 1. Preferably, in this structure, Ar²⁰¹ is an aromatic hydrocarbon structure. More preferably, Ar²⁰¹ includes 1 to 5 benzene rings linked together. Still more preferably, the number of benzene rings is 1.

With this structure, the solubility is expected to be improved, and the charge transportability is also expected to be improved.

### (III) Dendron

The compound represented by formula (201) has a structure in which a dendron is bonded to ring A1 or ring A2. For example, Ar²⁰¹ and Ar²⁰² each have a benzene ring structure, and Ar²⁰³ has a biphenyl or terphenyl structure. i1 and i2 are each 1 to 6. i3 is 2, and j is 2.

With this structure, the solubility is expected to be improved, and the charge transportability is also expected to be improved.

B²⁰¹-L²⁰⁰-B²⁰² (IV)

The structure represented by B²⁰¹-L²⁰⁰-B²⁰² is preferably a structure represented by the following formula (203) or (204).

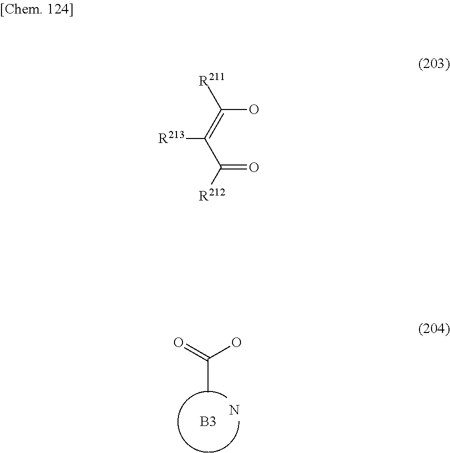

In formula (203), R²¹¹, R²¹², and R²¹³ each independently represent a substituent.

In formula (204), ring B3 represents an aromatic heterocyclic structure containing a nitrogen atom and optionally having a substituent. Ring B3 is preferably a pyridine ring.

### (Preferred Phosphorescent Light-Emitting Material)

No particular limitation is imposed on the phosphorescent light-emitting material represented by formula (201) above. Preferred examples thereof include the following materials.

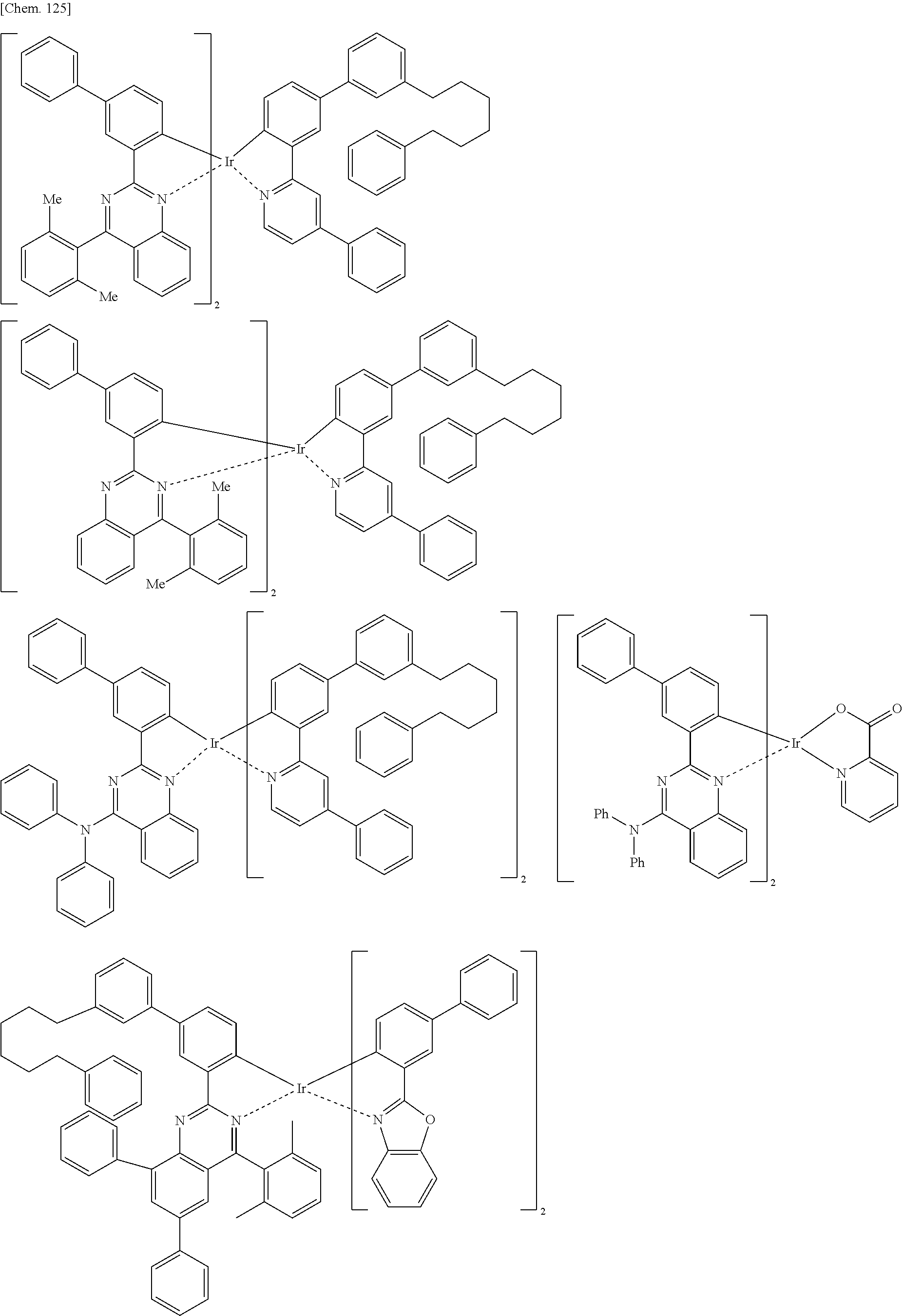

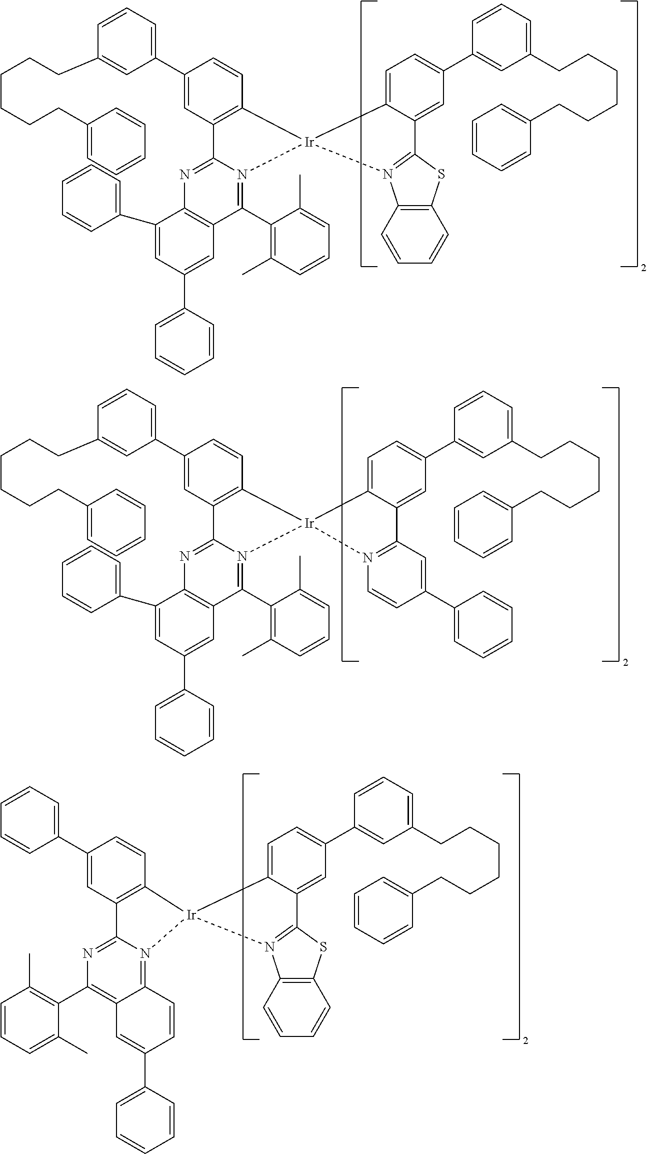

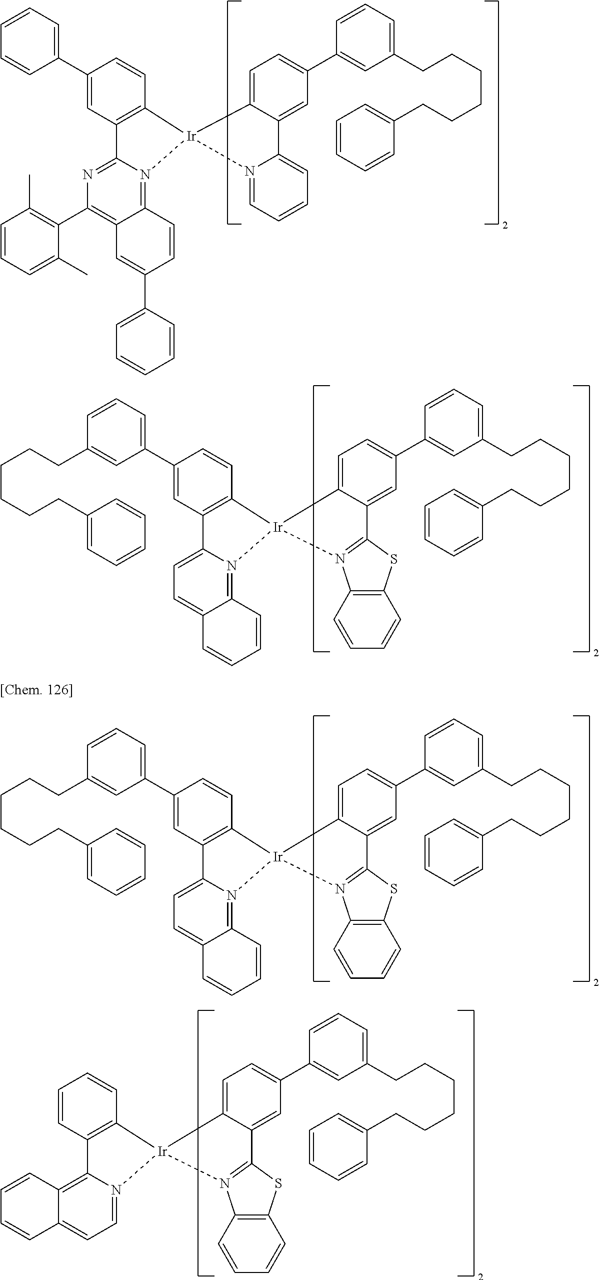

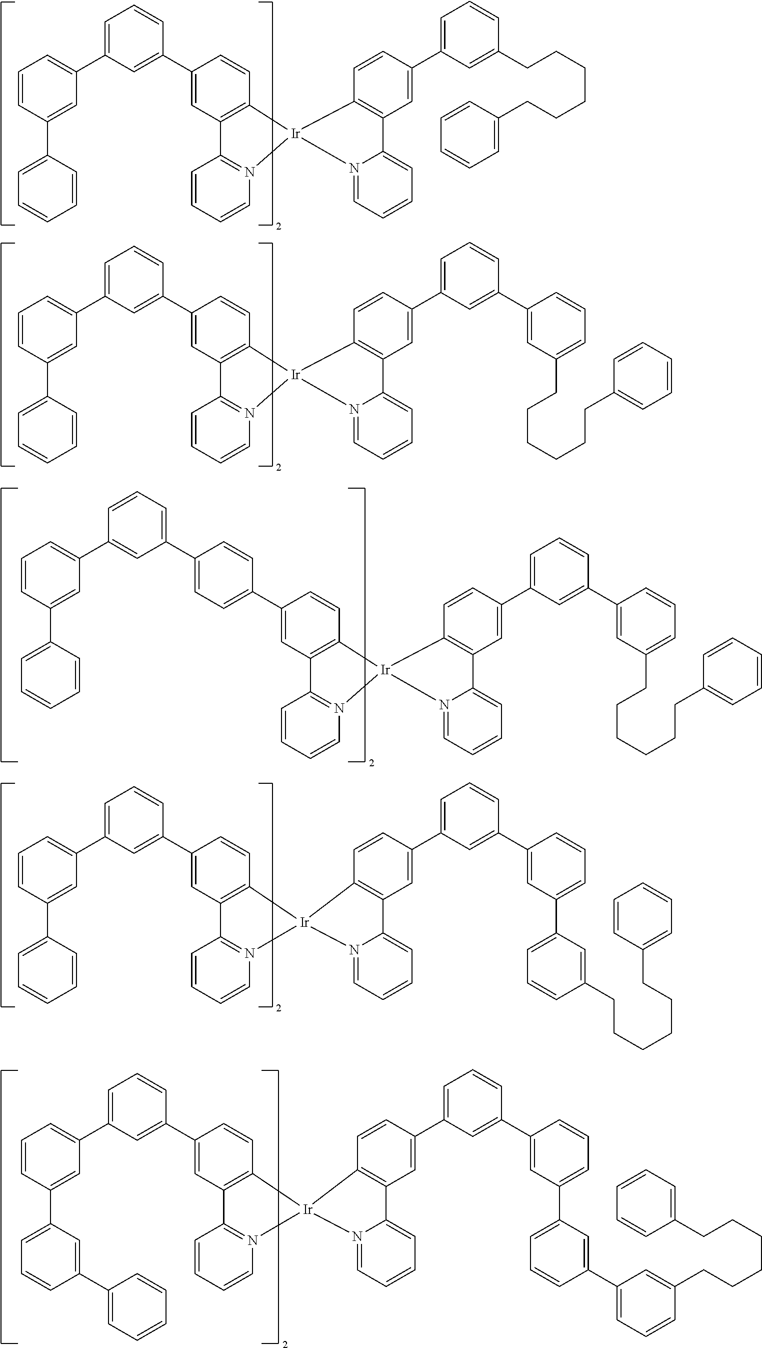

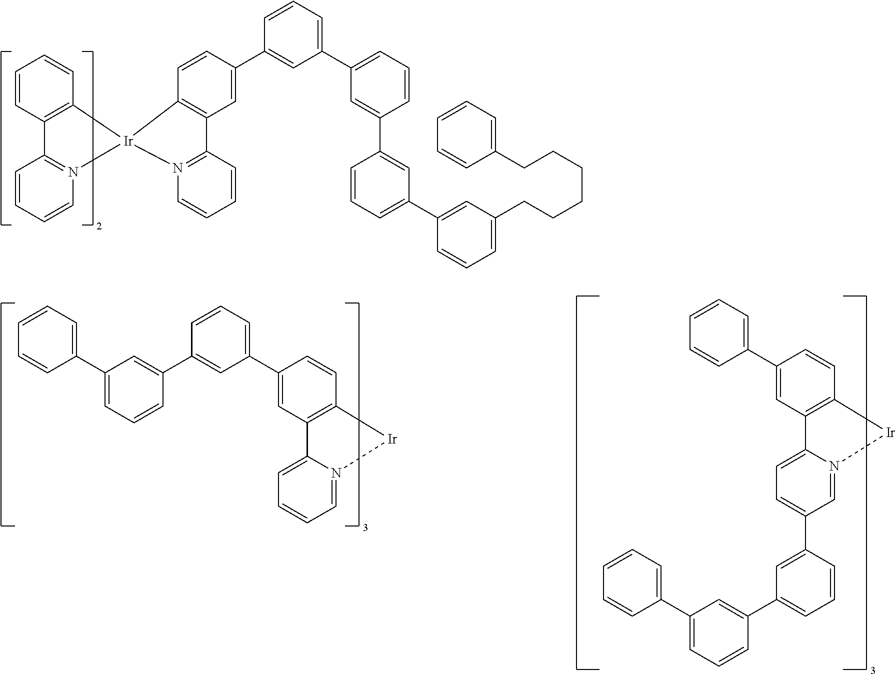

A phosphorescent light-emitting material represented by the following formula (205) is also preferred.

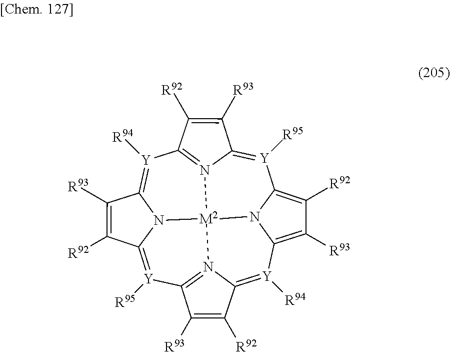

[In formula (205), M² represents a metal, and T represents a carbon atom or a nitrogen atom. R⁹² to R⁹⁵ each independently represent a substituent. When T is a nitrogen atom, R⁹⁴ and R⁹⁵ are not present.]

Specific examples of M² in formula (205) include metals selected from 7 to 11 groups in the periodic table. In particular, ruthenium, rhodium, palladium, silver, rhenium, osmium, iridium, platinum, and gold are preferred, and divalent metals such as platinum and palladium are particularly preferred.

In formula (205), R⁹² and R⁹³ each independently represent a hydrogen atom, a halogen atom, an alkyl group, an aralkyl group, an alkenyl group, a cyano group, an amino group, an acyl group, an alkoxycarbonyl group, a carboxyl group, an alkoxy group, an alkylamino group, an aralkylamino group, a haloalkyl group, a hydroxy group, an aryloxy group, an aromatic hydrocarbon group, or an aromatic heterocyclic group.

When T is a carbon atom, R⁹⁴ and R⁹⁵ each independently represent a substituent selected from the examples of R⁹² and R⁹³. When T is a nitrogen atom, no R⁹⁴ or R⁹⁵ is bonded directly to the T. R⁹² to R⁹⁵ may each optionally have a substituent. The substituent may be any of the above described substituents. Two or more selected from R⁹² to R⁹⁵ may be linked together to form a ring.

### (Molecular Weight)

The molecular weight of the phosphorescent light-emitting material is preferably 5000 or less, more preferably 4000 or less, and particularly preferably 3000 or less. The molecular weight of the phosphorescent light-emitting material is preferably 800 or more, more preferably 1000 or more, and still more preferably 1200 or more. When the molecular weight is within the above range, the phosphorescent light-emitting material are not aggregated, and the phosphorescent light-emitting material is mixed uniformly with the charge transport material, so that a light-emitting layer with high luminous efficiency may be obtained.

It is preferable that the molecular weight of the phosphorescent light-emitting material is high because the Tg, melting point, decomposition temperature, etc. are high and the phosphorescent light-emitting material and a light-emitting layer to be formed have high heat resistance and because deterioration in the quality of the film due to the generation of gas, recrystallization, and migration of molecules and an increase in the concentration of impurities caused by thermal decomposition of the material are unlikely to occur. However, it is preferable that the molecular weight of the phosphorescent light-emitting material is small because the organic compound can be easily purified.

### <Charge Transport Material>

The charge transport material used for the light-emitting layer is a material having a skeleton with good charge transportability and is selected preferably from electron transport materials, hole transport materials, and bipolar materials that can transport both electrons and holes.

Specific examples of the skeleton with good charge transportability include an aromatic structure, an aromatic amine structure, a triarylamine structure, a dibenzofuran structure, a naphthalene structure, a phenanthrene structure, a phthalocyanine structure, a porphyrin structure, a thiophene structure, a benzylphenyl structure, a fluorene structure, a quinacridone structure, a triphenylene structure, a carbazole structure, a pyrene structure, an anthracene structure, a phenanthroline structure, a quinoline structure, a pyridine structure, a pyrimidine structure, a triazine structure, an oxadiazole structure, and an imidazole structure.

The electron transport material is more preferably a compound having a pyridine structure, a pyrimidine structure, or a triazine structure and still more preferably a compound having a pyrimidine structure or a triazine structure because such a material has good electron transportability and has a relatively stable structure.

The hole transport material is a compound having a structure with good hole transportability. Among the above-described central skeletons with good charge transportability, a carbazole structure, a dibenzofuran structure, a triarylamine structure, a naphthalene structure, a phenanthrene structure or a pyrene structure is preferred as the structure with good hole transportability, and a carbazole structure, a dibenzofuran structure, or a triarylamine structure is more preferred.

The charge transport material used for the light-emitting layer has preferably a condensed ring structure including 3 or more rings and is more preferably a compound having two or more condensed ring structures each including 3 or more rings or a compound having at least one condensed ring including 5 or more rings. With these compounds, the rigidity of the molecule increases, and the effect of reducing the extent of molecular motion in response to heat can be easily obtained. Moreover, from the viewpoint of charge transportability and the durability of the material, it is preferable that the condensed ring including 3 or more rings and the condensed ring including 5 or more rings each include an aromatic hydrocarbon ring or an aromatic heterocycle.

Specific examples of the condensed ring structure including 3 or more rings include an anthracene structure, a phenanthrene structure, a pyrene structure, a chrysene structure, a naphthacene structure, a triphenylene structure, a fluorene structure, a benzofluorene structure, an indenofluorene structure, an indolofluorene structure, a carbazole structure, an indenocarbazole structure, an indolocarbazole structure, a dibenzofuran structure, and a dibenzothiophene structure. From the viewpoint of the charge transportability and solubility, it is preferable that the condensed ring structure is at least one selected from the group consisting of a phenanthrene structure, a fluorene structure, an indenofluorene structure, a carbazole structure, an indenocarbazole structure, an indolocarbazole structure, a dibenzofuran structure, and a dibenzothiophene structure. From the viewpoint of durability against electric charges, a carbazole structure or an indolocarbazole structure is more preferred.

In the present invention, from the viewpoint of the durability of the organic electroluminescent element against electric charges, it is preferable that at least one charge transport material in the light-emitting layer is a material having a pyrimidine skeleton or a triazine skeleton.

From the viewpoint of obtaining good flexibility, the charge transport material in the light-emitting layer is preferably a high-molecular weight material. A light-emitting layer formed using a material having high flexibility is preferred as a light-emitting layer of an organic electroluminescent element formed on a flexible substrate. When the charge transport material contained in the light-emitting layer is a high-molecular weight material, its molecular weight is preferably 5,000 or more and 1,000,000 or less, more preferably 10,000 or more and 500,000 or less, and still more preferably 10,000 or more and 100,000 or less.

From the viewpoint of the ease of synthesis and purification of the charge transport material in the light-emitting layer, the ease of designing its electron transport performance and hole transport performance, and the ease of adjusting the viscosity when it is dissolved in a solvent, the charge transport material is preferably a low-molecular weight material. When the charge transport material contained in the light-emitting layer is a low-molecular weight material, its molecular weight is preferably 5,000 or less, still more preferably 4,000 or less, particularly preferably 3,000 or less, and most preferably 2,000 or less and is preferably 300 or more, more preferably 350 or more, and still more preferably 400 or more.

### <Fluorescent Light-Emitting Material>

No particular limitation is imposed on the fluorescent light-emitting material, but the fluorescent light-emitting material is preferably a compound represented by the following formula (211).

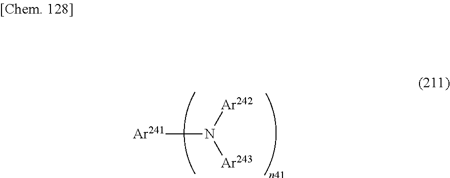

In formula (211) above, Ar²⁴¹ represents a condensed aromatic hydrocarbon ring structure optionally having a substituent. Ar²⁴² and Ar²⁴³ each independently represent an alkyl group optionally having a substituent, an aromatic hydrocarbon group optionally having a substituent, an aromatic heterocyclic group optionally having a substituent, or a group including any of these groups bonded together. n41 is an integer of 1 to 4.

Ar²⁴¹ represents preferably a condensed aromatic hydrocarbon ring structure having 10 to 30 carbon atoms. Specific examples of the ring structure include naphthalene, acenaphthene, fluorene, anthracene, phenanthrene, fluoranthene, pyrene, tetracene, chrysene, and perylene.

Ar²⁴¹ is more preferably a condensed aromatic hydrocarbon ring structure having 12 to 20 carbon atoms, and specific examples of the ring structure include acenaphthene, fluorene, anthracene, phenanthrene, fluoranthene, pyrene, tetracene, chrysene, and perylene.

Ar²⁴¹ is still more preferably a condensed aromatic hydrocarbon ring structure having 16 to 18 carbon atoms, and specific examples of the ring structure include fluoranthene, pyrene, and chrysene.

n41 is 1 to 4, preferably 1 to 3, still more preferably 1 to 2, and most preferably 2.

The alkyl groups represented by Ar²⁴² and Ar²⁴³ are each preferably an alkyl group having 1 to 12 carbon atoms and more preferably an alkyl group having 1 to 6 carbon atoms.

The aromatic hydrocarbon groups represented by Ar²⁴² and Ar²⁴³ are each preferably an aromatic hydrocarbon group having 6 to 30 carbon atoms, more preferably an aromatic hydrocarbon group having 6 to 24 carbon atoms, and most preferably a phenyl group or a naphthyl group.

The aromatic heterocyclic groups represented by Ar²⁴² and Ar²⁴³ are each preferably an aromatic heterocyclic group having 3 to 30 carbon atoms and more preferably an aromatic hydrocarbon group having 5 to 24 carbon atoms group. Specifically, each aromatic heterocyclic group is preferably a carbazolyl group, a dibenzofuranyl group, or a dibenzothiophenyl group and more preferably a dibenzofuranyl group.

The optional substituents on Ar²⁴¹, Ar²⁴², and Ar²⁴³ are each preferably a group selected from the substituent group S, more preferably a hydrocarbon group included in the substituent group S, and still more preferably a hydrocarbon group selected from the preferred groups in the substituent group S.

No particular limitation is imposed on the charge transport material used together with the fluorescent light-emitting material, but the charge transport material is preferably a material represented by the following formula (212).

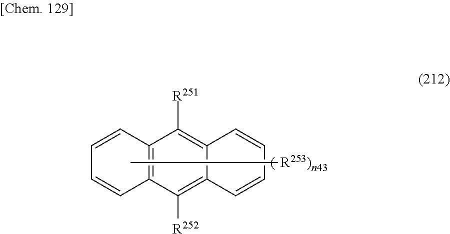

In formula (212) above, R²⁵¹ and R²⁵² are each independently a structure represented by formula (213). R²⁵³ represents a substituent. When a plurality of R²⁵³'s are present, they may be the same or different. n43 is an integer of 0 to 8.

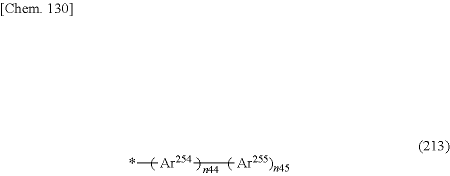

In formula (213) above, * represents a direct bond to the anthracene ring in formula (212). Ar²⁵⁴ and Ar²⁵⁵ each independently represent an aromatic hydrocarbon structure optionally having a substituent or an aromatic heterocyclic structure optionally having a substituent. When a plurality of Ar²⁵⁴'s are present, they may be the same or different. When a plurality of Ar²⁵⁵'s are present, they may be the same or different. n44 is an integer of 1 to 5, and n45 is an integer of 0 to 5.

Ar²⁵⁴ is preferably an aromatic hydrocarbon structure that is a monocycle or condensed ring having 6 to 30 carbon atoms and optionally having a substituent and more preferably an aromatic hydrocarbon structure that is a monocycle or condensed ring having 6 to 12 carbon atoms and optionally having a substituent.

Ar²⁵⁵ is preferably an aromatic hydrocarbon structure that is a monocycle or condensed ring having 6 to 30 carbon atoms and optionally having a substituent or an aromatic heterocyclic structure that is a condensed ring having 6 to 30 carbon atoms and optionally having a substituent. Ar²⁵⁵ is more preferably an aromatic hydrocarbon structure that is a monocycle or condensed ring having 6 to 12 carbon atoms and optionally having a substituent or an aromatic heterocyclic structure that is a condensed ring having 12 carbon atoms and optionally having a substituent.

n44 is preferably an integer of 1 to 3 and more preferably 1 or 2.

n45 is preferably an integer of 0 to 3 and more preferably 0 to 2.

The optional substituents on R²⁵³, Ar²⁵⁴, and Ar²⁵⁵ serving as substituents are each preferably a group selected from the substituent group S. These are each more preferably a hydrocarbon group included in the substituent group S and still more preferably a hydrocarbon group selected from the preferred groups in the substituent group S.

The molecular weights of the fluorescent light-emitting material and the charge transport material are each preferably 5,000 or less, still more preferably 4,000 or less, particularly preferably 3,000 or less, and most preferably 2,000 or less. The molecular weights are each preferably 300 or more, more preferably 350 or more, and still more preferably 400 or more.

### [Hole Blocking Layer]

The hole blocking layer 6 may be disposed between the light-emitting layer 5 and the electron injection layer 8 described later. The hole blocking layer 6 is an electron transport layer and serves also as a layer preventing holes moving from the anode 2 from reaching the cathode 9. The hole blocking layer 6 is a layer disposed on the light-emitting layer 5 so as to be in contact with the cathode 9-side interface of the light-emitting layer 5.

The hole blocking layer 6 has the function of preventing holes moving from the anode 2 from reaching the cathode 9 and the function of efficiently transporting electrons injected from the cathode 9 toward the light-emitting layer 5.

Examples of the physical properties required for the material forming the hole blocking layer 6 include high electron mobility, low hole mobility, a large energy gap (the difference between the HOMO and LUMO), and a high excited triplet energy level (T1). Examples of the material of the hole blocking layer 6 that satisfies these requirements include: meatal complexes such as mixed ligand complexes such as bis(2-methyl-8-quinolinolato) (phenolato)aluminum and bis(2-methyl-8-quinolinolato) (triphenylsilanolato)aluminum and binuclear metal complexes such as bis(2-methyl-8-quinolato)aluminum-μ-oxo-bis-(2-methyl-8-quinolinolato)aluminum; styryl compounds such as distyrylbiphenyl derivatives (JP11-242996A); triazole derivatives such as 3-(4-biphenylyl)-4-phenyl-5(4-tert-butylphenyl)-1,2,4-triazole (JP7-41759A); and phenanthroline derivatives such as bathocuproine (JP10-79297A). Moreover, a compound having at least one pyridine ring substituted at the 2-, 4-, and 6-positions and described in WO2005/022962 is also preferred as the material of the hole blocking layer 6.

No particular limitation is imposed on the method for forming the hole blocking layer 6. The hole blocking layer 6 can be formed using a wet deposition method, a vapor deposition method, or another method.

The hole blocking layer 6 can have any thickness so long as the effects of the invention are not significantly impaired. The thickness of the hole blocking layer 6 is generally 0.3 nm or more and preferably 0.5 nm or more and is generally 100 nm or less and preferably 50 nm or less.

### [Electron Transport Layer]

The electron transport layer 7 is a layer disposed between the light-emitting layer 5 and the cathode 9 to transport electrons.

An electron transport material used for the electron transport layer 7 is generally a compound having high efficiency of electron injection from the cathode 9 or an adjacent layer on the cathode 9 side, having high electron mobility, and capable of transporting injected electrons efficiently. Examples of a compound that satisfies these requirements include metal complexes such as an aluminum complex and an lithium complex of 8-hydroxyquinoline (JP59-194393A), metal complexes of 10-hydroxybenzo[h]quinoline, oxadiazole derivatives, distyrylbiphenyl derivatives, silole derivatives, 3-hydroxyflavone metal complexes, 5-hydroxyflavone metal complexes, benzoxazole metal complexes, benzothiazole metal complexes, trisbenzimidazolylbenzene (U.S. Pat. No. 5,645,948), quinoxaline compounds (JP6-207169A), phenanthroline derivatives (JP5-331459A), 2-t-butyl-9,10-N,N′-dicyanoanthraquinonediimine, triazine compound derivatives, n-type hydrogenated amorphous silicon carbide, n-type zinc sulfide, and n-type zinc selenide.

Other examples of the electron transport material used for the electron transport layer 7 include materials obtained by doping electron transport organic compounds typified by nitrogen-containing heterocyclic compounds such as bathophenanthroline and metal complexes such as an aluminum complex of 8-hydroxyquinoline with alkali metals such as sodium, potassium, cesium, lithium, and rubidium (JP10-27017A, JP2002-100478A, and JP2002-100482A). These materials are preferred because electron injectability and transportability and good film quality can be obtained simultaneously. It is also effective to dope any of the above electron transport organic compounds with an inorganic salt such as lithium fluoride or cesium carbonate.

No particular limitation is imposed on the method for forming the electron transport layer 7. The electron transport layer 7 can be formed using a wet deposition method, a vapor deposition method, or another method.

The electron transport layer 7 can have any thickness so long as the effects of the invention are not significantly impaired. The thickness of the electron transport layer 7 is generally 1 nm or more and preferably 5 nm or more and is generally 300 nm or less and preferably 100 nm or less.

### [Electron Injection Layer]

To inject electrons injected from the cathode 9 efficiently into the light-emitting layer 5, the electron injection layer 8 may be disposed between the electron transport layer 7 and the cathode 9 described later. The electron injection layer 8 is formed of, for example, an inorganic salt.

Examples of the material of the electron injection layer 8 include lithium fluoride (LiF), magnesium fluoride (MgF₂), lithium oxide (Li₂O), and cesium carbonate(II) (CsCO₃) (see, for example, Applied Physics Letters, 1997, Vol. 70, pp. 152; JP10-74586A; IEEE Transactions on Electron Devices, 1997, Vol. 44, pp. 1245; and SID 04 Digest, pp. 154).

The electron injection layer 8 often has no charge transportability. Therefore, to inject electrons efficiently, it is preferable to use the electron injection layer 8 as a very thin film, and its thickness is generally 0.1 nm or more and is preferably 5 nm or less.

### [Cathode]

The cathode 9 is an electrode that functions to inject electrons into a layer on the light-emitting layer 5 side.

Typical examples of the material of the cathode 9 include: metals such as aluminum, gold, silver, nickel, palladium, and platinum; metal oxides such as indium and/or tin oxides; halogenated metals such as copper iodide; carbon black; and electrically conductive polymers such as poly(3-methylthiophene), polypyrrole, and polyaniline. In particular, metals having a low work function are preferred in order to inject electrons efficiently, and an appropriate metal such as tin, magnesium, indium, calcium, aluminum, or silver or an alloy thereof is used. Specific examples include electrodes of low-work function alloys such as magnesium-silver alloys, magnesium-indium alloys, and aluminum-lithium alloys.

Only one material may be used for the cathode 9, or a combination of two or more materials at any ratio may be used.

The film thickness of the cathode 9 differs depending on the required transparency. When the cathode 9 is required to be transparent, the visible light transmittance is generally 60% or more and preferably 80% or more. In this case, the thickness of the cathode 9 is generally 5 nm or more and preferably 10 nm or more and is generally 1000 nm or less and preferably 500 nm or less. When the cathode 9 can be opaque, the cathode 9 can have any thickness, and the cathode may serve also as a substrate.

A different electrically conductive material may be deposited on the cathode 9.

For example, for the purpose of protecting the cathode formed of a low-work function metal such as an alkali metal such as sodium or cesium or an alkaline earth metal such as barium or calcium, a metal layer having a large work function and stable in air may be deposited on the cathode. This is preferable because the stability of the element increases. For this purpose, a metal such as aluminum, silver, copper, nickel, chromium, gold, or platinum is used. Only one of these metals may be used, or a combination of two or more at any ratio may be used.

### [Additional Layers]

The organic electroluminescent element of the invention may have a different structure so long as this does not depart from the spirit of the invention. For example, a layer different from the layers described above may be disposed between the anode 2 and the cathode 9 so long as the performance of the element is not impaired. Any of the non-essential layers described above may be omitted.

One or two or more additional organic layers may be disposed as cathode protective layers on the cathode 9.

In the layer structure described above, the components other than the substrate may be stacked in the reverse order. For example, in the layer structure in FIG. 1, the components other than the substrate 1 may be stacked on the substrate 1 in the order of the cathode 9, the electron injection layer 8, the electron transport layer 7, the hole blocking layer 6, the light-emitting layer 5, the hole transport layer 4, the hole injection layer 3, and the anode 2.

The organic electroluminescent element of the invention may be formed as a single organic electroluminescent element, may be applied to a structure in which a plurality of organic electroluminescent elements are arranged in an array, or may be applied to a structure in which anodes and cathodes are arranged in an X-Y matrix.

Each of the layers described above may contain a component other than the materials describes above so long as the effects of the invention are not significantly impaired.

### [Organic Electroluminescent Device]

Two or more organic electroluminescent elements that emit light of different colors may be disposed to form an organic electroluminescent device such as an organic electroluminescent display device or an organic electroluminescent lighting apparatus. In this organic electroluminescent device, when at least one organic electroluminescent element, preferably all the organic electroluminescent elements are each the organic electroluminescent element of the invention, the organic electroluminescent device can have high quality.

### [Organic Electroluminescent Display Device]

No particular limitation is imposed on the type and structure of the organic electroluminescent display device using the organic electroluminescent element of the invention. The organic electroluminescent display device can be assembled by an ordinary method using the organic electroluminescent element of the invention.

The organic electroluminescent display device can be formed using, for example, a method described in “Yuki EL Disupurei (Organic EL Display)” (Ohmsha, Ltd. published on August 20, Heisei 16, written by TOKITO Shizuo, ADACHI Chihaya, and MURATA Hideyuki).

### [Organic Electroluminescent Lighting Apparatus]

No particular limitation is imposed on the type and structure of the organic electroluminescent lighting apparatus using the organic electroluminescent element of the invention. The organic electroluminescent lighting apparatus can be assembled by an ordinary method using the organic electroluminescent element of the invention.

### EXAMPLES

The present invention will next be specifically described by way of Examples. However, the invention is not limited to the following Examples and can be embodied in various forms within the spirit of the invention.

### [Evaluation of Flatness of Functional Films]

### Example 1

### <Preparation of Composition>

A high-molecular weight charge transport compound (P-1) represented by a structural formula below (weight average molecular weight: about 18,000), a low-molecular weight charge transport compound (molecular weight: 717) (M-1) represented by a structural formula below, and an electron accepting compound (HI-1) represented by a structural formula below were weighed using an electronic balance at a weight ratio of (P-1):(M-1):(HI-1)=65:22:13 to thereby prepare a hole injection material 1. Next, butyl benzoate (boiling point: about 250° C., vapor pressure: about 2.9 Pa) and 1,1-diphenylpentane (boiling point: about 308° C., vapor pressure: about 0.17 Pa) were mixed at a weight ratio of 75:25 to thereby obtain a solvent mixture 1. The hole injection material 1 and the solvent mixture 1 were mixed in a screw vial such that the concentration of the hole injection material 1 was 2.0% by weight, and the screw vial containing the mixture was placed in a vacuum chamber. The vacuum chamber was evacuated and purged with nitrogen. This procedure was repeated three times to replace the gas portion in the screw vial with nitrogen. Then the screw vial was heated at a hot plate temperature of 110° C. for 3 hours while a magnetic stirrer was used to stir the mixture at 420 rpm. The resulting composition was cooled to near room temperature and filtrated using a membrane filter with a pore size of 0.2 μm to thereby obtain a composition 1.

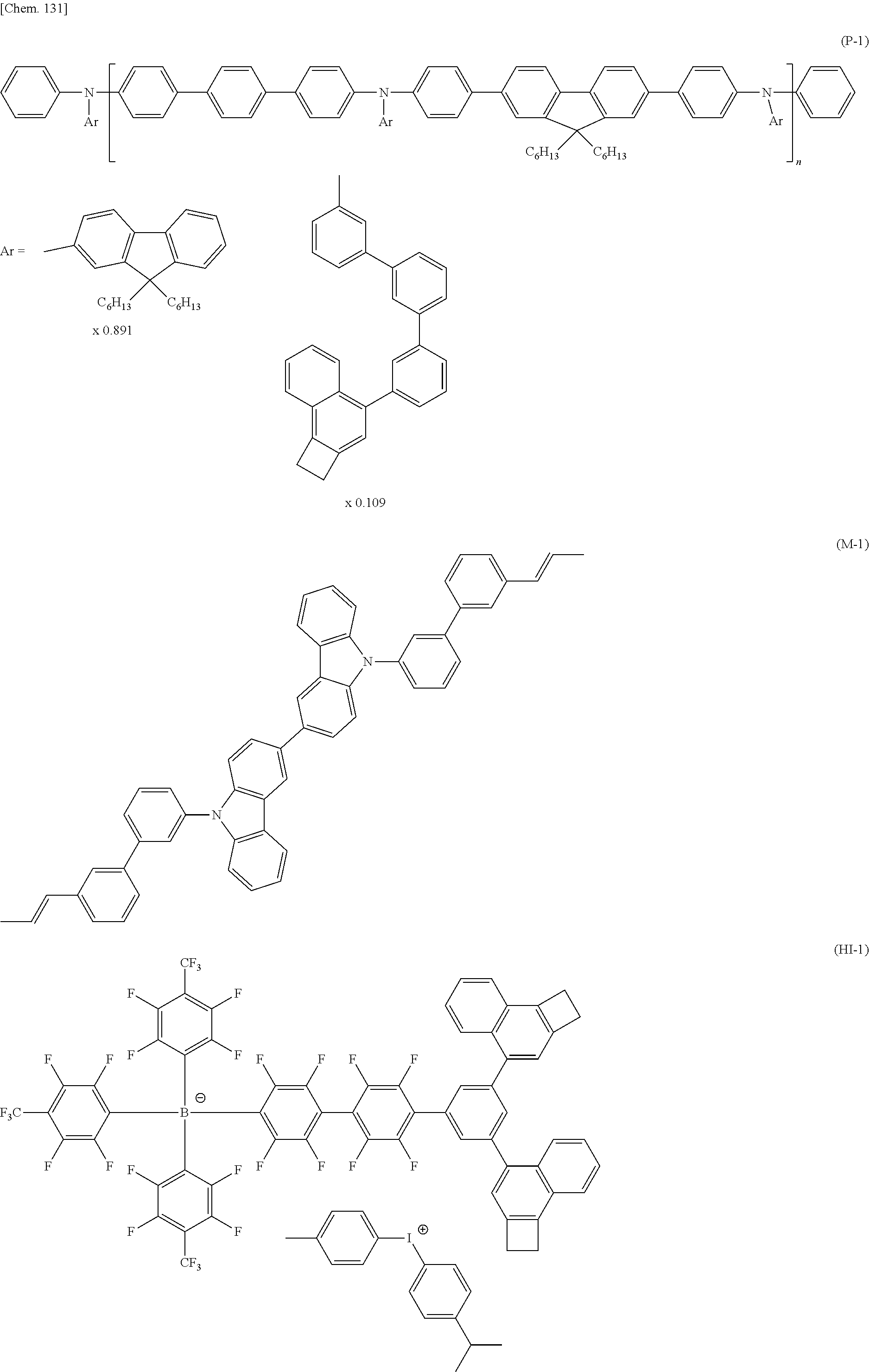

### <Preparation of Substrate>

An indium-tin oxide (ITO) film, a silver-indium compound film, and an indium-tin oxide film were deposited in this order on a 0.5 mm-thick glass substrate by a sputtering method, and an electrode pattern was formed by general photolithography. A liquid repellent photosensitive resist was applied to the substrate to a film thickness of 1.0 μm, and openings were produced by general photolithography. The dimensions of the openings were a major axis length of about 170 μm and a minor axis length of 50 μm.

The obtained substrate was subjected to ultrasonic cleaning in ultrapure water for 15 minutes and dried in a clean oven preheated to 130° C. for 10 minutes. The step of baking the substrate on a hot plate heated to 230° C. for 10 minutes in order to remove moisture adhering to the surface was performed immediately before the application of the composition.

### <Application of Composition>

The composition 1 was charged into an inkjet printer cartridge (DMCLCP-11610 manufactured by FUJIFILM Corporation) using a micropipette and applied to the openings of the substrate using an inkjet printer (DMP-2831 manufactured by FUJIFILM Corporation). The ejection voltage of the inkjet printer was adjusted such that the volume of one droplet of the composition ejected from the nozzle of the inkjet head was 10 pL, and the composition 1 was applied such that seven droplets were placed in one opening. The composition 1 was applied to a total of 1,100 openings, i.e., 55 openings in the minor axis direction×20 openings in the major axis direction, and then the following drying and firing steps were performed.

### <Drying and Firing>

The coating film obtained was placed in a sealed chamber having an openable-closable lid and was vacuum-dried using a multistage pump (VMR-050 manufactured by ULVAC, Inc.) including a combination of a mechanical booster pump and a rotary pump until the pressure was reduced to 0.1 Pa or lower to thereby obtain a functional film.

The vacuum drying was performed as follows. The pressure was reduced from the atmospheric pressure to 1000 to 2000 Pa over 30 seconds. Then the vacuum pump was isolated from the vacuum chamber, and the pressure was maintained for 3 minutes. Then the vacuum chamber was again evacuated using the vacuum pump to reduce the pressure to 0.1 Pa or lower over 30 seconds or longer. The solvent component in the composition was thereby volatilized, and a functional film was formed.

The functional film was placed on a hot plate heated to 230° C. and fired for 30 minutes to thereby obtain a functional film 1.

### <Evaluation of Functional Film>

A profile of the thickness of the obtained functional film in the major axis direction of the openings was measured using a stylus type profilometer (Kosaka Laboratory Ltd. ET-100). The thickness profile measured was used to compute flatness U using the following formula (1), and the flatness of the functional film 1 was evaluated.

$$U = LF / LB \times 100 ( \% ) \qquad ( 1 )$$

Here, LB is the length of one opening in banks, and LF is the length of (a region of) the functional film in which the thickness does not exceed the average thickness of the thickness profile by 5 nm or more.

The functional film 1 was observed visually under an optical microscope, and the roughness of the thickness profile was analyzed to check for the presence or absence of film roughening. When no film roughening was found, the film was rated “OK.” When film roughening was found, the film was rated “NG.”

### Example 2

The high-molecular weight charge transport compound, the low-molecular weight charge transport compound, and the electron accepting compound used in Example 1 were weighed using an electronic balance such that the mixing weight ratio was (P-1):(M-1):(HI-1)=43.5:43.5:13 to thereby obtain a hole injection material 2. Then the substrate preparation and the film deposition process were performed as in Example 1, and the flatness U was computed.

### Example 3

The high-molecular weight charge transport compound, the low-molecular weight charge transport compound, and the electron accepting compound used in Example 1 were weighed using an electronic balance such that the mixing weight ratio was (P-1):(M-1):(HI-1)=22:65:13 to thereby obtain a hole injection material 3. Then the substrate preparation and the film deposition process were performed as in Example 1, and the flatness U was computed.

### Comparative Example 1

The high-molecular weight charge transport compound, the low-molecular weight charge transport compound, and the electron accepting compound used in Example 1 were weighed using an electronic balance such that the mixing weight ratio was (P-1):(M-1):(HI-1)=87:0:13 to thereby obtain a hole injection material 4. Then the substrate preparation and the film deposition process were performed as in Example 1, and the flatness U was computed.

### Comparative Example 2

The high-molecular weight charge transport compound, the low-molecular weight charge transport compound, and the electron accepting compound used in Example 1 were weighed using an electronic balance such that the mixing weight ratio was (P-1):(M-1):(HI-1)=0:87:13 to thereby obtain a hole injection material 5. Then the substrate preparation and the film deposition process were performed as in Example 1, and the flatness U was computed.

### Example 4

The solvent mixture 1 used in Example 1 was changed to a solvent mixture 2 prepared by mixing 2-isopropylnaphthalene (boiling point: about 262° C., vapor pressure: about 1.7 Pa), 2-ethylhexyl benzoate (boiling point: about 298° C., vapor pressure: about 0.68 Pa), and benzyl benzoate (boiling point: about 324° C., vapor pressure: about 0.33 Pa) at a weight ratio of 70:20:10. Moreover, the high-molecular weight charge transport compound, the low-molecular weight charge transport compound, and the electron accepting compound used in Example 1 were weighed using an electronic balance such that the mixing weight ratio was (P-1):(M-1):(HI-1)=78:9:13 to thereby obtain a hole injection material 6. Then the substrate preparation and the film deposition process were performed as in Example 1, and the flatness U was computed.

### Example 5

The high-molecular weight charge transport compound, the low-molecular weight charge transport compound, and the electron accepting compound used in Example 1 were weighed using an electronic balance such that the mixing weight ratio was (P-1):(M-1):(HI-1)=65:22:13 to thereby obtain a composition having the same chemical composition as that of the hole injection material 1. The solvent mixture used was the solvent mixture 2 as in Example 4. Then the substrate preparation and the film deposition process were performed as in Example 1, and the flatness U was computed.

### Example 6

The high-molecular weight charge transport compound, the low-molecular weight charge transport compound, and the electron accepting compound used in Example 1 were weighed using an electronic balance such that the mixing weight ratio was (P-1):(M-1):(HI-1)=43.5:43.5:13 to thereby obtain a composition having the same chemical composition as that of the hole injection material 2. The solvent mixture used was the solvent mixture 2 as in Example 4. Then the substrate preparation and the film deposition process were performed as in Example 1, and the flatness U was computed.

### Example 7

The high-molecular weight charge transport compound, the low-molecular weight charge transport compound, and the electron accepting compound used in Example 1 were weighed using an electronic balance such that the mixing weight ratio was (P-1):(M-1):(HI-1)=22:65:13 to thereby obtain a composition having the same chemical composition as that of the hole injection material 3. The solvent mixture used was the solvent mixture 2 as in Example 4. Then the substrate preparation and the film deposition process were performed as in Example 1, and the flatness U was computed.

### Comparative Example 3

The high-molecular weight charge transport compound, the low-molecular weight charge transport compound, and the electron accepting compound used in Example 1 were weighed using an electronic balance such that the mixing weight ratio was (P-1):(M-1):(HI-1)=87:0:13 to thereby obtain a composition having the same chemical composition as that of the hole injection material 4. The solvent mixture used was the solvent mixture 2 as in Example 4. Then the substrate preparation and the film deposition process were performed as in Example 1, and the flatness U was computed.

### Comparative Example 4

The high-molecular weight charge transport compound, the low-molecular weight charge transport compound, and the electron accepting compound used in Example 1 were weighed using an electronic balance such that the mixing weight ratio was (P-1):(M-1):(HI-1)=0:87:13 to thereby obtain a composition having the same chemical composition as that of the hole injection material 5. The solvent mixture used was the solvent mixture 2 as in Example 4. Then the substrate preparation and the film deposition process were performed as in Example 1, and the flatness U was computed.

### Example 8

The high-molecular weight charge transport compound (P-1) used in Example 1 was changed to a high-molecular weight charge transport compound (weight average molecular weight: about 18,300) having a repeating unit represented by formula (P-2) below, and the low-molecular weight charge transport compound (M-1) was changed to a low-molecular weight charge transport compound represented by formula (M-2) below (molecular weight: 1,274). The high-molecular weight charge transport compound, the low-molecular weight charge transport compound, and the electron accepting compound were weighed using an electronic balance such that the mixing weight ratio was (P-2):(M-2):(HI-1)=43.5:43.5:13 to thereby obtain a hole injection material 7. The solvent mixture used was the solvent mixture 2 as in Example 4. Then the substrate preparation and the film deposition process were performed as in Example 1, and the flatness U was computed.

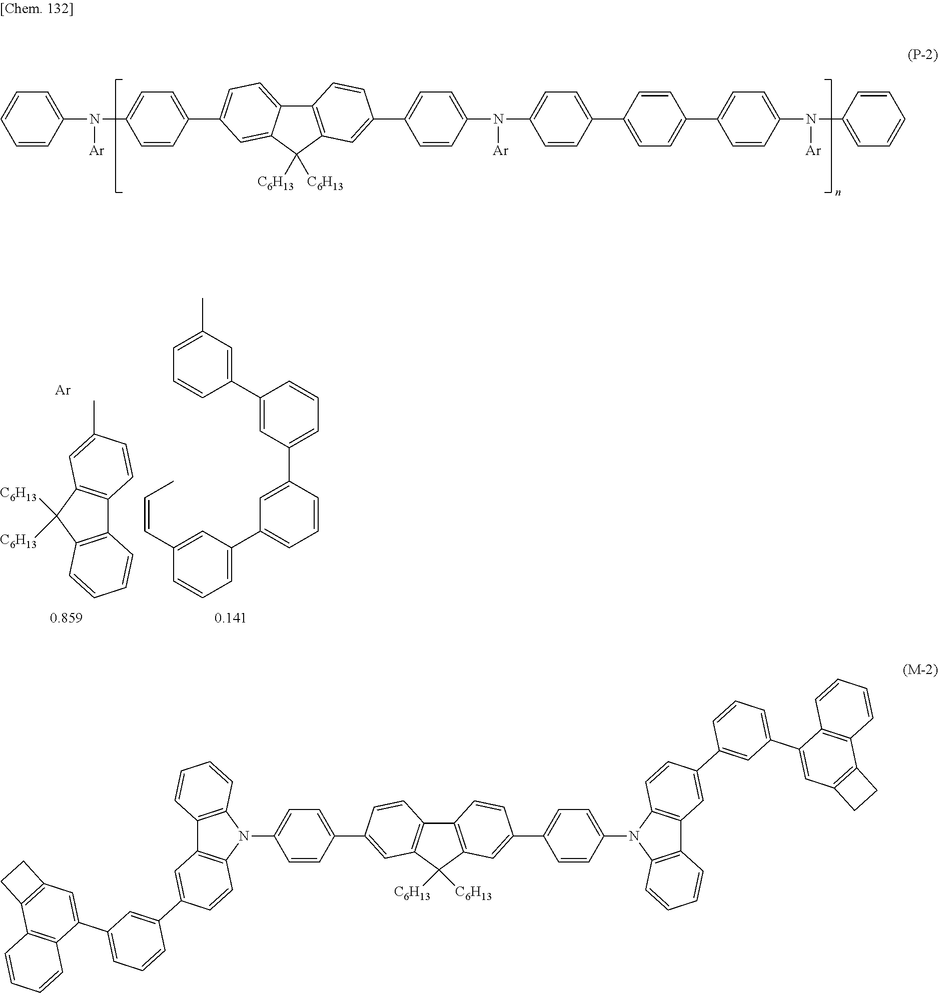

### Example 11

The high-molecular weight charge transport compound (P-1) used in Example 1 was changed to a high-molecular weight charge transport compound (weight average molecular weight: about 41,000) having a repeating unit represented by formula (P-4) below. The high-molecular weight charge transport compound, the low-molecular weight charge transport compound, and the electron accepting compound were weighed using an electronic balance such that the mixing weight ratio was (P-4):(M-1):(HI-1)=43.5:43.5:13 to thereby obtain a hole injection material 8. The solvent mixture used was the solvent mixture 2 as in Example 4. Then the substrate preparation and the film deposition process were performed as in Example 1, and the flatness U was computed.

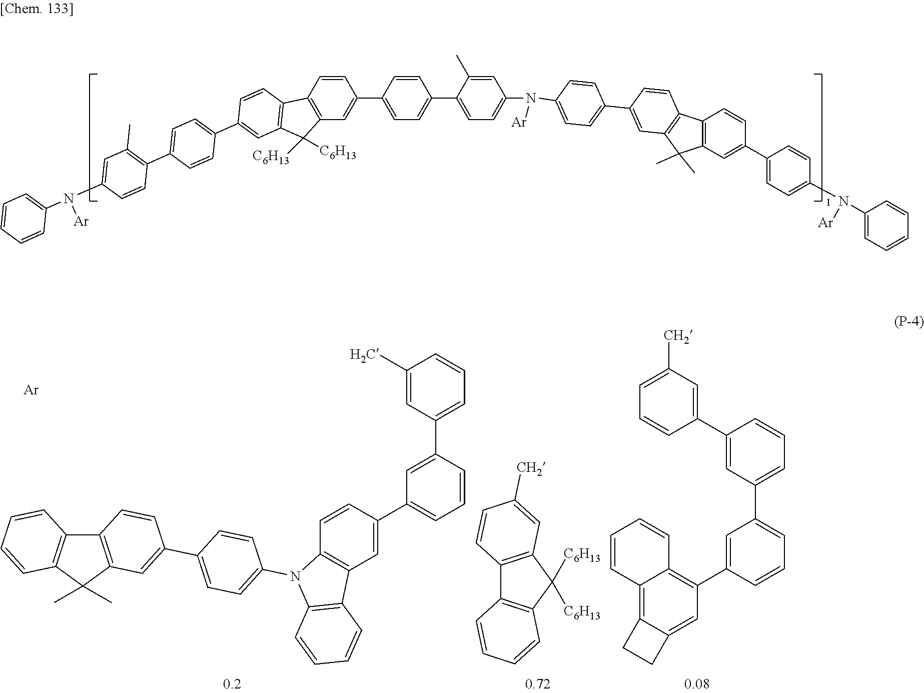

### Example 12

The high-molecular weight charge transport compound (P-1) used in Example 1 was changed to a high-molecular weight charge transport compound (weight average molecular weight: about 37,500) having a repeating unit represented by formula (P-5) below, and the low-molecular weight charge transport compound (M-1) was changed to the low-molecular weight charge transport compound (molecular weight: 1,274) represented by formula (M-2) above. The high-molecular weight charge transport compound, the low-molecular weight charge transport compound, and the electron accepting compound were weighed using an electronic balance such that the mixing weight ratio was (P-5):(M-2):(HI-1)=43.5:43.5:13 to thereby obtain a hole injection material 9. The solvent mixture used was the solvent mixture 2 as in Example 4. Then the substrate preparation and the film deposition process were performed as in Example 1, and the flatness U was computed.

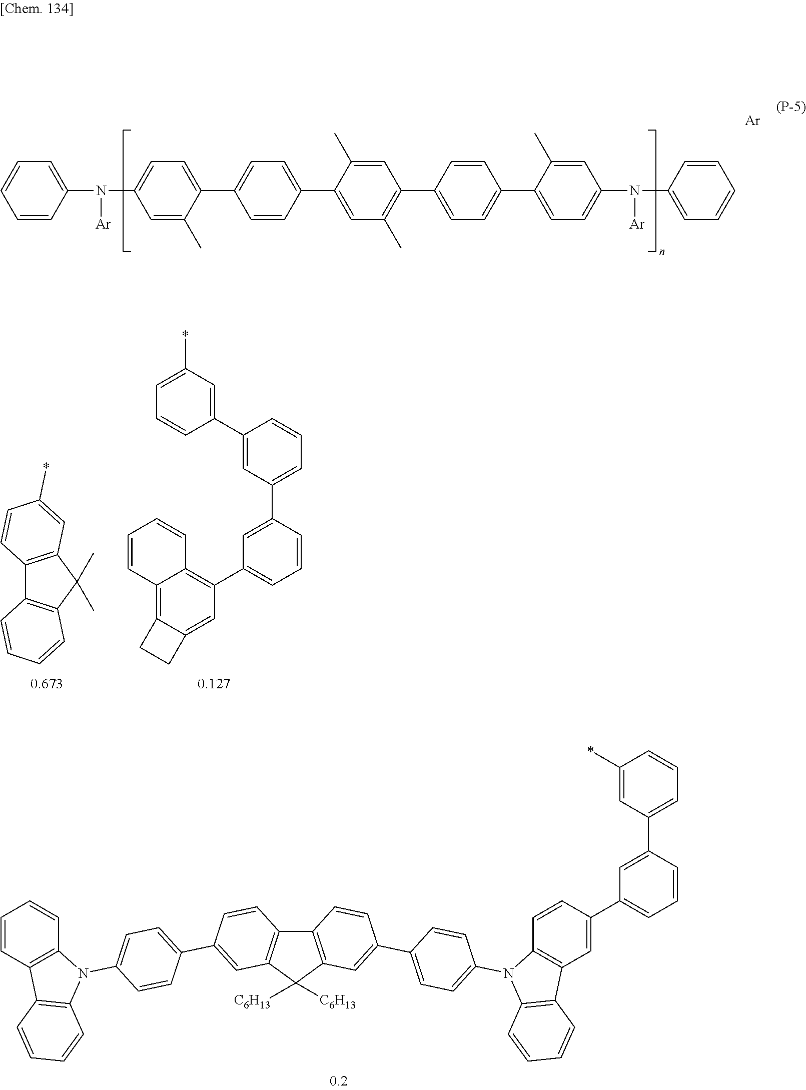

### Comparative Example 9

The low-molecular weight charge transport compound (M-1) used in Example 1 was changed to a low-molecular weight charge transport compound (molecular weight: 948) represented by formula (M-4) below. The high-molecular weight charge transport compound, the low-molecular weight charge transport compound, and the electron accepting compound were weighed using an electronic balance such that the mixing weight ratio was (P-1):(M-4):(HI-1)=43.5:43.5:13 to thereby obtain a hole injection material 10. The solvent mixture used was the solvent mixture 2 as in Example 4. Then the substrate preparation and the film deposition process were performed as in Example 1, and the flatness U was computed.

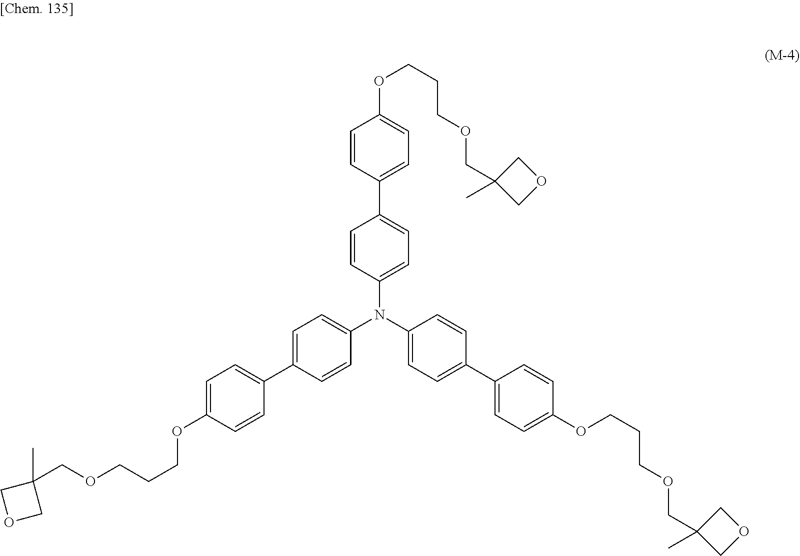 [SMILES: CC1(COCCCOc2ccc(-c3ccc(N(c4ccc(-c5ccc(OCCCOCC6(C)COC6)cc5)cc4)c4ccc(-c5ccc(OCCCOCC6(C)COC6)cc5)cc4)cc3)cc2)COC1]

### Example 131

The low-molecular weight charge transport compound (M-1) used in Example 1 was changed to a low-molecular weight charge transport compound (molecular weight: 921) represented by formula (M-5) below. The high-molecular weight charge transport compound, the low-molecular weight charge transport compound, and the electron accepting compound were weighed using an electronic balance such that the mixing weight ratio was (P-1):(M-5):(HI-1)=43.5:43.5:13 to thereby obtain a hole injection material 11. The solvent mixture used was the solvent mixture 2 as in Example 4. Then the substrate preparation and the film deposition process were performed as in Example 1, and the flatness U was computed.

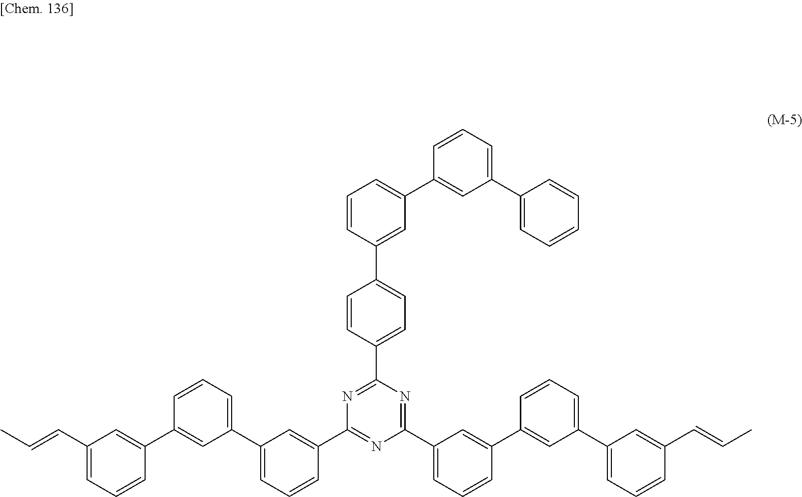 [SMILES: C/C=C/c1cccc(-c2cccc(-c3cccc(-c4nc(-c5ccc(-c6cccc(-c7cccc(-c8ccccc8)c7)c6)cc5)nc(-c5cccc(-c6cccc(-c7cccc(/C=C/C)c7)c6)c5)n4)c3)c2)c1]

### Example 14

The high-molecular weight charge transport compound (P-1) used in Example 1 was changed to the high-molecular weight charge transport compound (weight average molecular weight: about 18,300) having the repeating unit represented by formula (P-2) above, and the low-molecular weight charge transport compound (M-1) was changed to a low-molecular weight charge transport compound (molecular weight: 990) represented by formula (M-6) below. The high-molecular weight charge transport compound, the low-molecular weight charge transport compound, and the electron accepting compound were weighed using an electronic balance such that the mixing weight ratio was (P-2):(M-6):(HI-1)=43.5:43.5:13 to thereby obtain a hole injection material 12. The solvent mixture used was the solvent mixture 2 as in Example 4. Then the substrate preparation and the film deposition process were performed as in Example 1, and the flatness U was computed.

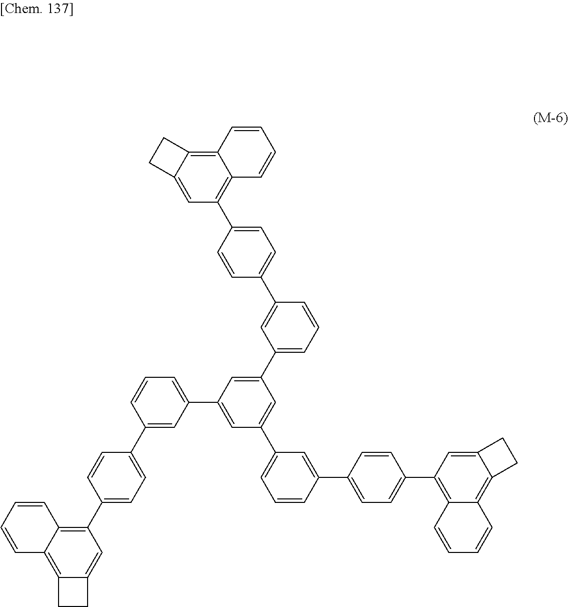 [SMILES: c1cc(-c2ccc(-c3cc4c(c5ccccc35)CC4)cc2)cc(-c2cc(-c3cccc(-c4ccc(-c5cc6c(c7ccccc57)CC6)cc4)c3)cc(-c3cccc(-c4ccc(-c5cc6c(c7ccccc57)CC6)cc4)c3)c2)c1]

### Example 151

The high-molecular weight charge transport compound (P-1) used in Example 1 was changed to the high-molecular weight charge transport compound (weight average molecular weight: about 18,300) having the repeating unit represented by formula (P-2) above, and the low-molecular weight charge transport compound (M-1) was changed to a low-molecular weight charge transport compound (molecular weight: 715) represented by formula (M-7) below. The high-molecular weight charge transport compound, the low-molecular weight charge transport compound, and the electron accepting compound were weighed using an electronic balance such that the mixing weight ratio was (P-2):(M-7):(HI-1)=43.5:43.5:13 to thereby obtain a hole injection material 13. The solvent mixture used was the solvent mixture 2 as in Example 4. Then the substrate preparation and the film deposition process were performed as in Example 1, and the flatness U was computed.

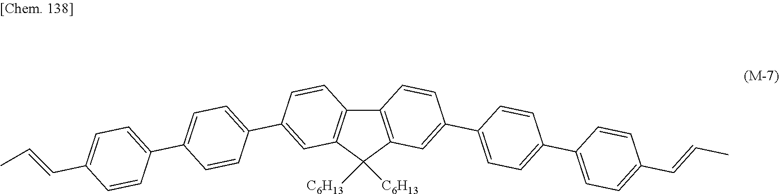

### Example 161

The low-molecular weight charge transport compound (M-1) used in Example 1 was changed to a low-molecular weight charge transport compound (molecular weight: 715) represented by formula (M-8) below. The high-molecular weight charge transport compound, the low-molecular weight charge transport compound, and the electron accepting compound were weighed using an electronic balance such that the mixing weight ratio was (P-1):(M-8):(HI-1)=43.5:43.5:13 to thereby obtain a hole injection material 14. The solvent mixture used was the solvent mixture 2 as in Example 4. Then the substrate preparation and the film deposition process were performed as in Example 1, and the flatness U was computed.

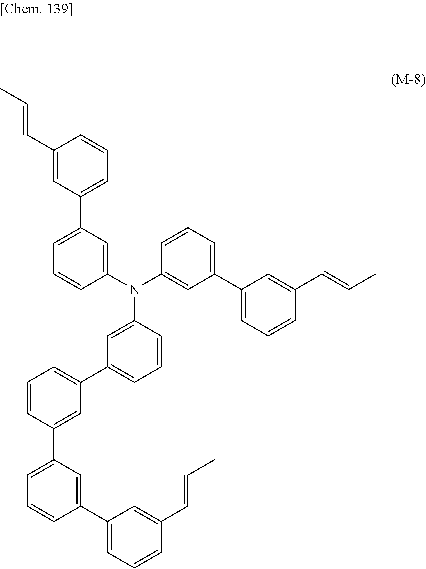 [SMILES: C/C=C/c1cccc(-c2cccc(-c3cccc(-c4cccc(N(c5cccc(-c6cccc(/C=C/C)c6)c5)c5cccc(-c6cccc(/C=C/C)c6)c5)c4)c3)c2)c1]

### Example 17

The high-molecular weight charge transport compound and the low-molecular weight charge transport compound used in Example 1 were weighed using an electronic balance such that the mixing weight ratio was (P-1):(M-1)=50:50 to thereby obtain a hole transport material 15. The solvent mixture used was the solvent mixture 2 as in Example 4. Then the substrate preparation and the film deposition process were performed as in Example 1, and the flatness U was computed.

### Example 18

The high-molecular weight charge transport compound (P-1) used in Example 17 was changed to the high-molecular weight charge transport compound having the repeating unit represented by formula (P-2) above, and the low-molecular weight charge transport compound (M-1) was changed to the low-molecular weight charge transport compound represented by formula (M-2) above. The high-molecular weight charge transport compound and the low-molecular weight charge transport compound were weighed using an electronic balance such that the mixing weight ratio was (P-2):(M-2)=50:50 to thereby obtain a hole transport material 16. The solvent mixture used was the solvent mixture 2 as in Example 4. Then the substrate preparation and the film deposition process were performed as in Example 1, and the flatness U was computed.

### Comparative Example 10

The high-molecular weight charge transport compound (P-1) used in Example 17 was omitted, and only the low-molecular weight charge transport compound (M-2) was used to obtain a hole transport material 17. The solvent mixture used was the solvent mixture 2 as in Example 4. Then the substrate preparation and the film deposition process were performed as in Example 1, and the flatness U was computed.

### Comparative Example 11

The low-molecular weight charge transport compound (M-1) used in Example 17 was omitted, and only the high-molecular weight charge transport compound (P-1) was used to obtain a hole transport material 18. The solvent mixture used was the solvent mixture 2 as in Example 4. Then the substrate preparation and the film deposition process were performed as in Example 1, and the flatness U was computed.

### Comparative Example 12

The high-molecular weight charge transport compound (P-1) used in Comparative Example 11 was changed to a high-molecular weight charge transport compound (molecular weight: about 40,000) having a repeating unit represented by formula (P-6) below, and this high-molecular weight charge transport compound was used as a hole transport material 19. The solvent mixture used was the solvent mixture 2 as in Example 4. Then the substrate preparation and the film deposition process were performed as in Example 1, and the flatness U was computed.

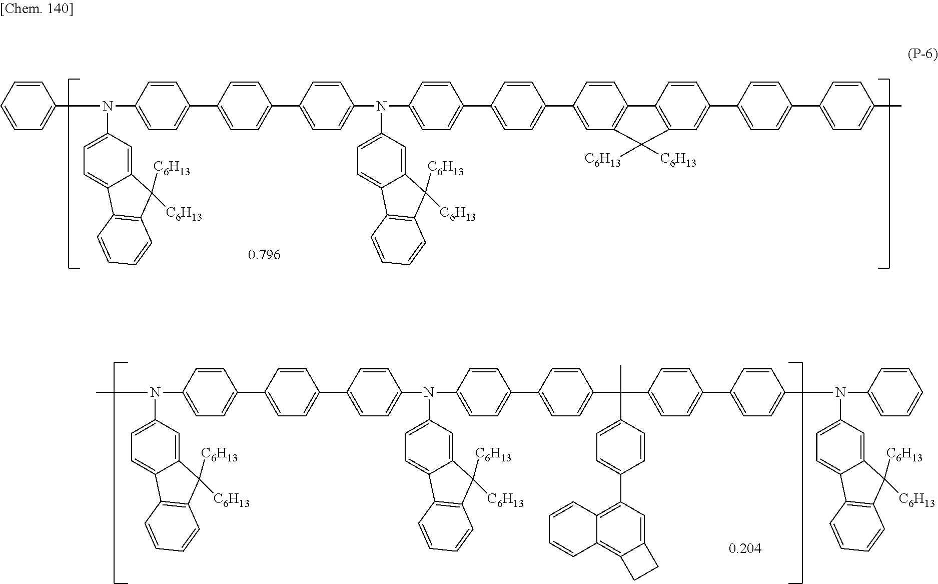

### Example 19

The low-molecular weight charge transport compound (M-1) used in Example 17 was changed to the low-molecular weight charge transport compound represented by formula (M-5) above. The high-molecular weight charge transport compound and the low-molecular weight charge transport compound were weighed using an electronic balance such that the mixing weight ratio was (P-1):(M-5)=50:50 to thereby obtain a hole transport material 20. The solvent mixture used was the solvent mixture 2 as in Example 4. Then the substrate preparation and the film deposition process were performed as in Example 1, and the flatness U was computed.

### Example 20

The high-molecular weight charge transport compound (P-1) used in Example 17 was changed to the high-molecular weight charge transport compound having the repeating unit represented by formula (P-2) above, and the low-molecular weight charge transport compound (M-1) was changed to the low-molecular weight charge transport compound represented by formula (M-6) above. The high-molecular weight charge transport compound and the low-molecular weight charge transport compound were weighed using an electronic balance such that the mixing weight ratio was (P-2):(M-6)=50:50 to thereby obtain a hole transport material 21. The solvent mixture used was the solvent mixture 2 as in Example 4. Then the substrate preparation and the film deposition process were performed as in Example 1, and the flatness U was computed.

### Example 21

The high-molecular weight charge transport compound (P-1) used in Example 17 was changed to the high-molecular weight charge transport compound having the repeating unit represented by formula (P-2) above, and the low-molecular weight charge transport compound (M-1) was changed to the low-molecular weight charge transport compound represented by formula (M-7) above. The high-molecular weight charge transport compound and the low-molecular weight charge transport compound were weighed using an electronic balance such that the mixing weight ratio was (P-2):(M-7)=50:50 to thereby obtain a hole transport material 22. The solvent mixture used was the solvent mixture 2 as in Example 4. Then the substrate preparation and the film deposition process were performed as in Example 1, and the flatness U was computed.

### Example 22

The low-molecular weight charge transport compound (M-1) used in Example 17 was changed to the low-molecular weight charge transport compound represented by formula (M-8) above. The high-molecular weight charge transport compound and the low-molecular weight charge transport compound were weighed using an electronic balance such that the mixing weight ratio was (P-1):(M-8)=50:50 to thereby obtain a hole transport material 23. The solvent mixture used was the solvent mixture 2 as in Example 4. Then the substrate preparation and the film deposition process were performed as in Example 1, and the flatness U was computed.

### Example 231

The high-molecular weight charge transport compound (P-1) used in Example 17 was changed to the high-molecular weight charge transport compound having the repeating unit represented by formula (P-2) above, and the low-molecular weight charge transport compound (M-1) was changed to a compound (molecular weight: 564) represented by formula (M-9) below. The high-molecular weight charge transport compound and the low-molecular weight charge transport compound were weighed using an electronic balance such that the mixing weight ratio was (P-2):(M-9)=50:50 to thereby obtain a hole transport material 24. The solvent mixture used was the solvent mixture 2 as in Example 4. Then the substrate preparation and the film deposition process were performed as in Example 1, and the flatness U was computed.

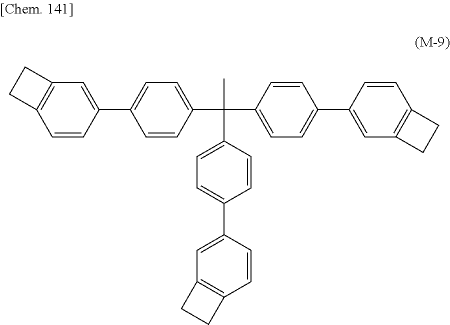 [SMILES: CC(c1ccc(-c2ccc3c(c2)CC3)cc1)(c1ccc(-c2ccc3c(c2)CC3)cc1)c1ccc(-c2ccc3c(c2)CC3)cc1]

### Example 24

The high-molecular weight charge transport compound (P-1) used in Example 17 was changed to a high-molecular weight charge transport compound (weight average molecular weight: about 16,000) having a repeating unit represented by formula (P-7) below. The high-molecular weight charge transport compound and the low-molecular weight charge transport compound were weighed using an electronic balance such that the mixing weight ratio was (P-7):(M-1)=50:50 to thereby obtain a hole transport material 25. The solvent mixture used was the solvent mixture 2 as in Example 4. Then the substrate preparation and the film deposition process were performed as in Example 1, and the flatness U was computed.

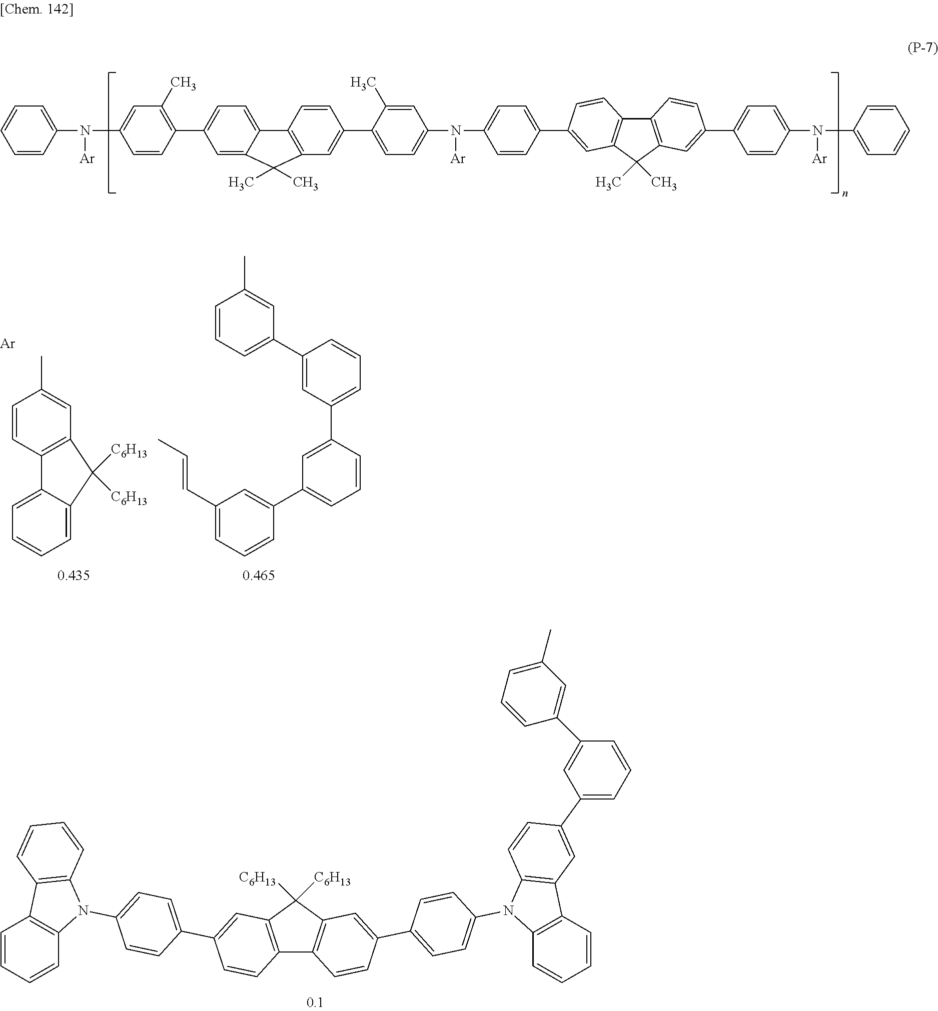

### [Results 1]

The results of the flatness evaluation described above are summarized in Tables 1 to 3. As for the solvent mixture 1, the flatness in Examples 1 to 3 into which the low-molecular weight charge transport compound was mixed was found to be significantly higher than that in Comparative Example 1 using only the high-molecular weight charge transport compound and the electron accepting compound. In Comparative Example 2 using only the low-molecular weight charge transport compound and the electron accepting compound, the flatness was relatively good. However, roughening of the film surface was found in the film fired at 230° C. This suggests a reduction in heat resistance.

As for the solvent mixture 2, even in Comparative Example 3 having the chemical composition including only the high-molecular weight charge transport compound and the electron accepting compound, the flatness was high to some extent. However, even with this solvent system, a reduction in the rise of the wetting shape was found in Examples 4 to 7 into which the low-molecular weight charge transport compound was mixed, and the flatness was found to be improved. In Comparative Example 4 using only the low-molecular weight charge transport compound and the electron accepting compound, roughening of the film surface was found as in Comparative Example 2. Therefore, the heat resistance of this functional film is assumed to be low.

Even in Examples 8 and 11 to 16 in which the structure of the high-molecular weight charge transport compound and/or the structure of the low-molecular weight charge transport compound was changed, the flatness was sufficient.

Even with compositions containing no electron accepting compound, the flatness in Examples 17 to 24 into which a low-molecular weight charge transport compound was mixed was sufficient and better than that in Comparative Examples 9 to 12 using only the high-molecular weight charge transport compound and the electron accepting compound.

### [Evaluation of Performance of Organic Electroluminescent Elements]

The improvement in flatness U by the composition of the invention has been described above using Examples. However, if the functions of an organic electroluminescent element produced using the flat film obtained in the invention are low, the primary object of the invention, i.e., the production of an organic electroluminescent element using the flat film, cannot be achieved.

Whether the functions of organic electroluminescent elements produced using the composition of the invention were maintained was verified by way of Examples.

### Example 9

A transparent electrically conductive indium-tin oxide (ITO) film deposited to a thickness of 50 nm on a glass substrate (a sputtered film manufactured by GEOMATEC Co., Ltd.) was patterned by general photolithography and etching with hydrochloric acid to form 2 mm-wide stripes, and an anode was thereby formed. The substrate with the patterned ITO film was subjected to ultrasonic cleaning with an aqueous surfactant solution, washing with ultrapure water, ultrasonic cleaning with ultrapure water, and washing with ultrapure water in this order, dried using compressed air, and finally subjected to UV ozone cleaning.

A composition prepared by dissolving 1.3% by weight of the high-molecular weight charge transport compound (P-1), 1.3% by weight of the low-molecular weight charge transport compound (M-1), and 0.4% by weight of the electron accepting compound (HI-1) in anisole was used as a hole injection layer-forming composition

The solution was applied to the substrate described above by spin coating in air and dried on a hot plate at 230° C. in air for 30 minutes, and a uniform thin film having a thickness of 50 nm was obtained as a hole injection layer.

Next, a high-molecular weight charge transport compound having the following structural formula (HT-1) was dissolved in 1,3,5-trimethylbenzene to prepare a 2.0% by weight solution.

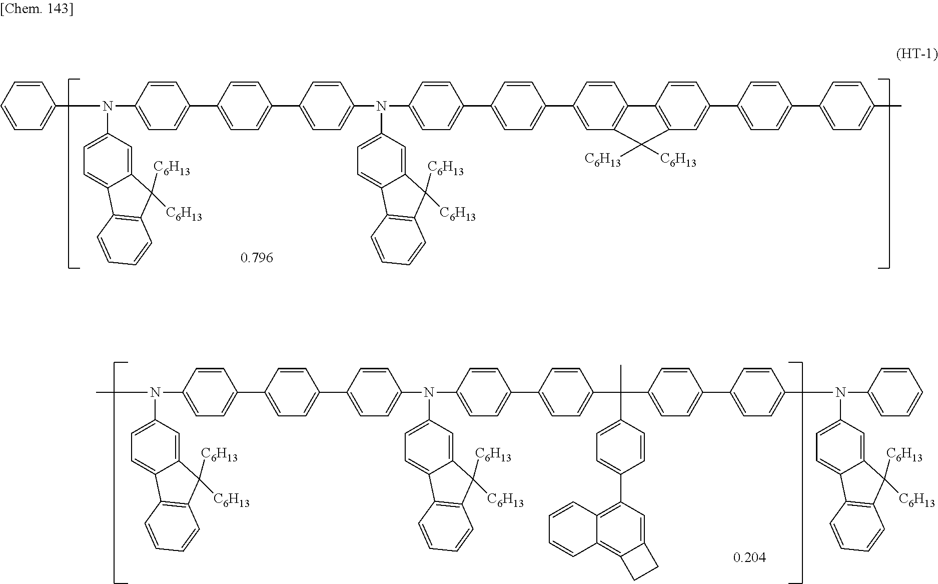

This solution was applied by spin coating to the substrate with the hole injection layer applied thereto in a nitrogen glove box and dried on a hot plate at 230° C. for 30 minutes in the nitrogen glove box, and a uniform thin film having a thickness of 40 nm was formed as a hole transport layer.

Next, a host material having the following structural formula (BH-1) and a dopant compound having the following structural formula (BD-1) were dissolved at a ratio of 100 parts by mass:10 parts by mass in cyclohexylbenzene to prepare a 4.2% by weight solution.

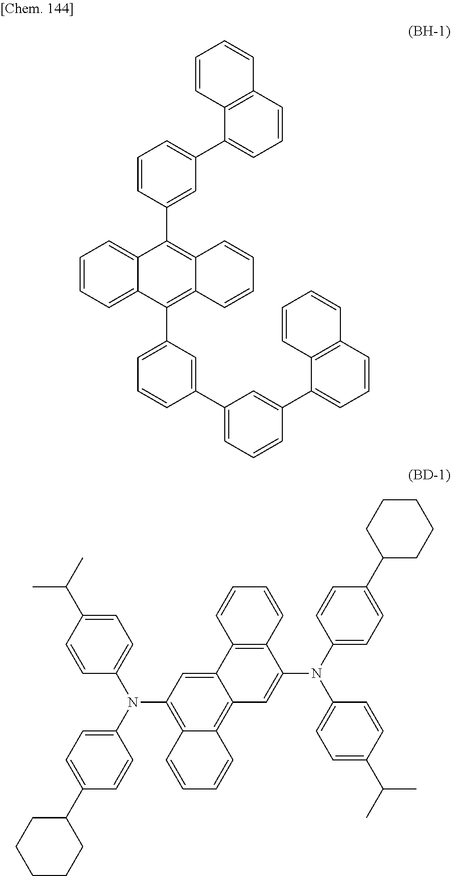

This solution was applied by spin coating to the substrate with the hole transport layer applied thereto in the nitrogen glove box to form a uniform thin film having a thickness of 40 nm and dried on a hot plate at 120° C. for 20 minutes in the nitrogen glove box to thereby form a light-emitting layer.

The substrate with the light-emitting layer deposited thereon was placed in a vacuum vapor deposition apparatus, and the apparatus was evacuated to 2×10⁻⁴ Pa or lower.

Next, the following structural formula (ET-1) and 8-hydroxyquinolinolato-lithium were co-deposited at a film thickness ratio of 2:3 onto the light-emitting layer by a vacuum vapor deposition method to thereby form an electron transport layer having a thickness of 30 nm.

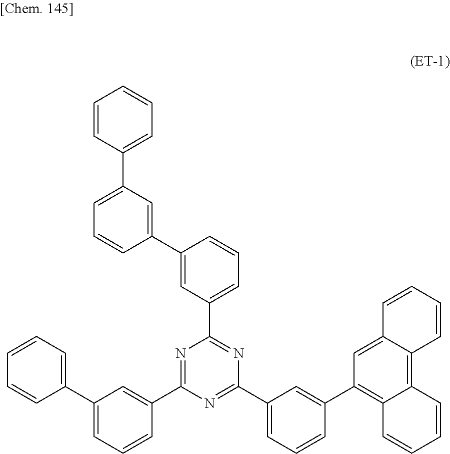 [SMILES: c1ccc(-c2cccc(-c3cccc(-c4nc(-c5cccc(-c6ccccc6)c5)nc(-c5cccc(-c6cc7ccccc7c7ccccc67)c5)n4)c3)c2)cc1]

Next, a 2 mm-wide stripe-shaped shadow mask used as a cathode deposition mask was brought into close contact with the substrate so as to be orthogonal to the ITO stripes for the anode, and aluminum in a molybdenum boat was heated to form an aluminum layer having a thickness of 80 nm by a vacuum vapor deposition method, and a cathode was thereby formed. An organic electroluminescent element having a light-emitting portion having an area of 2 mm×2 mm was obtained in the manner described above.

In a space filled with nitrogen, a moisture-oxygen adsorbent was applied to the inner side of a glass substrate having a hollow structure, and the glass substrate with the organic electroluminescent element formed thereon was disposed such that its surface with the organic electroluminescent element formed thereon faced the surface of the hollow glass with the moisture-oxygen adsorbent applied thereto. An ultraviolet curable resin was applied so as to surround the outer circumference of the organic electroluminescent element to bond these surfaces together. The ultraviolet curable resin was irradiated with ultraviolet rays to form a structure for isolating the organic electroluminescent element from the outside space. In this manner, the surface of the organic electroluminescent element can be isolated from moisture and oxygen while no structure is in direct contact with the surface of the organic electroluminescent element, and the performance of the organic electroluminescent element can be evaluated with the influences of moisture and oxygen eliminated.

### Example 10

An element was produced using the same procedure as in Example 9 except that a composition prepared by dissolving 1.3% by weight of the high-molecular weight charge transport compound (P-2), 1.3% by weight of the low-molecular weight charge transport compound (M-2), and 0.4% by weight of the electron accepting compound (HI-1) in anisole was used as the hole injection layer-forming composition.

### Reference Example 1

An element was produced using the same procedure as in Example 9 except that a composition prepared by dissolving 2.6% by weight of the high-molecular weight charge transport compound (P-1) and 0.4% by weight of the electron accepting compound (HI-1) in anisole was used as the hole injection layer-forming composition.

### Comparative Example 5

An element was produced using the same procedure as in Example 9 except that a composition prepared by dissolving 1.3% by weight of the high-molecular weight charge transport compound (P-2), 1.3% by weight of a low-molecular weight charge transport compound having a structure represented by the following formula (M-3), and 0.4% by weight of the electron accepting compound (HI-1) in anisole was used as the hole injection layer-forming composition.

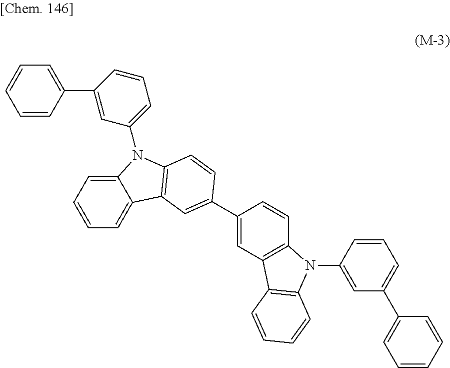 [SMILES: c1ccc(-c2cccc(-n3c4ccccc4c4cc(-c5ccc6c(c5)c5ccccc5n6-c5cccc(-c6ccccc6)c5)ccc43)c2)cc1]

### Comparative Example 6

An element was produced using the same procedure as in Example 9 except that a composition prepared by dissolving only 2.6% by weight of the low-molecular weight charge transport compound (M-2) and 0.4% by weight of the electron accepting compound (HI-1) in anisole was used as the hole injection layer-forming composition.

### Comparative Example 7

An element was produced using the same procedure as in Example 9 except that a composition prepared by dissolving 1.3% by weight of a high-molecular weight charge transport compound (weight average molecular weight: about 41,200) having a repeating structure represented by the following formula (P-3), 1.3% by weight of the low-molecular weight charge transport compound (M-2), and 0.4% by weight of the electron accepting compound (HI-1) in anisole was used as the hole injection layer-forming composition.

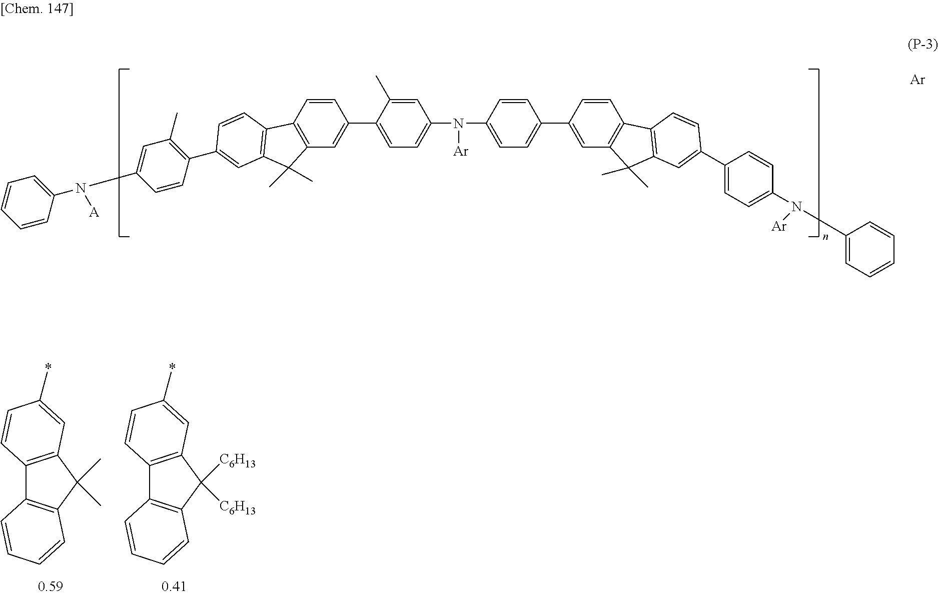

### Comparative Example 13

An element was produced using the same procedure as in Example 9 except that a composition prepared by dissolving 2.6% by weight of the low-molecular weight charge transport compound (M-1) and 0.4% by weight of the electron accepting compound (HI-1) in anisole was used as the hole injection layer-forming composition.

### Example 25

An element was produced using the same procedure as in Example 9 except that a composition prepared by dissolving 1.3% by weight of the high-molecular weight charge transport compound (P-4), 1.3% by weight of the low-molecular weight charge transport compound (M-1), and 0.4% by weight of the electron accepting compound (HI-1) in butyl benzoate was prepared as the hole injection layer-forming composition and that a vacuum drying method was used after the spin coating.

### Example 26

An element was produced using the same procedure as in Example 9 except that a composition prepared by dissolving 1.3% by weight of the high-molecular weight charge transport compound (P-5), 1.3% by weight of the low-molecular weight charge transport compound (M-2), and 0.4% by weight of the electron accepting compound (HI-1) in butyl benzoate was used as the hole injection layer-forming composition and that a vacuum drying method was used after the spin coating.

### Comparative Example 14

An element was produced using the same procedure as in Example 9 except that a composition prepared by dissolving 1.3% by weight of the high-molecular weight charge transport compound (P-1), 1.3% by weight of the low-molecular weight charge transport compound (M-4), and 0.4% by weight of the electron accepting compound (HI-1) in butyl benzoate was used as the hole injection layer-forming composition and that a vacuum drying method was used after the spin coating.

### Example 27

An element was produced using the same procedure as in Example 9 except that a composition prepared by dissolving 1.3% by weight of the high-molecular weight charge transport compound (P-1), 1.3% by weight of the low-molecular weight charge transport compound (M-5), and 0.4% by weight of the electron accepting compound (HI-1) in butyl benzoate was used as the hole injection layer-forming composition and that a vacuum drying method was used after the spin coating.

### Example 28

An element was produced using the same procedure as in Example 9 except that a composition prepared by dissolving 1.3% by weight of the high-molecular weight charge transport compound (P-2), 1.3% by weight of the low-molecular weight charge transport compound (M-6), and 0.4% by weight of the electron accepting compound (HI-1) in butyl benzoate was used as the hole injection layer-forming composition and that a vacuum drying method was used after the spin coating.

### Example 29

An element was produced using the same procedure as in Example 9 except that a composition prepared by dissolving 1.3% by weight of the high-molecular weight charge transport compound (P-1), 1.3% by weight of the low-molecular weight charge transport compound (M-8), and 0.4% by weight of the electron accepting compound (HI-1) in butyl benzoate was used as the hole injection layer-forming composition and that a vacuum drying method was used after the spin coating.

### Example 30

An element was produced using the same procedure as in Example 9 except that a composition prepared by dissolving 1.3% by weight of the high-molecular weight charge transport compound (P-2), 1.3% by weight of the low-molecular weight charge transport compound (M-7), and 0.4% by weight of the electron accepting compound (HI-1) in butyl benzoate was used as the hole injection layer-forming composition and that a vacuum drying method was used after the spin coating.

### Comparative Example 15

An element was produced using the same procedure as in Example 9 except that a composition prepared by dissolving 2.3% by weight of the high-molecular weight charge transport compound (P-1), 0.3% by weight of a low-molecular weight charge transport compound (CBP) shown below, and 0.4% by weight of the electron accepting compound (HI-1) in butyl benzoate was used as the hole injection layer-forming composition and that a vacuum drying method was used after the spin coating.

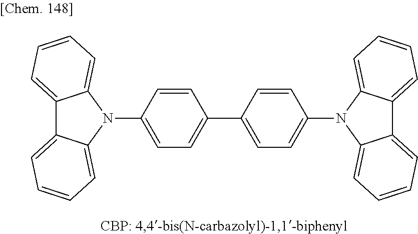 [SMILES: c1ccc2c(c1)c1ccccc1n2-c1ccc(-c2ccc(-n3c4ccccc4c4ccccc43)cc2)cc1]

### [Evaluation of Elements]

The organic electroluminescent elements obtained in Examples 9 to 10 and 25 to 30, Comparative Examples 5 to 7 and 13 to 15, and Reference Example 1 were caused to emit light, and the light obtained was blue light with a peak wavelength of 468 nm. Each of the elements was caused to emit light at 1,000 cd/m², and the voltage (V) and current efficiency (cd/A) in this case were measured. The element was continuously energized at a current density of 20 mA/cm², and a luminance reduction lifetime (when the reduction in luminance reached 90%) was measured. The difference between the voltage of the organic electroluminescent element in Comparative Example 5 and the voltage of the organic electroluminescent element in one of the Examples, Comparative Examples, and Reference Example other than Comparative Example 5, i.e., the value of “the voltage of one of the organic electroluminescent elements other than that in Comparative Example 5−the voltage of the organic electroluminescent element in Comparative Example 5” (which is hereinafter referred to as the “voltage difference”) is shown in Tables 4 and 5.

The ratio of the current luminous efficiency (cd/A) of the organic electroluminescent element in one of the Examples, Comparative Examples, and Reference Example other than Comparative Example 5 relative to that of the organic electroluminescent element in Comparative Example 5, i.e., “the current luminous efficiency of the organic electroluminescent element in one of the Examples, Comparative Examples, and Reference Example other than Comparative Example 5/the current luminous efficiency of the organic electroluminescent element in Comparative Example 5,” (which is hereinafter referred to as the “relative current luminous efficiency”) is shown in Tables 4 and 5.

Each of the organic electroluminescent elements was continuously energized at a current density of 20 mA/cm², and the time (hr) until the luminance of the organic electroluminescent element decreased to 90% of the initial luminance was measured. This value is defined as LT90. The ratio of the LT90 of the organic electroluminescent element in one of the Examples, Comparative Examples, and Reference Example other than Comparative Example 5 to that of the organic electroluminescent element in Comparative Example 5, i.e., “the LT90 of one of the organic electroluminescent elements other than that in Comparative Example 5/the LT90 of the organic electroluminescent element in Comparative Example 5,” (which is hereinafter referred to as the “relative lifetime”) was determined and is shown in Tables 4 and 5.

TABLE 4

| | High- | Low- | | | | |
|---|---|---|---|---|---|---|
| | molecular | molecular | | | | |
| | weight | weight | | | Relative | |
| | charge | charge | Electron | Voltage | current | |
| | transport | transport | accepting | difference/ | luminous | Relative |
| | compound | compound | compound | V | efficiency | lifetime |
| Example 9 | P-1 | M-1 | HI-1 | −0.2 | 1.13 | 3.3 |
| | ∘ | ∘ | ∘ | | | |
| Example 10 | P-2 | M-2 | HI-1 | −0.1 | 1.13 | 3.8 |
| | ∘ | ∘ | ∘ | | | |
| Reference | P-1 | — | HI-1 | −0.2 | 1.16 | 3.8 |
| Example 1 | ∘ | — | ∘ | | | |
| Comparative | P-2 | M-3 | HI-1 | 0 | 1.00 | 1.0 |
| Example 5 | ∘ | x | ∘ | | | |
| Comparative | — | M-2 | HI-1 | 2.6 | 1.16 | 2.3 |
| Example 6 | — | ∘ | ∘ | | | |
| Comparative | | M-2 | HI-1 | 0.3 | 1.19 | 2.4 |
| Example 7 | x | ∘ | ∘ | | | |

TABLE 5

| | High- | Low- | | | | |
|---|---|---|---|---|---|---|
| | molecular | molecular | | | | |
| | weight | weight | | | Relative | |
| | electron | electron | Electron | | current | |
| | transport | transport | accepting | Voltage | luminous | Relative |
| | compound | compound | compound | difference/V | efficiency | lifetime |
| Comparative | — | M-1 | HI-1 | −0.1 | 1.11 | 2.8 |
| Example 13 | | ∘ | ∘ | | | |
| Example 25 | P-4 | M-1 | HI-1 | −0.3 | 1.19 | 5.5 |
| | ∘ | ∘ | ∘ | | | |
| Example 26 | P-5 | M-2 | HI-1 | 0.7 | 1.14 | 5.1 |
| | ∘ | ∘ | ∘ | | | |
| Comparative | P-1 | M-4 | HI-1 | 1.9 | 1.16 | 3.0 |
| Example 14 | ∘ | ∘ | ∘ | | | |
| Example 27 | P-1 | M-5 | HI-1 | 0.1 | 0.99 | 3.5 |
| | ∘ | ∘ | ∘ | | | |
| Example 28 | P-2 | M-6 | HI-1 | 0.1 | 1.13 | 5.3 |
| | ∘ | ∘ | ∘ | | | |
| Example 29 | P-1 | M-8 | HI-1 | 0.5 | 1.1 | 3.5 |
| | ∘ | ∘ | ∘ | | | |
| Example 30 | P-2 | M-7 | HI-1 | −0.2 | 1.02 | 3.8 |
| | ∘ | ∘ | ∘ | | | |
| Comparative | P-1 | CBP | HI-1 | −0.1 | 1.1 | 1.4 |
| Example 15 | ∘ | x | ∘ | | | |

In Tables 4 and 5, the symbols ∘ and x shown below the materials have the following meanings. The symbol ∘ is assigned to a material having a crosslinking group, and the symbol x is assigned to a material having no crosslinking group. As can be seen from the results in Tables 4 and 5, with the compositions including crosslinking groups as described in the present invention, the element characteristics such as voltage, current luminous efficiency, and lifetime did not deteriorate and were good.

However, the low-molecular weight charge transport compound (M-4) does not satisfy the formulas for the low-molecular weight charge transport compound defined in the invention. Therefore, although sufficient flatness was obtained as shown in Comparative Example 9, the increase in voltage was very large, and the characteristics were found to deteriorate.

### Example 31

The same composition as that in Reference Example 1 was prepared as the hole injection layer-forming composition, and a hole injection layer was formed in the same manner as in Example 9.

Next, a composition was prepared by dissolving 1.5% by weight of the high-molecular weight charge transport compound (P-1) and 1.5% by weight of the low-molecular weight charge transport compound (M-1) in butyl benzoate. This solution was applied by spin coating to the substrate with the hole injection layer deposited thereon in a nitrogen glove box, then vacuum dried, and dried on a hot plate at 230° C. for 30 minutes in the nitrogen glove box, and a uniform thin film with a thickness of 40 nm was thereby formed and used as a hole transport layer.

Then the same procedure as in Example 9 was repeated to produce an element.

### Example 32

An element was produced using the same procedure as in Example 31 except that a composition was prepared by dissolving 1.5% by weight of the high-molecular weight charge transport compound (P-2) and 1.5% by weight of the low-molecular weight charge transport compound (M-2) in butyl benzoate and that this composition was used to form the hole transport layer.

### Example 33

An element was produced using the same procedure as in Example 31 except that a composition was prepared by dissolving 2.7% by weight of the high-molecular weight charge transport compound (P-2) and 0.3% by weight of the low-molecular weight charge transport compound (M-9) in butyl benzoate and that this composition was used to form the hole transport layer.

### Example 34

An element was produced using the same procedure as in Example 31 except that a composition was prepared by dissolving 1.5% by weight of the high-molecular weight charge transport compound (P-7) and 1.5% by weight of the low-molecular weight charge transport compound (M-2) in butyl benzoate and that this composition was used to form the hole transport layer.

### Comparative Example 16

An element was produced using the same procedure as in Example 31 except that a composition was prepared by dissolving 3.0% by weight of the low-molecular weight charge transport compound (M-2) in butyl benzoate and that this composition was used to form the hole transport layer.

### Comparative Example 17

An element was produced using the same procedure as in Example 31 except that a composition was prepared by dissolving 3.0% by weight of the low-molecular weight charge transport compound (P-1) in butyl benzoate and that this composition was used to form the hole transport layer.

### Example 35

An element was produced using the same procedure as in Example 31 except that a composition was prepared by dissolving 1.5% by weight of the high-molecular weight charge transport compound (P-1) and 1.5% by weight of the low-molecular weight charge transport compound (M-5) in butyl benzoate and that this composition was used to form the hole transport layer.

### [Evaluation of Elements]

The organic electroluminescent elements obtained in Examples 31 to 35 and Comparative Examples 16 to 17 were caused to emit light, and the light obtained was blue light with a peak wavelength of 468 nm. Each of the elements was caused to emit light at 1,000 cd/m², and the voltage (V) and current efficiency (cd/A) in this case were measured. The difference between the voltage of the organic electroluminescent element in Comparative Example 17 and the voltage of the organic electroluminescent element in one of the Examples and Comparative Examples other than Comparative Example 17, i.e., “the voltage of one of the organic electroluminescent elements other than that in Comparative Example 17−the voltage of the organic electroluminescent element in Comparative Example 17,” (which is hereinafter referred to as the “voltage difference”) is shown in Table 6.

The ratio of the current luminous efficiency (cd/A) of the organic electroluminescent element in one of the Examples and Comparative Examples other than Comparative Example 17 to the current luminous efficiency of the organic electroluminescent element in Comparative Example 17, i.e., “the current luminous efficiency of one of the organic electroluminescent elements other than that in Comparative Example 17/the current luminous efficiency of the organic electroluminescent element in Comparative Example 17,” (which is hereinafter referred to as the “relative current luminous efficiency” is shown in Table 6.

TABLE 6

| | High- | Low- | | | |
|---|---|---|---|---|---|
| | molecular | molecular | | | |
| | weight | weight | | | Relative |
| | electron | electron | Electron | | current |
| | transport | transport | accepting | Voltage | luminous |
| | compound | compound | compound | difference/V | efficiency |
| Example 31 | P-1 | M-1 | — | −1.5 | 2.7 |
| | ∘ | ∘ | | | |
| Example 32 | P-2 | M-2 | — | −0.4 | 5.3 |
| | ∘ | ∘ | | | |
| Example 33 | P-2 | M-9 | — | 0.7 | 2.2 |
| | ∘ | ∘ | | | |
| Example 34 | P-7 | M-2 | — | 0.8 | 6.3 |
| | ∘ | ∘ | | | |
| Comparative | — | M-2 | — | 4.9 | 2.6 |
| Example 16 | | ∘ | | | |
| Comparative | P-1 | — | — | 0.0 | 1.0 |
| Example 17 | ∘ | | | | |
| Example 35 | P-1 | M-5 | — | −1.8 | 4.4 |
| | ∘ | ∘ | | | |

As can be seen from the results in Table 6, with the composition of the invention containing the high-molecular weight charge transport compound having a crosslinking group and the low-molecular weight charge transport compound having a crosslinking group, the element characteristics such as the voltage and current luminous efficiency did not deteriorate significantly and were good.

### Example 36

The same composition as that in Reference Example 1 was prepared as the hole injection layer-forming composition, and a hole injection layer was formed in the same manner as in Example 9.

Next, a composition was prepared by dissolving 1.5% by weight of the high-molecular weight charge transport compound (P-1) and 1.5% by weight of the low-molecular weight charge transport compound (M-5) in butyl benzoate. This solution was applied by spin coating to the substrate with the hole injection layer deposited thereon in a nitrogen glove box, then vacuum-dried, and dried on a hot plate at 230° C. for 30 minutes in the nitrogen glove box, and a uniform thin film with a thickness of 40 nm was thereby formed and used as a hole transport layer.

Next, a host composition having the following structural formal (GH-1), the low-molecular weight charge transport compound (M-3), and a dopant compound having the following structural formula (GD-1) were dissolved at a ratio of 50 parts by mass:50 parts by mass:42 parts by mass in cyclohexylbenzene to prepare a 7.1% by weight solution.

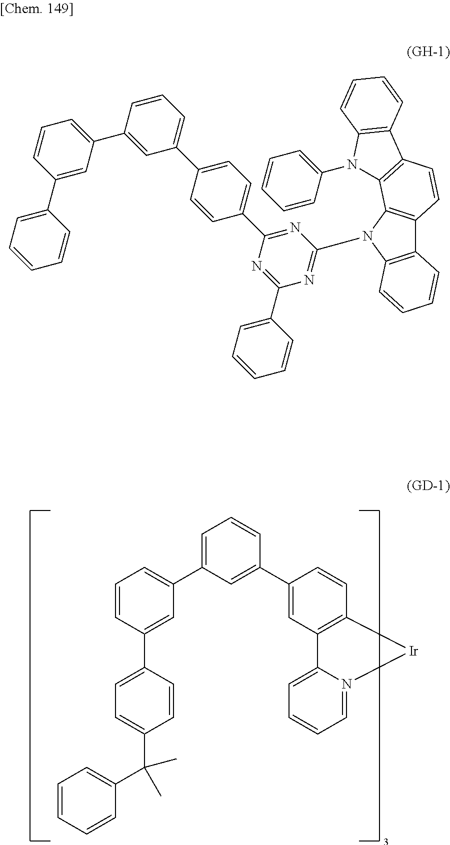

This solution was applied by spin coating to the substrate with the hole transport layer deposited thereon in a nitrogen glove box to form a uniform thin film having a thickness of 60 nm, and the resulting film was dried on a hot plate at 120° C. for 20 minutes in the nitrogen glove box and used as a light-emitting layer. Then the same procedure as in Example 9 was repeated to produce an element.

### Example 37

An element was produced using the same procedure as in Example 36 except that a composition was prepared by dissolving 2.7% by weight of the high-molecular weight charge transport compound (P-2) and 0.3% by weight of the low-molecular weight charge transport compound (M-6) in butyl benzoate and that this composition was used to form the hole transport layer.

### Example 38

An element was produced using the same procedure as in Example 36 except that a composition was prepared by dissolving 1.5% by weight of the high-molecular weight charge transport compound (P-1) and 1.5% by weight of the low-molecular weight charge transport compound (M-8) in butyl benzoate and that this composition was used to form the hole transport layer.

### Example 39

An element was produced using the same procedure as in Example 36 except that a composition was prepared by dissolving 1.5% by weight of the high-molecular weight charge transport compound (P-2) and 1.5% by weight of the low-molecular weight charge transport compound (M-7) in butyl benzoate and that this composition was used to form the hole transport layer.

### Comparative Example 18

An element was produced using the same procedure as in Example 36 except that a composition was prepared by dissolving 3.0% by weight of the high-molecular weight charge transport compound (P-1) in butyl benzoate and that this composition was used to form the hole transport layer.

### [Evaluation of Elements]

The organic electroluminescent elements obtained in Examples 36 to 39 and Comparative Example 18 were caused to emit light, and the light obtained was green light with a peak wavelength of 523 nm. Each of the elements was caused to emit light at 1,000 cd/m², and the voltage (V) and current efficiency (cd/A) in this case were measured. The difference between the voltage of the organic electroluminescent element in Comparative Example 18 and the voltage of the organic electroluminescent element in one of the Examples and Comparative Example other than Comparative Example 18, i.e., “the voltage of one of the organic electroluminescent elements other than that in Comparative Example 18−the voltage of the organic electroluminescent element in Comparative Example 18,” (which is hereinafter referred to as the “voltage difference”) is shown in Table 7.

The ratio of the current luminous efficiency (cd/A) of the organic electroluminescent element in one of the Examples and Comparative Example other than Comparative Example 18 to the current luminous efficiency of the organic electroluminescent element in Comparative Example 18, i.e., “the current luminous efficiency of one of the organic electroluminescent elements other than that in Comparative Example 18/the current luminous efficiency of the organic electroluminescent element in Comparative Example 18,” (which is hereinafter referred to as the “relative current luminous efficiency” is shown in Table 5.

TABLE 7

| | High- | Low- | | | |
|---|---|---|---|---|---|
| | molecular | molecular | | | |
| | weight | weight | | | Relative |
| | electron | electron | Electron | | current |
| | transport | transport | accepting | Voltage | luminous |
| | compound | compound | compound | difference/V | efficiency |
| Example 36 | P-1 | M-5 | — | −4.5 | 2.5 |
| | ∘ | ∘ | | | |
| Example 37 | P-2 | M-6 | — | 0.9 | 1.3 |
| | ∘ | ∘ | | | |
| Example 38 | P-1 | M-8 | — | −0.2 | 1.9 |
| | ∘ | ∘ | | | |
| Example 39 | P-2 | M-7 | — | −0.3 | 2.3 |
| | ∘ | ∘ | | | |
| Comparative | P-1 | — | — | 0.0 | 1.0 |
| Example 18 | ∘ | | | | |

As can be seen from the results in Table 7, with the composition of the invention containing the high-molecular weight charge transport compound having a crosslinking group and the low-molecular weight charge transport compound having a crosslinking group, the element characteristics such as the voltage and current luminous efficiency did not deteriorate significantly and were good.

Although the present invention has been described in detail by way of the specific modes, it is apparent for those skilled in the art that various changes can be made without departing from the spirit and scope of the present invention.

The present application is based on Japanese Patent Application No. 2021-184744 filed on Nov. 12, 2021, the entire contents of which are incorporated herein by reference.

### REFERENCE SIGNS LIST

1 substrate
2 anode
3 hole injection layer
4 hole transport layer
5 light-emitting layer
6 hole blocking layer
7 electron transport layer
8 electron injection layer
9 cathode
10 organic electroluminescent element

1. A composition, comprising:
at least one high-molecular weight charge transport compound having a weight average molecular weight of 10,000 or more and having a crosslinking group;
at least one low-molecular weight charge transport compound having a molecular weight of 5,000 or less and having a crosslinking group; and
at least one aromatic organic solvent,
wherein the low-molecular weight charge transport compound is selected from the group consisting of a compound represented by formula (71) below, a compound represented by formula (72) below, a compound represented by formula (73) below, a compound represented by formula (74) below, a compound represented by formula (75) below, a compound represented by formula (1) below, and a compound represented by formula (2) below, 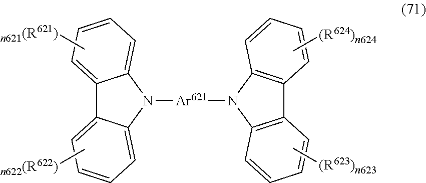
wherein, in formula (71),
Ar⁶²¹ represents a divalent aromatic hydrocarbon group having 6 to 50 carbon atoms and optionally having a substituent;
R⁶²¹, R⁶²², R⁶²³, and R⁶²⁴ each independently represent a deuterium atom, a halogen atom, a monovalent aromatic hydrocarbon group having 6 to 50 carbon atoms and optionally having a substituent and/or a crosslinking group, or a crosslinking group;
formula (71) includes at least two crosslinking groups;
n621, n622, n623, and n624 are each independently an integer of 0 to 4; and
the sum of n621, n622, n623, and n624 is 1 or more, 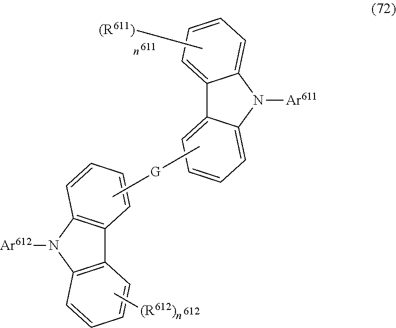
wherein, in formula (72),
Ar⁶¹¹ and Ar⁶¹² each independently represent a divalent aromatic hydrocarbon group having 6 to 50 carbon atoms and optionally having a substituent and/or a crosslinking group;
R⁶¹¹ and R⁶¹² are each independently a deuterium atom, a halogen atom, a monovalent aromatic hydrocarbon group having 6 to 50 carbon atoms and optionally having a substituent and/or a crosslinking group, or a crosslinking group;
G represents a single bond or a divalent aromatic hydrocarbon group having 6 to 50 carbon atoms and optionally having a substituent and/or a crosslinking group;
the compound represented by formula (72) has at least two crosslinking groups; and
n⁶¹¹ and n⁶¹² are each independently an integer of 0 to 4, 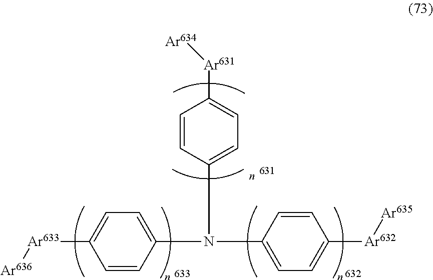
wherein, in formula (73),
Ar⁶³¹, Ar⁶³², and Ar⁶³³ each independently represent a direct bond or an aromatic hydrocarbon group having 6 to 30 carbon atoms optionally having a monovalent substituent;
Ar⁶³⁴, Ar⁶³⁵, and Ar⁶³⁶ are each independently a monovalent aromatic hydrocarbon group having 6 to 30 carbon atoms or a monovalent aromatic heterocyclic group having 3 to 24 carbon atoms, and the monovalent aromatic hydrocarbon group and the monovalent aromatic heterocyclic group may each optionally have a substituent or a crosslinking group;
at least two selected from Ar⁶³⁴, Ar⁶³⁵, and Ar⁶³⁶ each have a crosslinking group;
n⁶³¹, n⁶³², and n⁶³³ each independently represent an integer of 0 to 3; and
the crosslinking groups included in Ar⁶³⁴, Ar⁶35, and Ar⁶³⁶ are each independently formula (a) or (b) below, 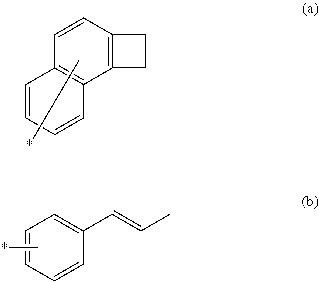
wherein, in formulas (a) and (b), * represents a position of bonding to Ar⁶³⁴, Ar⁶³⁵, or Ar⁶³⁶, 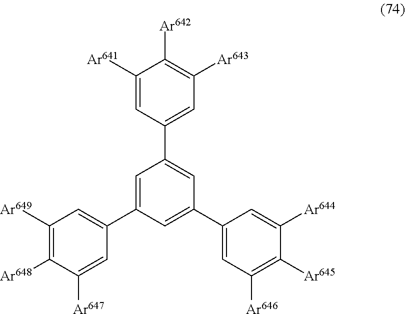
wherein, in formula (74),
Ar⁶⁴¹ to Ar⁶⁴⁹ each independently represent a hydrogen atom, a benzene ring structure optionally having a substituent and/or a crosslinking group, or a structure in which 2 to 10 benzene ring structures each optionally having a substituent and/or a crosslinking group are linked together in a non-branched or branched manner; and
the compound represented by formula (74) has at least two crosslinking groups, 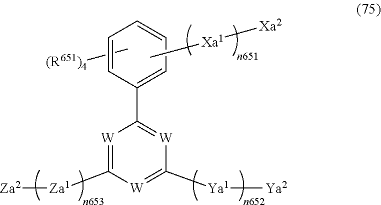
wherein, in formula (75),
W's each independently represent CH or N, and at least one W is N;
Xa¹, Ya¹, and Za¹ each independently represent a divalent aromatic hydrocarbon group having 6 to 30 carbon atoms and optionally having a substituent or a divalent aromatic heterocyclic group having 3 to 30 carbon atoms and optionally having a substituent;
Xa², Ya², and Za² each independently represent a hydrogen atom, an aromatic hydrocarbon group having 6 to 30 carbon atoms and optionally having a substituent and/or a crosslinking group, an aromatic heterocyclic group having 3 to 30 carbon atoms and optionally having a substituent and/or a crosslinking group, or a crosslinking group;
n651, n652, and n653 each independently represent an integer of 0 to 6;
at least one of n651, n652, and n653 is an integer of 1 or more;
when n651 is 2 or more, a plurality of Xa¹'s present may be the same or different;
when n652 is 2 or more, a plurality of Ya¹'s present may be the same or different;
when n653 is 2 or more, a plurality of Za¹'s present may be the same or different;
at least two of Xa², Ya², and Za² each have a crosslinking group;
each of four R⁶⁵¹'s represents a hydrogen atom or a substituent, and the four R⁶⁵¹'s may be the same or different; and
when n651, n652, or n653 is 0, a corresponding one of Xa², Ya², and Za² is not a hydrogen atom, 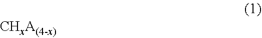
wherein, in formula (1),
C represents a carbon atom, and H represents a hydrogen atom;
A's each independently represent a substituent represented by formula (2′) below; and
x represents an integer of 0 to 2, 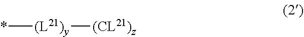
wherein, in formula (2′),
L²¹'s each independently represent a bonding group optionally having a substituent;
CL²¹'s each independently represent a crosslinking group represented by formula (3) below;
* represents a direct bond to the carbon atom in formula (1);
y represents an integer of 1 to 6, and z represents an integer of 0 to 4;
when z is 0, a hydrogen atom instead of CL²¹ is bonded to a bonding group L²¹; and
three or more CL²¹'s are present in the compound represented by formula (1), 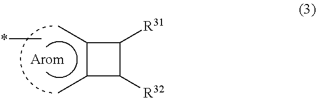
wherein, in formula (3),
Arom represents an aromatic ring having 3 to 30 carbon atoms and optionally having a substituent;
R³¹ and R³² each independently represent a hydrogen atom or an alkyl group;
* represents a direct bond to L²¹ in formula (2′), and the direct bond to formula (2′) is bonded to Arom, 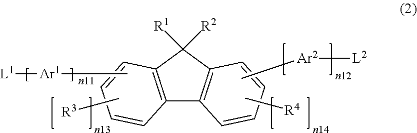
wherein, in formula (2),
Ar¹ and Ar² each independently represent a divalent aromatic group having 6 to 60 carbon atoms and optionally having a substituent;
R¹, R², R³, and R⁴ each independently represent an alkyl group optionally having a substituent or an aromatic group optionally having a substituent;
R¹ and R², R³'s, or R⁴'s may be bonded together to form a ring;
L¹ and L² each independently represent a crosslinking group;
n11 and n12 each independently represent an integer of 0 to 5; and
n13 and n14 each independently represent an integer of 0 to 3.

2. The composition according to claim 1, further comprising at least one electron accepting compound having a fluorine atom and a crosslinking group in a molecular structure thereof.

3. The composition according to claim 2, wherein each crosslinking group included in the high-molecular weight charge transport compound, each crosslinking group included in the low-molecular weight charge transport compound, except for the crosslinking groups included in Ar⁶³⁴, Ar⁶³⁵, and Ar⁶³⁶ in formula (73), and each crosslinking group included in the electron accepting compound are each selected from the following group T of crosslinking groups:
<group T of crosslinking groups> 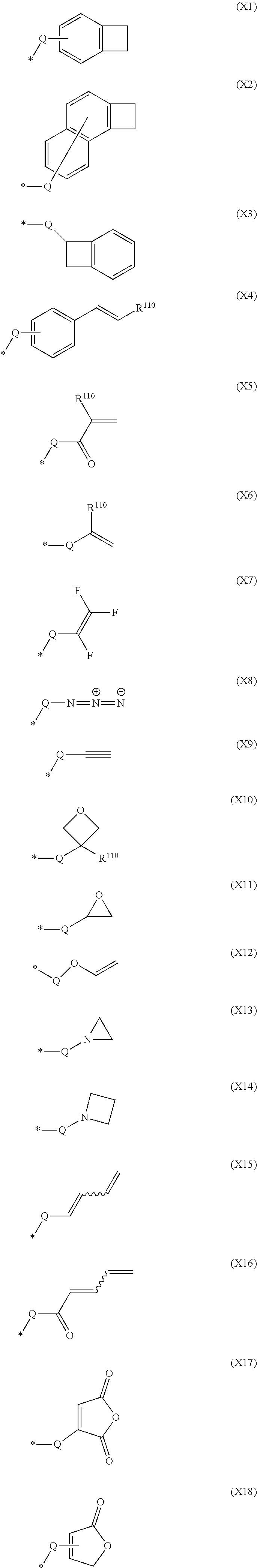
wherein, in formulas (X1) to (X18), Q represents a direct bond or a linking group;
* represents a bonding position;
R¹¹⁰ in each of formulas (X4), (X5), (X6), and (X10) represents a hydrogen atom or an alkyl group optionally having a substituent;
each of the benzene rings and the naphthalene ring in formula (X1) to (X4) may optionally have a substituent, and any of the substituents may be bonded together to form a ring; and
each cyclobutene ring in formula (X1) to (X3) may optionally have a substituent.

4. The composition according to claim 3, wherein at least one of the high-molecular weight charge transport compound, the low-molecular weight charge transport compound, and the electron accepting compound includes a crosslinking group represented by formula (X2) or (X4) included in the group T of crosslinking groups.

5. The composition according to claim 3, wherein Q is a divalent aromatic hydrocarbon group optionally having a substituent.

6. The composition according to claim 1, wherein the high-molecular weight charge transport compound having a crosslinking group includes a repeating unit represented by formula (50) below: 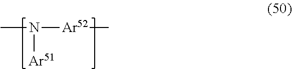
wherein, in formula (50),
Ar⁵¹ represents an aromatic hydrocarbon group, an aromatic heterocyclic group, or a group in which a plurality of groups selected from aromatic hydrocarbon groups and aromatic heterocyclic groups are linked together;
Ar⁵² represents a divalent aromatic hydrocarbon group, a divalent aromatic heterocyclic group, or a divalent group in which a plurality of groups selected from the group consisting of divalent aromatic hydrocarbon groups and divalent aromatic heterocyclic groups are linked together directly or via a linking group;
Ar⁵¹ and Ar⁵² do not form a ring via a single bond or a linking group; and
Ar⁵¹ and Ar⁵² may each optionally have a substituent and/or a crosslinking group.

7. The composition according to claim 6, wherein the repeating unit represented by formula (50) is a repeating unit represented by the following formula (60): 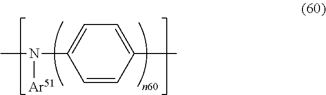
wherein, in formula (60),
Ar⁵¹ is the same as Ar⁵¹ in formula (50) above; and
n60 represents an integer of 1 to 5.

8. The composition according to claim 6, wherein the repeating unit represented by formula (50) is a repeating unit represented by formula (54), (55), (56), or (57) below: 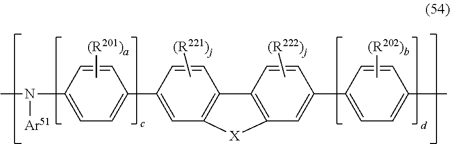
wherein, in formula (54),
Ar⁵¹ is the same as Ar⁵¹ in formula (50) above;
X is —C(R²⁰⁷)(R²⁰⁸)—, —N(R²⁰⁹)—, or —C(R²¹¹)(R²¹²)—C(R²¹³)(R²¹⁴)—;
R²⁰¹, R²⁰², R²²¹, and R²²² are each independently an alkyl group optionally having a substituent and/or a crosslinking group;
R²⁰⁷ to R²⁰⁹ and R²¹¹ to R²¹⁴ are each independently a hydrogen atom, an alkyl group optionally having a substituent and/or a crosslinking group, an aralkyl group optionally having a substituent and/or a crosslinking group, or an aromatic hydrocarbon group optionally having a substituent and/or a crosslinking group;
a and b are each independently an integer of 0 to 4;
c is an integer of 0 to 3;
d is an integer of 0 to 4; and
i and j are each independently an integer of 0 to 3, 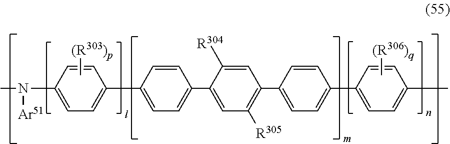
wherein, in formula (55),
Ar⁵¹ is the same as Ar⁵¹ in formula (54) above;
R³⁰³ and R³⁰⁶ each independently represent an alkyl group optionally having a substituent and/or a crosslinking group;
R³⁰⁴ and R³⁰⁵ each independently represent an alkyl group optionally having a substituent and/or a crosslinking group, an alkoxy group optionally having a substituent and/or a crosslinking group, or an aralkyl group optionally having a substituent and/or a crosslinking group;
l is 0 or 1;
m is 1 or 2;
n is 0 or 1;
p is 0 or 1; and
q is 0 or 1, 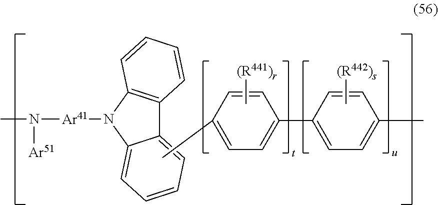
wherein, in formula (56),
Ar⁵¹ is the same as Ar⁵¹ in formula (54) above;
Ar⁴¹ represents a divalent aromatic hydrocarbon group optionally having a substituent, a divalent aromatic heterocyclic group optionally having a substituent, or a divalent group in which a plurality of groups selected from the group consisting of divalent aromatic hydrocarbon groups and divalent aromatic heterocyclic groups are linked together directly or via a linking group;
R⁴⁴¹ and R⁴⁴² each independently represent an alkyl group optionally having a substituent;
t is 1 or 2;
u is 0 or 1; and
r and s are each independently an integer of 0 to 4, 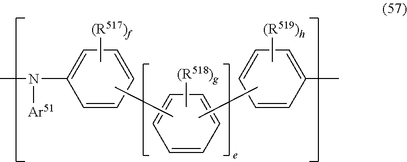
wherein, in formula (57),
Ar⁵¹ is the same as Ar⁵¹ in formula (50) above;
R⁵¹⁷ to R¹⁹ each independently represent an alkyl group optionally having a substituent and/or a crosslinking group, an alkoxy group optionally having a substituent and/or a crosslinking group, an aralkyl group optionally having a substituent and/or a crosslinking group, an aromatic hydrocarbon group optionally having a substituent and/or a crosslinking group, or an aromatic heterocyclic group optionally having a substituent and/or a crosslinking group;
f, g, and h each independently represent an integer of 0 to 4; and
e represents an integer of 0 to 3,
provided that, when g is 1 or more, e is 1 or more.

9. The composition according to claim 8, wherein X in formula (54) above is —C(R²⁰⁷)(R²⁰⁸)—, —N(R²⁰⁹)—, or —C(R²¹¹)(R²¹²)—C(R²¹³)(R²¹⁴)—; and at least one of R²⁰⁷ and R²⁰⁸, R²⁰⁹, or at least one of R²¹¹ to R²¹⁴ is an alkyl group having a crosslinking group, an aralkyl group having a crosslinking group, or an aromatic hydrocarbon group having a crosslinking group.

10. The composition according to claim 8, wherein the high-molecular weight charge transport compound having a crosslinking group further includes, as the repeating unit represented by formula (50) above, a repeating unit represented by formula (60) below in addition to at least one selected from the repeating unit represented by formula (54) above, the repeating unit represented by formula (55) above, the repeating unit represented by formula (56) above, and the repeating unit represented by formula (57) above: 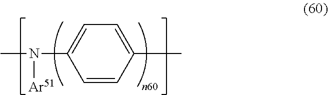
wherein, in formula (60),
Ar⁵¹ is the same as Ar⁵¹ in formula (50) above; and
n60 represents an integer of 1 to 5.

11. The composition according to claim 6, wherein Ar⁵¹ has a crosslinking group.

12. The composition according to claim 1, wherein Ar⁶²¹ in formula (71) above is a divalent group formed by bonding a plurality of structures selected from 1 to 4 benzene rings each optionally having a substituent and 1 or 2 fluorene rings each optionally having a substituent in any order in a linear or branched manner.

13. The composition according to claim 1, wherein Ar⁶²¹ in formula (71) above has at least one partial structure selected from the following formulas (71-1) to (71-11) and (71-21) to (71-24): 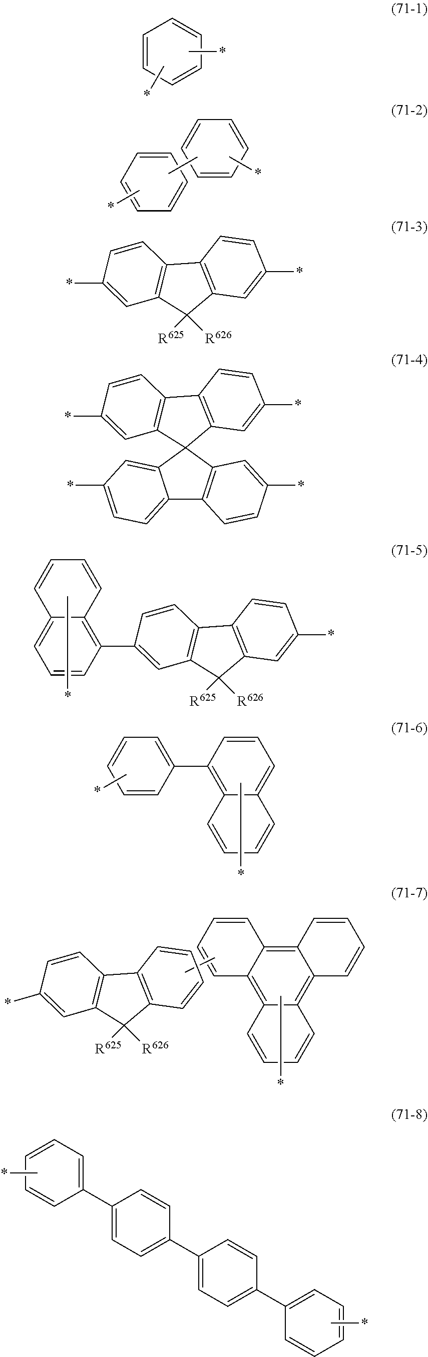 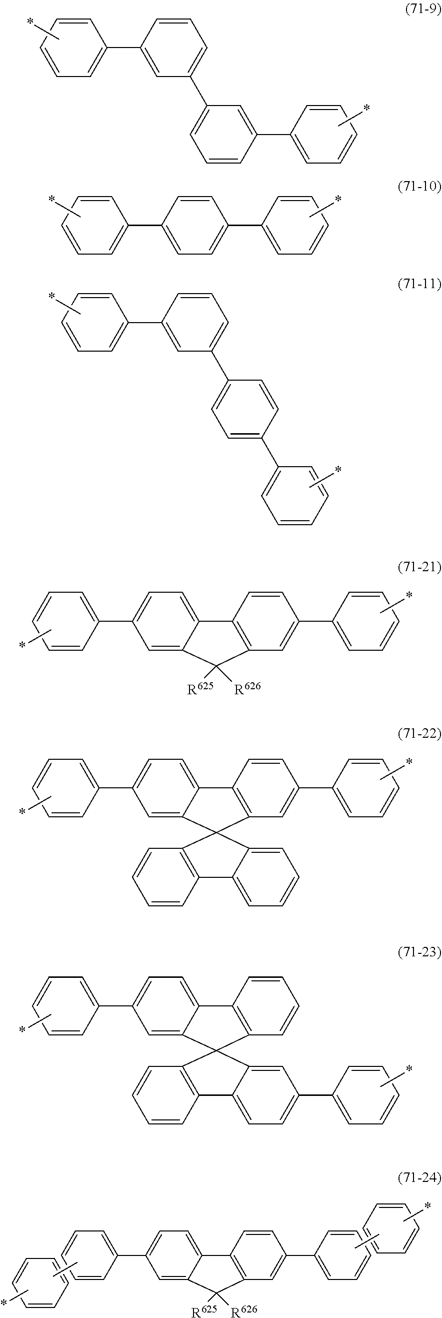
in each of formulas (71-1) to (71-11) and (71-21) to (71-24) above,
each * represents a bond to an adjacent structure or a hydrogen atom; when two *'s are present, at least one of the two *'s represents a position of bonding to an adjacent structure; when four *'s are present, at least one of any two of the four *'s represents a position of bonding to an adjacent structure;
R⁶²⁵ and R⁶²⁶ each independently represent an alkyl group having 6 to 12 carbon atoms, an alkenyl group, an alkynyl group, an alkoxy group, an aryloxy group, an alkoxycarbonyl group, an acyl group, a halogen atom, a haloalkyl group, an alkylthio group, an arylthio group, a silyl group, a siloxy group, a cyano group, an aralkyl group, or a monovalent aromatic hydrocarbon group having 6 to 30 carbon atoms; and R⁶²⁵ and R⁶²⁶ may be bonded together to form a ring.

14. The composition according to claim 1, wherein R⁶²¹, R⁶²², R⁶²³, and R⁶²⁴ in formula (71) above are each independently an aromatic hydrocarbon group having 6 to 50 carbon atoms and optionally having a crosslinking group or a crosslinking group.

15. The composition according to claim 1, wherein, in formula (71) above, n621 and n623 are each 1; n622 and n624 are each 0; and R⁶²¹ and R⁶²³ are each independently an aromatic hydrocarbon group having 6 to 50 carbon atoms and substituted with a crosslinking group or a crosslinking group.

16. The composition according to claim 1, wherein Ar⁶¹ and Ar⁶¹² in formula (72) above are each independently a phenyl group having a crosslinking group or a monovalent group that includes a plurality of benzene rings bonded together in a linear or branched manner and that has a crosslinking group.

17. The composition according to claim 1, wherein at least one of Ar⁶¹¹ and Ar⁶¹² in formula (72) above has at least one partial structure selected from the following formulas (72-1) to (72-6): 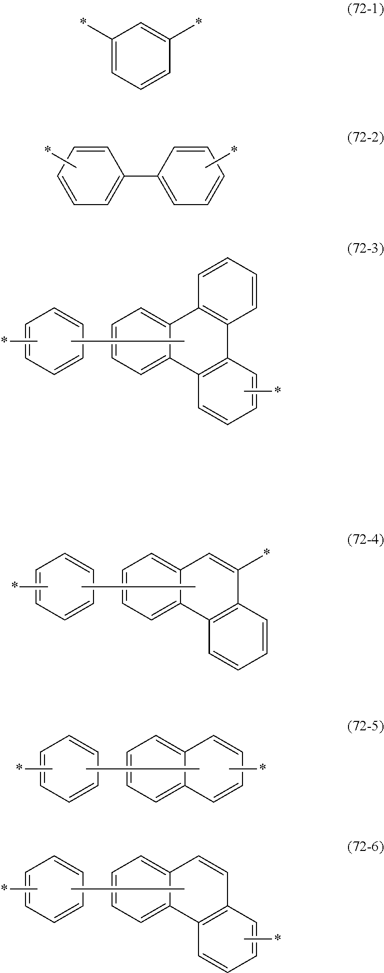
in each of formulas (72-1) to (72-6) above, each * represents a bond to an adjacent structure or a hydrogen atom; and at least one of two *'s represents a position of bonding to an adjacent structure.

18. The composition according to claim 1, wherein, in formula (72) above, n⁶¹¹ and n⁶¹² are each 0.

19. The composition according to claim 1, wherein, in formula (72) above, G is a single bond.

20. The composition according to claim 2, wherein the electron accepting compound is represented by the following formula (81): 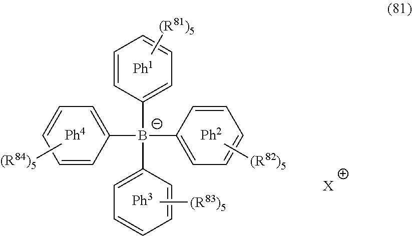
wherein, in formula (81), five R⁸¹'s, five R⁸²'s, five R⁸³'s, five R⁸⁴'s are each independent; R⁸¹'s to R⁸⁴'s each independently represent a hydrogen atom, a deuterium atom, a halogen atom, an aromatic hydrocarbon group having 6 to 50 carbon atoms and optionally having a substituent and/or a crosslinking group, an aromatic heterocyclic group having 3 to 50 carbon atoms and optionally having a substituent and/or a crosslinking group, a fluorine-substituted alkyl group having 1 to 12 carbon atoms, or a crosslinking group;
Ph¹, Ph², Ph³, Ph⁴ are symbols representing four benzene rings; and
X⁺ represents a counter cation.

21. The composition according to claim 20, wherein, in formula (81) above, at least one of -Ph¹-(R⁸¹)₅, -Ph²-(R⁸²)₅, -Ph³-(R⁸³)₅, and -Ph⁴-(R⁸⁴)₅ is a group represented by the following formula (84) and having four fluorine atoms: 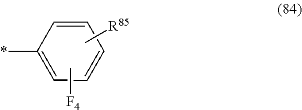
wherein, in formula (84), * represents a bond to boron B in formula (81);
F₄ represents substitution with four fluorine atoms; and
R⁸⁵ represents an aromatic hydrocarbon group optionally having a substituent and/or a crosslinking group or a crosslinking group.

22. The composition according to claim 1, wherein the substituents included in the high-molecular weight charge transport compound and the low-molecular weight charge transport compound are each independently selected from the following substituent group X:
<substituent group X>
alkyl groups having 1 to 24 carbon atoms,
alkenyl group having 2 to 24 carbon atoms,
alkynyl groups having 2 to 24 carbon atoms,
alkoxy groups having 1 to 24 carbon atoms,
aryloxy groups and heteroaryloxy groups having 4 to 36 carbon atoms,
alkoxycarbonyl groups having 2 to 24 carbon atoms,
dialkylamino groups having 2 to 24 carbon atoms,
diarylamino groups having 10 to 36 carbon atoms,
arylalkylamino groups having 7 to 36 carbon atoms,
acyl groups having 2 to 24 carbon atoms,
halogen atoms,
haloalkyl groups having 1 to 12 carbon atoms,
alkylthio groups having 1 to 24 carbon atoms,
arylthio groups having 4 to 36 carbon atoms,
silyl groups having 2 to 36 carbon atoms,
siloxy groups having 2 to 36 carbon atoms,
a cyano group,
aromatic hydrocarbon groups having 6 to 36 carbon atoms, and
aromatic heterocyclic groups having 4 to 36 carbon atoms,
wherein each of the above substituents may have a linear, branched, or cyclic structure, and wherein, when any of the substituents are adjacent to each other, the substituents adjacent to each other may be bonded together to form a ring.

23. The composition according to claim 1, wherein the at least one aromatic organic solvent comprises two or more aromatic organic solvents having different boiling points, and wherein the two or more aromatic organic solvents include an aromatic organic solvent having a boiling point of 270° C. or higher.

24. The composition according to claim 1, wherein a content of the low-molecular weight charge transport compound with respect to the total amount of functional materials contained in the composition is 10% by weight to 75% by weight.

25. A method for manufacturing an organic electroluminescent element using the composition according to claim 1, the method comprising:
applying the composition to regions separated by a partition wall layer by printing using an inkjet method;
vacuum-drying the printed composition in a vacuum chamber to volatilize the organic solvent; and
baking the vacuum-dried composition at high temperature.

26. The method for manufacturing an organic electroluminescent element according to claim 25, wherein, in the vacuum-drying in the vacuum chamber, the time required for the pressure in the vacuum chamber to reach a pressure lower than the vapor pressure of an organic solvent having the lowest vapor pressure among the at least one organic solvent contained in the composition is 60 seconds or longer and 1800 seconds or shorter.

27. The method for manufacturing an organic electroluminescent element according to claim 25, wherein the composition is applied by printing such that films having two different thicknesses equal to or more than 10 nm are deposited, and the composition is vacuum-dried in one vacuum chamber simultaneously.
